(19) United States
(12) Patent Application Publication
(10) Pub. No.: US 2024/0251675 A1
(43) Pub. Date: Jul. 25, 2024

(54) LIGHT EMITTING ELEMENT AND POLYCYCLIC COMPOUND FOR THE SAME

(71) Applicant: Samsung Display Co., Ltd., Yongin-si (KR)

(72) Inventors: TAEIL KIM, Yongin-si (KR); SUN YOUNG PAK, Yongin-si (KR); JUNHA PARK, Yongin-si (KR); MUN-KI SIM, Yongin-si (KR); MINJUNG JUNG, Yongin-si (KR); Seonhyoung HUR, Yongin-si (KR)

(73) Assignee: Samsung Display Co., Ltd., Yongin-si (KR)

(21) Appl. No.: 18/486,424

(22) Filed: Oct. 13, 2023

(30) Foreign Application Priority Data
Jan. 3, 2023 (KR) 10-2023-0000565

(51) Int. Cl. H10K 85/60; C09K 11/06

(52) U.S. Cl. CPC H10K 85/658; C09K 11/06; H10K 85/654; H10K 85/6572; H10K 85/6574; H10K 85/6576; C07B 2200/05; H10K 2101/20

(57) ABSTRACT

Embodiments provide a light emitting element that includes a first electrode, a second electrode facing the first electrode, and at least one functional layer disposed between the first electrode and the second electrode. The at least one functional layer includes a first compound represented by Formula 1, and at least one of a second compound represented by Formula HT and a third compound represented by Formula ET, wherein Formulas 1, HT, and ET are each explained in the specification.

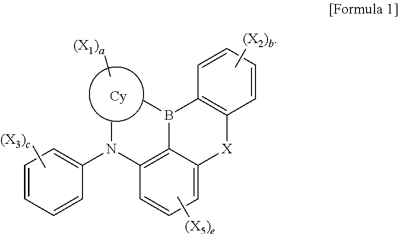

### CROSS-REFERENCE TO RELATED APPLICATION(S)

This application claims priority to and benefits of Korean Patent Application No. 10-2023-0000565 under 35 U.S.C. § 119, filed on Jan. 3, 2023 in the Korean Intellectual Property Office, the entire contents of which are incorporated herein by reference.

### BACKGROUND

### 1. Technical Field

The disclosure relates to a polycyclic compound and a light emitting element including the same.

### 2. Description of the Related Art

Active development continues for organic electroluminescence display devices and the like as image display devices. Organic electroluminescence display devices and the like are display devices which include so-called self-luminescent light emitting elements in which holes and electrons respectively injected from a first electrode and a second electrode recombine in an emission layer, so that a luminescent material in the emission layer emits light to achieve display.

In the application of light emitting elements to display devices, there is a demand for light emitting elements having low driving voltage, high light emitting efficiency, and long service life, and continuous development is required on materials for light emitting elements that are capable of stably achieving such characteristics.

In order to implement an organic electroluminescence element having high light emitting efficiency, technologies pertaining to phosphorescence emission using triplet state energy or to delayed fluorescence using triplet-triplet annihilation (TTA) in which singlet excitons are generated through the collision of triplet excitons are being developed. Development is currently directed to thermally activated delayed fluorescence (TADF) materials which uses delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element having increased light emitting efficiency and longer service life.

The disclosure also provides a polycyclic compound capable of improving light emitting efficiency and service life.

An embodiment provides a light emitting element which may include a first electrode, a second electrode facing the first electrode, and at least one functional layer disposed between the first electrode and the second electrode, wherein the at least one functional layer may include a first compound represented by Formula 1, and at least one of a second compound represented by Formula HT and a third compound represented by Formula ET.

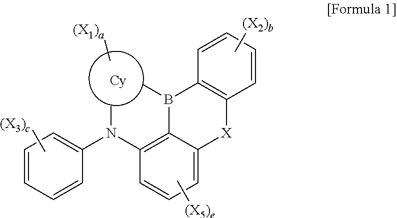

In Formula 1, Cy may be a substituted or unsubstituted hydrocarbon ring having 5 to 30 ring-forming carbon atoms or a substituted or unsubstituted heterocycle having 2 to 30 ring-forming carbon atoms; X may be N(Rₓ), O, S, Se, or Te; and Rₓ may be a group represented by Formula 1a.

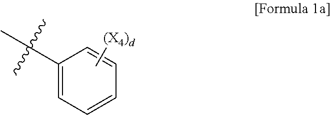

In Formulas 1 and 1a, a and b may each independently be an integer from 1 to 4; c and d may each independently be an integer from 1 to 5; e may be an integer from 1 to 3; at least one of X₁ to X₅ may each independently be a group represented by Formula 2; and the remainder of X₁ to X₅ may each independently be a hydrogen atom, a cyano group, a substituted or unsubstituted oxy group, a substituted or unsubstituted alkyl group having 1 to 60 carbon atoms, a substituted or unsubstituted cycloalkyl group having 3 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

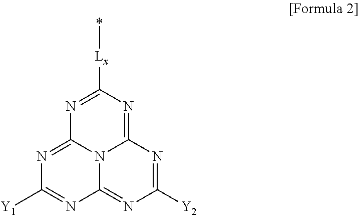

In Formula 2, Lₓ may be a direct linkage, a substituted or unsubstituted amine group, a substituted or unsubstituted arylene group having 6 to 60 carbon atoms, or a substituted or unsubstituted heteroarylene group having 2 to 60 ring-forming carbon atoms; and Y₁ and Y₂ may each independently be a substituted or unsubstituted amine group, a substituted or unsubstituted aryl group having 6 to 60 ring-forming carbon atoms, or a substituted or unsubstituted heteroaryl group having 2 to 60 ring-forming carbon atoms.

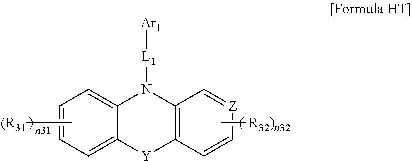

In Formula HT, L₁ may be a direct linkage, a substituted or unsubstituted arylene group having 6 to 30 ring-forming carbon atoms, or a substituted or unsubstituted heteroarylene group having 2 to 30 ring-forming carbon atoms; Ar₁ may be a substituted or unsubstituted aryl group having 6 to 30 ring-forming carbon atoms or a substituted or unsubstituted heteroaryl group having 2 to 30 ring-forming carbon atoms; Y may be a direct linkage, C(Ryi)(R_{y2}), or Si(R_{y3})(R_{y4}); Z may be C(R_{z}) or N; R_{y1} to R_{y4}, R₃₁, R₃₂, and R_{z} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring; n31 may be an integer from 0 to 4; and n32 may be an integer from 0 to 3.

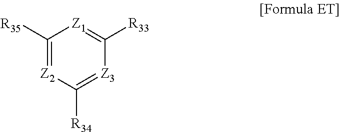

In Formula ET, Z₁ to Z₃ may each independently be N or C(R₃₆); at least one of Z₁ to Z₃ may each be N; and R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

In an embodiment, the at least one functional layer may further include a fourth compound represented by Formula PS.

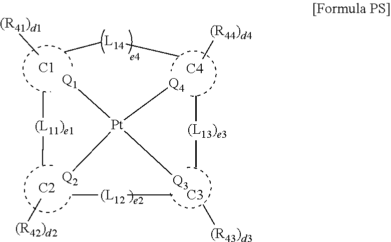

In Formula PS, Q₁ to Q₄ may each independently be C or N; C1 to C4 are each independently a substituted or unsubstituted hydrocarbon ring having 5 to 30 ring-forming carbon atoms or a substituted or unsubstituted heterocycle having 2 to 30 ring-forming carbon atoms; L₁₁ to L₁₄ may each independently be a direct linkage,

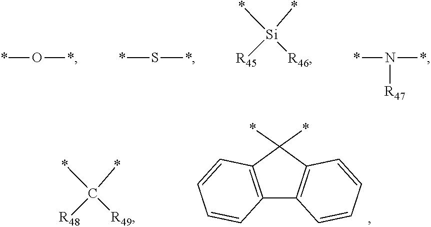

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, wherein in L₁₁ to L₁₄, -* represents a bond to one of C1 to C4; e1 to e4 may each independently be 0 or 1; R₄₁ to R₄₉ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring; and d1 to d4 may each independently be an integer from 0 to 4.

In an embodiment, the first compound may be represented by any one of Formulas 1-1a to 1-1d.

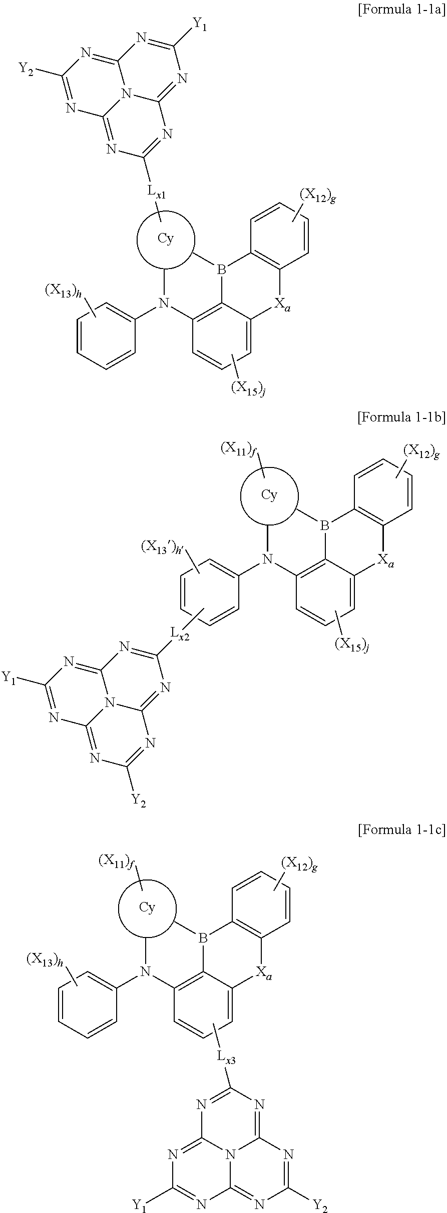

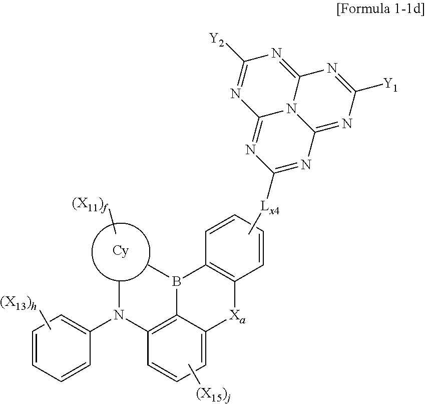

In Formulas 1-1a to 1-1d, Lₓ₁ to Lₓ₄ may each independently be a direct linkage, a substituted or unsubstituted amine group, a substituted or unsubstituted arylene group having 6 to 20 ring-forming carbon atoms, or a substituted or unsubstituted heteroarylene group having 2 to 20 ring-forming carbon atoms; Xₐ may be N(Rₓ₁), O, S, Se, or Te; and Rₓ₁ may be a group represented by Formula 1b.

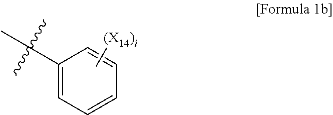

In Formulas 1-1a to 1-1d and 1b, X₁₁ to X₁₅ and X_{13′} may each independently be a hydrogen atom, a cyano group, a substituted or unsubstituted oxy group, a substituted or unsubstituted alkyl group having 1 to 60 carbon atoms, a substituted or unsubstituted cycloalkyl group having 3 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring; f and g may each independently be an integer from 1 to 4; h and i may each independently be an integer from 1 to 5; j may be an integer from 1 to 3; h′ may be an integer from 0 to 4; Cy is the same as defined in Formula 1; and Y₁, and Y₂ are the same as defined in Formula 2.

In an embodiment, the first compound may be represented by any one of Formulas 1-2a to 1-2d.

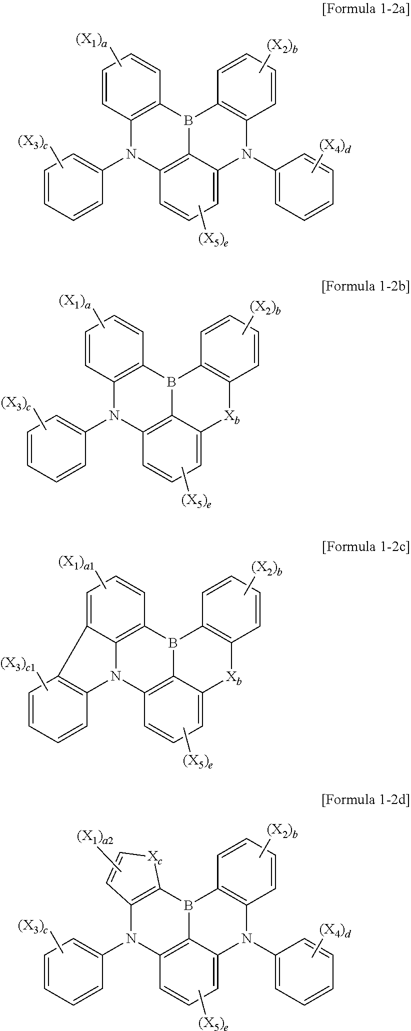

In Formulas 1-2a to 1-2d, a1 may be an integer from 1 to 3; a2 may be 1 or 2; c1 may be an integer from 1 to 4; X_{b} and X_{c} may each independently be O, S, Se, or Te; and X₁ to X₅ and a to e are the same as defined in Formula 1.

In an embodiment, the group represented by Formula 2 may be represented by any one of Formulas 2-1 to 2-3.

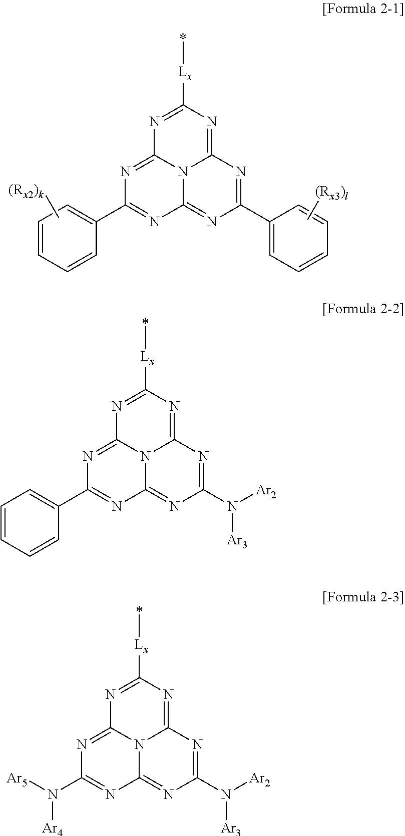

In Formulas 2-1 to 2-3, Rₓ₂ and Rₓ₃ may each independently be a hydrogen atom or a t-butyl group; k and 1 may each independently be an integer from 0 to 5; Ar₂ to Ar₅ may each independently be an unsubstituted phenyl group, or bonded to an adjacent group to form a ring; and Lₓ is the same as defined in Formula 2.

In an embodiment, the at least one functional layer may include at least one compound selected from Compound Group 1, which is explained below.

In an embodiment, the at least one functional layer may include an emission layer, a hole transport region disposed between the first electrode and the emission layer, and an electron transport region disposed between the emission layer and the second electrode; wherein the emission layer may include the first compound, and at least one of the second compound and the third compound.

In an embodiment, the emission layer may emit delayed fluorescence.

In an embodiment, the emission layer may emit blue light.

In an embodiment, the at least one functional layer may include the first compound, the second compound, and the third compound.

In an embodiment, the at least one functional layer may include the first compound, the second compound, the third compound, and the fourth compound.

An embodiment provides a light emitting element which may include a first electrode, a second electrode facing the first electrode, and an emission layer disposed between the first electrode and the second electrode, wherein the emission layer may include a polycyclic compound represented by Formula 1. In Formula 1, Cy may be a substituted or unsubstituted hydrocarbon ring having 5 to 30 ring-forming carbon atoms or a substituted or unsubstituted heterocycle having 2 to 30 ring-forming carbon atoms; X may be N(Rₓ), O, S, Se, or Te; and Rₓ may be a group represented by Formula 1a.

In Formulas 1 and 1a, a and b may each independently be an integer from 1 to 4; c and d may each independently be an integer from 1 to 5; e may be an integer from 1 to 3; at least one of X₁ to X₅ may each independently be a group represented by Formula 3; and the remainder of X₁ to X₅ may each independently be a hydrogen atom, a cyano group, a substituted or unsubstituted oxy group, a substituted or unsubstituted alkyl group having 1 to 60 carbon atoms, a substituted or unsubstituted cycloalkyl group having 3 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

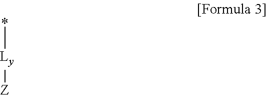

In Formula 3, L_{y} may be a direct linkage, a substituted or unsubstituted amine group, a substituted or unsubstituted arylene group having 6 to 60 ring-forming carbon atoms, or a substituted or unsubstituted heteroarylene group having 2 to 60 ring-forming carbon atoms; and Z may be a substituted or unsubstituted tricyclic heteroaryl group having 6 to 11 ring-forming carbon atoms and 2 to 7 ring-forming nitrogen atoms.

In an embodiment, the polycyclic compound may be represented by any one of Formulas 1-1a to 1-1d, which are explained herein.

In an embodiment, the polycyclic compound may be represented by any one of Formulas 1-2a to 1-2d, which are explained herein.

In an embodiment, Z may be a group represented by Formula 4.

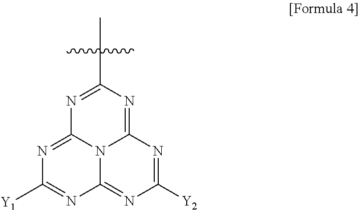

In Formula 4, Y₁ and Y₂ may each independently be a substituted or unsubstituted amine group, a substituted or unsubstituted aryl group having 6 to 20 ring-forming carbon atoms, or a substituted or unsubstituted heteroaryl group having 2 to 20 ring-forming carbon atoms.

An embodiment provides a polycyclic compound which may be represented by Formula 1, which is explained herein.

In an embodiment, Formula 1 may be represented by any one of Formulas 1-1a to 1-1d, which are explained herein.

In an embodiment, Formula 1 may be represented by any one of Formulas 1-2a to 1-2d, which are explained herein.

In an embodiment, the group represented by Formula 2 may be represented by any one of Formulas 2-1 to 2-3, which are explained herein.

In an embodiment, the polycyclic compound represented by Formula 1 may be selected from Compound Group 1, which is explained below.

An embodiment provides a display device which may include a base layer, a circuit layer disposed on the base layer, and a display element layer disposed on the circuit layer and including a light emitting element. The light emitting element may include a first electrode, a second electrode facing the first electrode, and at least one functional layer disposed between the first electrode and the second electrode, wherein the at least one functional layer may include a first compound represented by Formula 1, and at least one of a second compound represented by Formula HT and a third compound represented by Formula ET, and wherein Formulas 1, HT, and ET are explained herein.

In an embodiment, the at least one functional layer may include an emission layer, a hole transport region disposed between the first electrode and the emission layer, and an electron transport region disposed between the emission layer and the second electrode; wherein the emission layer may include the first compound, and at least one of the second compound and the third compound.

In an embodiment, the display device may further include a light control layer disposed on the display element layer and including a quantum dot.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view of a display device according to an embodiment;

FIG. 10 is a schematic cross-sectional view of a display device according to an embodiment; and

FIG. 11 is a schematic perspective view of an electronic device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, oxy group, thio group, sulfinyl group, sulfonyl group, carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be linked to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as mutually “adjacent groups” and two ethyl groups in 1,1-diethylcyclopentane may be interpreted as mutually “adjacent groups”. For example, two methyl groups in 4,5-dimethylphenanthrene may be interpreted as mutually “adjacent groups”.

In the specification, examples of a halogen atom may include a fluorine atom, a chlorine atom, a bromine atom, and an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, a s-butyl group, a t-butyl group, an i-butyl group, a 2-ethylbutyl group, a 3,3-a dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and the like, but are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and the like, but are not limited thereto.

In the specification, an alkenyl group may be a hydrocarbon group including at least one carbon-carbon double bond in the middle or an end of an alkyl group having 2 or more carbon atoms. An alkenyl group may be linear or branched. The number of carbon atoms in an alkenyl group is not particularly limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, and the like, but are not limited thereto.

In the specification, an alkynyl group may be a hydrocarbon group including at least one carbon-carbon triple bond in the middle or an end of an alkyl group having 2 or more carbon atoms. An alkynyl group may be linear or branched. The number of carbon atoms in an alkynyl group is not particularly limited, but may be 2 to 30, 2 to 20, or 2 to 10. Examples of an alkynyl group may include an ethynyl group, a propynyl group, and the like, but are not limited thereto.

In the specification, a hydrocarbon ring group may be any functional group or substituent derived from an aromatic hydrocarbon ring or an aliphatic hydrocarbon ring.

In the specification, any functional group or substituent derived from an aliphatic hydrocarbon ring may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and the like, but are not limited thereto.

In the specification, a fluorenyl group may be substituted, and two substituents may be bonded to each other to form a spiro structure. Examples of a substituted fluorenyl group may include the groups shown below. However, embodiments are not limited thereto.

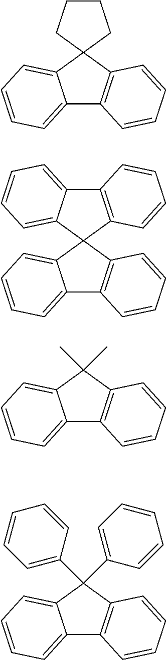

In the specification, a heterocyclic group may be any functional group or substituent derived from a ring including at least one of B, O, N, P, Si, S, Se, or Te as a heteroatom. A heterocyclic group may be an aliphatic heterocyclic group or an aromatic heterocyclic group. An aromatic heterocyclic group may be a heteroaryl group. An aliphatic heterocycle and an aromatic heterocycle may be monocyclic or polycyclic. When a heterocyclic group contains two or more heteroatoms, the two or more heteroatoms may be the same as or different from each other.

In the specification, an aliphatic heterocyclic group may include at least one of B, O, N, P, Si, S, Se, or Te as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and the like, but are not limited to thereto.

In the specification, a heteroaryl group may include at least one of B, O, N, P, Si, S, Se, or Te as a heteroatom. When a heteroaryl group contains two or more heteroatoms, the two or more heteroatoms may be the same as or different from each other. A heteroaryl group may be monocyclic or polycyclic. The number of ring-forming carbon atoms in a heteroaryl group may be 2 to 60, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and the like, but are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkyl silyl group or an aryl silyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and the like, but are not limited thereto.

In the specification, the number of carbon atoms in an amino group is not particularly limited, but may be 1 to 30. An amino group may be an alkyl amino group, an aryl amino group, or a heteroaryl amino group. Examples of an amino group may include a methylamino group, a dimethylamino group, a phenylamino group, a diphenylamino group, a naphthylamino group, a 9-methyl-anthracenylamino group, a triphenylamino group, and the like, but are not limited thereto.

In the specification, the number of carbon atoms in a carbonyl group is not particularly limited, but may be 1 to 40, 1 to 30, or 1 to 20. For example, a carbonyl group may have one of the following structures, but is not limited thereto.

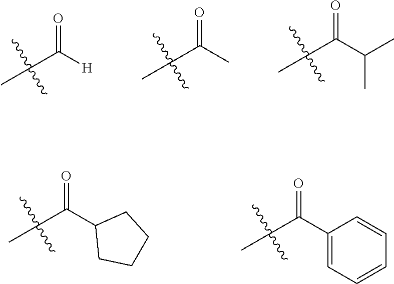

In the specification, the number of carbon atoms in a sulfinyl group or a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkyl thio group or an aryl thio group. A thio group may be a sulfur atom that is bonded to an alkyl group or to an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and the like, but are not limited to thereto.

In the specification, an oxy group may be an oxygen atom that is bonded to an alkyl group or to an aryl group as defined above. An oxy group may be an alkoxy group or an aryl oxy group. An alkoxy group may be linear, branched, or cyclic. The number of carbon atoms in an alkoxy group is not particularly limited, but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, and the like, but are not limited thereto.

In the specification, a boron group may be a boron atom that is bonded to an alkyl group or to an aryl group as defined above. A boron group may be an alkyl boron group or an aryl boron group. Examples of a boron group may include a dimethyl boron group, a diethyl boron group, a t-butylmethyl boron group, a diphenyl boron group, a phenyl boron group, and the like, but are not limited thereto.

In the specification, the number of carbon atoms in an amine group is not particularly limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group, and the like, but are not limited thereto.

In the specification, the above-described examples of the alkyl group may also apply to an alkylthio group, an alkyl sulfoxy group, an alkylaryl group, an alkylamino group, an alkyl boron group, an alkyl silyl group, and an alkyl amine group.

In the specification, the above-described examples of the aryl group may also apply to an aryloxy group, an arylthio group, an aryl sulfoxy group, an arylamino group, an aryl boron group, an aryl silyl group, and an aryl amine group.

In the specification, a direct linkage may be a single bond.

In the specification, the symbols

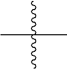

and -* each represent a bond to a neighboring atom in a corresponding formula or moiety.

Hereinafter, embodiments will be described with reference to the accompanying drawings.

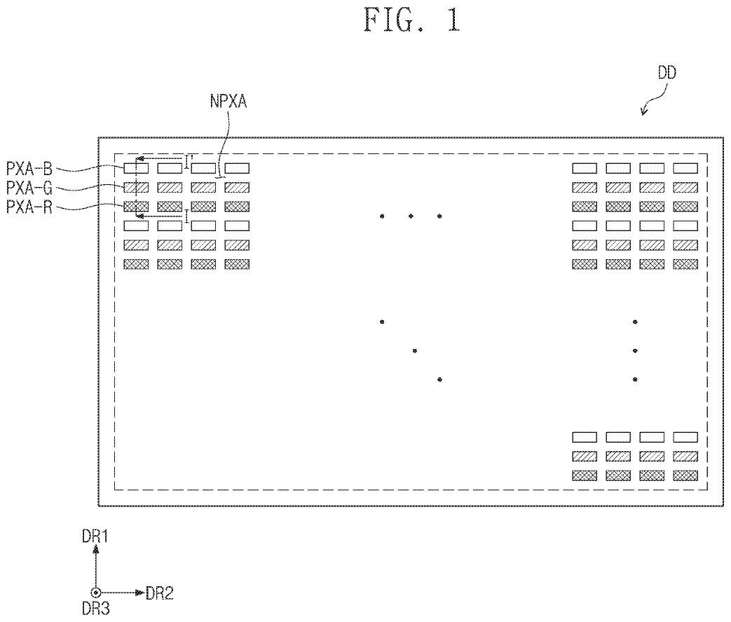

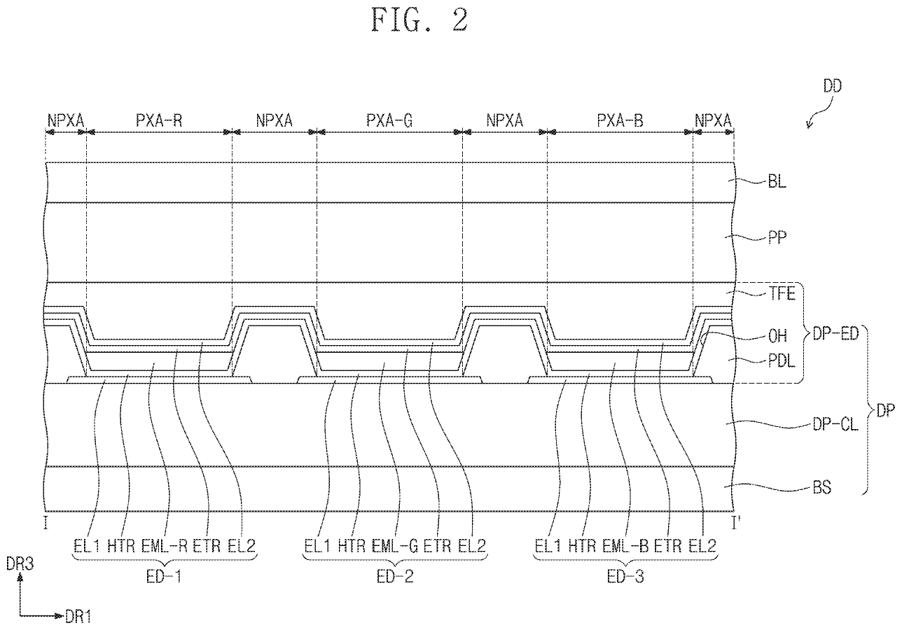

FIG. 1 is a schematic plan view of a display device DD according to an embodiment. FIG. 2 is a schematic cross-sectional view of a display device DD according to an embodiment. FIG. 2 is a schematic cross-sectional view showing a portion corresponding to line I-I′ in FIG. 1.

A display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP and may control light that is reflected at the display panel DP from an external light. The optical layer PP may include, for example, a polarizing layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, and the like. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic resin, a silicone-based resin, and an epoxy-based resin.

The display panel DP may include a base layer BS, a circuit layer DP-CL provided on the base layer BS, and a display element layer DP-ED. The display element layer DP-ED may include pixel defining films PDL, light emitting elements ED-1, ED-2, and ED-3 disposed between the pixel defining films PDL, and an encapsulation layer TFE disposed on the light emitting elements ED-1, ED-2, and ED-3.

The base layer BS may provide a base surface on which the display element layer DP-ED is disposed. The base layer BS may be a glass substrate, a metal substrate, a plastic substrate, and the like. However, embodiments are not limited thereto, and the base layer BS may include an inorganic layer, an organic layer, or a composite material layer.

In an embodiment, the circuit layer DP-CL may be disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display element layer DP-ED.

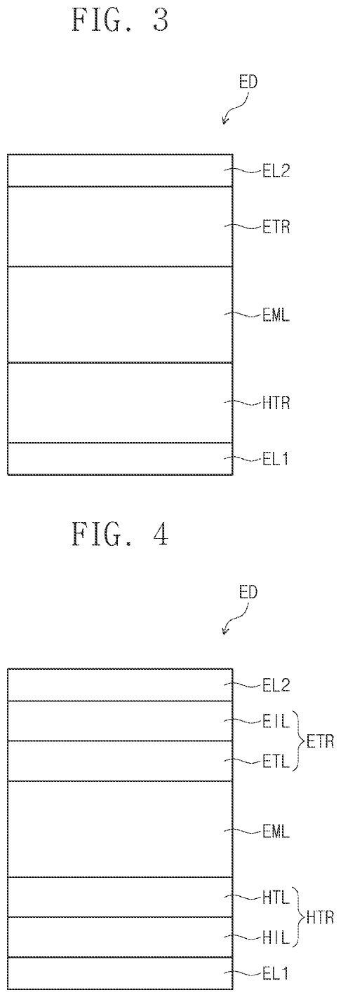

The light emitting elements ED-1, ED-2, and ED-3 may each have a structure of a light emitting element ED of an embodiment according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 shows an embodiment in which the emission layers EML-R, EML-G, and EML-B of the light emitting elements ED-1, ED-2, and ED-3 are disposed in openings OH defined in the pixel defining films PDL, and the hole transport region HTR, the electron transport region ETR, and the second electrode EL2 are each provided as a common layer throughout the light emitting elements ED-1, ED-2, and ED-3. However, embodiments are not limited thereto. Although not shown in FIG. 2, in an embodiment, the hole transport region HTR and the electron transport region ETR may each be provided by being patterned inside the openings OH defined in the pixel defining films PDL. For example, in an embodiment, the hole transport region HTR, the emission layers EML-R, EML-G, and EML-B, and the electron transport region ETR of the light emitting elements ED-1, ED-2, and ED-3 may each be patterned and provided through an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be a single layer or a stack of multiple layers. The encapsulation layer TFE may include at least one insulating layer. In an embodiment, the encapsulation layer TFE may include at least one inorganic film (hereinafter, an encapsulation inorganic film). In an embodiment, the encapsulation layer TFE may include at least one organic film (hereinafter, an encapsulation organic film) and at least one encapsulation inorganic film.

The encapsulation inorganic film protects the display element layer DP-ED from moisture and/or oxygen, and the encapsulation organic film protects the display element layer DP-ED from foreign substances such as dust particles. The encapsulation inorganic film may include silicon nitride, silicon oxy nitride, silicon oxide, titanium oxide, aluminum oxide, or the like, but is not limited thereto. The encapsulation organic film may include an acrylic compound, an epoxy-based compound, and the like. The encapsulation organic film may include a photopolymerizable organic material, but embodiments are not limited thereto.

The encapsulation layer TFE may be disposed on the second electrode EL2, and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light generated from each of the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining films PDL. The non-light emitting regions NPXA may be regions between the neighboring light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2 and ED-3 may be disposed in the openings OH defined by the pixel defining films PDL and separated from each other.

The light emitting regions PXA-R, PXA-G, and PXA-B may be arranged into groups according to the color of light generated from the light emitting elements ED-1, ED-2, and ED-3. In the display device DD according to an embodiment shown in FIGS. 1 and 2, three light emitting regions PXA-R, PXA-G, and PXA-B which respectively emit red light, green light, and blue light, are shown as an example. For example, the display device DD may include a red light emitting region PXA-R, a green light emitting region PXA-G, and a blue light emitting region PXA-B, which are distinct from one another.

In the display device DD according to an embodiment, the light emitting elements ED-1, ED-2, and ED-3 may emit light having wavelength ranges that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2 and ED-3 may emit light in a same wavelength range, or at least one light emitting element may emit light in a wavelength range that is different from the remainder. For example, the first to third light emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second direction DR2. In another embodiment, the red light emitting region PXA-R, the green light emitting region PXA-G, and the blue light emitting region PXA-B may be alternately arranged in this repeating order along a first direction DR1.

FIGS. 1 and 2 show that the light emitting regions PXA-R, PXA-G, and PXA-B are all similar in size, but embodiments are not limited thereto. In an embodiment, the light emitting regions PXA-R, PXA-G and PXA-B may be different in size from each other, according to wavelength range of emitted light. For example, the areas of the light emitting regions PXA-R, PXA-G, and PXA-B may be areas in a plan view that are defined by the first direction DR1 and the second direction DR2.

An arrangement of the light emitting regions PXA-R, PXA-G, and PXA-B is not limited to what is shown in FIG. 1, and the order in which the red light emitting region PXA-R, the green light emitting region PXA-G, and the blue light emitting region PXA-B are arranged may be provided in various combinations according to the display quality characteristics that are required for the display device DD. For example, the light emitting regions PXA-R, PXA-G, and PXA-B may be arranged in a pentile configuration (such as PENTILE™) or in a diamond configuration (such as Diamond Pixel™).

The areas of each of the light emitting regions PXA-R, PXA-G, and PXA-B may be different in size from one another. For example, in an embodiment, the green light emitting region PXA-G may be smaller than the blue light emitting region PXA-B in size, but embodiments are not limited thereto.

In the display device DD according to an embodiment which is shown in FIG. 2, at least one of the first to third light emitting elements ED-1, ED-2, and ED-3 may include a polycyclic compound according to an embodiment.

Hereinafter, FIGS. 3 to 6 are each a schematic cross-sectional view ofa light emitting element according to an embodiment. The light emitting element ED according to an embodiment may include a first electrode EL1, a second electrode EL2 facing the first electrode EL1. and at least one functional layer disposed between the first electrode EL1 and the second electrode EL2. The light emitting element ED according to an embodiment may include a polycyclic compound according to an embodiment, which will be described later, in at least one functional layer. In the specification, the polycyclic compound according to an embodiment may be referred to as a first compound.

The light emitting element ED may include a hole transport region HTR, an emission layer EML, and an electron transport region ETR, which may be stacked in that order, as the at least one functional layer. Referring to FIG. 3, the light emitting element ED according to an embodiment may include a first electrode EL1, a hole transport region HTR, an emission layer EML, an electron transport region ETR, and a second electrode EL2. In an embodiment, the light emitting element ED may include a polycyclic compound according to an embodiment, which will be described later, in the emission layer EML.

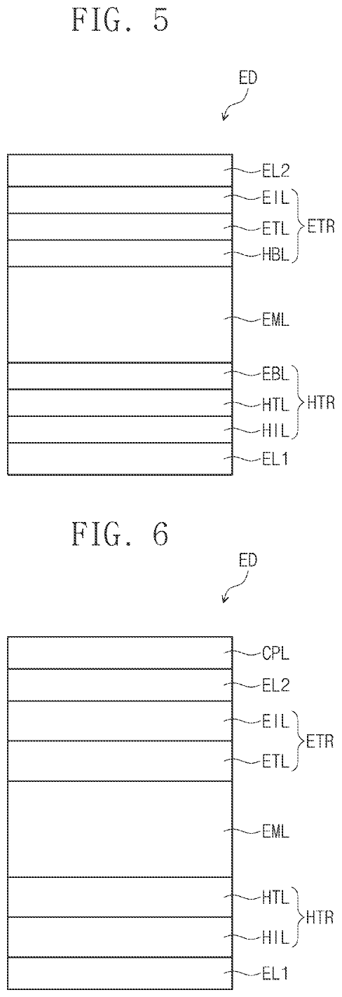

FIG. 4 shows, as compared with FIG. 3, a schematic cross-sectional view of a light emitting element ED according to an embodiment in which the hole transport region HTR includes a hole injection layer HIL and a hole transport layer HTL, and the electron transport region ETR includes an electron injection layer EIL and an electron transport layer ETL. FIG. 5 shows, as compared with FIG. 3, a schematic cross-sectional view of a light emitting element ED according to an embodiment in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. FIG. 6 shows, as compared with FIG. 4, a schematic cross-sectional view of a light emitting element ED according to an embodiment, in which a capping layer CPL is disposed on the second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

When the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), or the like. For example, the first electrode EL1 may have a three-layer structure of ITO/Ag/ITO, but embodiments are not limited thereto. In an embodiment, the first electrode EL1 may include the above-described metal materials, a combination of two or more metal materials selected from the above-described metal materials, or oxides of the above-described metal materials. The first electrode EL1 may have a thickness in a range of about 700 Å to about 10,000 Å. For example, the first electrode EL1 may have a thickness in a range of 1,000 Å to about 3,000 Å.

The hole transport region HTR may be provided on the first electrode EL1. The hole transport region HTR may include at least one of a hole injection layer HIL, a hole transport layer HTL, a buffer layer (not shown), a light emitting auxiliary layer (not shown), and an electron blocking layer EBL. The hole transport region HTR may have, for example, a thickness in a range of about 50 Å to about 15,000 Å.

The hole transport region HTR may be a layer consisting of a single material, a layer including different materials, or a structure including multiple layers including different materials.

In embodiments, the hole transport region HTR may have a single-layer structure formed of a hole injection layer HIL or a hole transport layer HTL, or may have a single-layer structure formed of a hole injection material or a hole transport material. In embodiments, the hole transport region HTR may have a single-layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1.

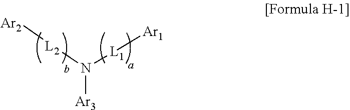

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms.

In an embodiment, a compound represented by Formula H-1 may be a monoamine compound. In another embodiment, a compound represented by Formula H-1 may be a diamine compound in which at least one of Ar₁ to Ar₃ includes an amine group as a substituent. In yet another embodiment, a compound represented by Formula H-1 may be a carbazole-based compound in which at least one of Ar₁ or Ar₂ includes a substituted or unsubstituted carbazole group, or may be a fluorene-based compound in which at least one of Ar₁ or Ar₂ includes a substituted or unsubstituted fluorene group.

The compound represented by Formula H-1 may be any compound selected from Compound Group H-1. However, the compounds listed in Compound Group H-1 are only examples, and the compound represented by Formula H-1 is not limited to Compound Group H-1.

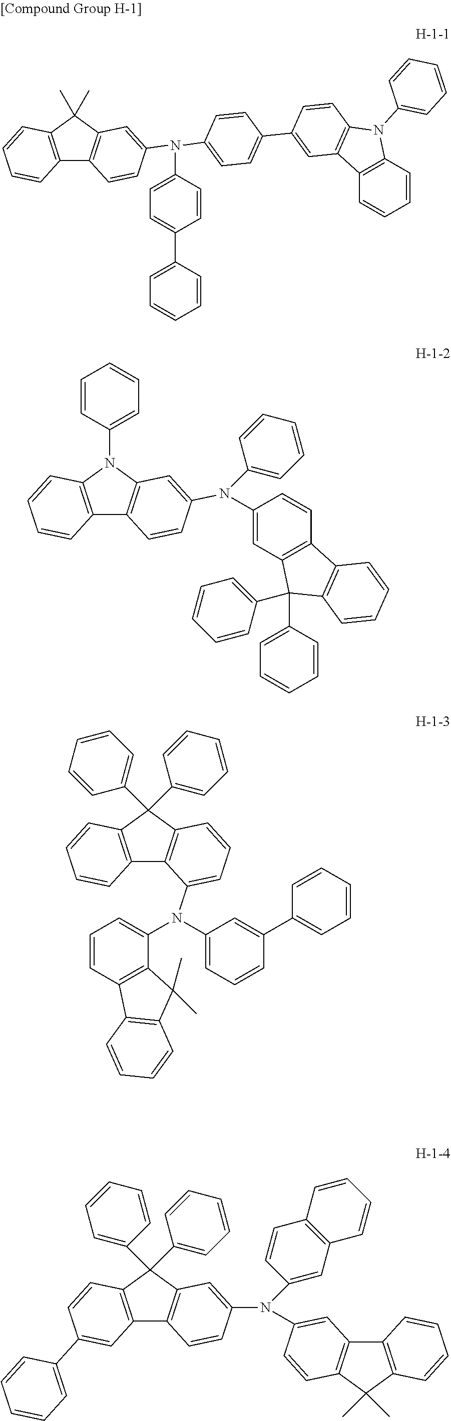 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

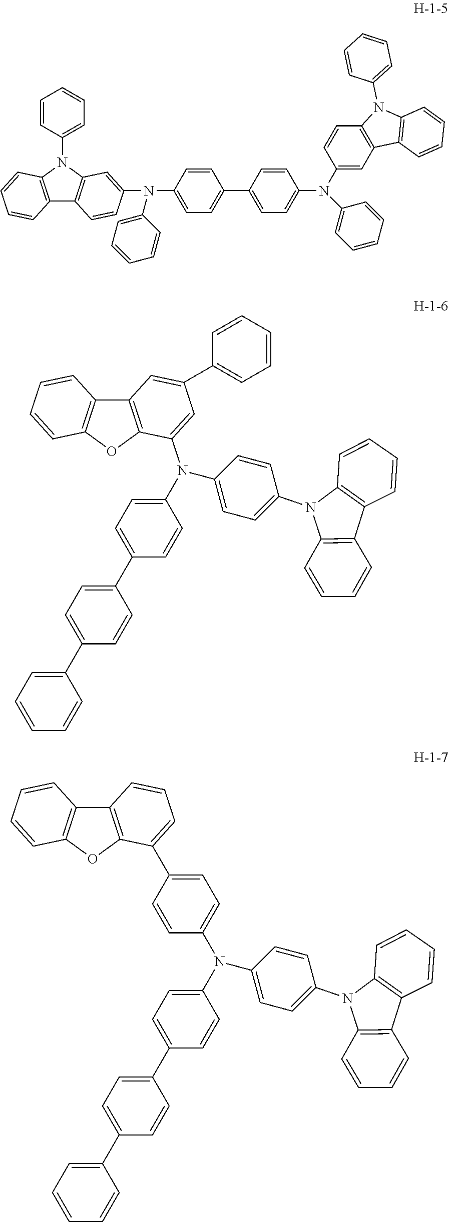 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

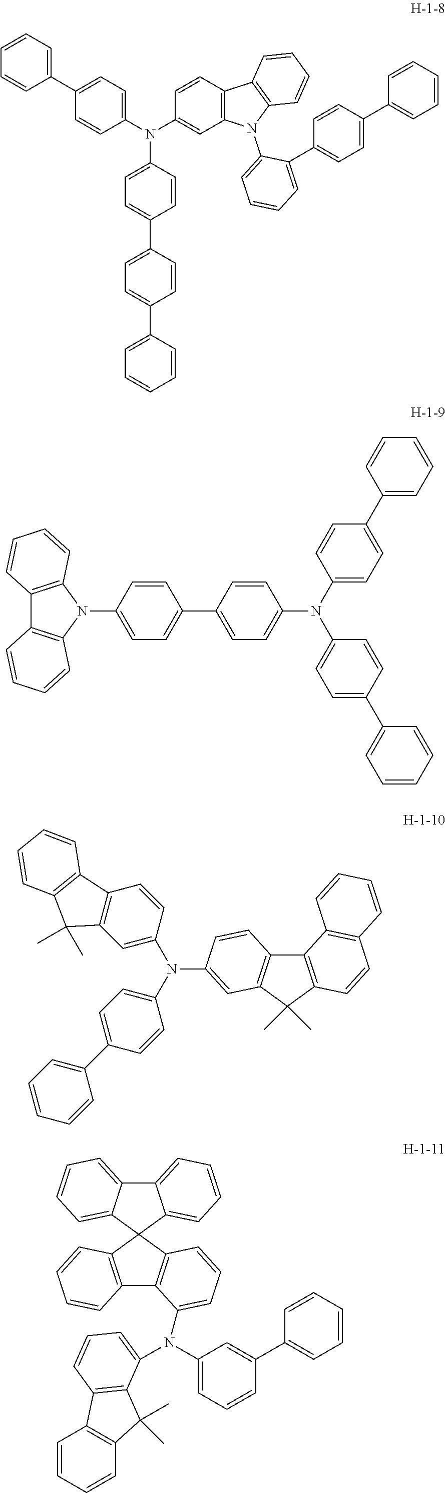

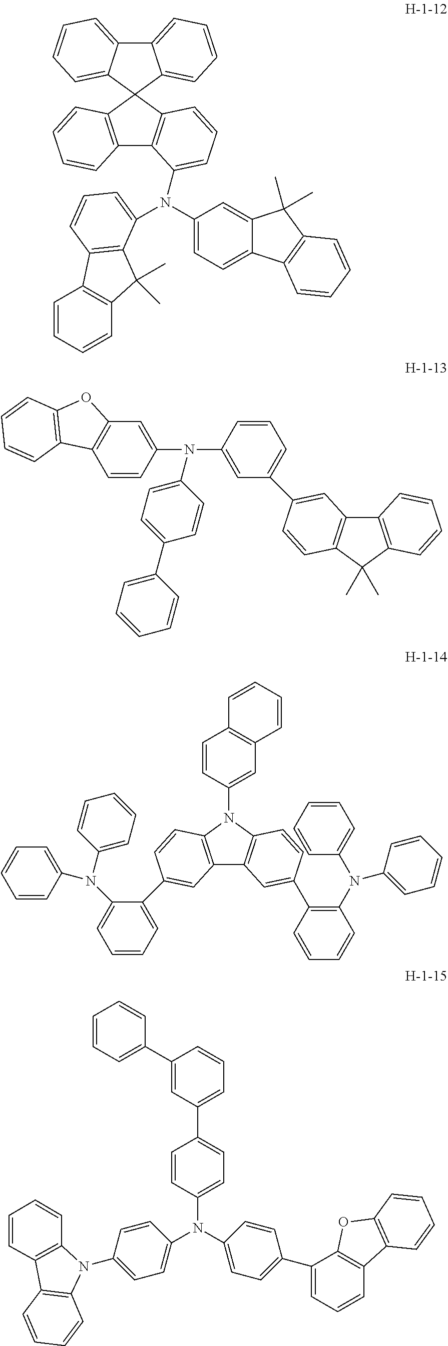 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

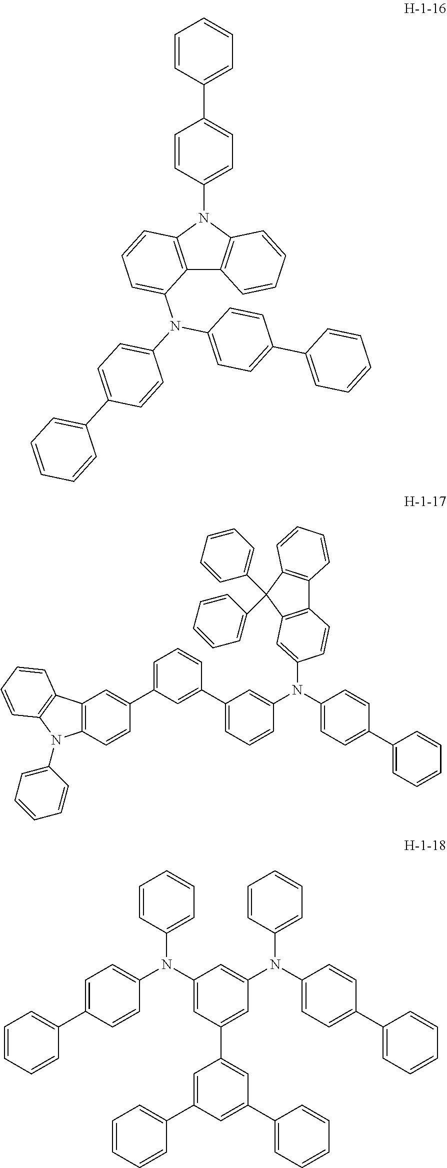 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

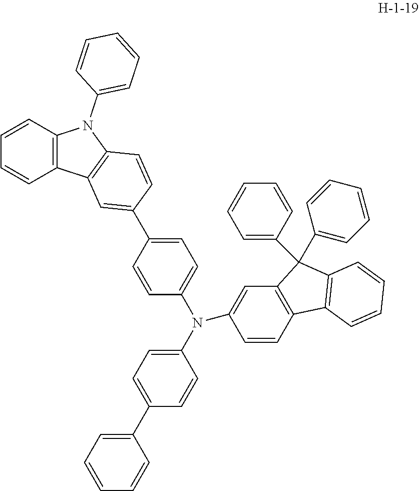 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/Dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium tetrakis(pentafluorophenyl)borate, dipyrazino[2,3-f: 2′,3′-h] quinoxaline-2,3,6,7,10,11-hexacarbonitrile (HATCN), and the like.

The hole transport region HTR may include carbazole-based derivatives such as N-phenyl carbazole and polyvinyl carbazole, fluorene-based derivatives, N,N′-bis(3-methylphenyl)-N,N′-diphenyl-[1,1-biphenyl]-4,4′-diamine (TPD), triphenylamine-based derivatives such as 4,4′,4″-tris(N-carbazolyl)triphenylamine (TCTA), N,N′-di(1-naphtalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), and the like.

The hole transport region HTR may include 9-(4-tert-Butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and the like.

The hole transport region HTR may include the compounds of the hole transport region described above in at least one of a hole injection layer HIL, a hole transport layer HTL, and an electron blocking layer EBL.

The hole transport region HTR may have a thickness in a range of about 100 Å to about 10,000 Å. For example, the hole transport region HTR may have a thickness in a range of about 100 to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 30 Å to about 1,000 Å. When the hole transport region HTR includes an electron blocking layer EBL, the electron blocking layer EBL may have a thickness in a range of about 10 Å to about 1,000 Å. When the thicknesses of the hole transport region HTR, the hole injection layer HIL, the hole transport layer HTL, and the electron blocking layer EBL satisfy the above-described ranges, satisfactory hole transport properties may be obtained without a substantial increase in driving voltage.

The hole transport region HTR may further include, in addition to the above-described materials, a charge generation material to increase conductivity. The charge generation material may be uniformly or non-uniformly dispersed in the hole transport region HTR. The charge generation material may be, for example, a p-dopant. The p-dopant may include at least one of halogenated metal compounds, quinone derivatives, metal oxides, and cyano group-containing compounds, but embodiments are not limited thereto.

For example, the p-dopant may include halogenated metal compounds such as CuI and RbI, quinone derivatives such as tetracyanoquinodimethane (TCNQ) and 2,3,5,6-tetrafluoro-7,7,8,8-tetracyanoquinodimethane (F4-TCNQ), metal oxides such as tungsten oxides and molybdenum oxides, cyano group-containing compounds such as dipyrazino[2,3-f: 2′,3′-h] quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), or the like, but is not limited thereto.

As described above, the hole transport region HTR may further include at least one of a buffer layer (not shown) or an electron blocking layer EBL, in addition to a hole injection layer HIL and a hole transport layer HTL. The buffer layer (not shown) may compensate for a resonance distance according to a wavelength of light emitted from an emission layer EML, and may thus increase light emitting efficiency. Materials which may be included in the hole transport region HTR may be used as materials included in the buffer layer (not shown). The electron blocking layer EBL may prevent the injection of electrons from an electron transport region ETR to a hole transport region HTR.

The emission layer EML may be provided on the hole transport region HTR. The emission layer EML may have a thickness in a range of about 100 Å to about 1.000 Å. For example, the emission layer EML may have a thickness in a range of about 100 Å to about 300 Å. The emission layer EML may be a layer consisting of a single material, a layer including different materials, or a structure including multiple layers including different materials.

In the light emitting element ED according to an embodiment, the emission layer EML may include a polycyclic compound according to an embodiment. In an embodiment, the emission layer EML may include the polycyclic compound as a dopant. The polycyclic compound may be a dopant material of the emission layer EML.

The polycyclic compound of an embodiment may have a core structure in which aromatic rings are fused through a boron atom, at least one nitrogen atom, and at least one heteroatom, and including a phenyl group linked to a nitrogen atom. The at least one heteroatom may be N, O, S, Se, or Te. When the at least one heteroatom is a nitrogen atom, the two nitrogen atoms of the core structure may each be linked to a phenyl group. For example, the core structure may include three aromatic rings, and each aromatic ring may be a hydrocarbon ring or a heterocycle. For example, the core structure may include three aromatic rings fused through a boron atom, at least one nitrogen atom, and at least one two nitrogen atoms. At least two of the aromatic rings may be benzene rings.

A substituent including a tricyclic heteroaryl group containing nitrogen atoms may be linked to at least one of the three aromatic rings or to a phenyl group linked to a nitrogen atom of the core structure. For example, the tricyclic heteroaryl group containing nitrogen atoms may contain 7 nitrogen atoms. For example, the tricyclic heteroaryl group containing nitrogen atoms may be a heptazine group.

In an embodiment, the emission layer EML may include a polycyclic compound represented by Formula 1. In the specification, the polycyclic compound may also be referred to as a first compound.

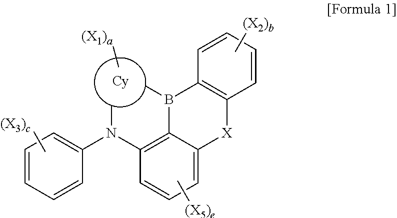

In Formula 1, Cy may be a substituted or unsubstituted hydrocarbon ring having 5 to 30 ring-forming carbon atoms, or a substituted or unsubstituted heterocycle having 2 to 30 ring-forming carbon atoms. For example, Cy may be a benzene ring, a naphthalene ring, a phenanthrene ring, a furan ring, a thiophene ring, a benzofuran ring, a benzothiophene ring, a benzoselenophene ring, or a dibenzofuran ring.

In Formula 1, X may be N(Rₓ), O, S, Se, or Te; and Rₓ may be a group represented by Formula 1a.

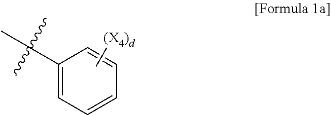

In Formula 1a,

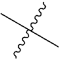

represents a bond to N of N(Rₓ).

In Formulas 1 and 1a, a and b may each independently be an integer from 1 to 4. In an embodiment, a and b may be the same as or different from each other. When a is 2 or greater, two or more X₁ groups may be the same as each other, or at least one group thereof may be different from the remainder. When b is 2 or greater, two or more X₂ groups may be the same as each other, or at least one group thereof may be different from the remainder.

In Formulas 1 and 1a, c and d may each independently be an integer from 1 to 5. In an embodiment, c and d may be the same as or different from each other. When c is 2 or greater, two or more X₃ groups may be the same as each other, or at least one group thereof may be different from the remainder. When d is 2 or greater, two or more X₄ groups may be the same as each other, or at least one group thereof may be different from the remainder.

In Formulas 1 and 1a, e may be an integer from 1 to 3. When e is 2 or greater, two or more X₅ groups may be the same as each other, or at least one group thereof may be different from the remainder.

In Formulas 1 and 1a, at least one of X₁ to X₅ is each independently a group represented by Formula 2; and the remainder of X₁ to X₅ may each independently be a hydrogen atom, a cyano group, a substituted or unsubstituted oxy group, a substituted or unsubstituted alkyl group having 1 to 60 carbon atoms, a substituted or unsubstituted cycloalkyl group having 3 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. In an embodiment, X₁ to X₅ may be the same as each other, or at least one group thereof may be different from the remainder.

For example, only one of X₁ to X₅ may be a group represented by Formula 2, two of X₁ to X₅ may each independently be a group represented by Formula 2, three of X₁ to X₅ may each independently be a group represented by Formula 2, four of X₁ to X₅ may each independently be a group represented by Formula 2, or all of X₁ to X₅ may each independently be a group represented by Formula 2.

For example, the remainder of X₁ to X₅, which are not a group represented by Formula 2, may each independently be a hydrogen atom, a cyano group, a methyl group, an isopropyl group, a t-butyl group, a pentyl group, a cyclopentyl group, a cyclohexyl group, a phenyl group substituted with a t-butyl group, a phenyl group substituted with a phenyl group, an unsubstituted phenyl group, a dimethylfluorenyl group, a furan group, a carbazole group substituted with a deuterium atom, a carbazole group substituted with a t-butyl group, an unsubstituted carbazole group, or a phenoxy group, or may be bonded to an adjacent group to form a benzofuran ring, a dimethylchroman ring, or a spirobifluorene ring.

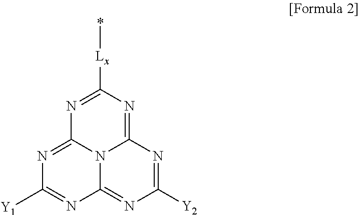

In Formula 2, Lₓ may be a direct linkage, a substituted or unsubstituted amine group, a substituted or unsubstituted arylene group having 6 to 60 carbon atoms, or a substituted or unsubstituted heteroarylene group having 2 to 60 ring-forming carbon atoms. For example, Lₓ may be a direct linkage, a phenylene group unsubstituted or substituted with a heptazine group, an unsubstituted biphenylene group, an unsubstituted naphthalene group, an unsubstituted anthracene group, an unsubstituted carbazole group, an amine group substituted with a phenyl group and a biphenyl group, or a phenoxazine group substituted with t-butyl group.

In Formula 2, Y₁ and Y₂ may each independently be a substituted or unsubstituted amine group, a substituted or unsubstituted aryl group having 6 to 60 ring-forming carbon atoms, or a substituted or unsubstituted heteroaryl group having 2 to 60 ring-forming carbon atoms. In an embodiment, Y₁ and Y₂ may be the same as or different from each other.

For example, Y₁ and Y₂ may each independently be a phenyl group unsubstituted or substituted with a t-butyl group, an amine group substituted with a phenyl group, or an unsubstituted carbazole group.

In Formula 2, -* represents a bond to the core structure of Formula 1. For example, it may represent a bond to a phenyl group bonded to a nitrogen atom of the core structure of Formula 1, or a bond to a benzene ring fused through a boron atom and a nitrogen atom, to a benzene ring fused through a boron atom and a heteroatom, or to Cy of Formula 1.

For example, the core structure of Formula 1 may be represented by the following structure.

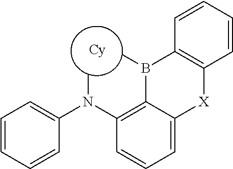

In an embodiment, the polycyclic compound represented by Formula 1 may be represented by any one of Formulas 1-1a to 1-1d.

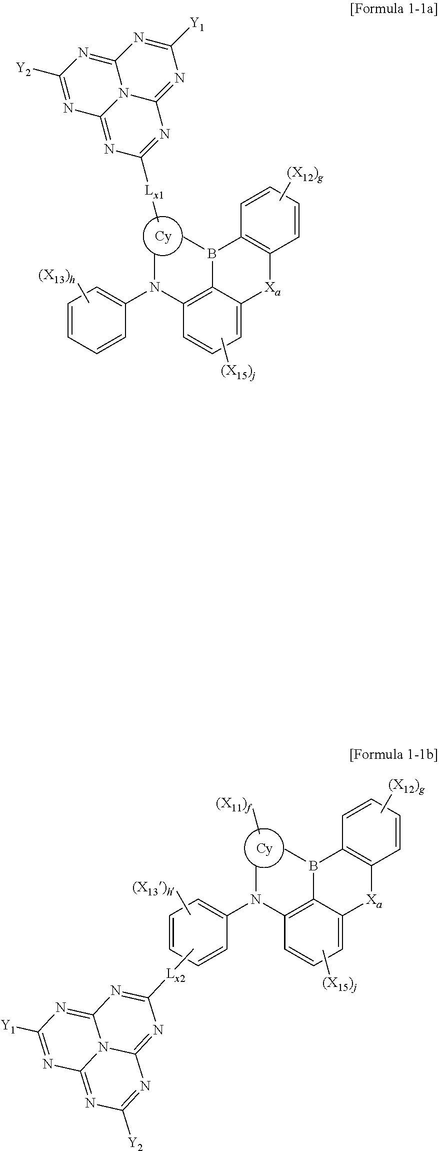

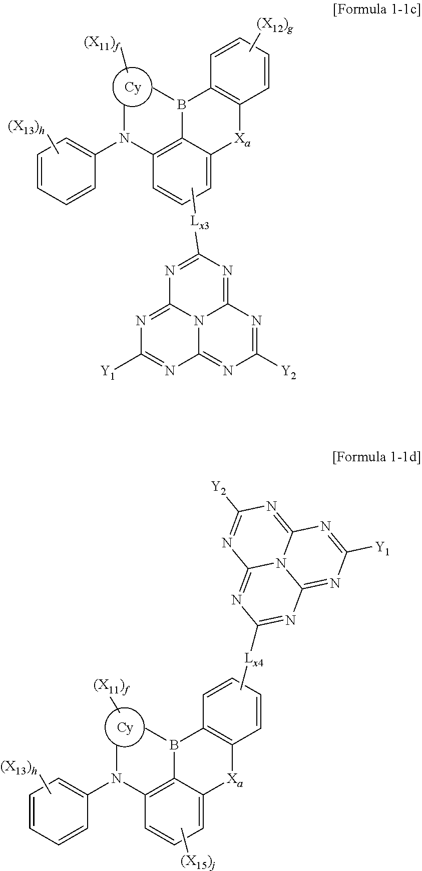

Formulas 1-1a to 1-1d each represent a case where a bonding position of a substituent represented by Formula 2 is further defined.

In Formulas 1-1a to 1-1d, Lₓ₁ to Lₓ₄ may each independently be a direct linkage, a substituted or unsubstituted amine group, a substituted or unsubstituted arylene group having 6 to 20 ring-forming carbon atoms, or a substituted or unsubstituted heteroarylene group having 2 to 20 ring-forming carbon atoms. In an embodiment, Lₓ₁ to Lₓ₄ may be the same as each other, or at least one thereof may be different from the remainder.

For example, Lₓ₁ to Lₓ₄ may each independently be a direct linkage, a phenylene group unsubstituted or substituted with a heptazine group, an unsubstituted biphenylene group, an unsubstituted naphthalene group, an unsubstituted anthracene group, an unsubstituted carbazole group, an amine group substituted with a phenyl group and a biphenyl group, or a phenoxazine group substituted with t-butyl group.

In Formulas 1-1a to 1-1d, Xₐ may be N(Rₓ₁), O, S, Se, or Te; and Rₓ₁ may be a group represented by Formula 1b.

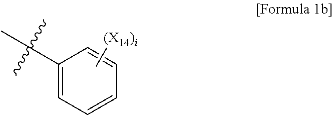

In Formula 1b,

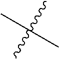

represents a bond to N of N(Rₓ₁).

In Formulas 1-1a to 1-1d and 1b, X₁₁ to X₁₅ and X_{13′} may each independently be a hydrogen atom, a cyano group, a substituted or unsubstituted oxy group, a substituted or unsubstituted alkyl group having 1 to 60 carbon atoms, a substituted or unsubstituted cycloalkyl group having 3 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. In an embodiment, X₁₁ to X₁₅ may be the same as each other, or at least one thereof may be different from the remainder.

For example, X₁₁ to X₁₅ and X_{13′} may each independently be a hydrogen atom, a cyano group, a methyl group, an isopropyl group, a t-butyl group, a pentyl group, a cyclopentyl group, a cyclohexyl group, a phenyl group substituted with a t-butyl group, a phenyl group substituted with a phenyl group, an unsubstituted phenyl group, a dimethylfluorenyl group, a furan group, a carbazole group substituted with a deuterium atom, a carbazole group substituted with a t-butyl group, an unsubstituted carbazole group, a heptazine group substituted with a phenyl group, or a phenoxy group, or may be bonded to an adjacent group to form a benzofuran ring, a dimethylchroman ring, or a spirobifluorene ring.

In Formulas 1-1a to 1-1d and 1b, f and g may each independently be an integer from 1 to 4. In an embodiment, f and g may be the same as or different from each other. When f is 2 or greater, two or more X₁₁ groups may be the same as each other, or at least one group thereof may be different from the remainder. When g is 2 or greater, two or more X₁₂ groups may be the same as each other, or at least one group thereof may be different from the remainder.

In Formulas 1-1a to 1-1d and 1b, h and i may each independently be an integer from 1 to 5. In an embodiment, h and i may be the same as or different from each other. When h is 2 or greater, two or more X₁₃ groups may be the same as each other, or at least one group thereof may be different from the remainder. When i is 2 or greater, two or more X₁₄ groups may be the same as each other, or at least one group thereof may be different from the remainder.

In Formulas 1-1a to 1-1d and 1b, j may be an integer from 1 to 3. When j is 2 or greater, two or more X₁₅ groups may be the same as each other, or at least one group thereof may be different from the remainder.

In Formulas 1-1a to 1-1d and 1b, h′ may be an integer from 0 to 4. A case where h′ is 0 may be the same as a case where h′ is 4 and all X_{13′} groups are hydrogen atoms. When h′ is 2 or greater, two or more X_{13′} groups may be the same as each other, or at least one group thereof may be different from the remainder.

In Formulas 1-1a to 1-1d and 1b, Cy is the same as defined in Formula 1, and Y₁ and Y₂ are the same as defined in Formula 2.

In an embodiment, the polycyclic compound represented by Formula 1 may be represented by any one of Formulas 1-2a to 1-2d.

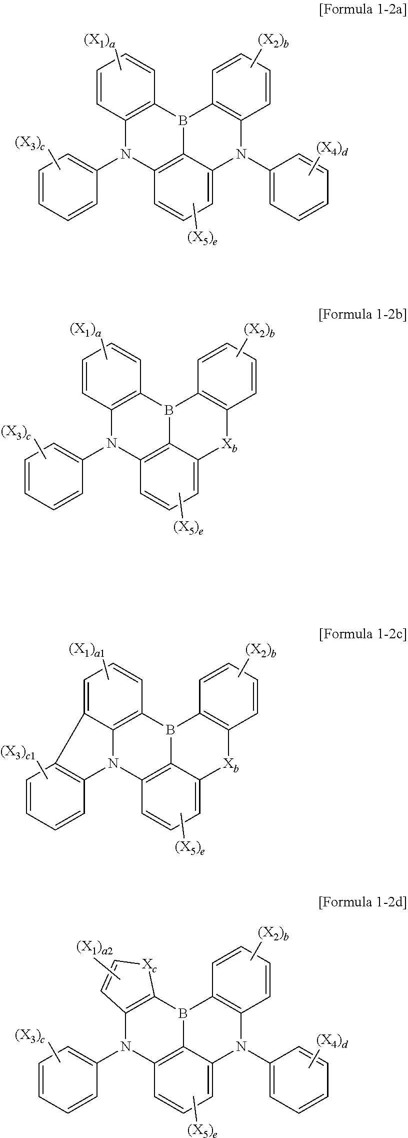

Formulas 1-2a to 1-2d each represent a case where Cy and X of Formula 1 are further defined.

In Formulas 1-2a to 1-2d, a1 may be an integer from 1 to 3. When a1 is 2 or greater, two or more X₁ groups may be the same as each other, or at least one group thereof may be different from the remainder.

In Formulas 1-2a to 1-2d, a2 may be 1 or 2. When a2 is 2, two X₁ groups may be the same as or different from each other.

In Formulas 1-2a to 1-2d, c1 may be an integer from 1 to 4. When c1 is 2 or greater, two or more X₃ groups may be the same as each other, or at least one group thereof may be different from the remainder.

In Formulas 1-2a to 1-2d, X_{b} and X_{c} may each independently be O, S, Se, or Te.

In Formulas 1-2a to 1-2d, X₁ to X₅ and a to e are the same as defined in Formula 1.

In an embodiment, the group represented by Formula 2 may be represented by any one of Formulas 2-1 to 2-3.

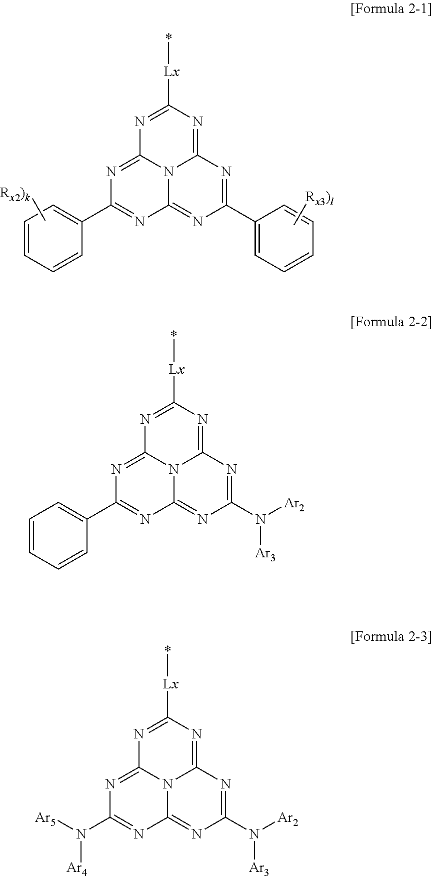

Formulas 2-1 to 2-3 each represent a case where Y₁ and Y₂ in Formula 2 are further defined.

In Formulas 2-1 to 2-3, Rₓ₂ and Rₓ₃ may each independently be a hydrogen atom or a t-butyl group.

In Formulas 2-1 to 2-3, k and 1 may each independently be an integer from 0 to 5. A case where k is 0 may be the same as a case where k is 5 and all Rₓ₂ groups are hydrogen atoms. When k is 2 or greater, two or more Rₓ₂ groups may be the same as each other, or at least one group thereof may be different from the remainder. A case where 1 is 0 may be the same as a case where 1 is 5 and all Rₓ₃ groups are hydrogen atoms. When 1 is 2 or greater, two or more Rₓ₃ groups may be the same as each other, or at least one group thereof may be different from the remainder.

In Formulas 2-1 to 2-3, Ar₂ to Ar₅ may each independently be an unsubstituted phenyl group, or bonded to an adjacent group to form a ring. When Ar₂ to Ar₅ are bonded to an adjacent group to form a ring, an unsubstituted carbazole group may be formed that includes a nitrogen atom to which Ar₂ to Ar₅ are bonded. In an embodiment, Ar₂ to Ar₅ may be the same as each other, or at least one group thereof may be different from the remainder.

In Formulas 2-1 to 2-3, Lₓ is the same as defined in Formula 2.

In an embodiment, in Formula 1, at least one of X₁ to X₅ may each independently be a group represented by Formula 3; and the remainder of X₁ to X₅ may each independently be a hydrogen atom, a cyano group, a substituted or unsubstituted oxy group, a substituted or unsubstituted alkyl group having 1 to 60 carbon atoms, a substituted or unsubstituted cycloalkyl group having 3 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

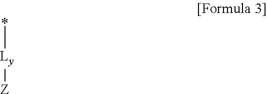

In Formula 3, L_{y} may be a direct linkage, a substituted or unsubstituted amine group, a substituted or unsubstituted arylene group having 6 to 60 ring-forming carbon atoms, or a substituted or unsubstituted heteroarylene group having 2 to 60 ring-forming carbon atoms. For example, L_{y} may be a direct linkage, a phenylene group unsubstituted or substituted with a heptazine group, an unsubstituted biphenylene group, an unsubstituted naphthalene group, an unsubstituted anthracene group, an unsubstituted carbazole group, an amine group substituted with a phenyl group and a biphenyl group, or a phenoxazine group substituted with t-butyl group.

In Formula 3, Z may be a substituted or unsubstituted tricyclic heteroaryl group having 6 to 11 ring-forming carbon atoms and 2 to 7 ring-forming nitrogen atoms. For example, Z may be a heptazine group containing 7 nitrogen atoms. For example, Z may be a phenyl group, an amine group, or a heptazine group substituted with a carbazole group.

In Formula 3, -* represents a bond to the core structure of Formula 1. For example, it may represent a bond to a phenyl group bonded to a nitrogen atom of the core structure of Formula 1, or a bond to a benzene ring fused through a boron atom and a nitrogen atom, to a benzene ring fused through a boron atom and a heteroatom, or to Cy of Formula 1.

For example, the core structure of Formula 1 may be represented by the following structure.

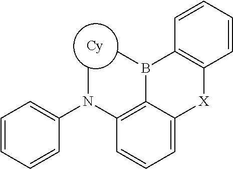

In an embodiment, Z may be a group represented by Formula 4.

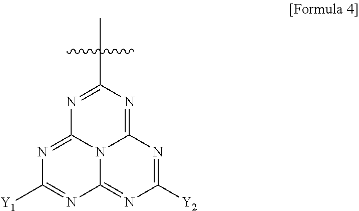

In Formula 4, Y₁ and Y₂ may each independently be a substituted or unsubstituted amine group, a substituted or unsubstituted aryl group having 6 to 20 ring-forming carbon atoms, or a substituted or unsubstituted heteroaryl group having 2 to 20 ring-forming carbon atoms.

For example, Y₁ and Y₂ may each independently be a phenyl group unsubstituted or substituted with a t-butyl group, an amine group substituted with a phenyl group, or an unsubstituted carbazole group.

In Formula 4,

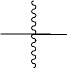

represents a bond to L_{y} in Formula 3.

In an embodiment, the polycyclic compound may be any compound selected from Compound Group 1. In an embodiment, in the light emitting element ED, the emission layer EML may include at least one compound selected from Compound Group 1.

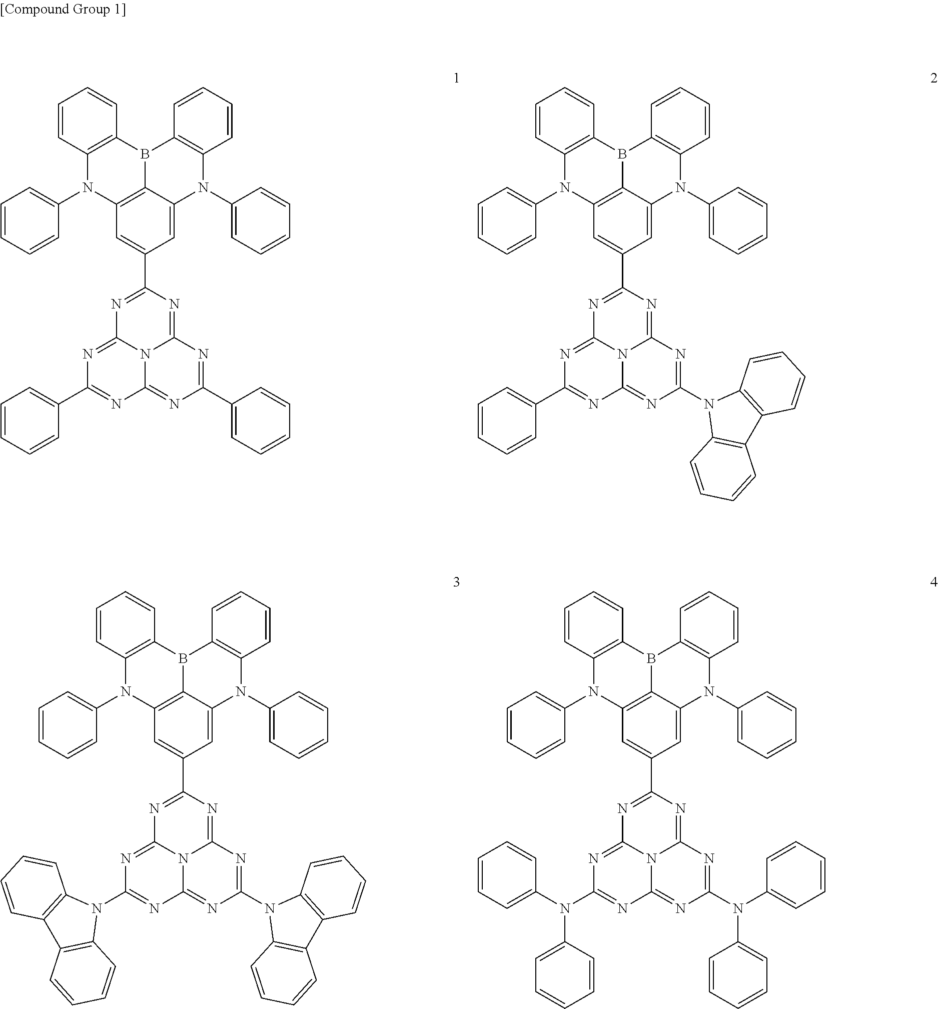 [SMILES: c1ccc(C2=NC3=NC(c4ccccc4)=NC4=NC(c5cc6c7c(c5)N(c5ccccc5)c5ccccc5B7c5ccccc5N6c5ccccc5)=NC(=N2)N34)cc1 ; c1ccc(C2=NC3=NC(n4c5ccccc5c5ccccc54)=NC4=NC(c5cc6c7c(c5)N(c5ccccc5)c5ccccc5B7c5ccccc5N6c5ccccc5)=NC(=N2)N43)cc1 ; c1ccc(N2c3ccccc3B3c4ccccc4N(c4ccccc4)c4cc(C5=NC6=NC(n7c8ccccc8c8ccccc87)=NC7=NC(n8c9ccccc9c9ccccc98)=NC(=N5)N67)cc2c43)cc1 ; c1ccc(N(C2=NC3=NC(c4cc5c6c(c4)N(c4ccccc4)c4ccccc4B6c4ccccc4N5c4ccccc4)=NC4=NC(N(c5ccccc5)c5ccccc5)=NC(=N2)N34)c2ccccc2)cc1]

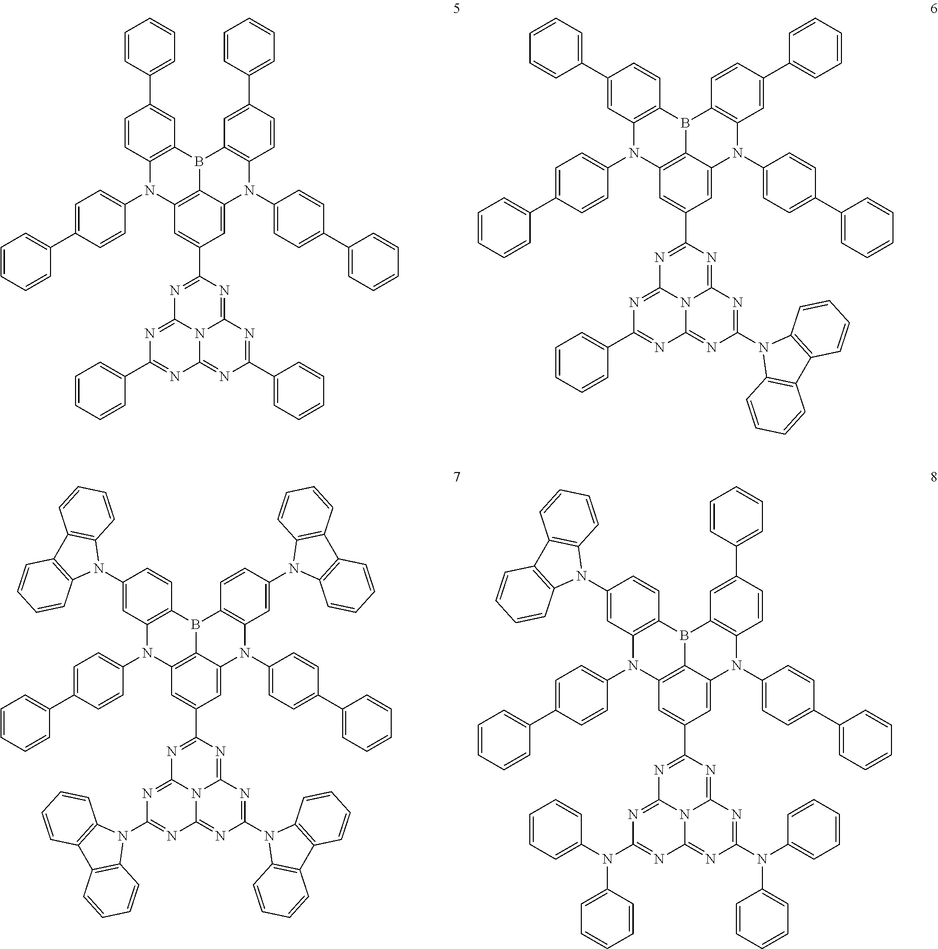

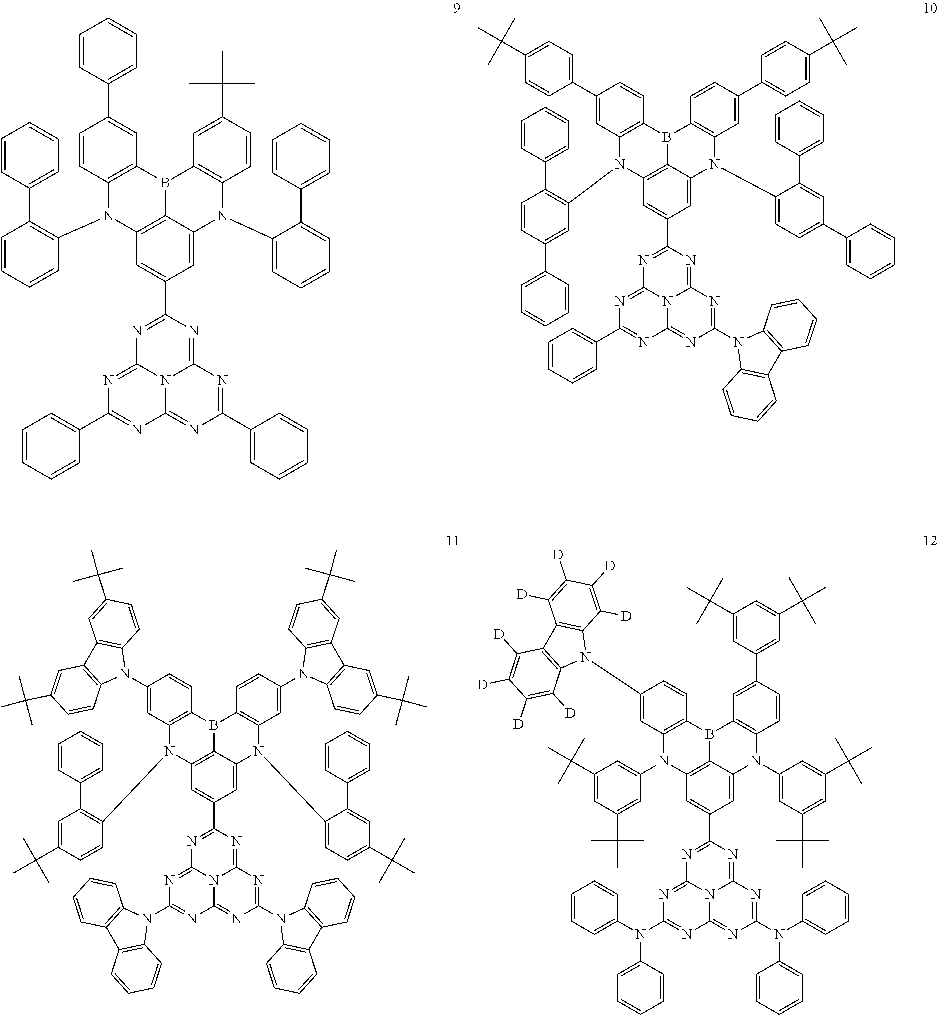

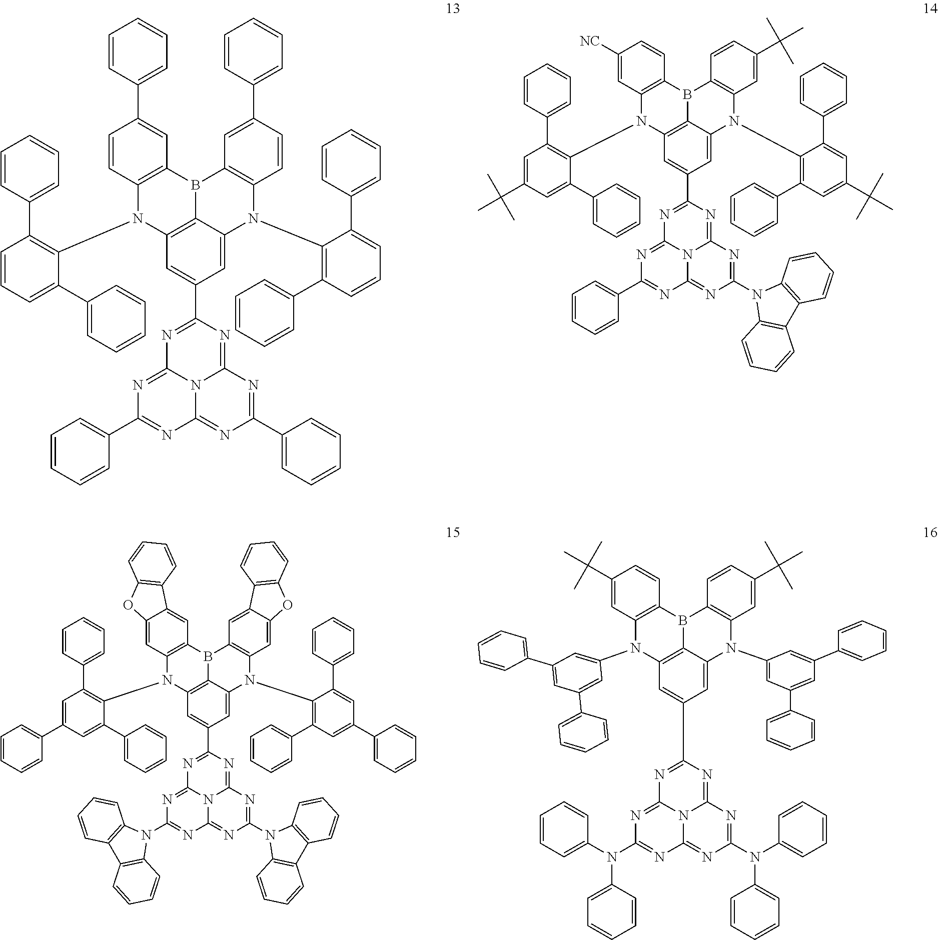

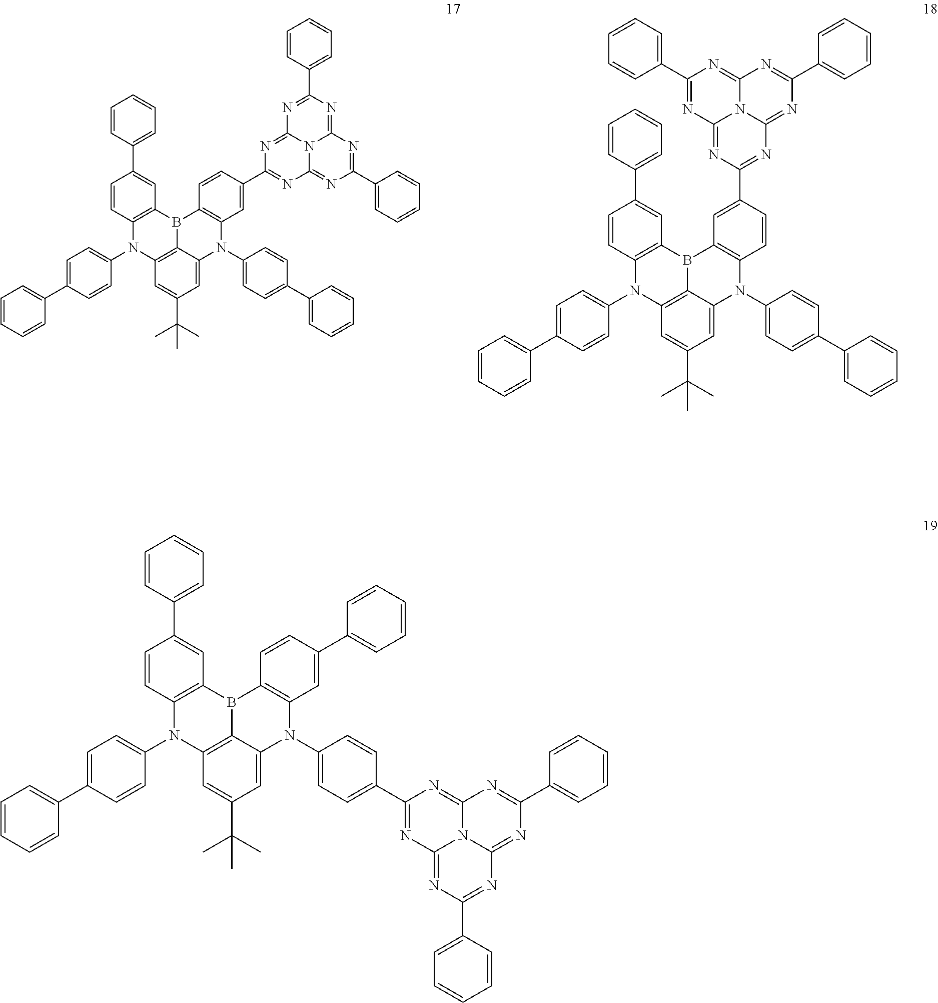 [SMILES: CC(C)(C)c1cc2c3c(c1)N(c1ccc(-c4ccccc4)cc1)c1cc(C4=NC5=NC(c6ccccc6)=NC6=NC(c7ccccc7)=NC(=N4)N65)ccc1B3c1cc(-c3ccccc3)ccc1N2c1ccc(-c2ccccc2)cc1 ; CC(C)(C)c1cc2c3c(c1)N(c1ccc(-c4ccccc4)cc1)c1ccc(-c4ccccc4)cc1B3c1cc(C3=NC4=NC(c5ccccc5)=NC5=NC(c6ccccc6)=NC(=N3)N54)ccc1N2c1ccc(-c2ccccc2)cc1 ; CC(C)(C)c1cc2c3c(c1)N(c1ccc(C4=NC5=NC(c6ccccc6)=NC6=NC(c7ccccc7)=NC(=N4)N65)cc1)c1cc(-c4ccccc4)ccc1B3c1cc(-c3ccccc3)ccc1N2c1ccc(-c2ccccc2)cc1]

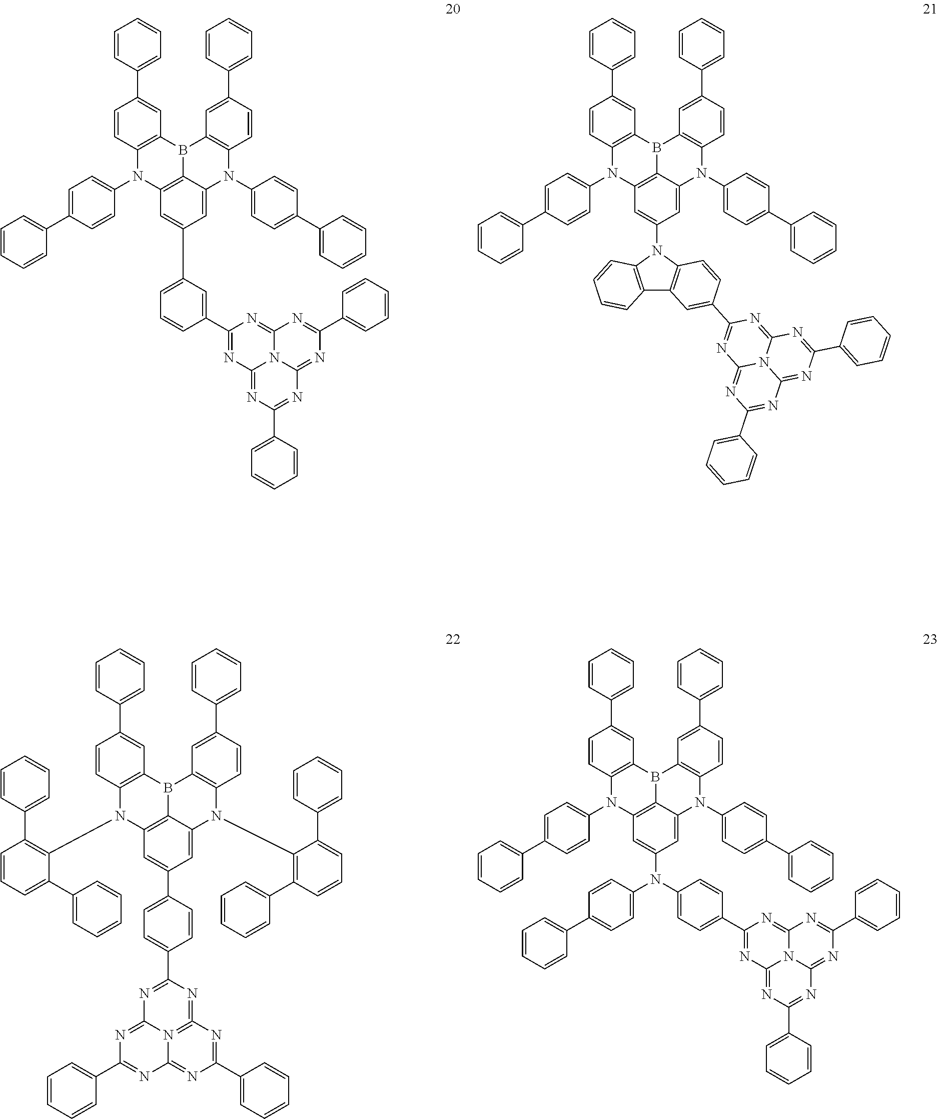

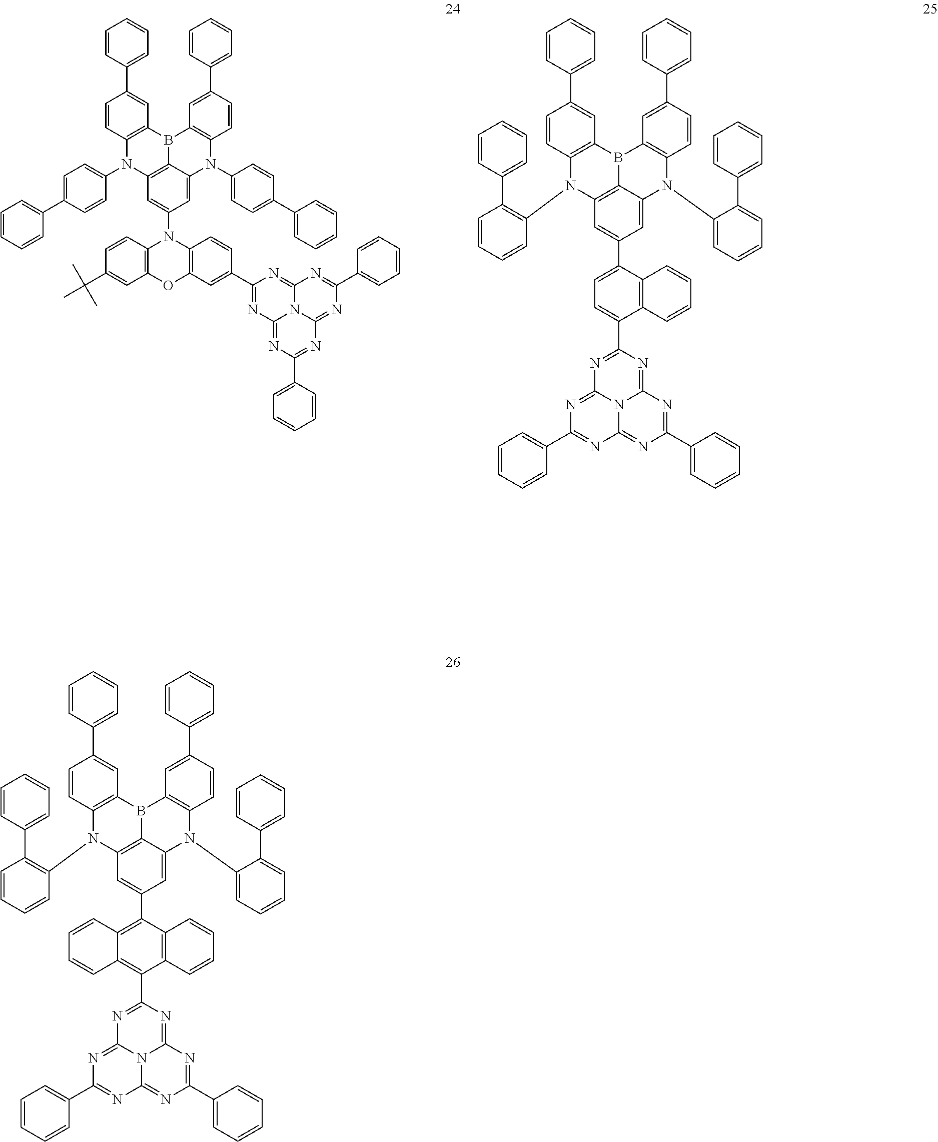 [SMILES: CC(C)(C)c1ccc2c(c1)Oc1cc(C3=NC4=NC(c5ccccc5)=NC5=NC(c6ccccc6)=NC(=N3)N54)ccc1N2c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1 ; c1ccc(C2=NC3=NC(c4ccccc4)=NC4=NC(c5ccc(-c6cc7c8c(c6)N(c6ccccc6-c6ccccc6)c6ccc(-c9ccccc9)cc6B8c6cc(-c8ccccc8)ccc6N7c6ccccc6-c6ccccc6)c6ccccc56)=NC(=N2)N34)cc1 ; c1ccc(C2=NC3=NC(c4ccccc4)=NC4=NC(c5c6ccccc6c(-c6cc7c8c(c6)N(c6ccccc6-c6ccccc6)c6ccc(-c9ccccc9)cc6B8c6cc(-c8ccccc8)ccc6N7c6ccccc6-c6ccccc6)c6ccccc56)=NC(=N2)N34)cc1]

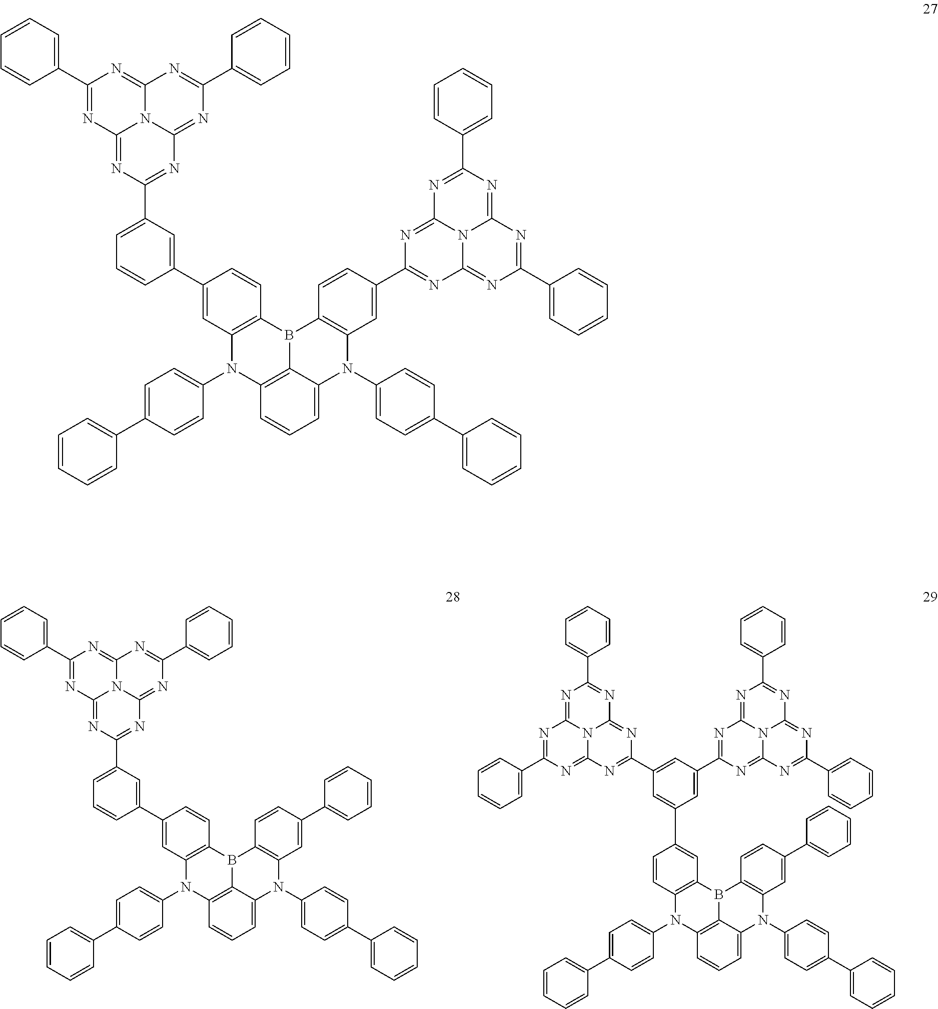

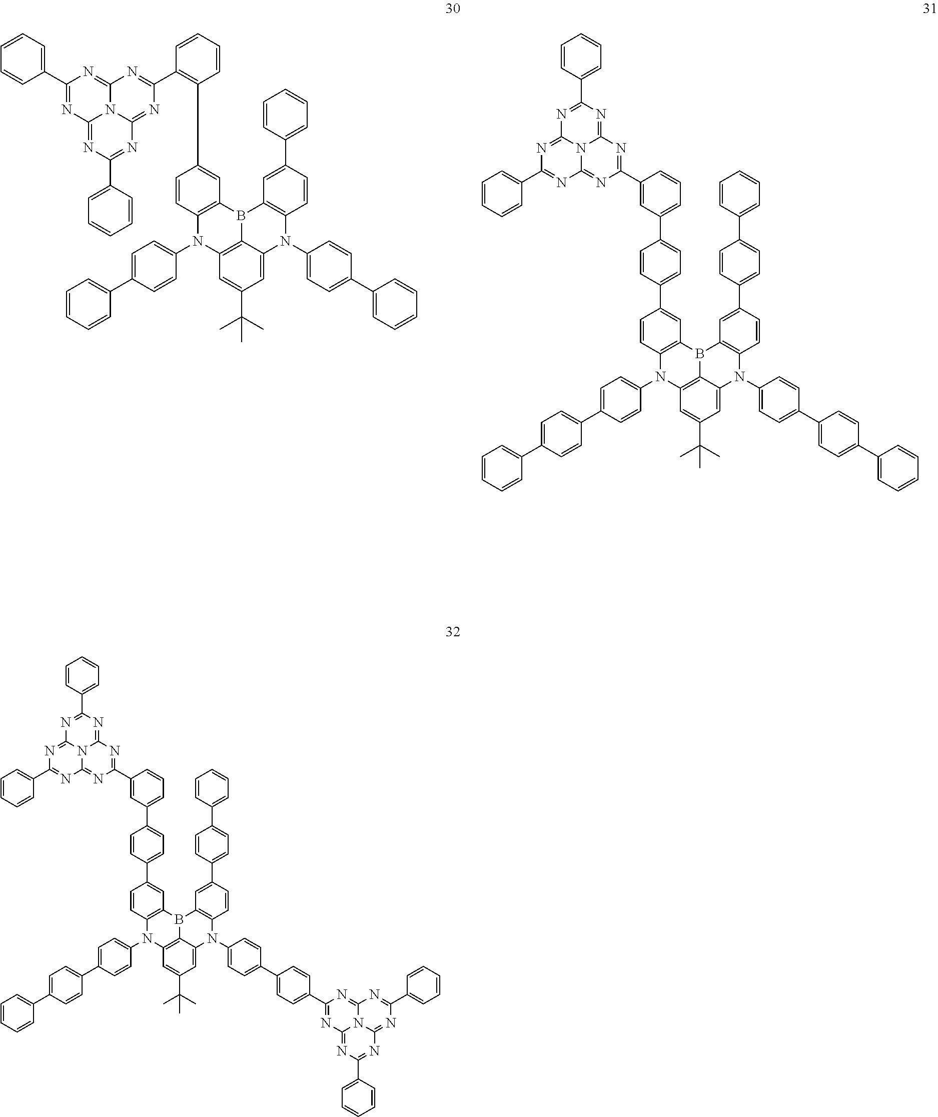

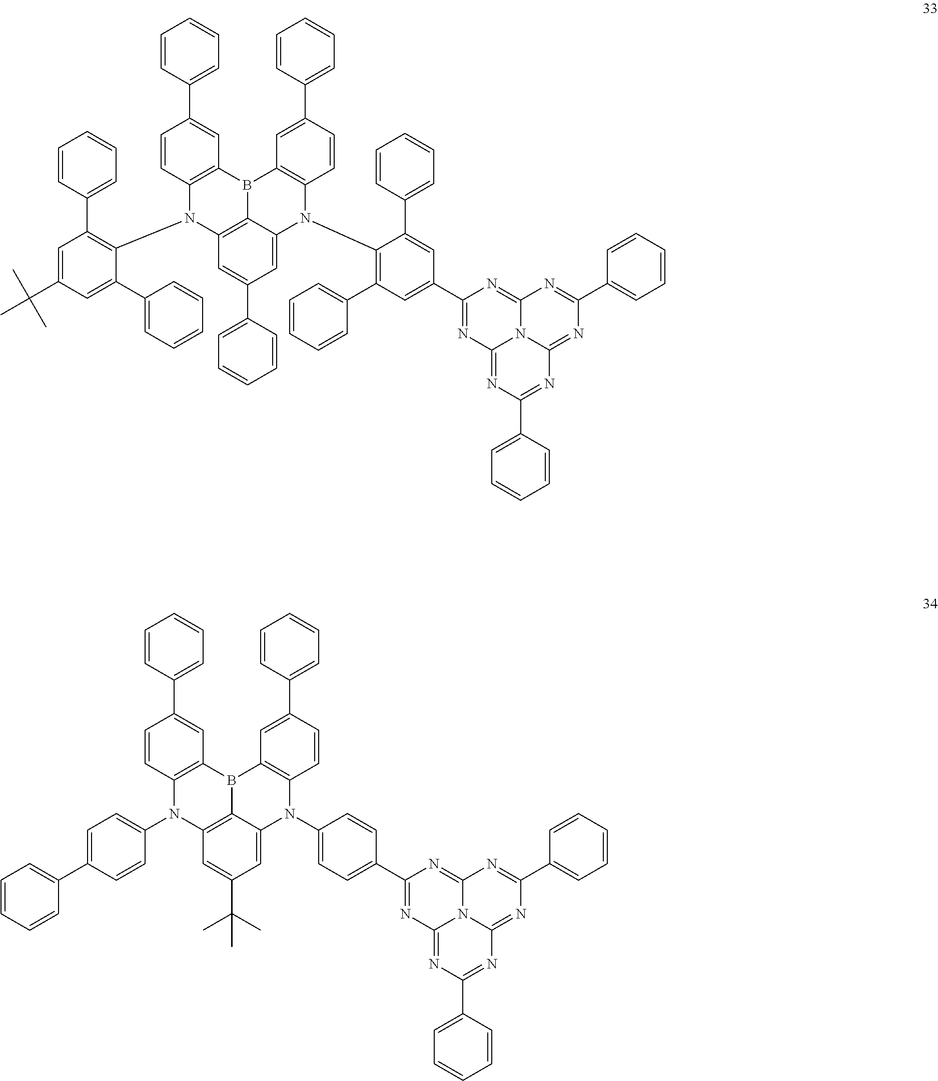 [SMILES: CC(C)(C)c1cc(-c2ccccc2)c(N2c3ccc(-c4ccccc4)cc3B3c4cc(-c5ccccc5)ccc4N(c4c(-c5ccccc5)cc(C5=NC6=NC(c7ccccc7)=NC7=NC(c8ccccc8)=NC(=N5)N76)cc4-c4ccccc4)c4cc(-c5ccccc5)cc2c43)c(-c2ccccc2)c1 ; CC(C)(C)c1cc2c3c(c1)N(c1ccc(-c4ccccc4)cc1)c1ccc(-c4ccccc4)cc1B3c1cc(-c3ccccc3)ccc1N2c1ccc(C2=NC3=NC(c4ccccc4)=NC4=NC(c5ccccc5)=NC(=N2)N43)cc1]

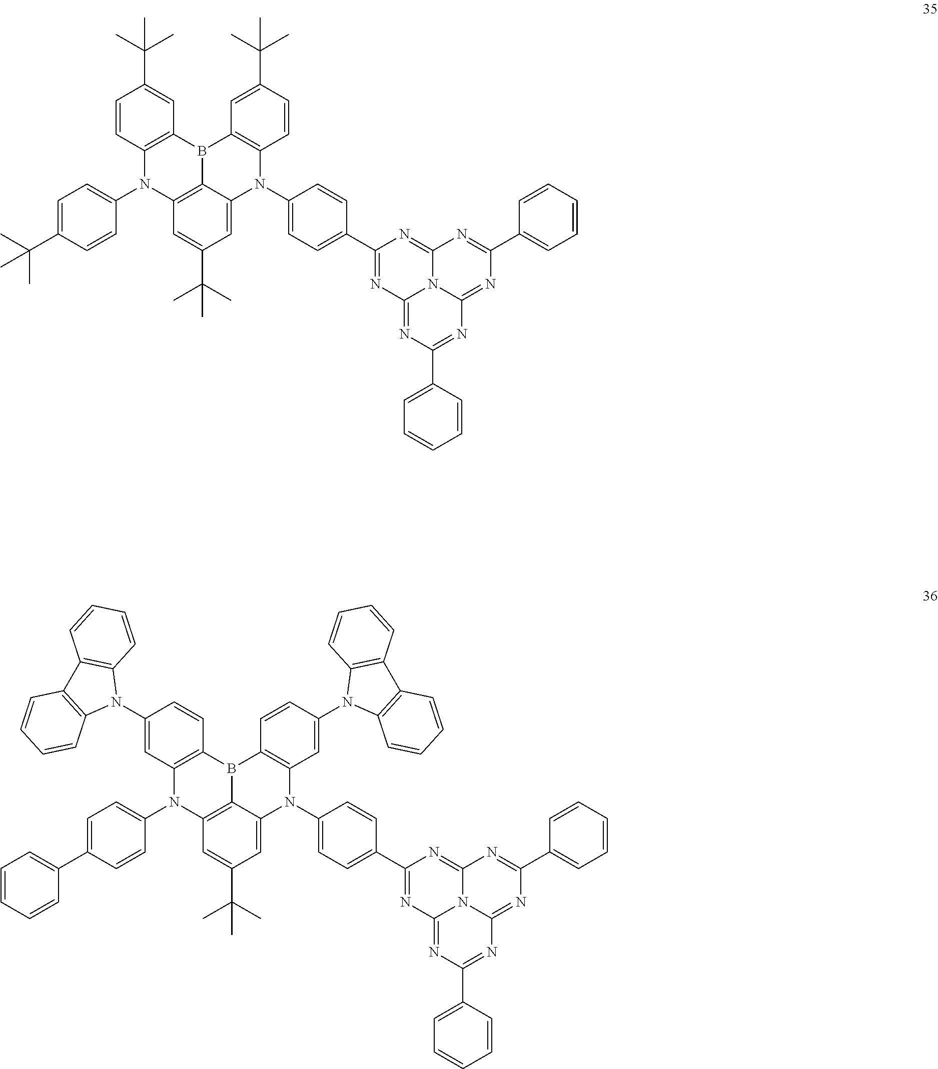 [SMILES: CC(C)(C)c1ccc(N2c3ccc(C(C)(C)C)cc3B3c4cc(C(C)(C)C)ccc4N(c4ccc(C5=NC6=NC(c7ccccc7)=NC7=NC(c8ccccc8)=NC(=N5)N76)cc4)c4cc(C(C)(C)C)cc2c43)cc1 ; CC(C)(C)c1cc2c3c(c1)N(c1ccc(-c4ccccc4)cc1)c1cc(-n4c5ccccc5c5ccccc54)ccc1B3c1ccc(-n3c4ccccc4c4ccccc43)cc1N2c1ccc(C2=NC3=NC(c4ccccc4)=NC4=NC(c5ccccc5)=NC(=N2)N43)cc1]

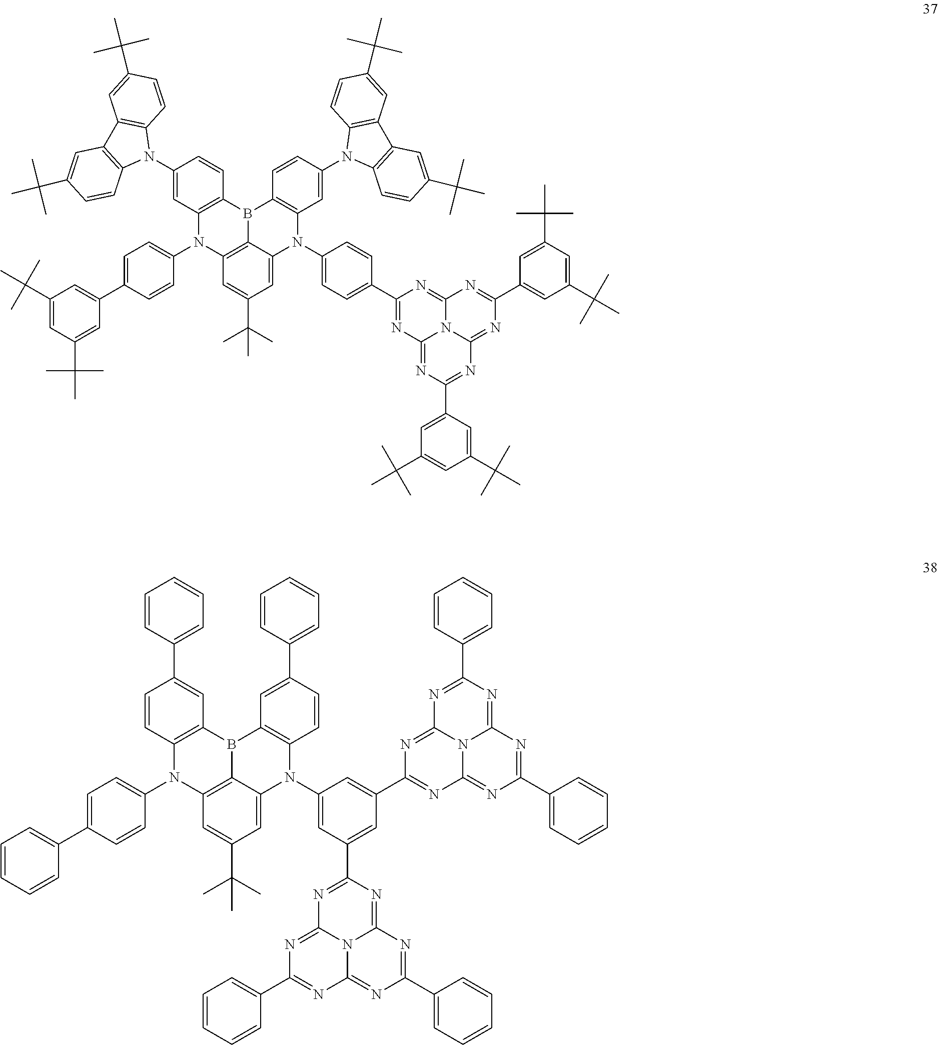 [SMILES: CC(C)(C)c1cc(C2=NC3=NC(c4ccc(N5c6cc(-n7c8ccc(C(C)(C)C)cc8c8cc(C(C)(C)C)ccc87)ccc6B6c7ccc(-n8c9ccc(C(C)(C)C)cc9c9cc(C(C)(C)C)ccc98)cc7N(c7ccc(-c8cc(C(C)(C)C)cc(C(C)(C)C)c8)cc7)c7cc(C(C)(C)C)cc5c76)cc4)=NC4=NC(c5cc(C(C)(C)C)cc(C(C)(C)C)c5)=NC(=N2)N34)cc(C(C)(C)C)c1 ; CC(C)(C)c1cc2c3c(c1)N(c1cc(C4=NC5=NC(c6ccccc6)=NC6=NC(c7ccccc7)=NC(=N4)N65)cc(C4=NC5=NC(c6ccccc6)=NC6=NC(c7ccccc7)=NC(=N4)N65)c1)c1ccc(-c4ccccc4)cc1B3c1cc(-c3ccccc3)ccc1N2c1ccc(-c2ccccc2)cc1]

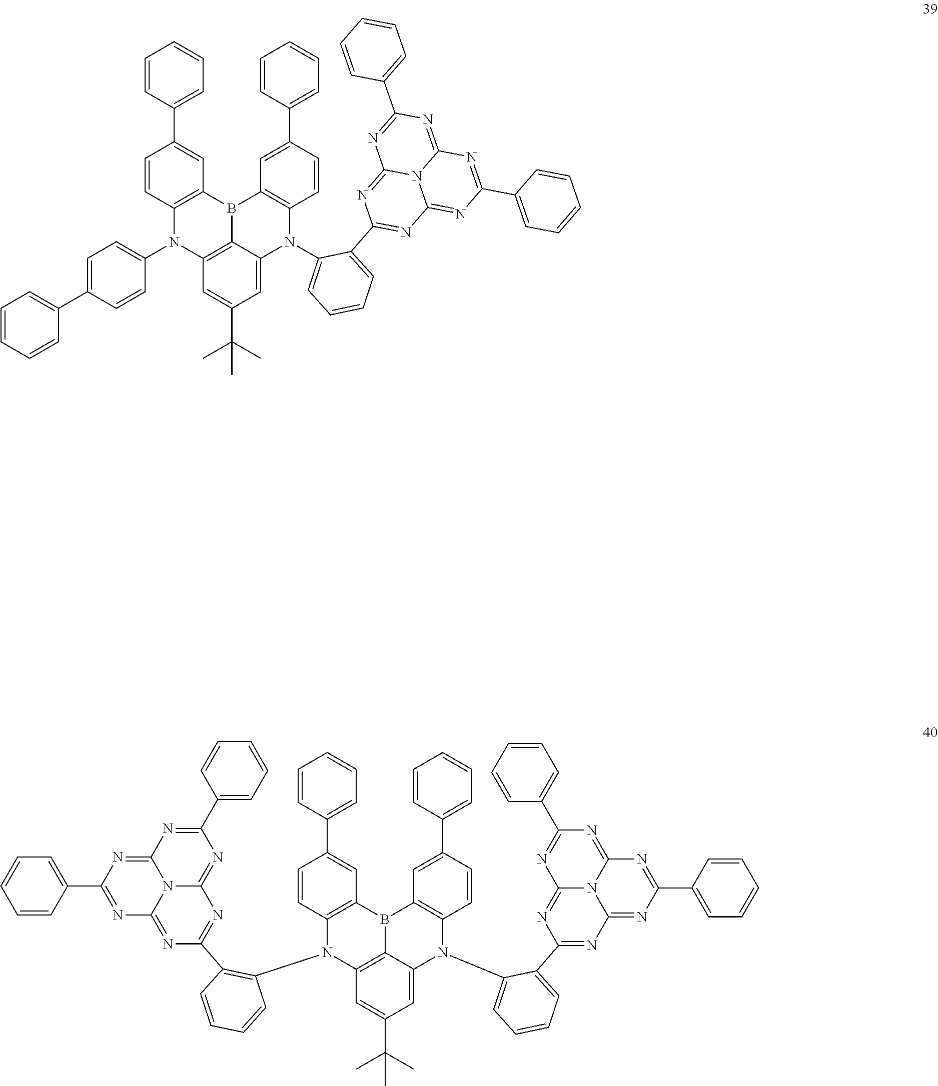 [SMILES: CC(C)(C)c1cc2c3c(c1)N(c1ccccc1C1=NC4=NC(c5ccccc5)=NC5=NC(c6ccccc6)=NC(=N1)N54)c1ccc(-c4ccccc4)cc1B3c1cc(-c3ccccc3)ccc1N2c1ccc(-c2ccccc2)cc1 ; CC(C)(C)c1cc2c3c(c1)N(c1ccccc1C1=NC4=NC(c5ccccc5)=NC5=NC(c6ccccc6)=NC(=N1)N54)c1ccc(-c4ccccc4)cc1B3c1cc(-c3ccccc3)ccc1N2c1ccccc1C1=NC2=NC(c3ccccc3)=NC3=NC(c4ccccc4)=NC(=N1)N32]

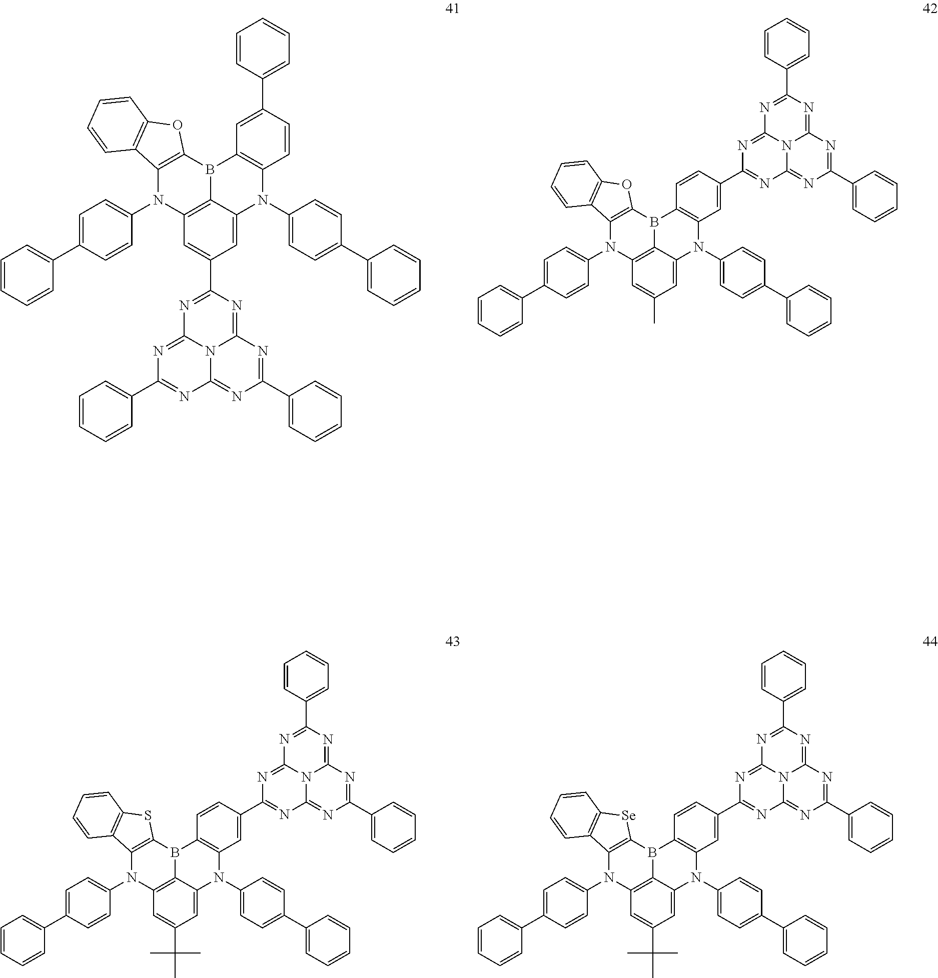

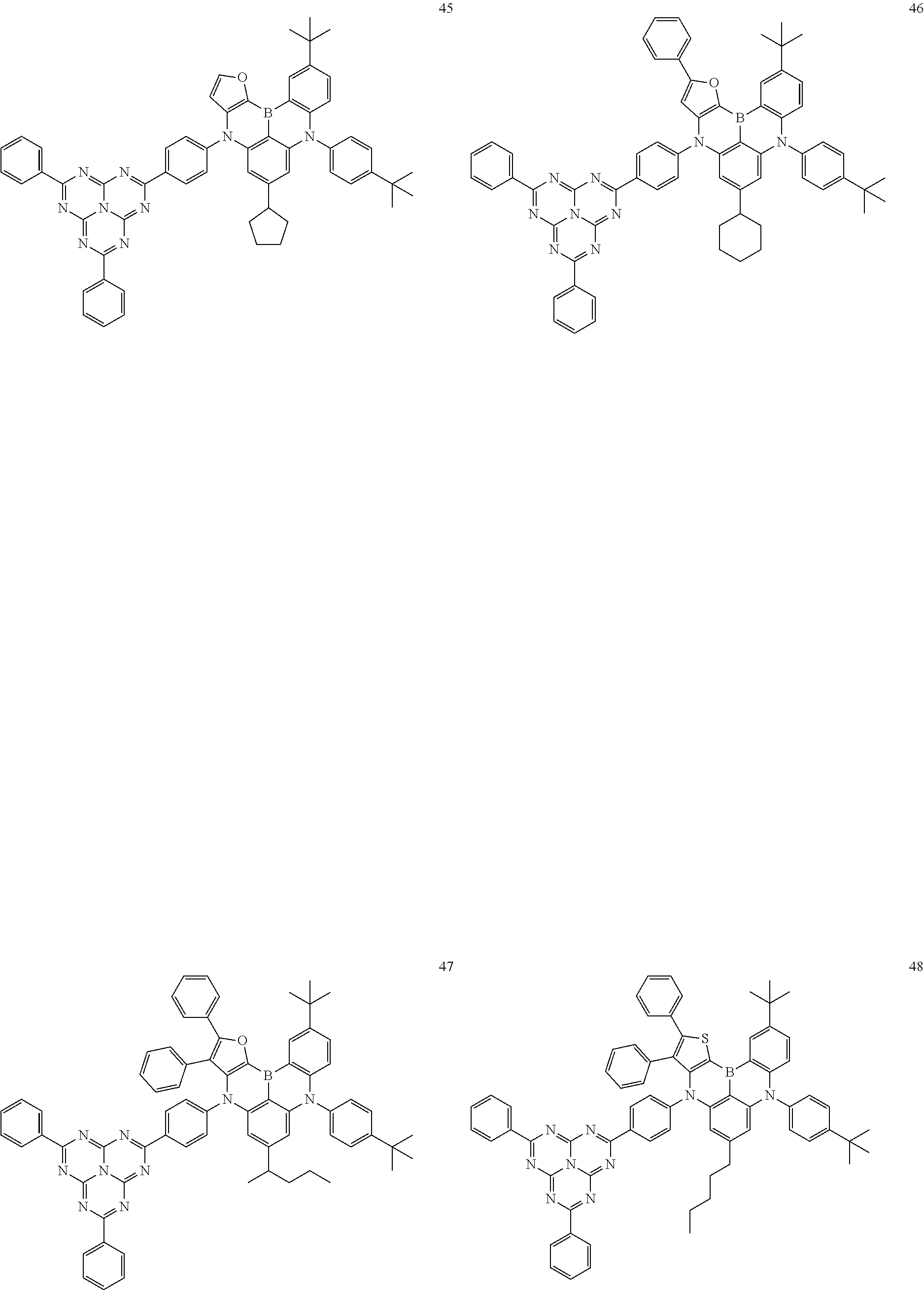

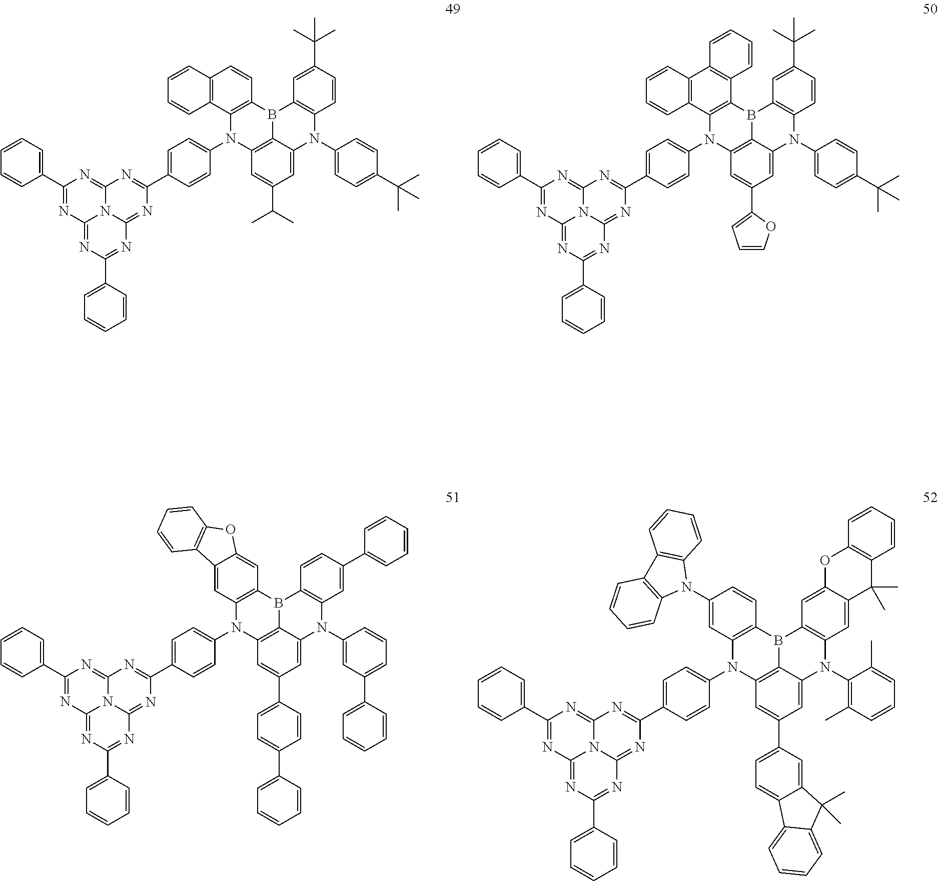

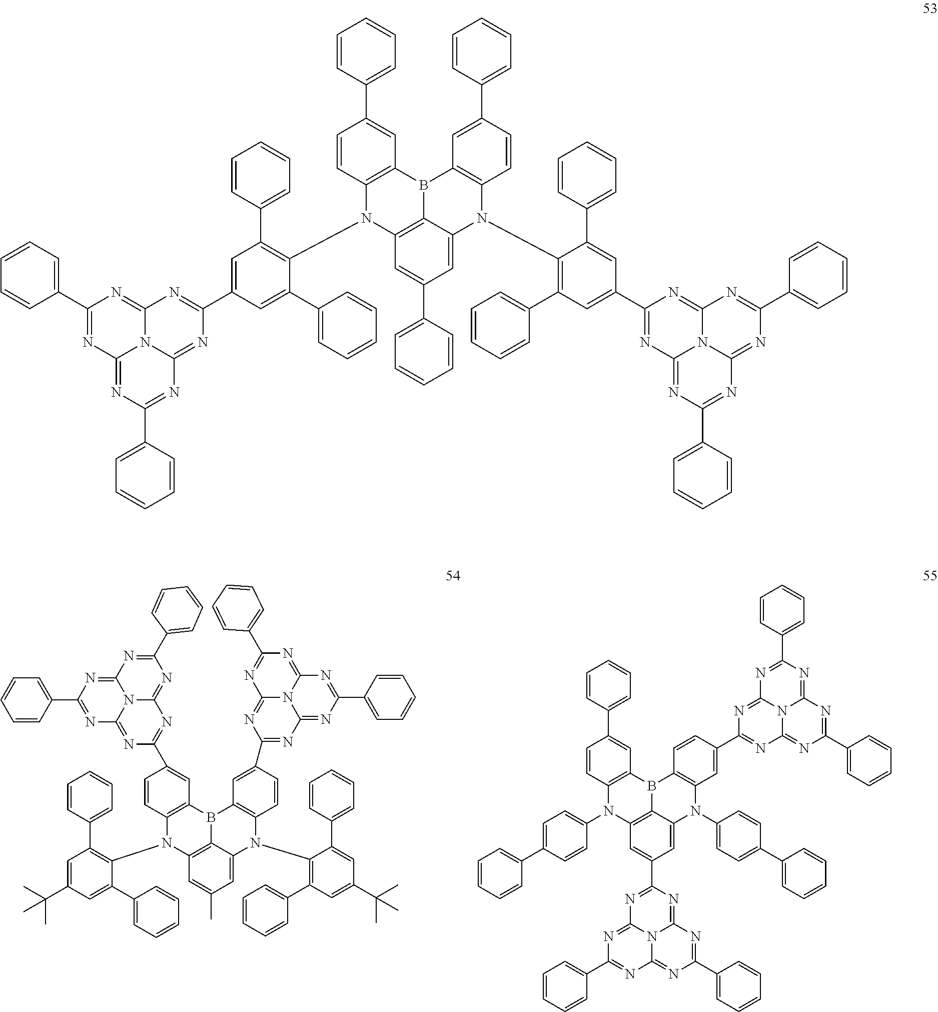

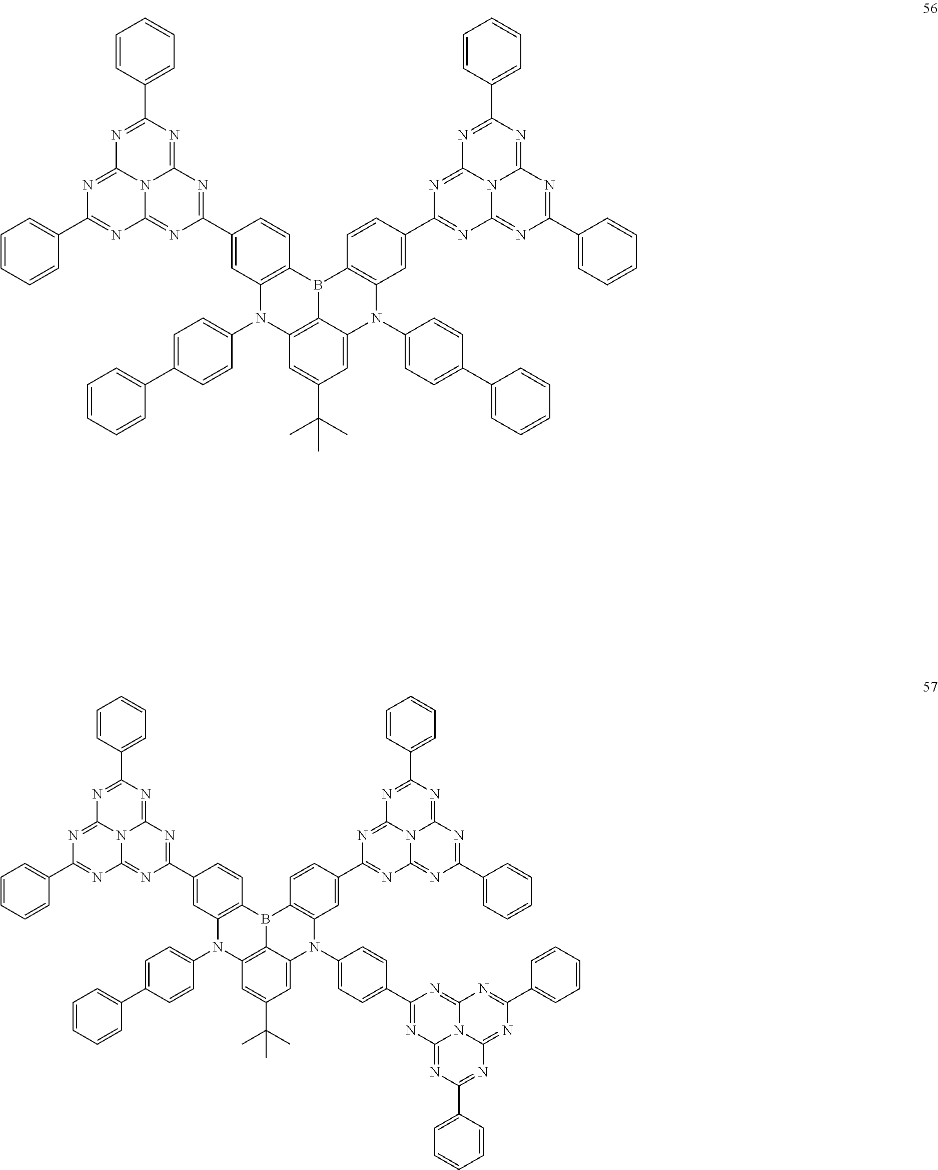 [SMILES: CC(C)(C)c1cc2c3c(c1)N(c1ccc(-c4ccccc4)cc1)c1cc(C4=NC5=NC(c6ccccc6)=NC6=NC(c7ccccc7)=NC(=N4)N65)ccc1B3c1ccc(C3=NC4=NC(c5ccccc5)=NC5=NC(c6ccccc6)=NC(=N3)N54)cc1N2c1ccc(-c2ccccc2)cc1 ; CC(C)(C)c1cc2c3c(c1)N(c1ccc(-c4ccccc4)cc1)c1cc(C4=NC5=NC(c6ccccc6)=NC6=NC(c7ccccc7)=NC(=N4)N65)ccc1B3c1ccc(C3=NC4=NC(c5ccccc5)=NC5=NC(c6ccccc6)=NC(=N3)N54)cc1N2c1ccc(C2=NC3=NC(c4ccccc4)=NC4=NC(c5ccccc5)=NC(=N2)N43)cc1]

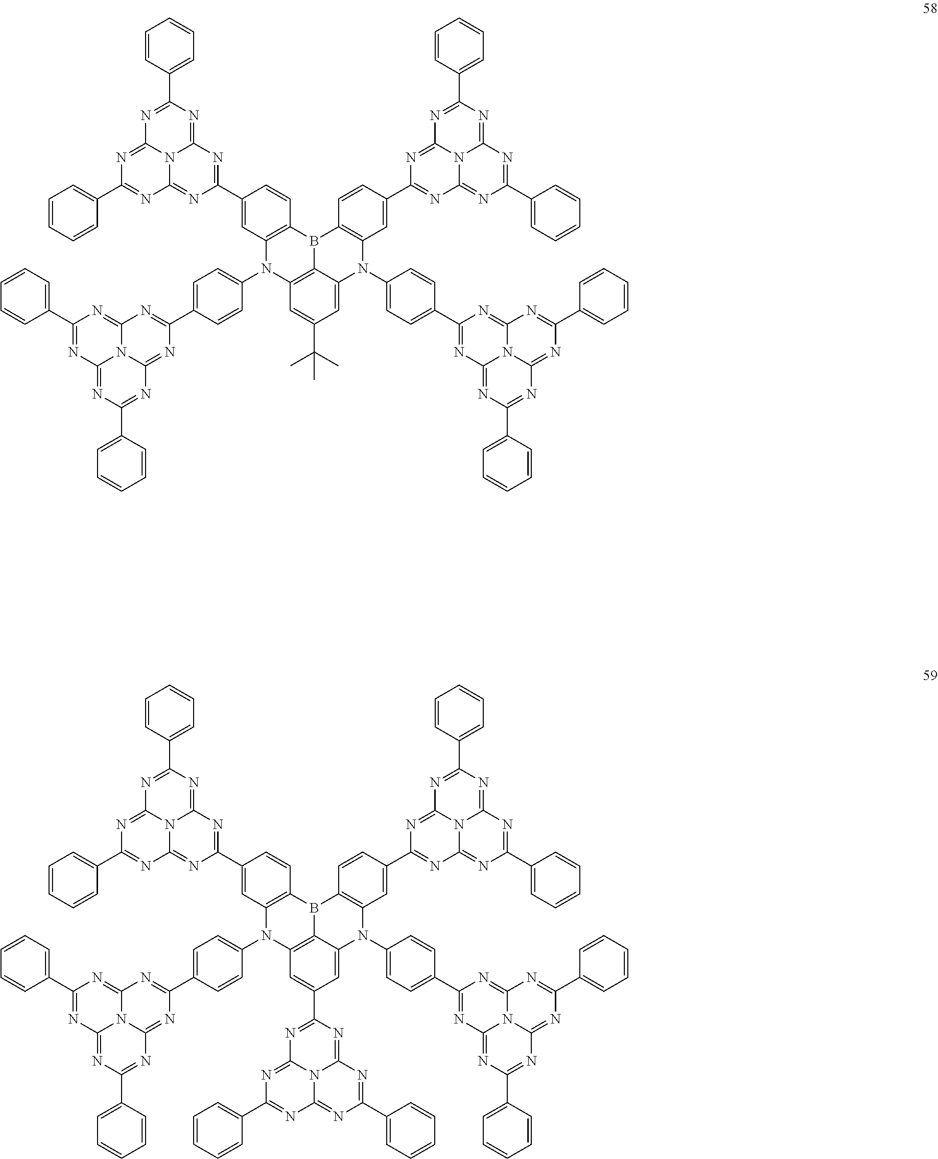

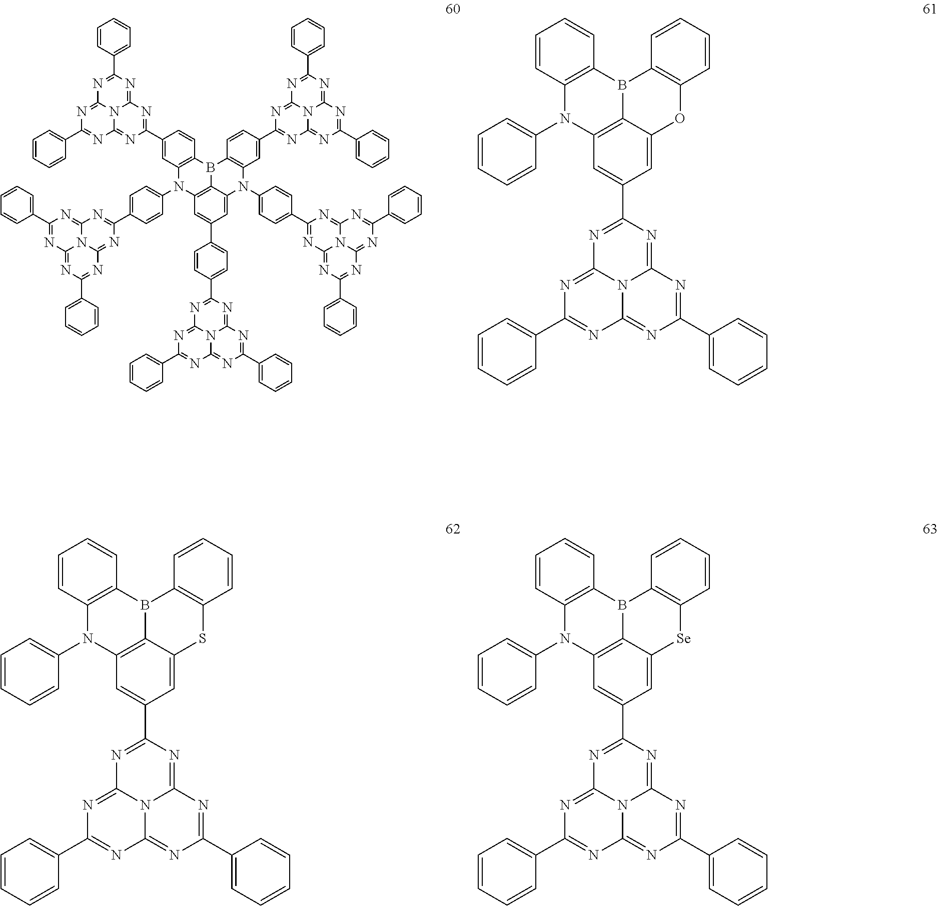

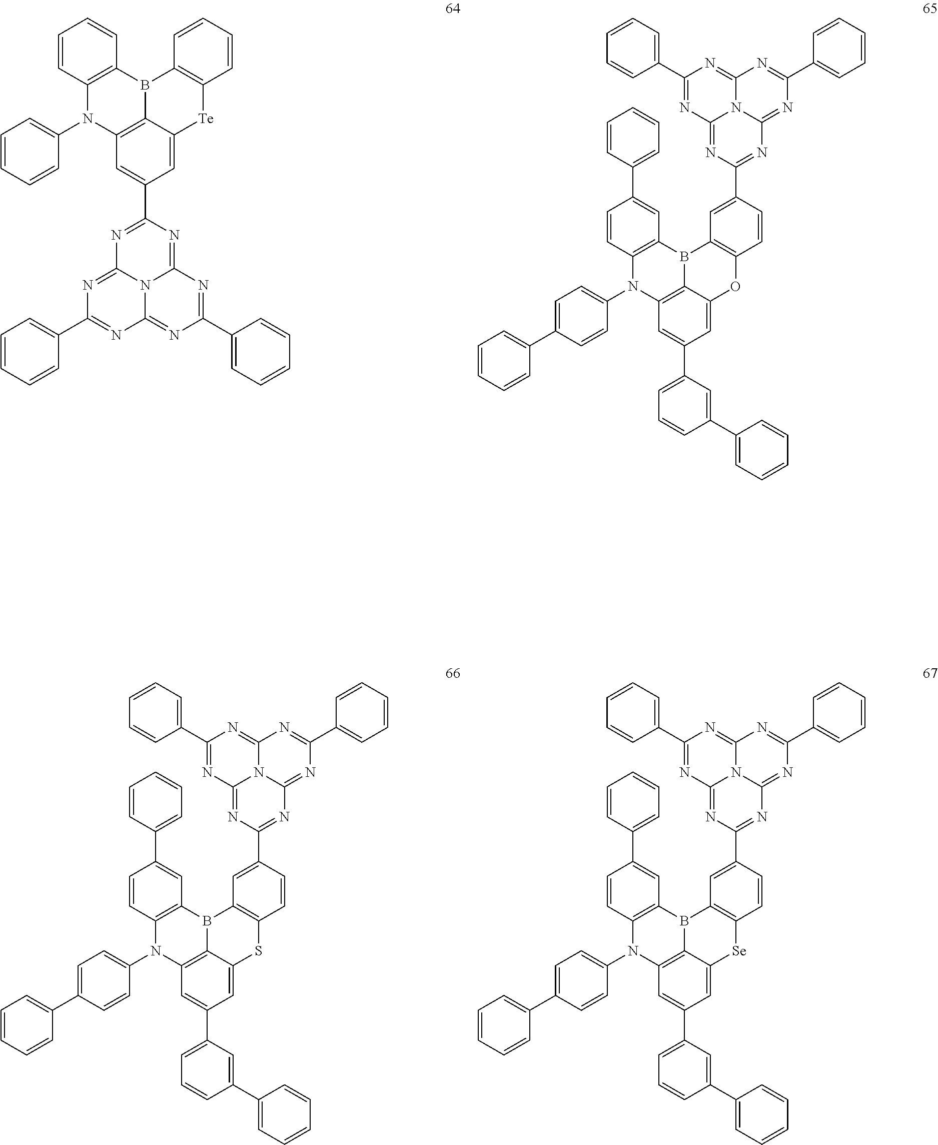

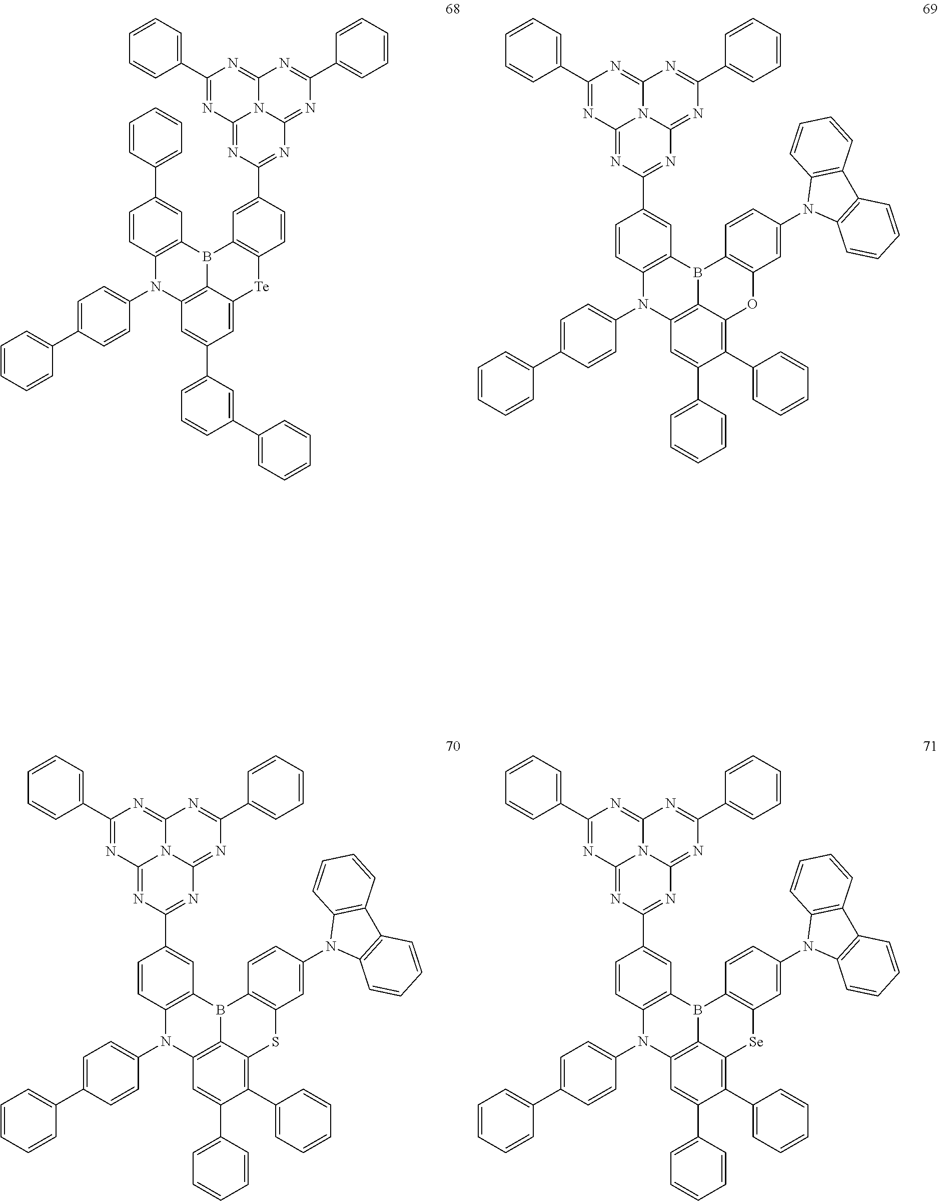

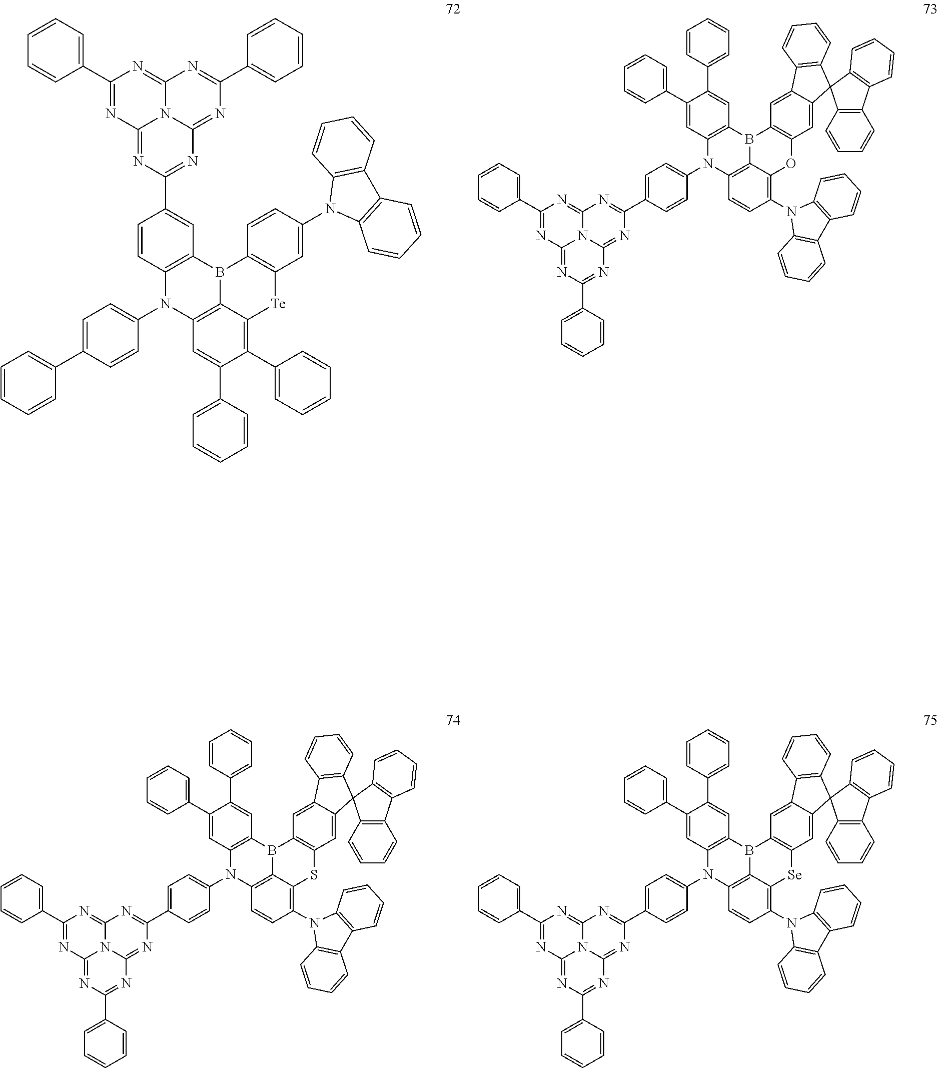

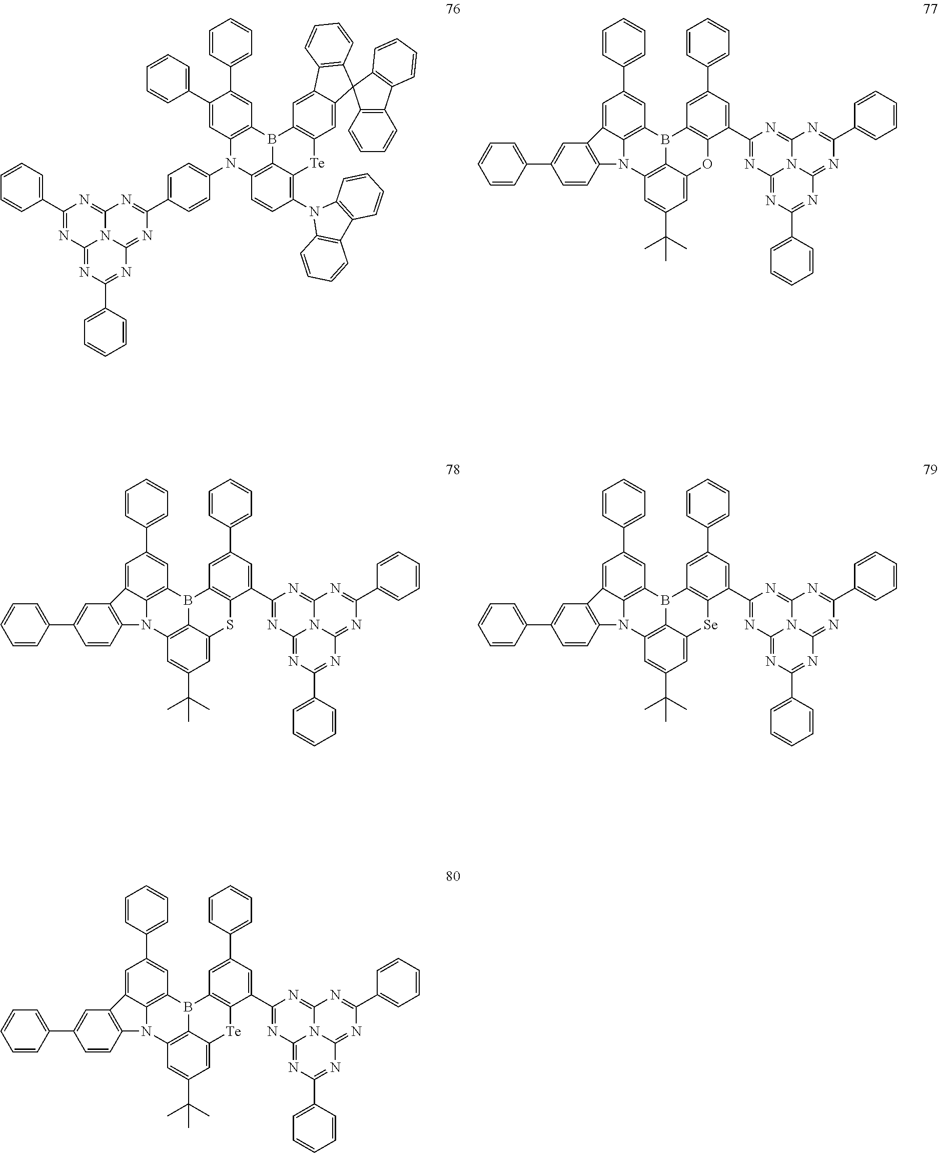

In Compound Group 1, D represents a deuterium atom.

As described above, the polycyclic compound represented by Formula 1 may have a core structure having multiple aromatic rings fused through a boron atom, at least one nitrogen atom, and at least one heteroatom, and including a phenyl group linked to a nitrogen atom. The at least one heteroatom may be N, O, S, Se, or Te. When a heteroatom of the core structure is a nitrogen atom, the core structure may include a phenyl group each linked to two nitrogen atoms. For example, the core structure may include three aromatic rings fused through a boron atom, at least one nitrogen atom, and at least one heteroatom. At least two of the three aromatic rings may be benzene rings.

In the core structure, a substituent including a tricyclic heteroaryl group containing nitrogen atoms may be linked to at least one of the three aromatic rings or to a phenyl group linked to a nitrogen atom. For example, the tricyclic heteroaryl group containing nitrogen atoms may be a heptazine group containing 7 nitrogen atoms.

When at least one heptazine group is bonded to the core structure of the polycyclic compound represented by Formula 1, characteristics of a light emitting element, such as light emitting efficiency, lifespan, and driving voltage, may be improved.

For example, the heptazine group imparts a high degree of steric hindrance to the polycyclic compound. From the high degree of steric hindrance provided by the heptazine group, Stokes-shift and full width at half maximum (FWHM) of an emission spectrum may be reduced, even when the polycyclic compound is included in a film in a light emitting element. Accordingly, when the polycyclic compound according to an embodiment is applied to a light emitting element, a dark blue color of light may be achieved, the color purity of emitted light may be improved, and light emitting efficiency may increase.

In the heptazine group, a triplet exciton energy level (T1 level) may be higher than a singlet exciton energy level (S1 level). A triplet exciton may be stabilized by a high triplet exciton energy level (T1) of the heptazine group, which is transferred to the core structure to achieve light emission. Accordingly, direct degradation of the polycyclic compound may be minimized. The heptazine group has a low (or deep) highest occupied molecular orbital (HOMO) energy level, which lowers the HOMO energy level of the polycyclic compound into which the heptazine group is introduced. Accordingly, direct exciton recombination in the core structure may be minimized. As a result, the stabilization of a triplet exciton and a low HOMO energy level may contribute to a longer service life of a light emitting element.

As the heptazine group having low electron density is introduced into the polycyclic compound, electron injection may be accelerated to maintain a low driving voltage.

In an embodiment, the emission layer EML may include the polycyclic compound represented by Formula 1. The emission layer EML may include the polycyclic compound as a dopant material. The polycyclic compound may be a thermally activated delayed fluorescent material. The polycyclic compound may be used as a thermally activated delayed fluorescent dopant. For example, in the light emitting element ED, the emission layer EML may include at least one polycyclic compound selected from Compound Group 1 as a thermally activated delayed fluorescent dopant. However, the use of the polycyclic compound is not limited thereto.

In an embodiment, the polycyclic compound represented by Formula 1 may be a thermally activated delayed fluorescent dopant in which a difference (ΔE_{ST}) between a lowest triplet exciton energy level (T1 level) and a lowest singlet exciton energy level (S1 level) is equal to or less than about 0.6 eV. For example, the polycyclic compound may be a thermally activated delayed fluorescent dopant in which a difference (ΔE_{ST}) between a lowest triplet exciton energy level (T1 level) and lowest singlet exciton energy level (S1 level) is equal to or less than about 0.2 eV.

In an embodiment, an emission spectrum of the polycyclic compound represented by Formula 1 may have a full width at half maximum (FWHM) in a range of about 10 to about 35 nm. The emission spectrum of the polycyclic compound may have a full width at half maximum (FWHM) in the range described above, and thus, light emitting efficiency may be improved when the polycyclic compound is applied to a light emitting element. Light emitting element service life may be improved when a polycyclic compound according to an embodiment is used as a blue light emitting element material for the light emitting element.

In an embodiment, the polycyclic compound represented by Formula 1 may emit blue light. In an embodiment, the polycyclic compound may have a maximum emission wavelength in a range of about 450 nm to about 480 nm. For example, the polycyclic compound may have a maximum emission wavelength in a range of about 455 nm to about 470 nm.

In an embodiment, the emission layer EML may include a first compound represented by Formula 1, and at least one of a second compound represented by Formula HT and a third compound represented by Formula ET.

In an embodiment, the emission layer EML may further include a second compound represented by Formula HT. In an embodiment, the second compound may be used as a hole transporting host material in the emission layer EML.

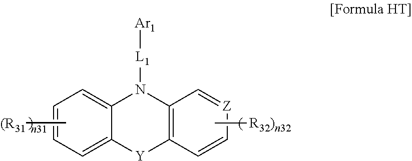

In Formula HT, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, or the like, but embodiments are not limited thereto.

In Formula HT, Ar₁ may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, or the like, but embodiments are not limited thereto.

In Formula HT, Y may be a direct linkage, C(R_{y1})(R_{y2}), or Si(R_{y3})(R_{y4}). For example, the two benzene rings that are bonded to the nitrogen atom in Formula HT may be connected to each other through a direct linkage,

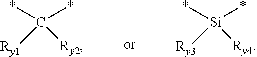

For example, when Y is a direct linkage, the second compound represented by Formula HT may include a carbazole moiety.

In Formula HT, Z may be C(R_{z}) or N.

In Formula HT, R_{y1} to R_{y4}, R₃₁, R₃₂, and R_{z} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R_{y1} to R_{y4} may each independently be a methyl group or a phenyl group. For example, R₃₁ and R₃₂ may each independently be a hydrogen atom or a deuterium atom.

In Formula HT, n31 may be an integer from 0 to 4. When n31 is 0, the second compound may not be substituted with R₃₁. A case where n31 is 4 and R₃₁ groups are all hydrogen atoms may be the same as a case where n31 is 0. When n31 is 2 or greater, two or more R₃₁ groups may be the same as each other, or at least one group thereof may be different from the remainder.

In Formula HT, n32 may be an integer from 0 to 3. When n32 is 0, the second compound may not be substituted with R₃₂. A case where n32 is 3 and R₃₂ groups are all hydrogen atoms may be the same as a case where n32 is 0. When n32 is 2 or greater, two or more R₃₂ groups may be the same as each other, or at least one group thereof may be different from the remainder.

In an embodiment, the emission layer EML may further include a third compound represented by Formula ET. In an embodiment, the third compound may be used as an electron transporting host material in the emission layer EML.

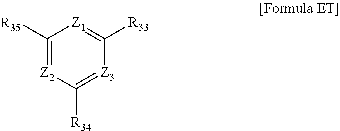

In Formula ET, Z₁ to Z₃ may each independently be N or C(R₃₆); and at least one of Z₁ to Z₃ may each be N. For example, Z₁ to Z₃ may each be N. For example, Z₁ and Z₂ may each be N, and Z₃ may be C(R₃₆); Z₁ may be C(R₃₆), and Z₂ and Z₃ may each be N; or Z₁ and Z₃ may each be N, and Z₂ may be C(R₃₆). For example, Z₁ may be N, Z₂ and Z₃ may each independently be C(R₃₆); Z₂ may be N, Z₁ and Z₃ may each independently be C(R₃₆); or Z₃ may be N, and Z₁ and Z₂ may each independently be C(R₃₆).

In Formula ET, R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₃₃ to R₃₆ may each independently be a substituted or unsubstituted phenyl group, a substituted or unsubstituted carbazole group, or the like, but embodiments are not limited thereto.

In an embodiment, the emission layer EML may include a second compound and a third compound, and the second compound and the third compound may form an exciplex. In the emission layer EML, a hole transporting host and an electron transporting host may form an exciplex. A triplet energy level of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, a triplet energy level (T1) of the exciplex formed by the hole transporting host and the electron transporting host may have an absolute value in a range of about 2.4 eV to about 3.0 eV. The triplet energy of the exciplex may have a value that is smaller than the energy gap of each host material. The exciplex may have a triplet energy level equal to or less than about 3.0 eV, which is an energy gap between the hole transporting host and the electron transporting host.

In an embodiment, the emission layer EML may further include a fourth compound, in addition to the first compound, the second compound, and the third compound as described above. The fourth compound may be used as a phosphorescent sensitizer in the emission layer EML. Energy may be transferred from the fourth compound to the first compound to emit light.

The emission layer EML may include a fourth compound that is an organometallic complex containing platinum (Pt) as a central metal atom and ligands bound to the central metal atom. In the light emitting element ED according to an embodiment, the emission layer EML may include a fourth compound represented by Formula PS.

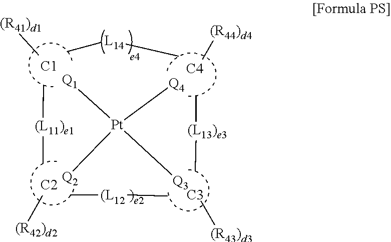

In Formula PS, Q₁ to Q₄ may each independently be C or N.

In Formula PS, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula PS, L₁₁ to L₄ may each independently be a direct linkage,

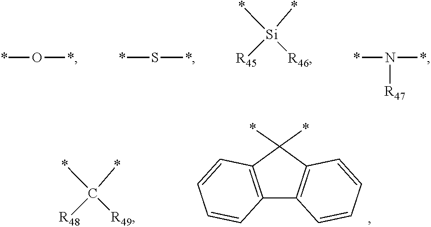

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, wherein in L₁₁ to L₁₄, -* represents a bond to one of C1 to C4.

In Formula PS, e1 to e4 may each independently be 0 or 1. When e1 is 0, C1 and C2 may not be directly connected to each other. When e2 is 0, C2 and C3 may not be directly connected to each other. When e3 is 0, C3 and C4 may not be directly connected to each other. When e4 is 0, C1 and C4 may not be directly connected to each other.

In Formula PS, R₄₁ to R₄₉ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₄₁ to R₄₉ may each independently be a substituted or unsubstituted methyl group, or a substituted or unsubstituted t-butyl group.

In Formula PS, d1 to d4 may each independently be an integer from 0 to 4. When d1 to d4 are each 0, the fourth compound may not be substituted with and R₄₁ to R₄₄. A case where d1 to d4 are each 4 and R₄₁ groups, R₄₂ groups, R₄₃ groups, and R₄₄ groups are each a hydrogen atom may be the same as a case where d1 to d4 are each 0. When d1 to d4 are each 2 or greater, multiple groups of each of R₄₁ to R₄₄ may be the same as each other, or at least one group thereof may be different from the remainder.

In an embodiment, in Formula PS, C1 to C4 may each independently be a substituted or unsubstituted hydrocarbon ring or a substituted or unsubstituted aromatic heterocycle that is represented by any one of Formula C-1 to Formula C-4.

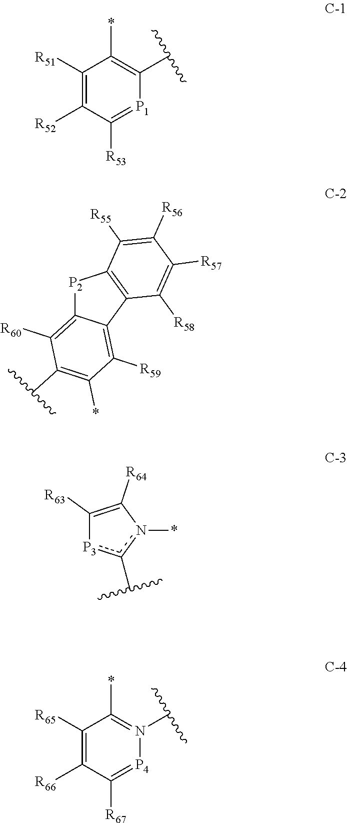

In Formula C-1 to Formula C-4, P₁— may be C—* or C(R₅₄), P₂ may be N—* or N(R₆₁), P₃ may be N—* or N(R₆₂), and P₄ may be C—* or C(R₆₈).

In Formula C-1 to Formula C-4, R₅₁ to R₆₈ may each independently be a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In Formula C-1 to Formula C-4,

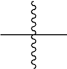

represents a bond to a central metal atom, which is Pt, and -* represents a bond to a neighboring ring group (C1 to C4) or to a linker (L₁₁ to L₁₄).

In an embodiment, the emission layer EML may include the first compound represented by Formula 1, and at least one of the second compound, the third compound, and the fourth compound. In an embodiment, the emission layer EML may include the first compound, the second compound, and the third compound. In the emission layer EML, the second compound and the third compound may form an exciplex, and energy may be transferred from the exciplex to the first compound to emit light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound to emit light. In an embodiment, the fourth compound may be a sensitizer. In the light emitting element ED, the fourth compound included in the emission layer EML may serve as a sensitizer to transfer energy from a host to the first compound, which is a light emitting dopant. For example, the fourth compound, which serves as an auxiliary dopant, may accelerate energy transfer to the first compound, which serves as a light emitting dopant, thereby increasing an emission ratio of the first compound. Accordingly, the emission layer EML may have increased emission efficiency. When energy transfer to the first compound increases, excitons formed in the emission layer EML may not accumulate in the emission layer EML and may emit light rapidly, thereby reducing deterioration of a light emitting element ED. Accordingly, the light emitting element ED may have an increased lifespan.

The light emitting element ED may include a first compound, a second compound, a third compound, and a fourth compound, and the emission layer EML may thus include a combination of two host materials and two dopant materials. In the light emitting element ED, the emission layer EML includes two different hosts, a first compound which emits delayed fluorescence, and a fourth compound which includes an organometallic complex, and thus the light emitting element ED may exhibit excellent emission efficiency.

In an embodiment, the second compound represented by Formula HT may be selected from Compound Group HT. In an embodiment, in the light emitting element ED, the second compound may include at least one compound selected from Compound Group HT. In Compound Group HT, D represents a deuterium atom, and Ph represents an unsubstituted phenyl group.

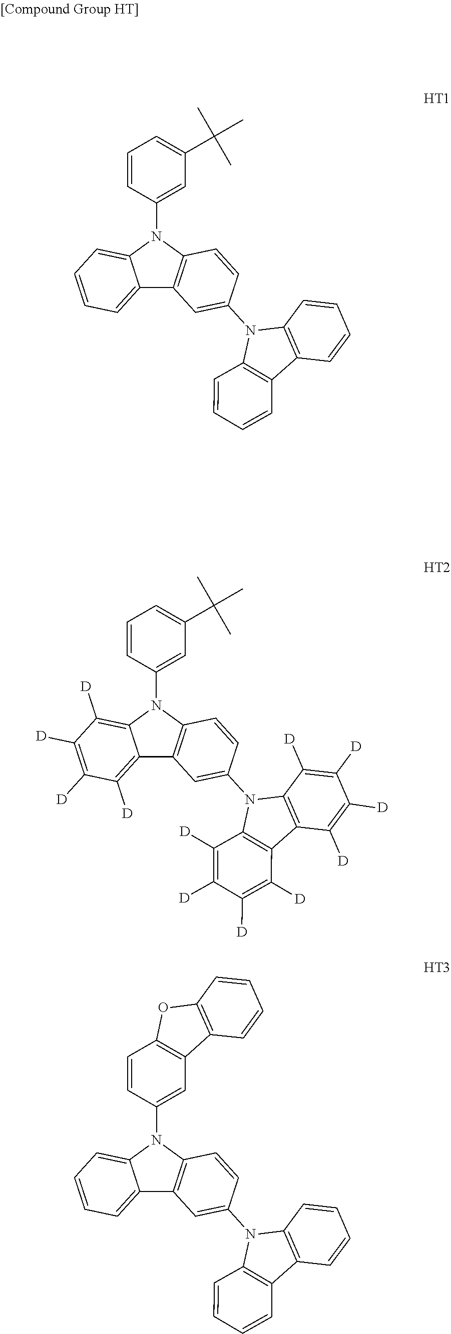 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

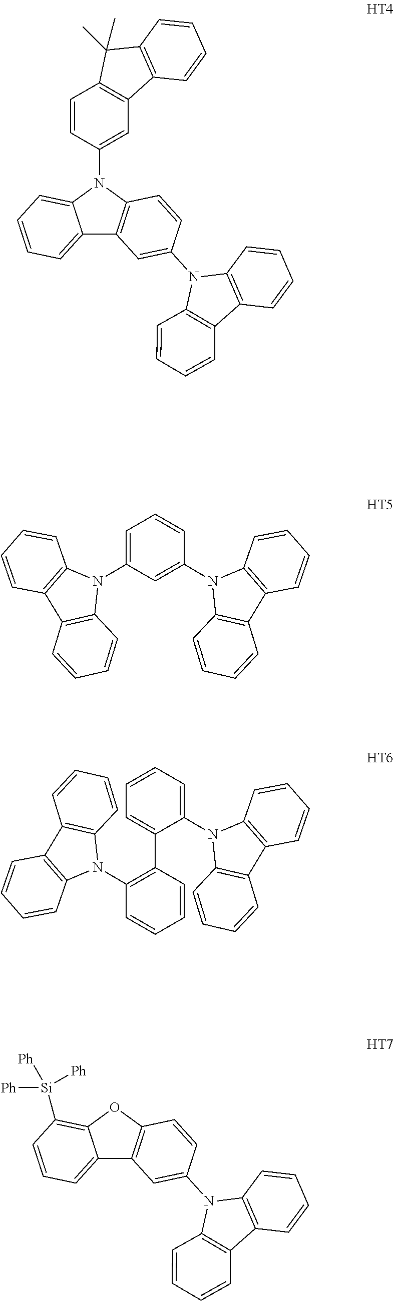 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

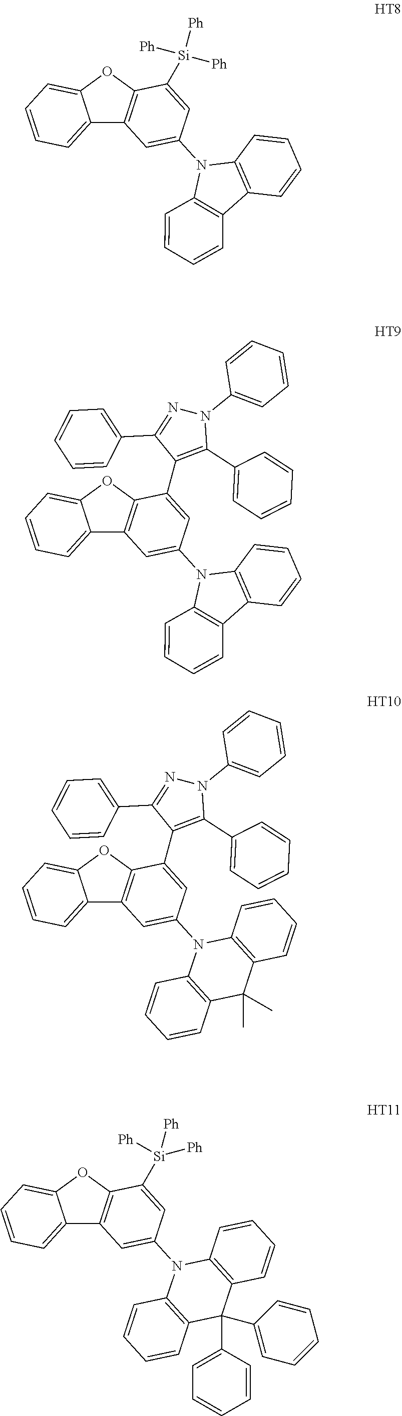 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

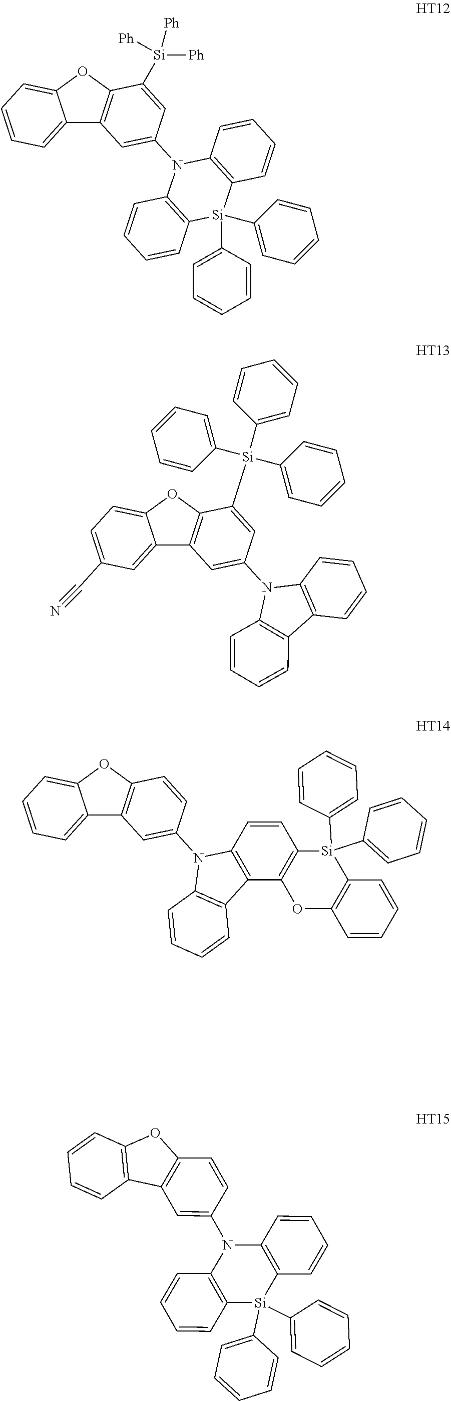 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1]

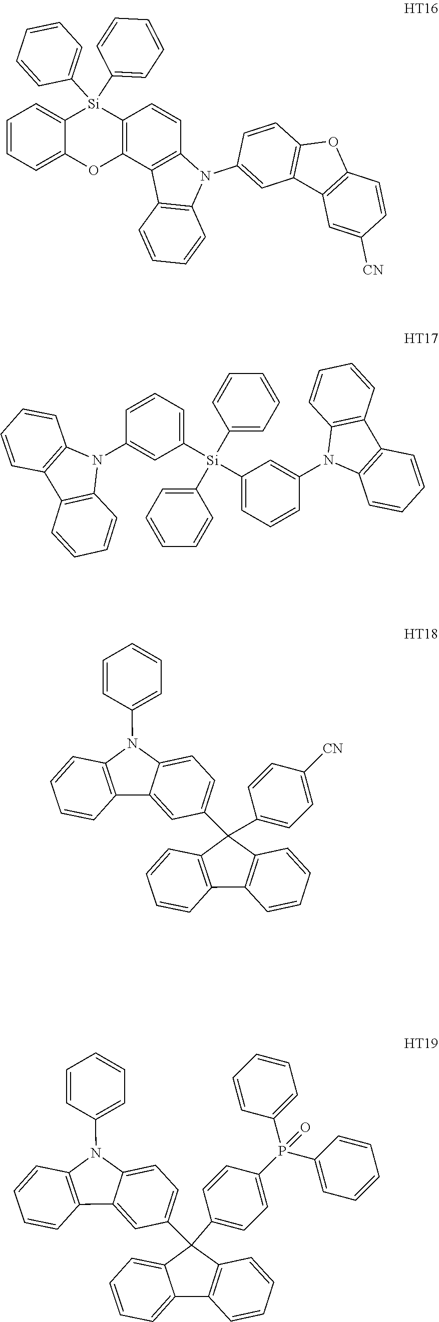 [SMILES: N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1]

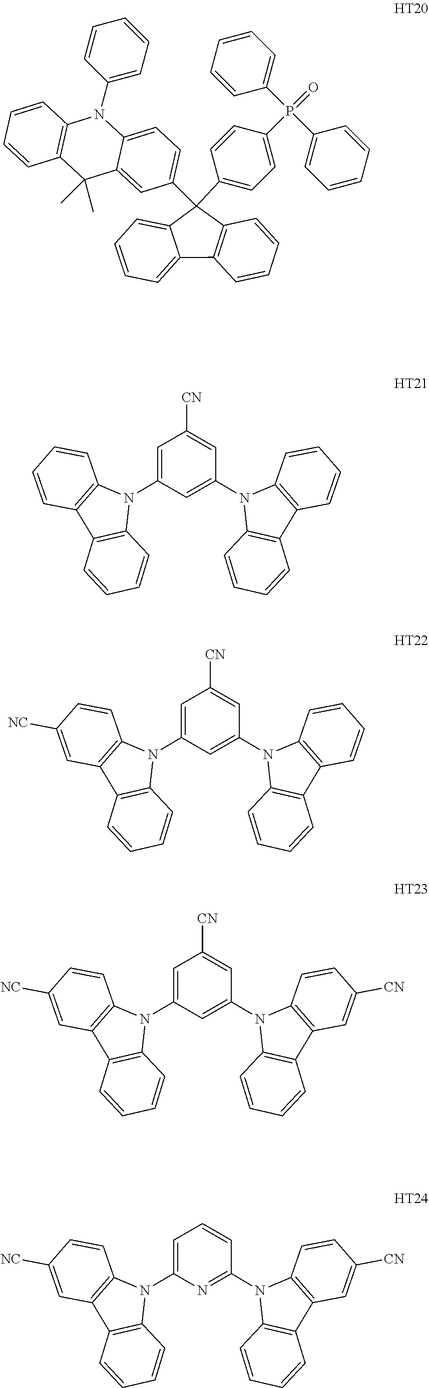 [SMILES: CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

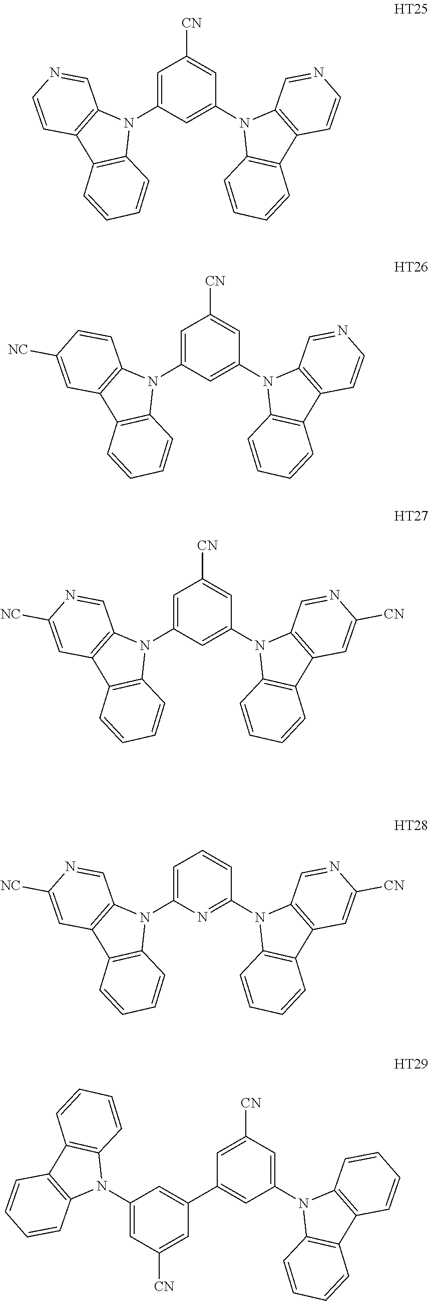 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1]

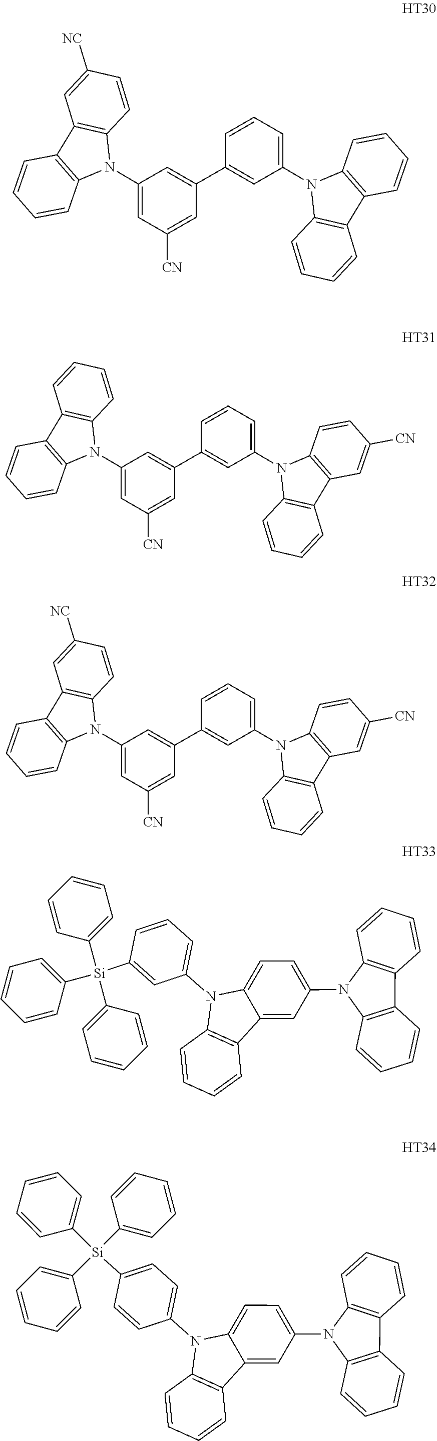 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2ccc(-n3c4ccccc4c4cc(-n5c6ccccc6c6ccccc65)ccc43)cc2)cc1]

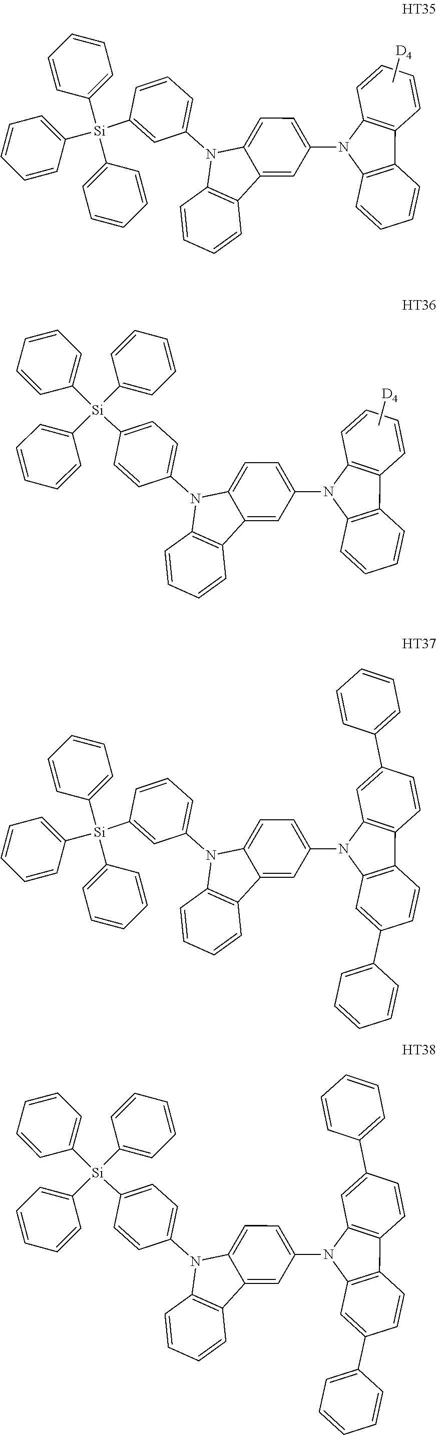

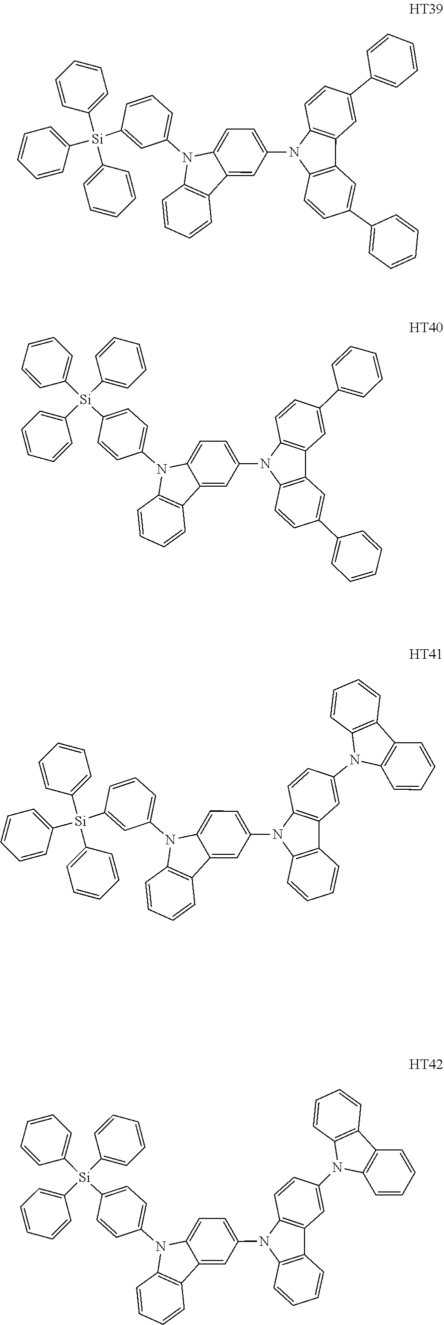 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

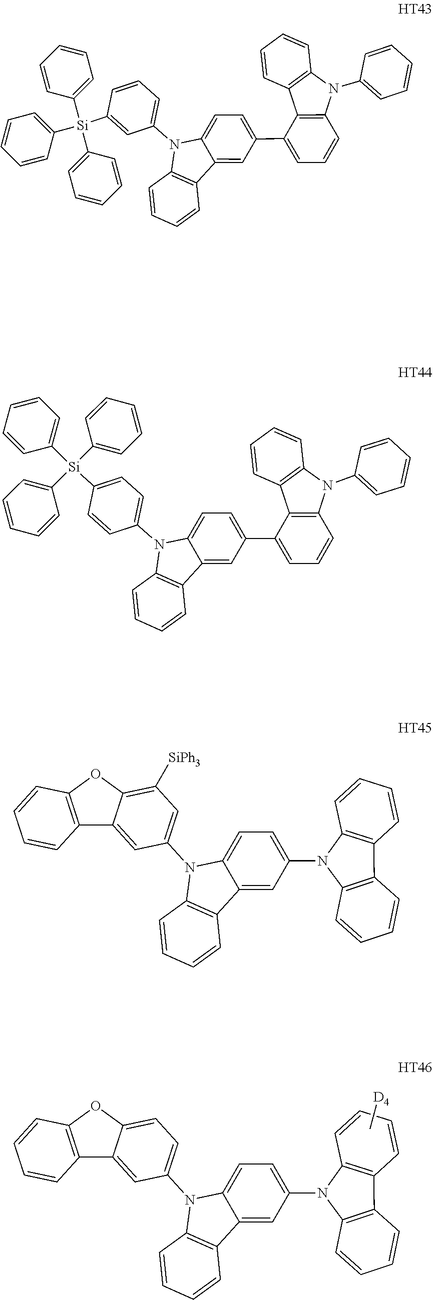

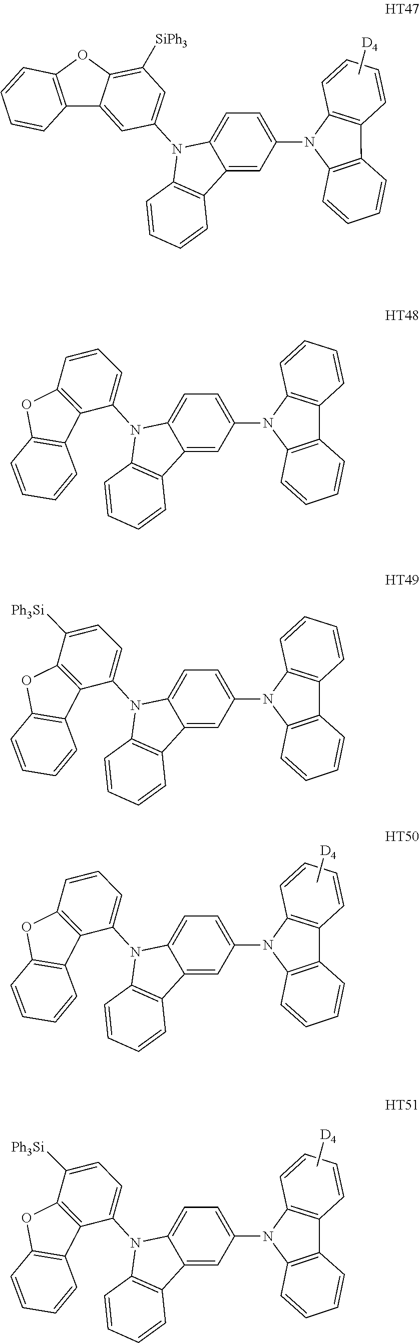

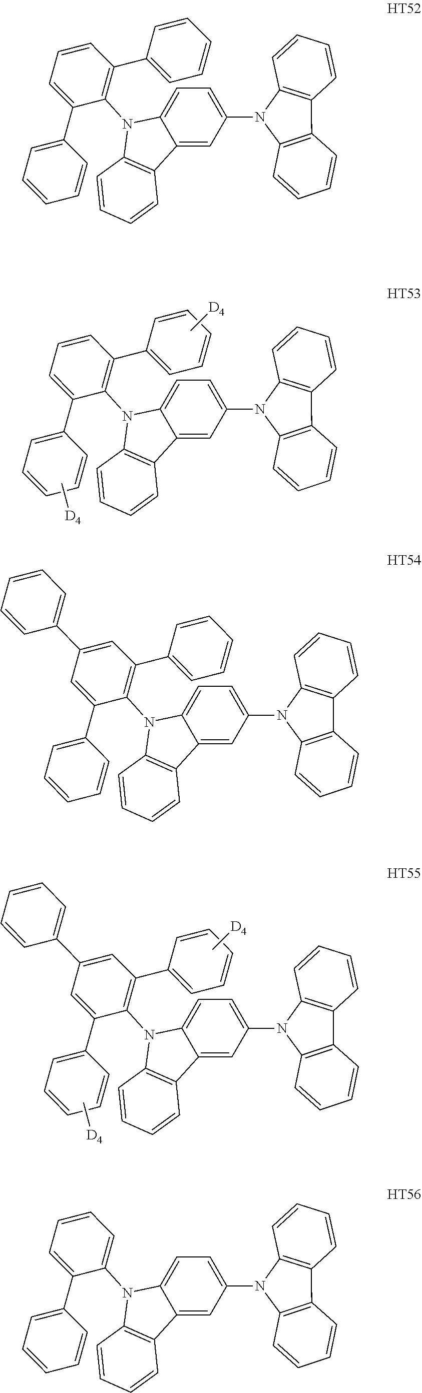

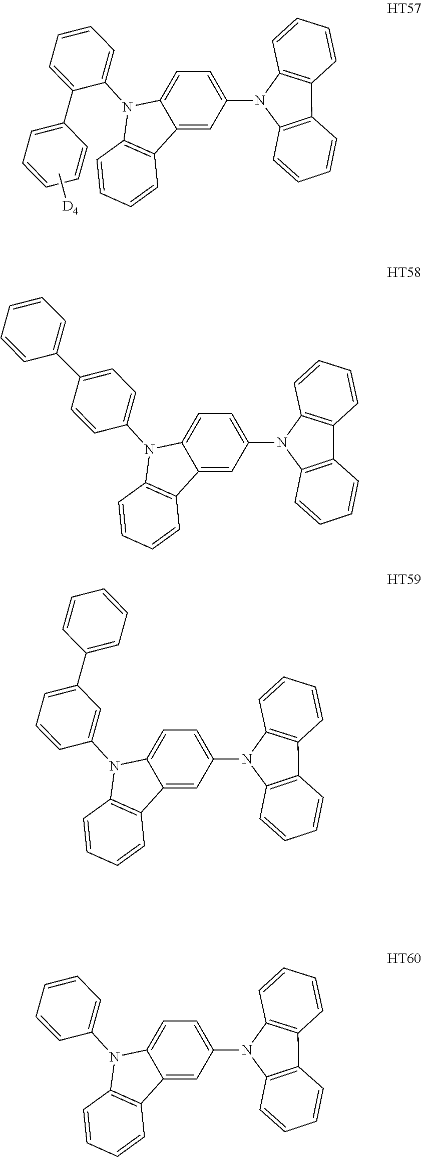

In an embodiment, the third compound represented by Formula ET may be selected from Compound Group ET. In an embodiment, in the light emitting element ED, the third compound may include at least one compound selected from Compound Group ET. In Compound Group ET, D represents a deuterium atom.

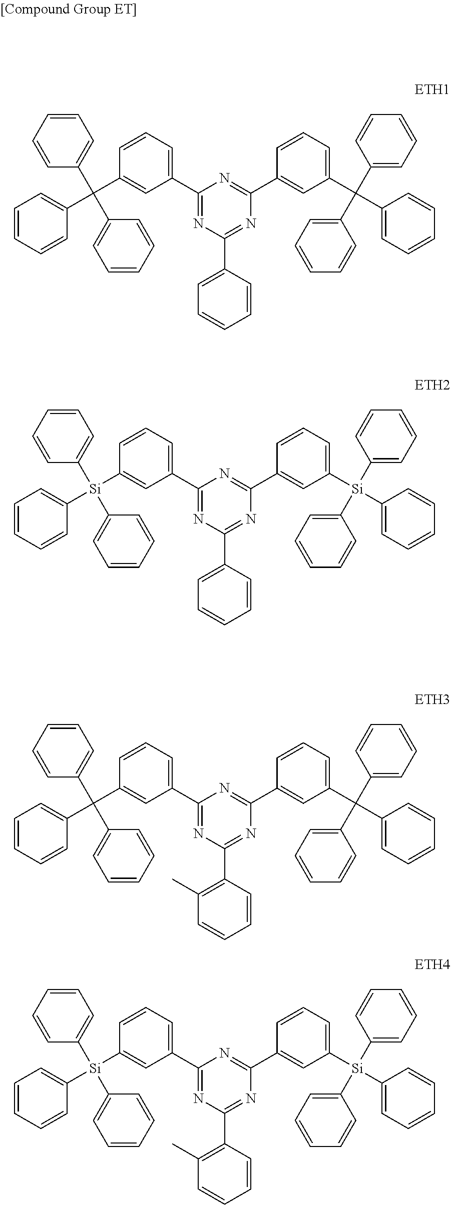 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

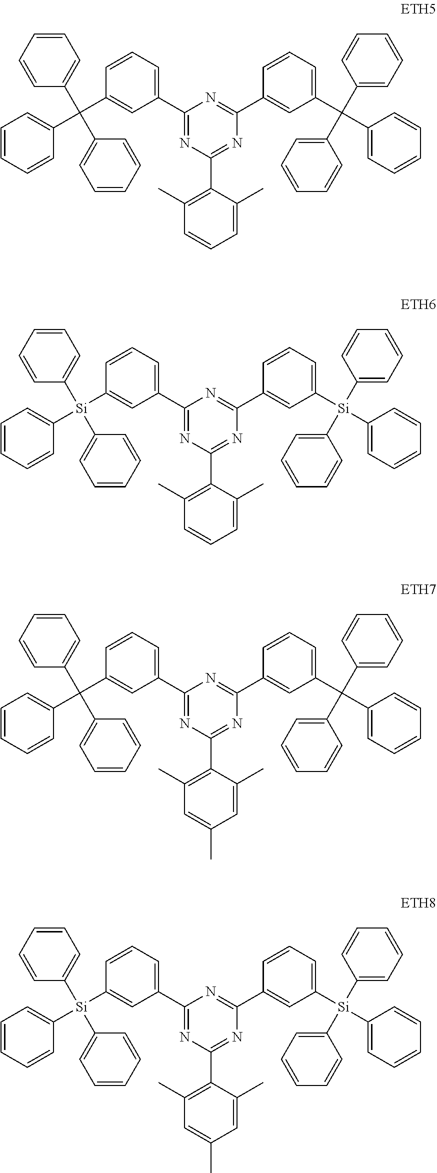 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

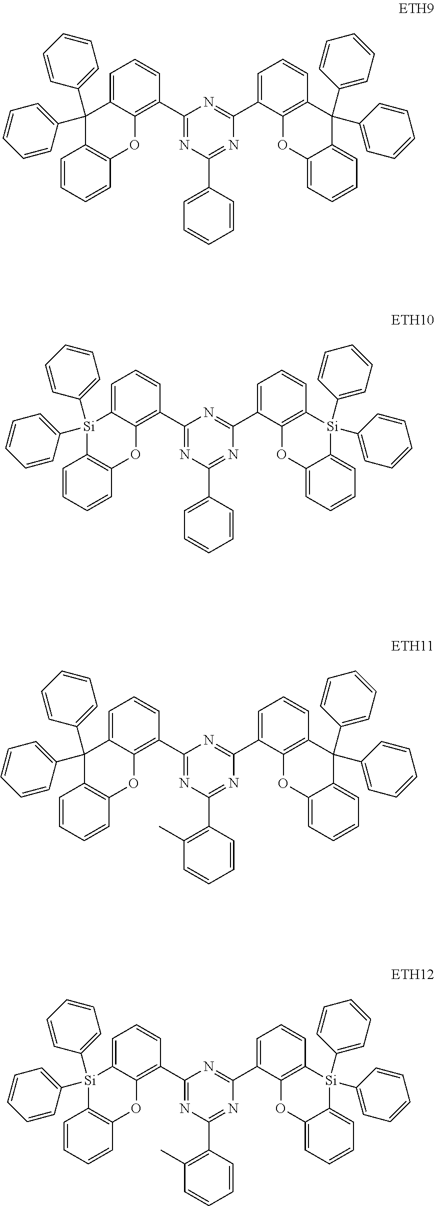 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

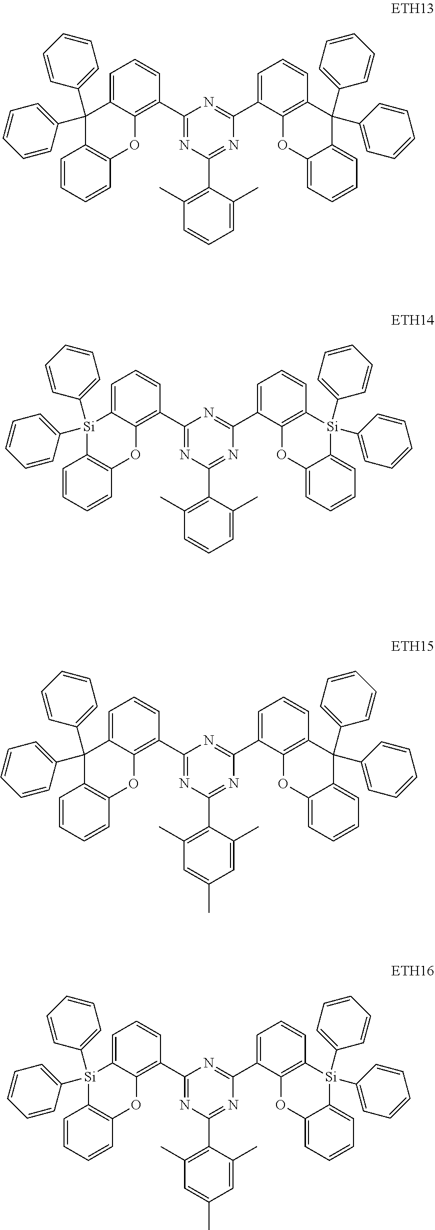 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

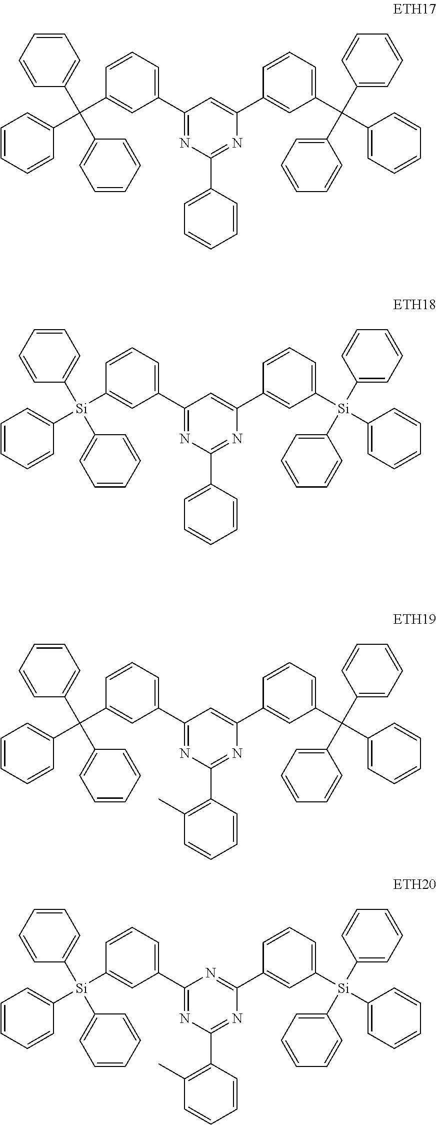 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

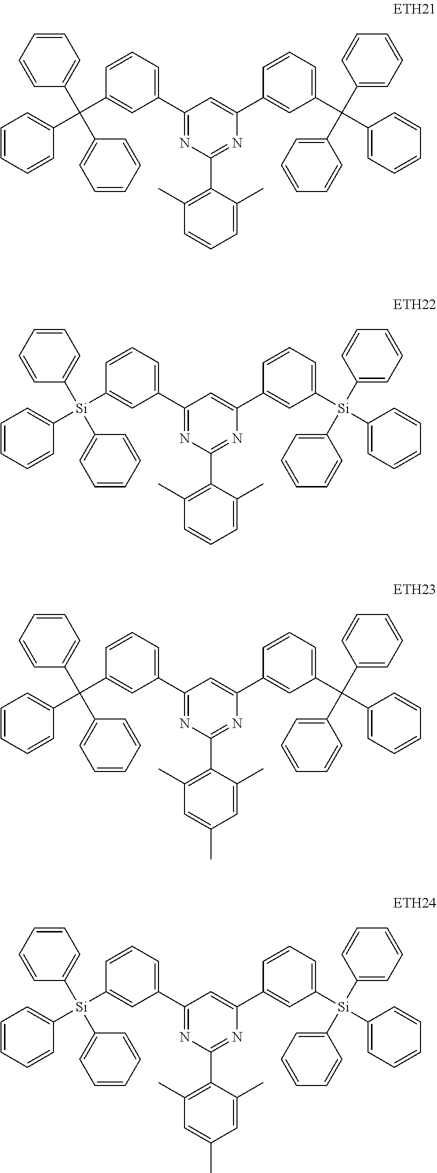 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

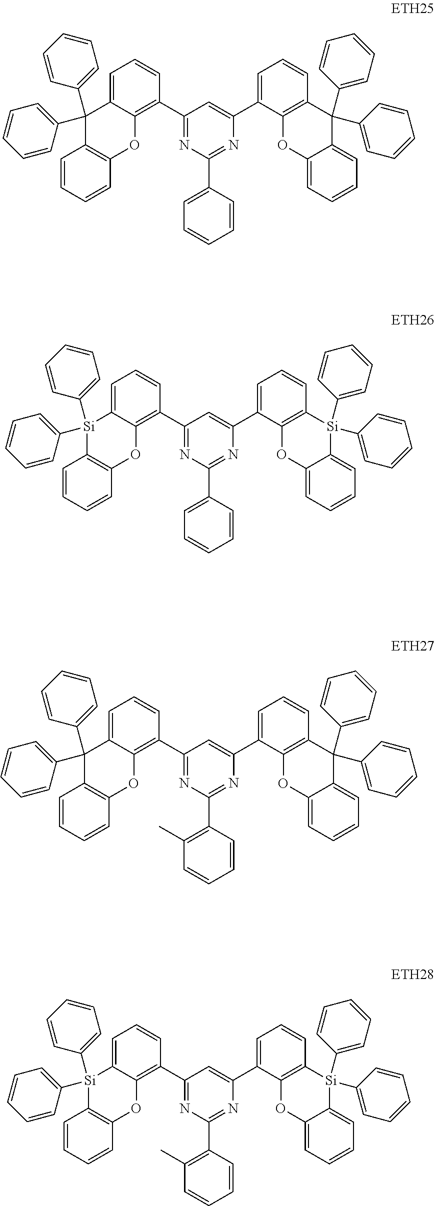 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

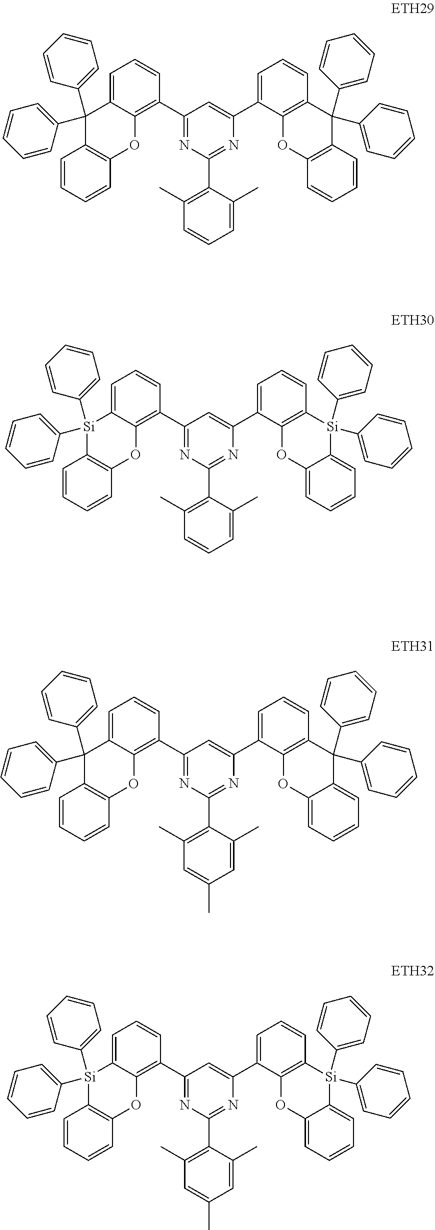 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

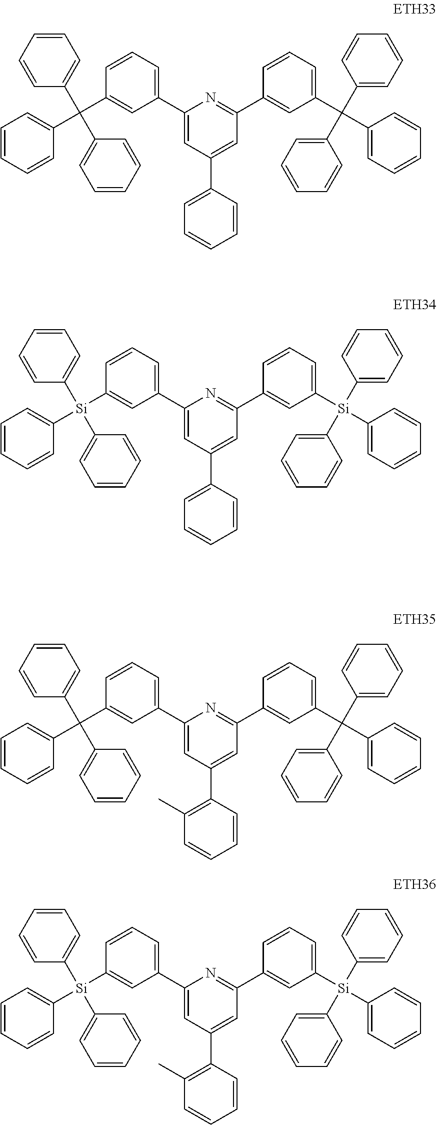 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

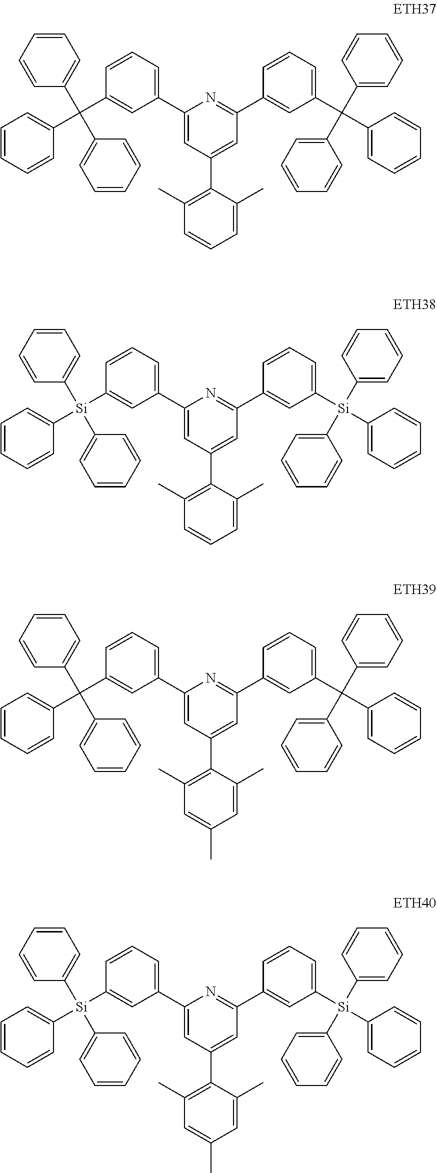 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

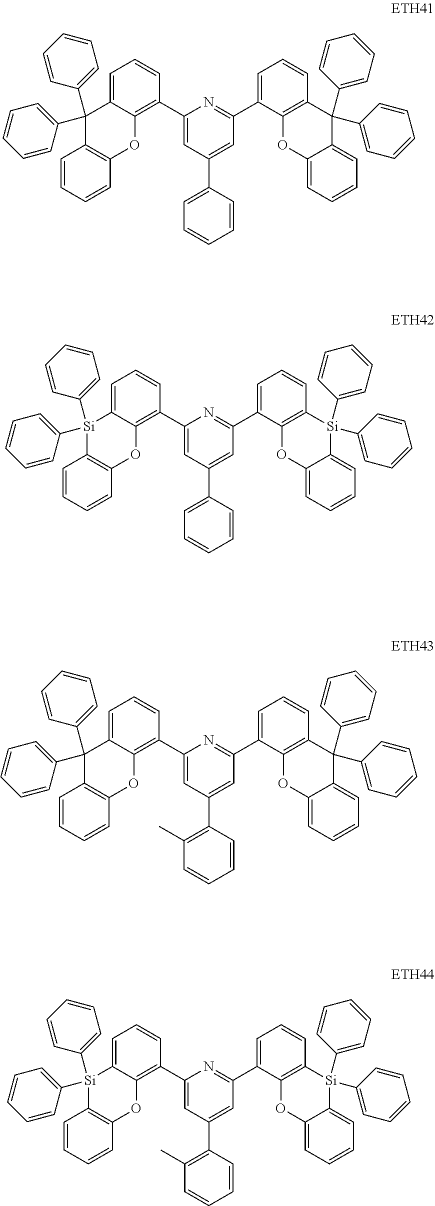 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

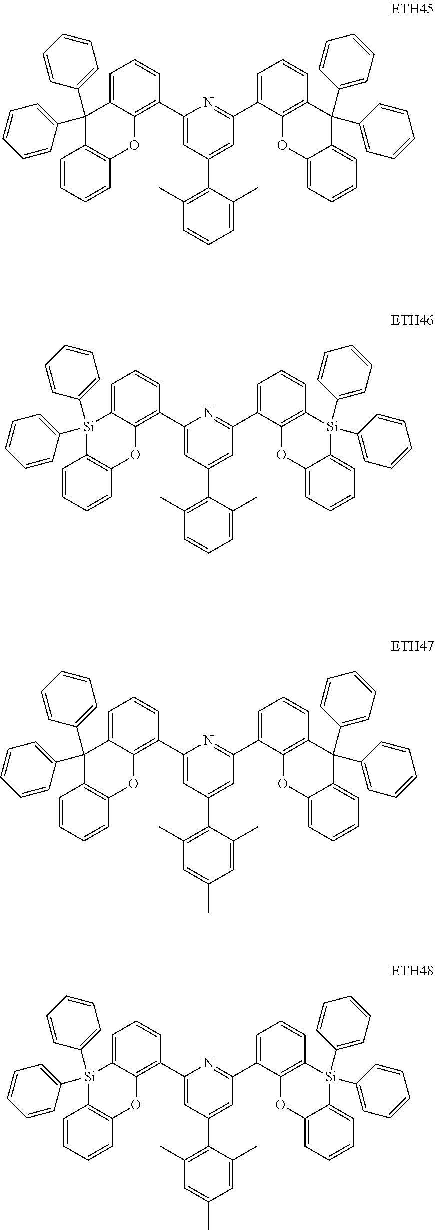 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

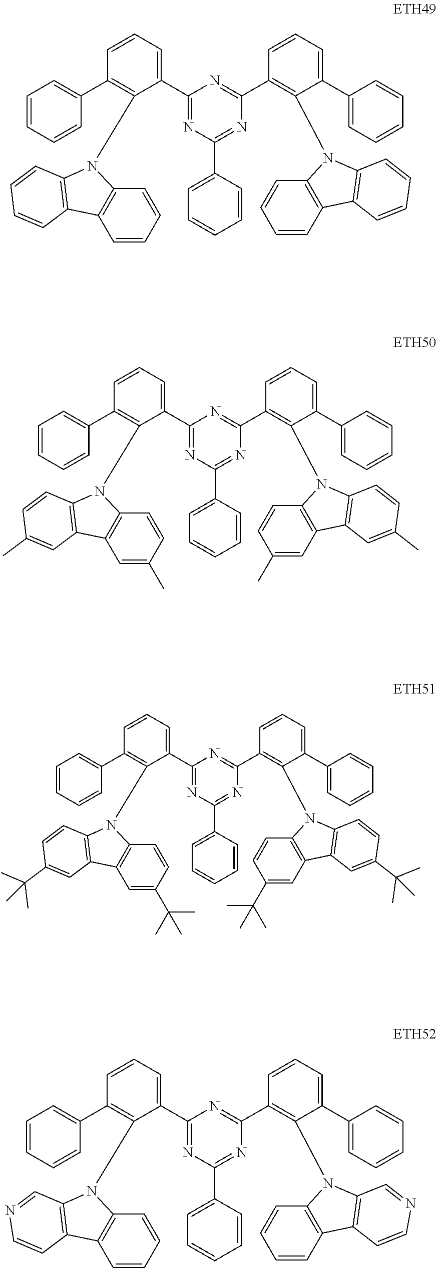

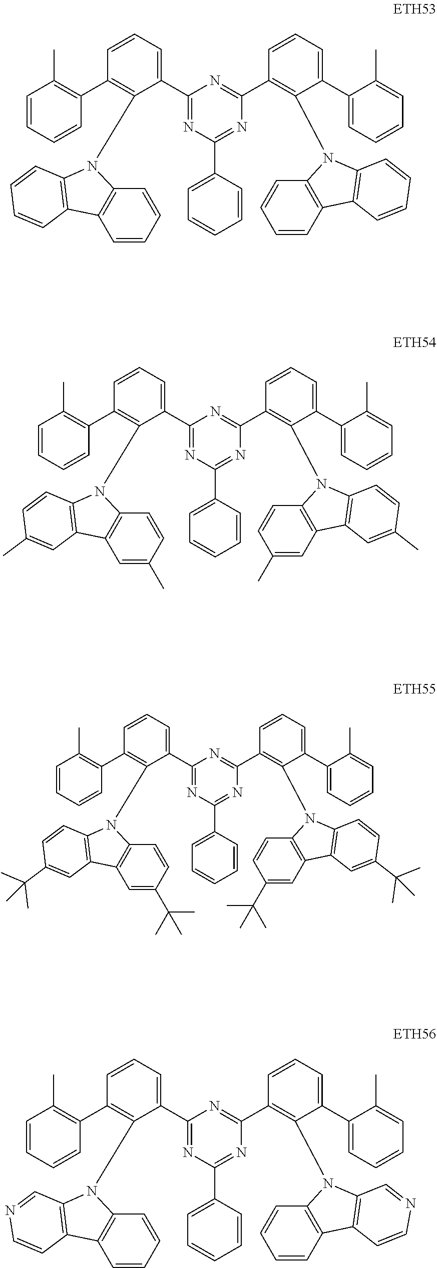

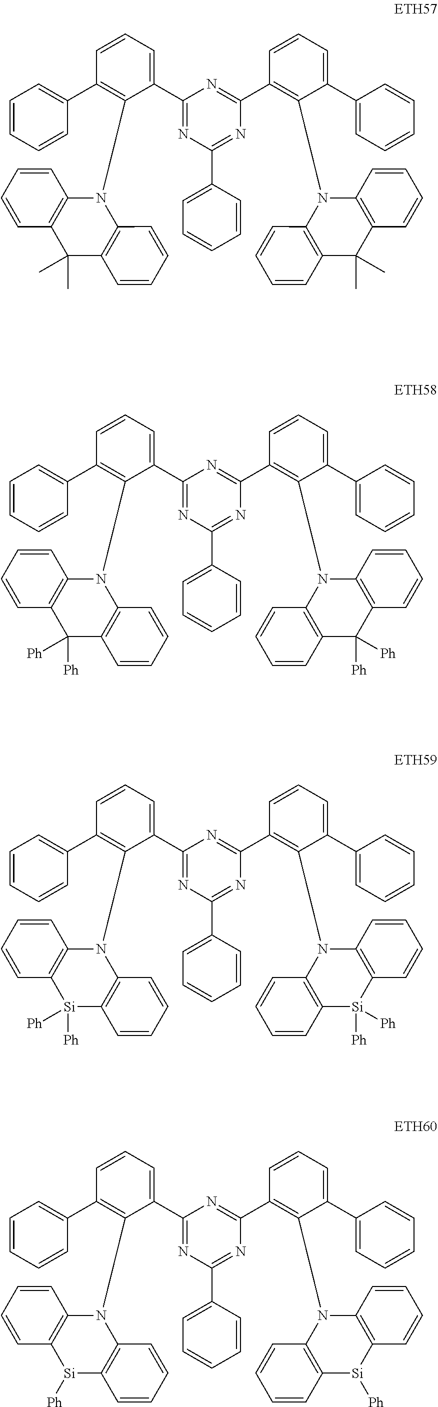

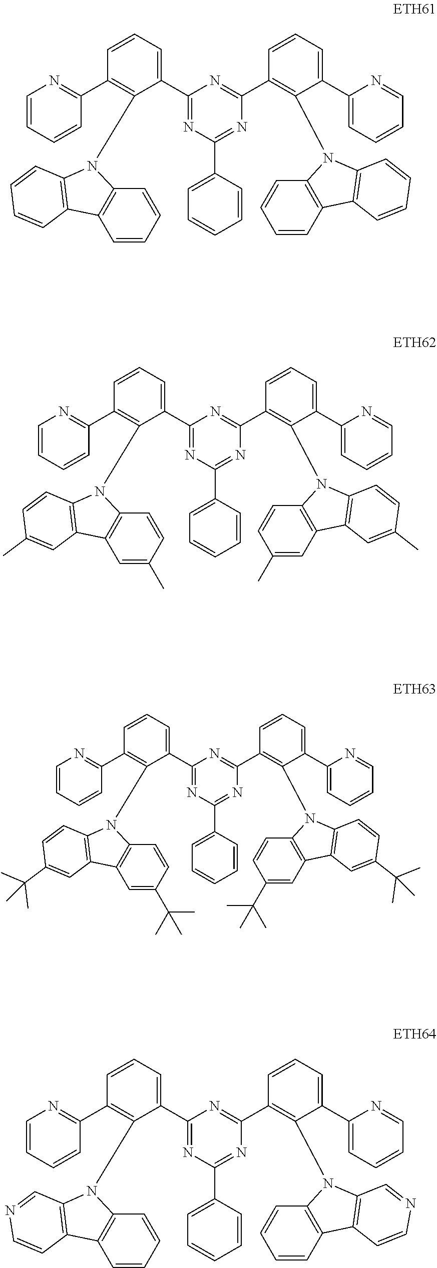

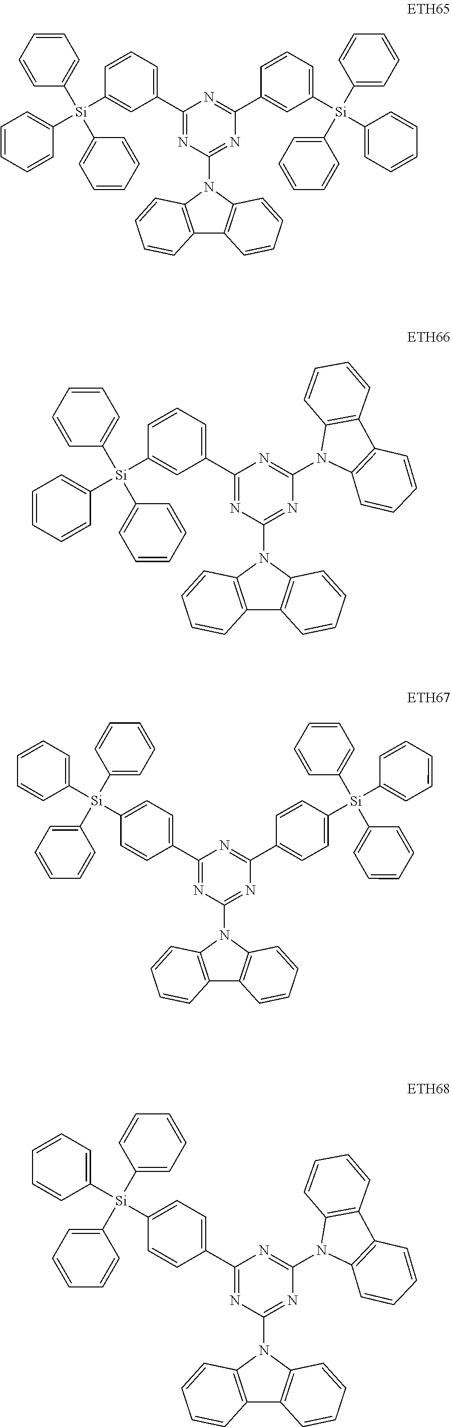 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

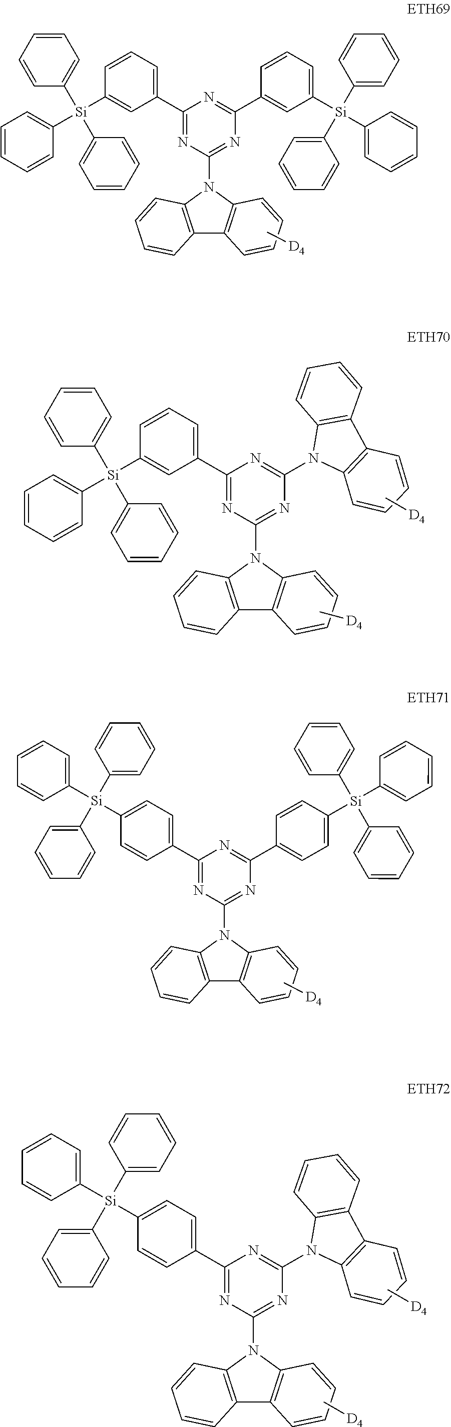

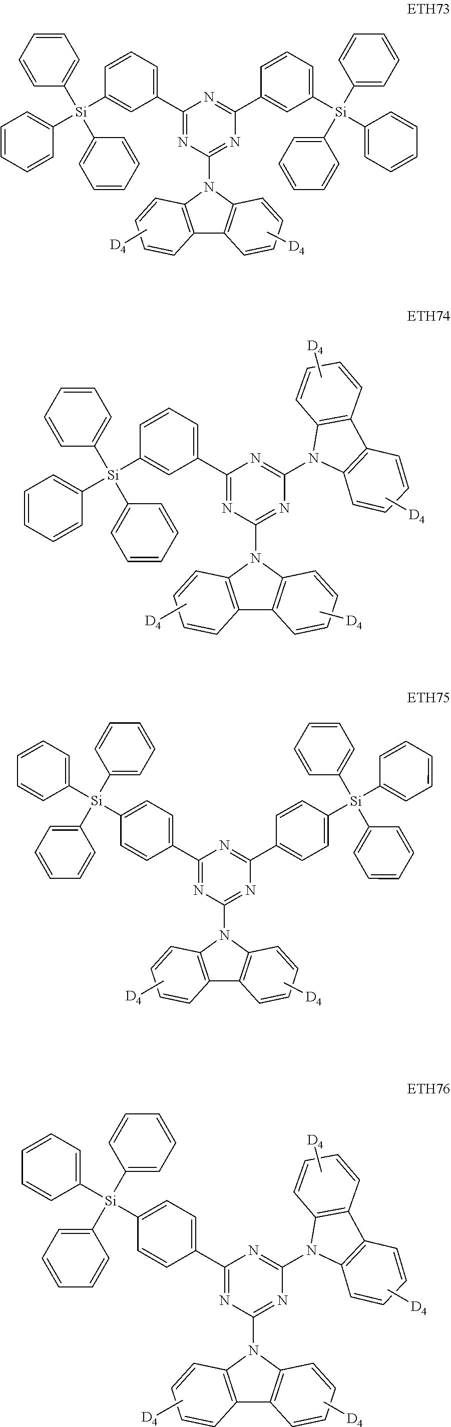

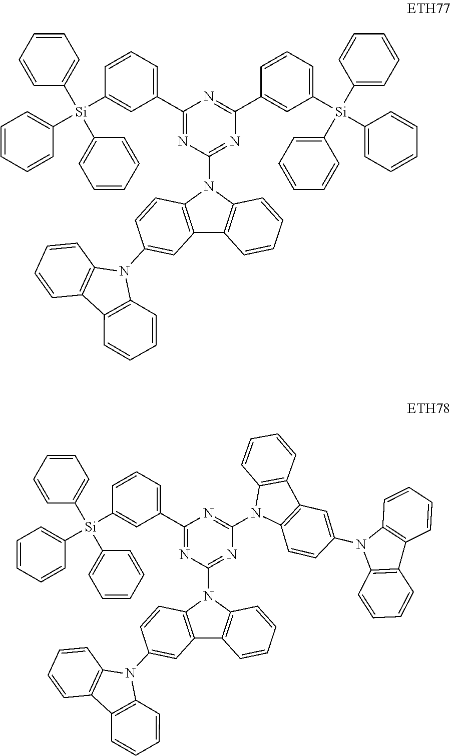 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1]

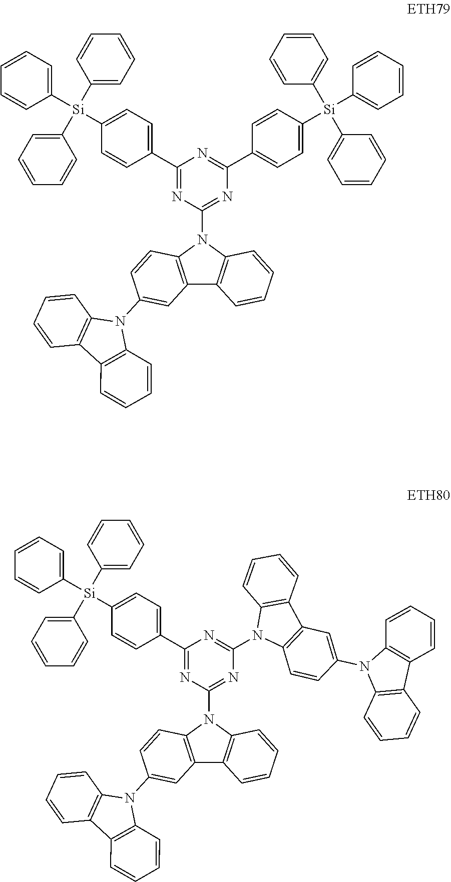 [SMILES: c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1 ; c1ccc([Si](c2ccccc2)(c2ccccc2)c2ccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)cc2)cc1]

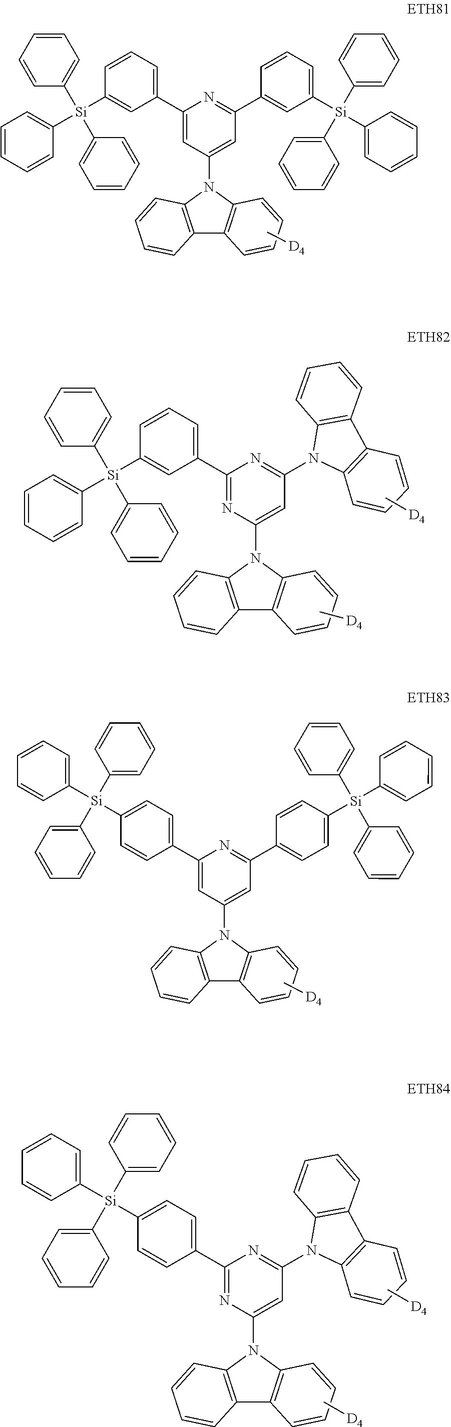

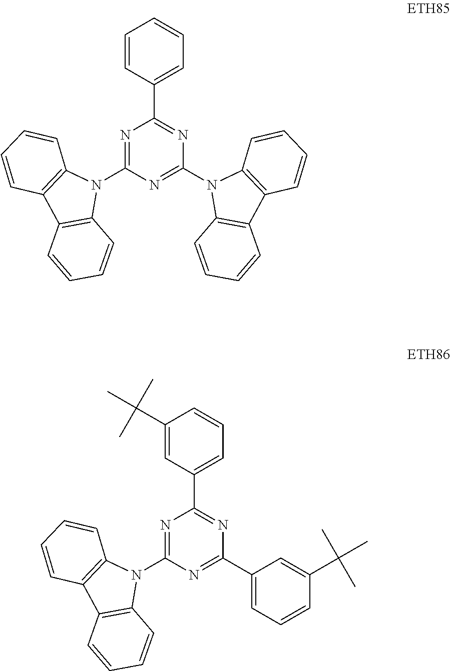 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In an embodiment, the fourth compound represented by Formula PS may be selected from Compound Group AD. In an embodiment, in the light emitting element ED, the fourth compound may include at least one compound selected from Compound Group AD.

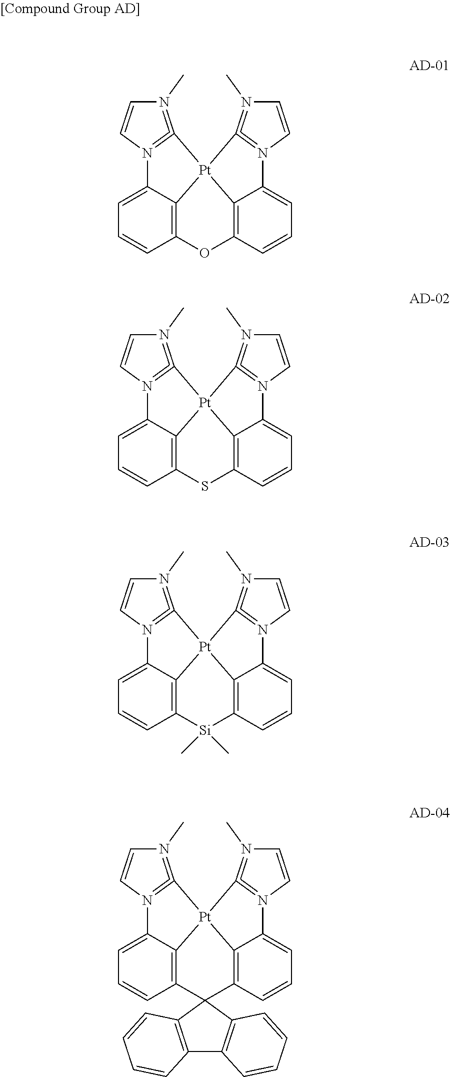

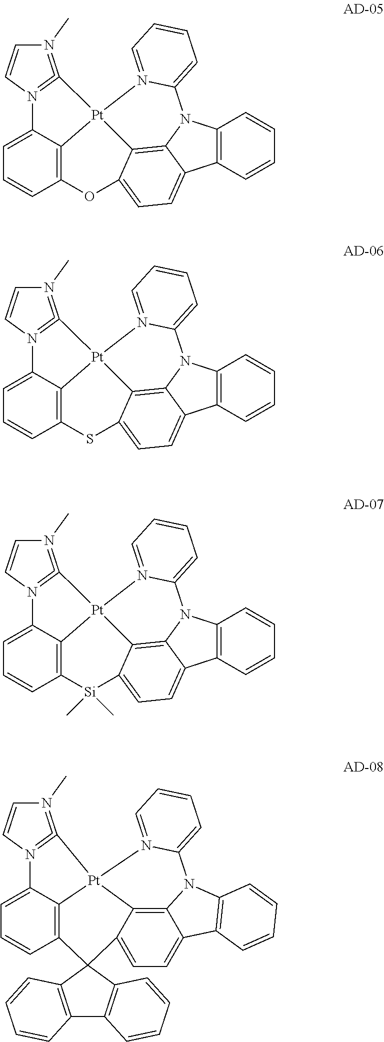

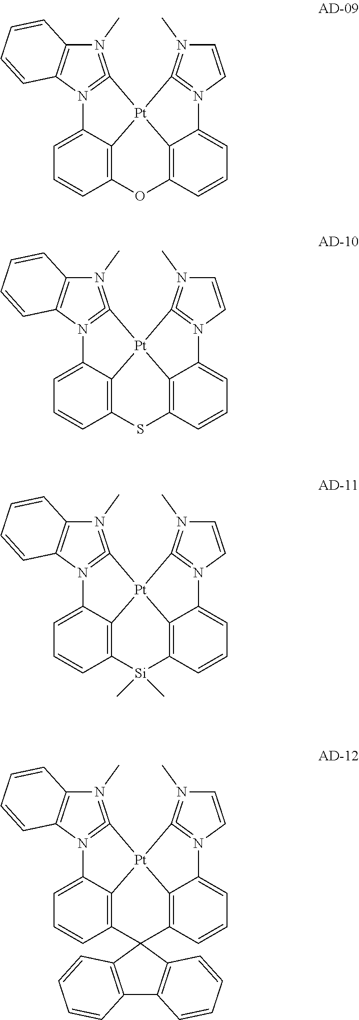

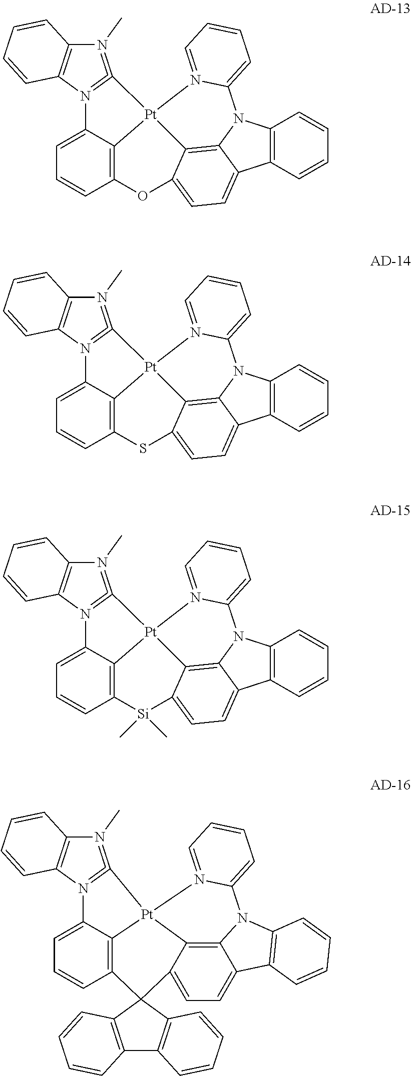

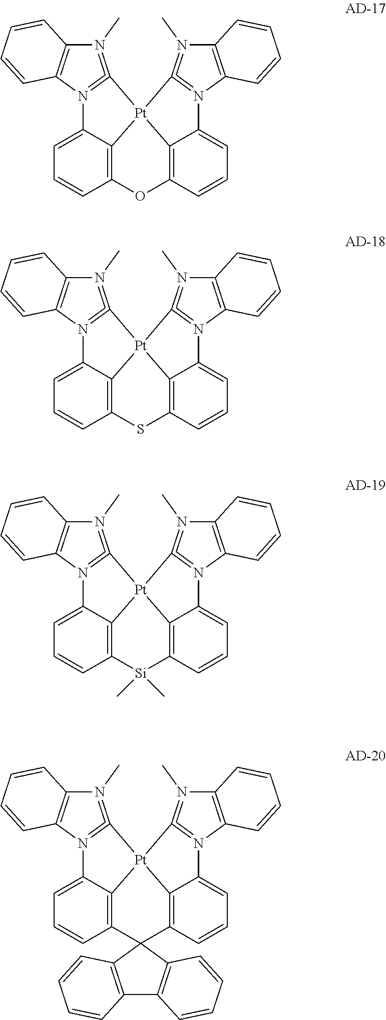

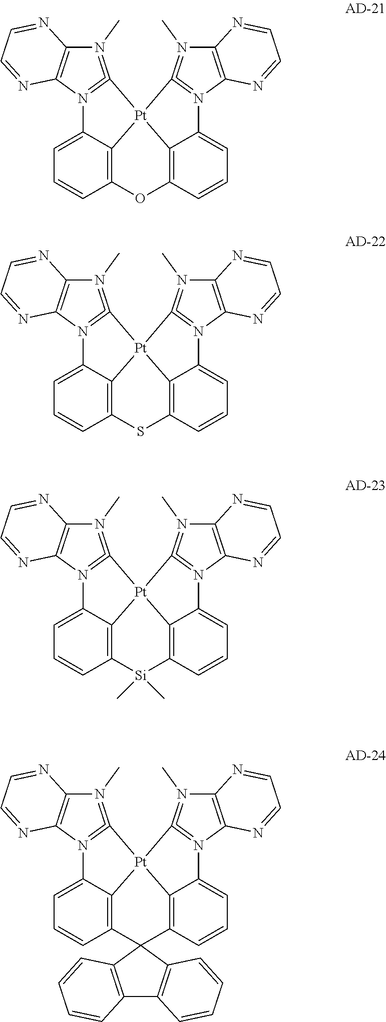

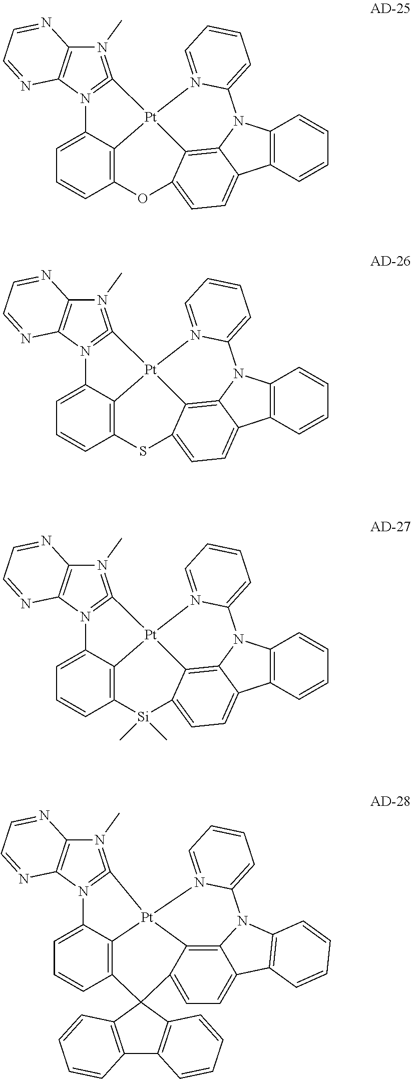

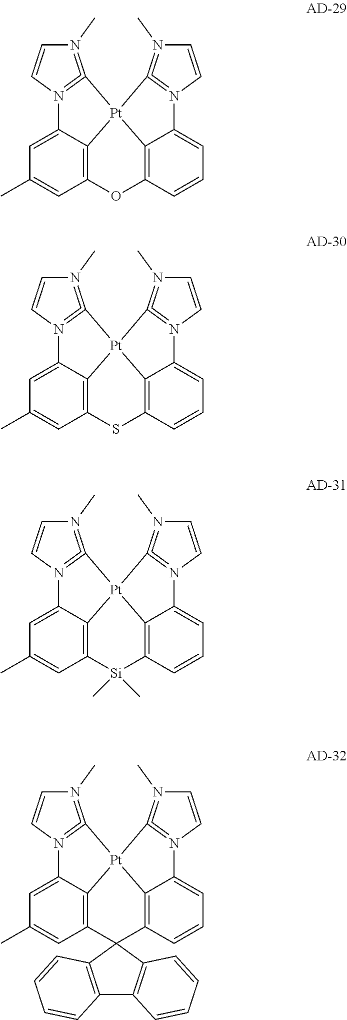

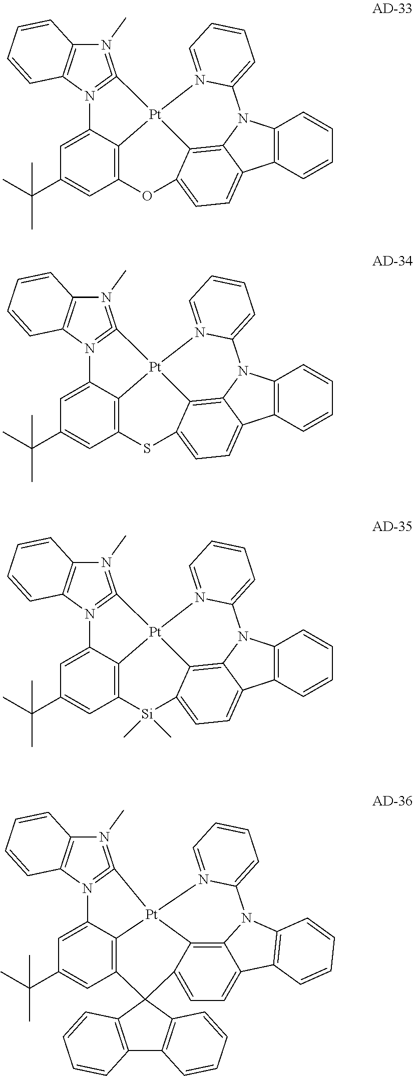

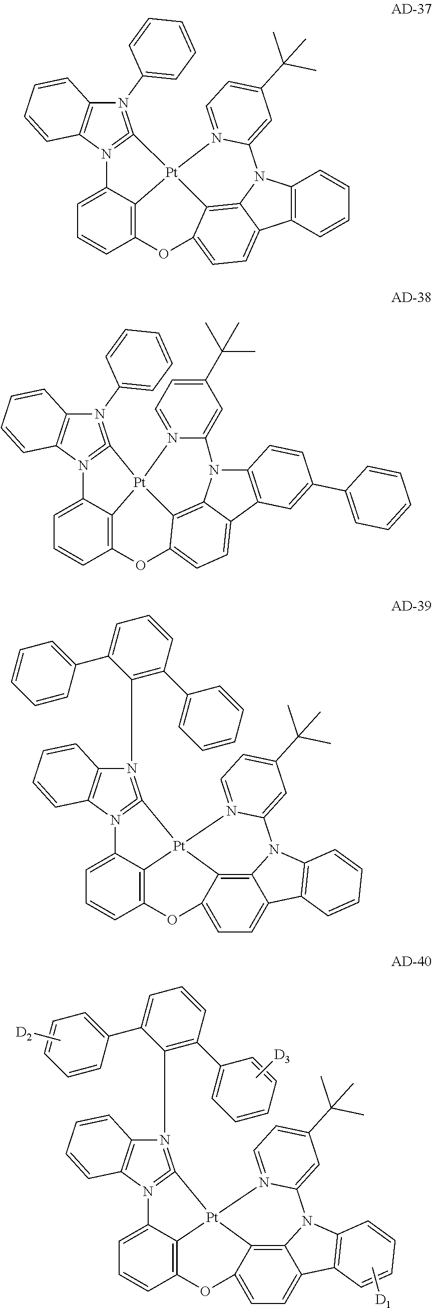

In an embodiment, the light emitting element ED may include multiple emission layers. The emission layers may be provided as a stack of emission layers, so that the light emitting element ED including multiple emission layers may emit white light. The light emitting element ED including multiple emission layers may be a light emitting element having a tandem structure. When the light emitting element ED includes multiple emission layers, at least one emission layer EML may include the first compound, the second compound, the third compound, and the fourth compound as described above.

In an embodiment, in the light emitting element ED, the emission layer EML may further include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting element ED according to an embodiment as shown in FIGS. 3 to 6, the emission layer EML may further include a host of the related art and a dopant of the related art, in addition to the host and dopant described above.

In an embodiment, the emission layer EML may include a compound represented by Formula E-1. The compound represented by Formula E-1 may be used as a fluorescent host material.

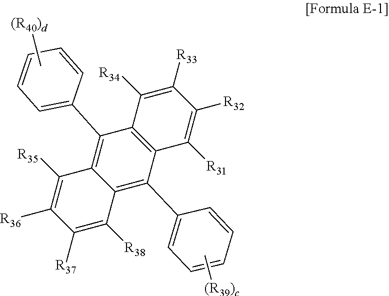

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, in Formula E-1, R₃₁ to R₄₀ may be linked to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any compound selected from Compound E1 to Compound E19.

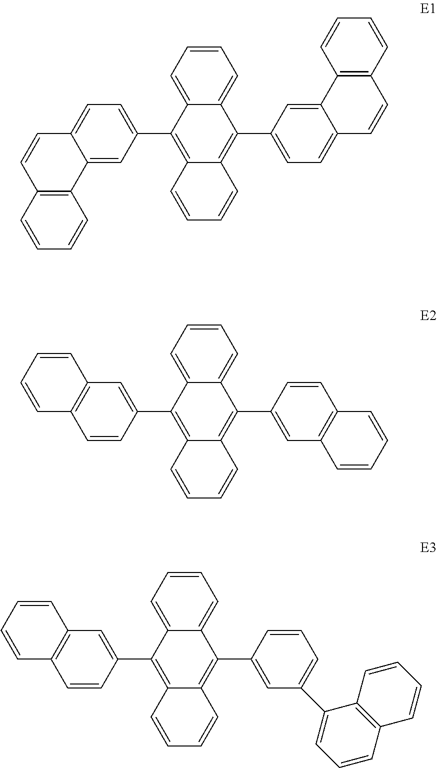

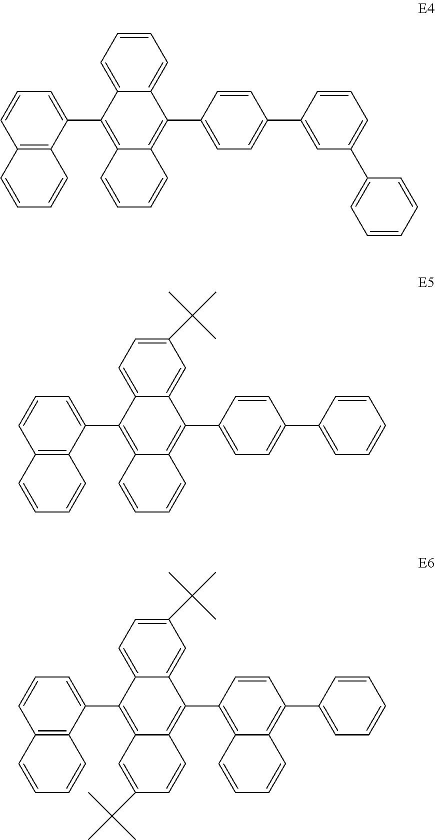

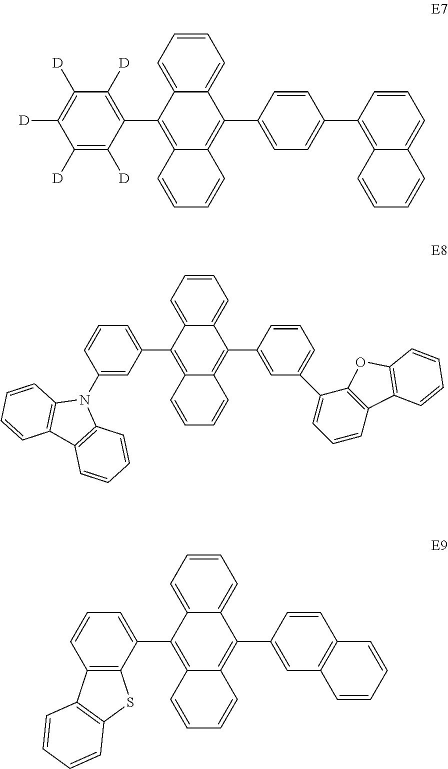 [SMILES: [2H]c1c([2H])c([2H])c(-c2c3ccccc3c(-c3ccc(-c4cccc5ccccc45)cc3)c3ccccc23)c([2H])c1[2H] ; c1cc(-c2c3ccccc3c(-c3cccc(-n4c5ccccc5c5ccccc54)c3)c3ccccc23)cc(-c2cccc3c2oc2ccccc23)c1 ; c1ccc2cc(-c3c4ccccc4c(-c4cccc5c4sc4ccccc45)c4ccccc34)ccc2c1]

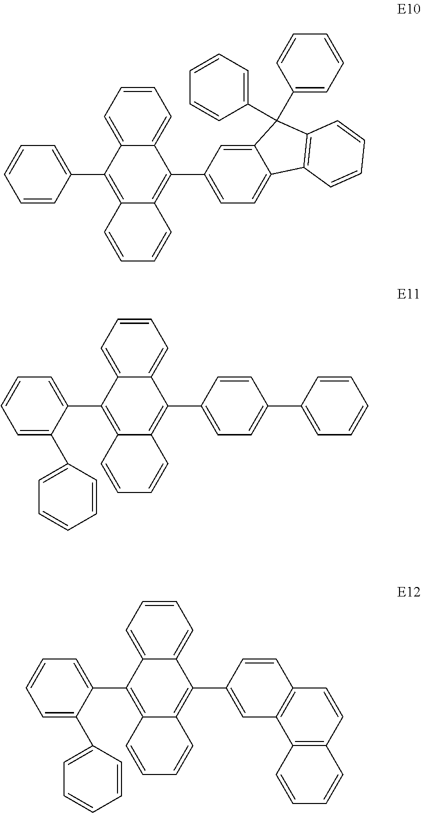

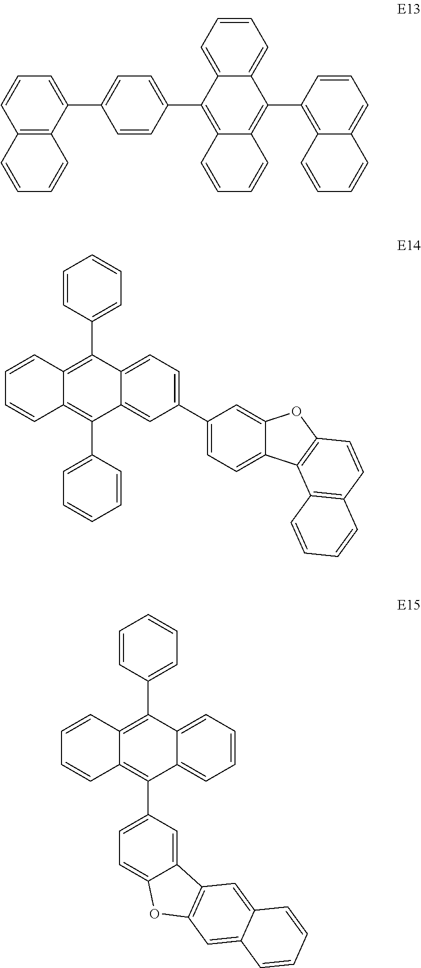

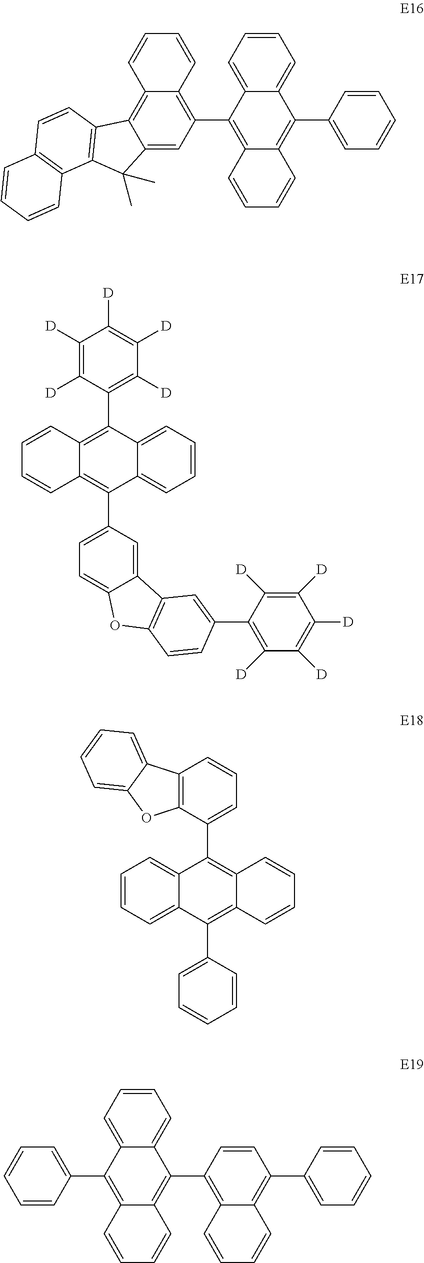

In an embodiment, the emission layer EML may include a compound represented by Formula E-2a or Formula E-2b. The compound represented by Formula E-2a or Formula E-2b may be used as a phosphorescent host material.

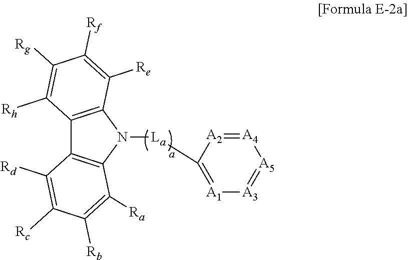

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, two or more Lₐ groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, Rₐ to Rᵢ may be bonded to an adjacent group to form a hydrocarbon ring or a heterocycle containing N, O, S, and the like as a ring-forming atom.

In Formula E-2a, two or three of A₁ to A₅ may each be N, and the remainder of A₁ to A₅ may each independently be C(Rᵢ).

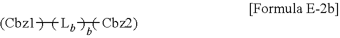

In Formula E-2b, Cbz1 and Cbz2 may each independently be an unsubstituted carbazole group or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or greater, two or more Le groups may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

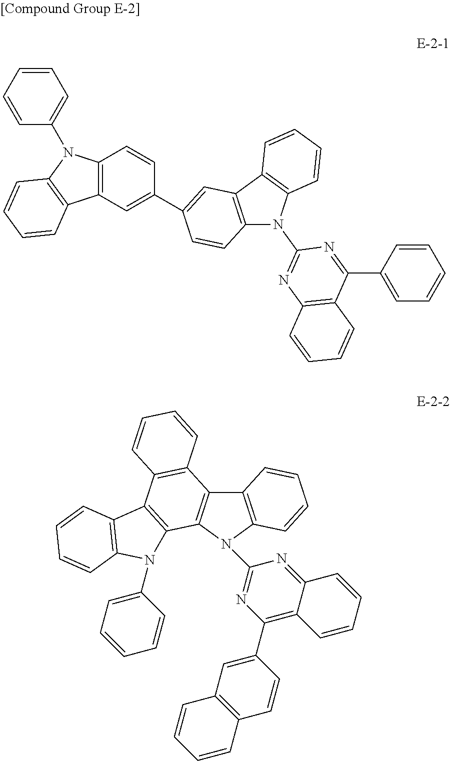 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1]

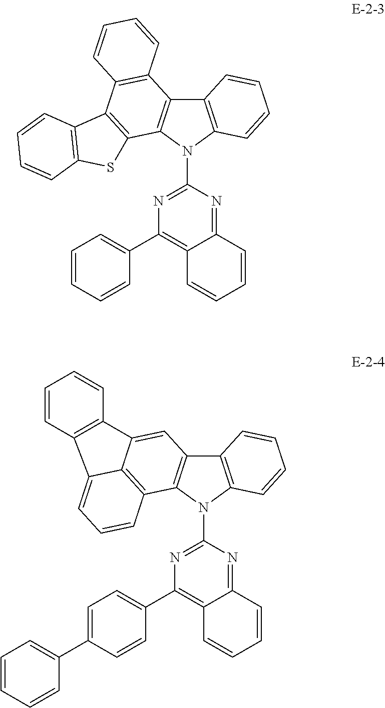 [SMILES: c1ccc(-c2nc(-n3c4ccccc4c4c5ccccc5c5c6ccccc6sc5c43)nc3ccccc23)cc1 ; c1ccc(-c2ccc(-c3nc(-n4c5ccccc5c5cc6c7c(cccc7c54)-c4ccccc4-6)nc4ccccc34)cc2)cc1]

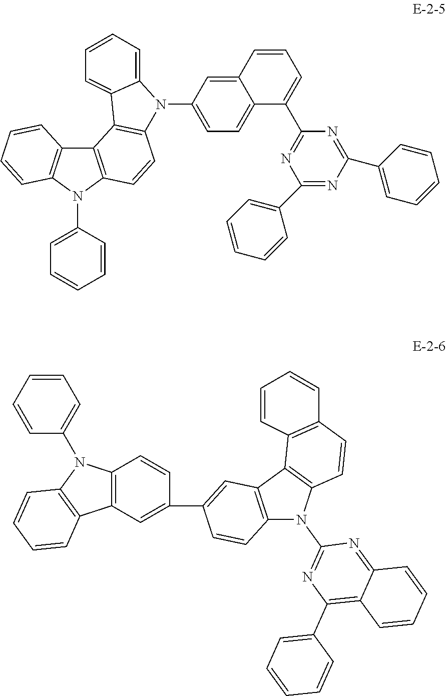 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

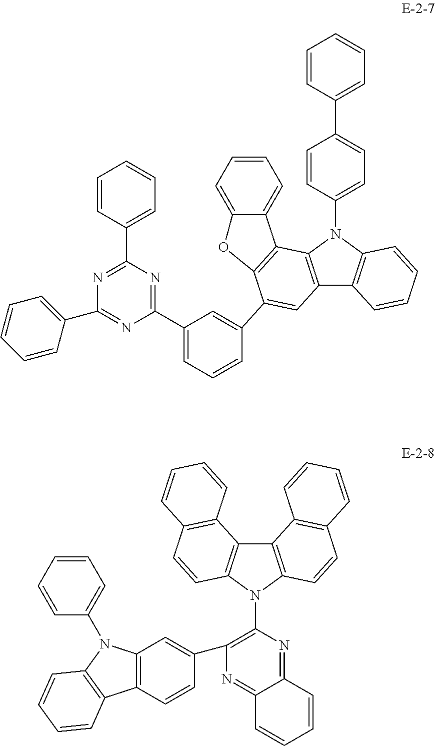 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

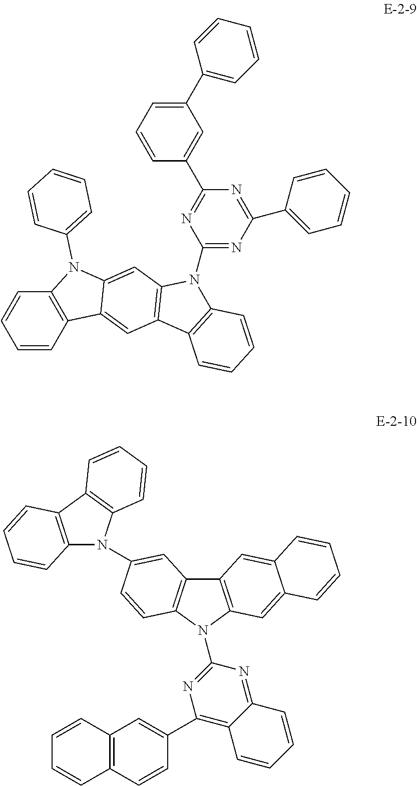 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1]

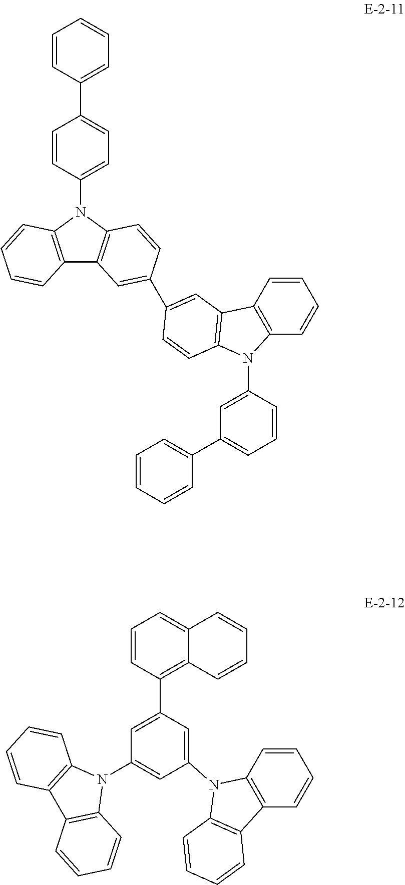 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

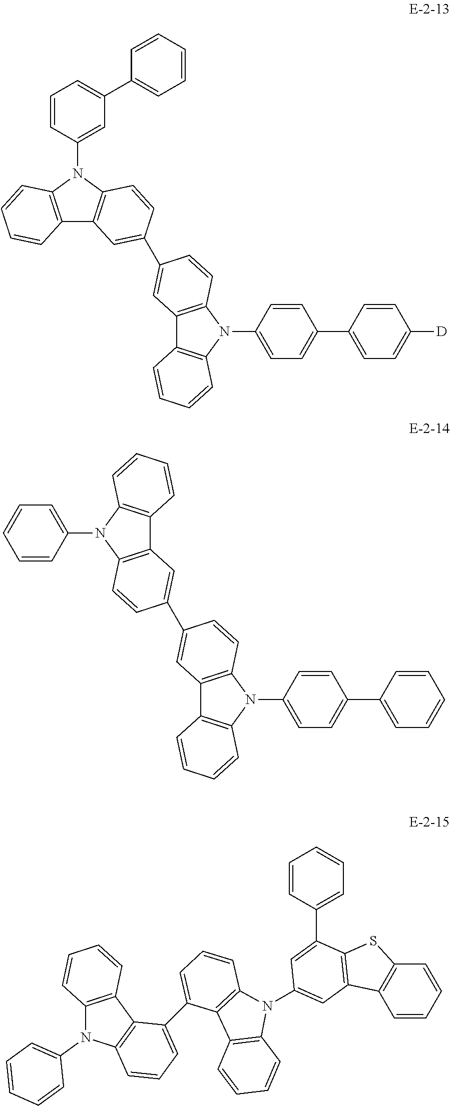 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

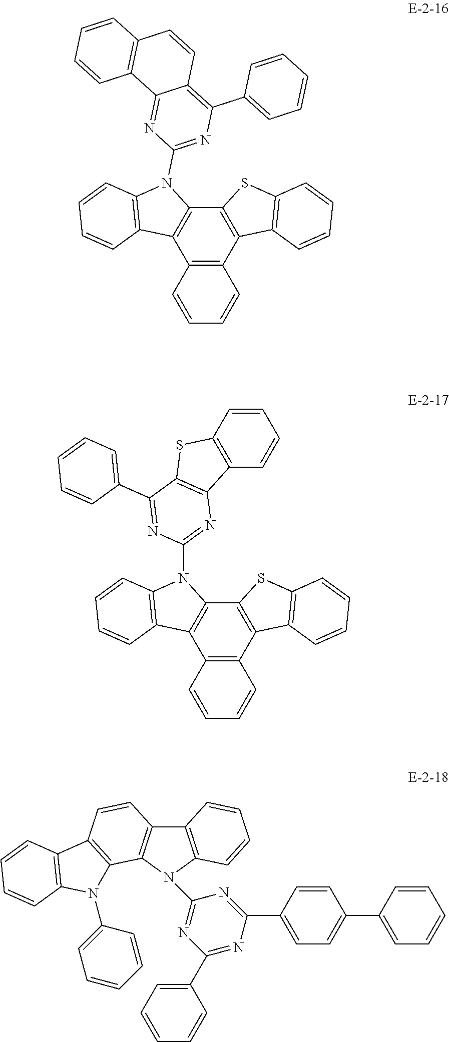 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

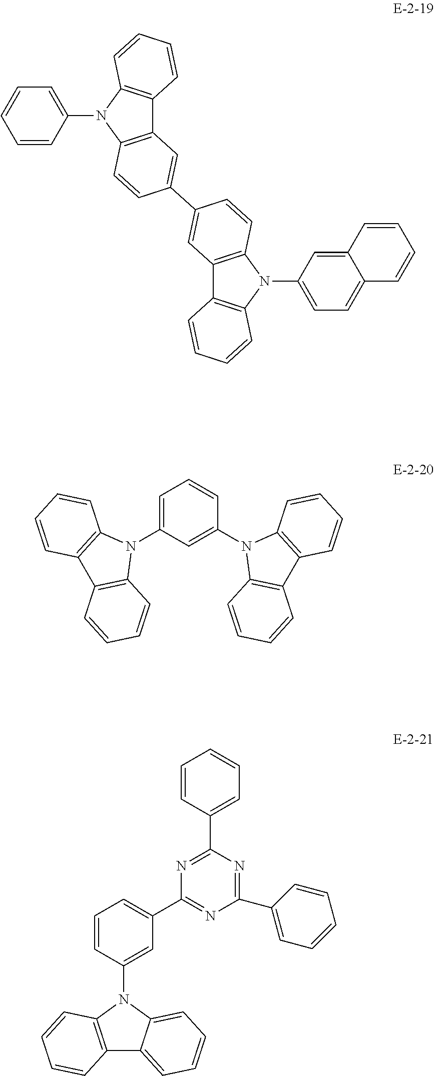 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

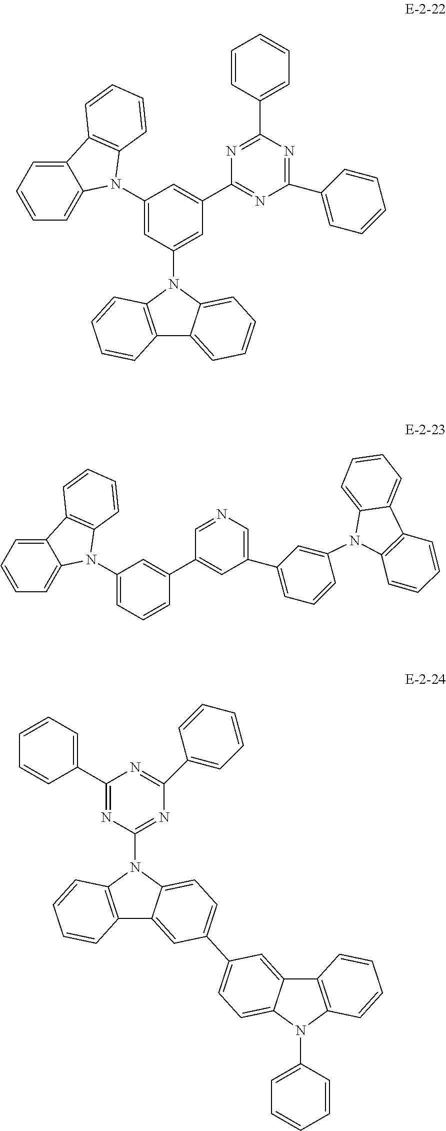 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one among bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazolyl-9-yl)benzene (mCP), 2,8-bis(diphenylphosphoryl)dibenzofuran (PPF), 4,4′,4″-tris(carbazol-9-yl)-triphenylamine (TCTA), and 1,3,5-tris(1-phenyl-1H-benzo[d]imidazol-2-yl)benzene (TPBi). However, embodiments are not limited thereto. For example, tris(8-hydroxyquinolino)aluminum (Alq₃), 9,10-di(naphthalene-2-yl)anthracene (ADN), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), and the like may be used as a host material.

The emission layer EML may include a compound represented by Formula M-a. The compound represented by Formula M-a may be used as a phosphorescent dopant material.

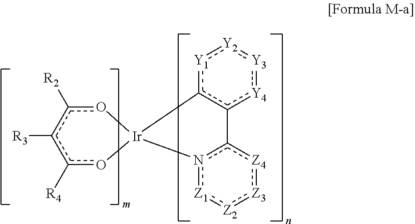

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

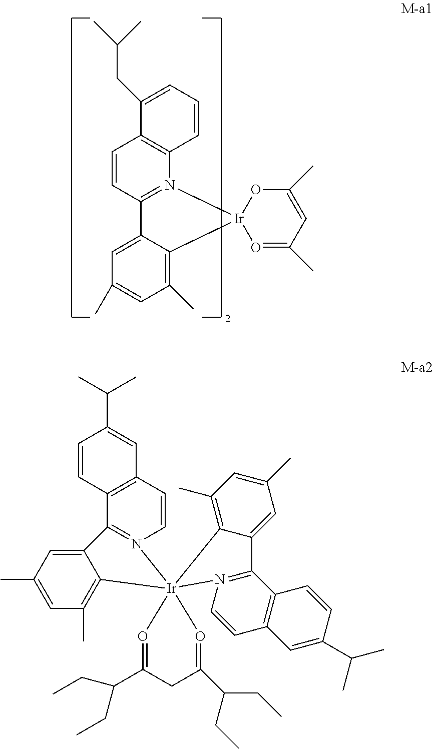

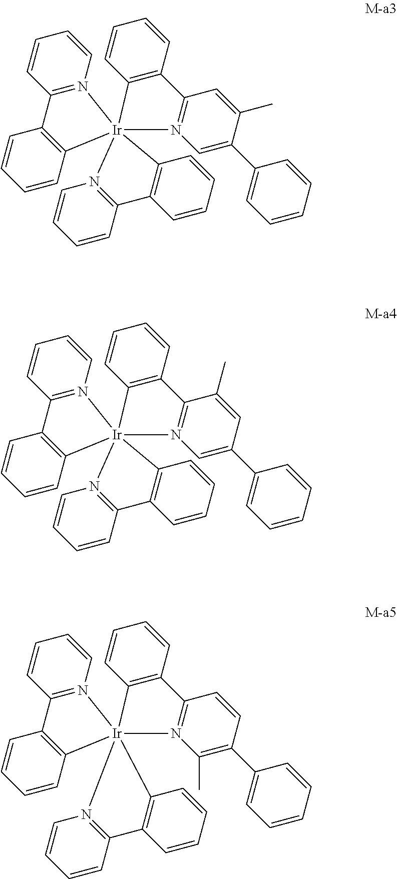

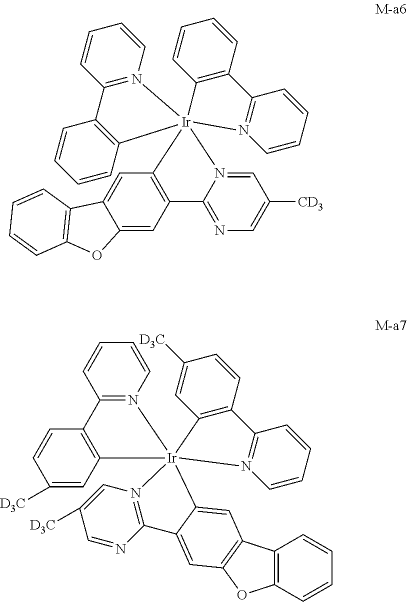

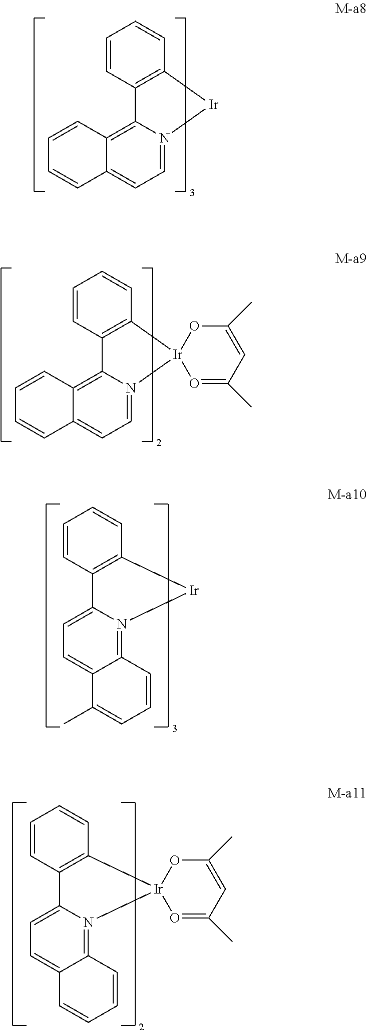

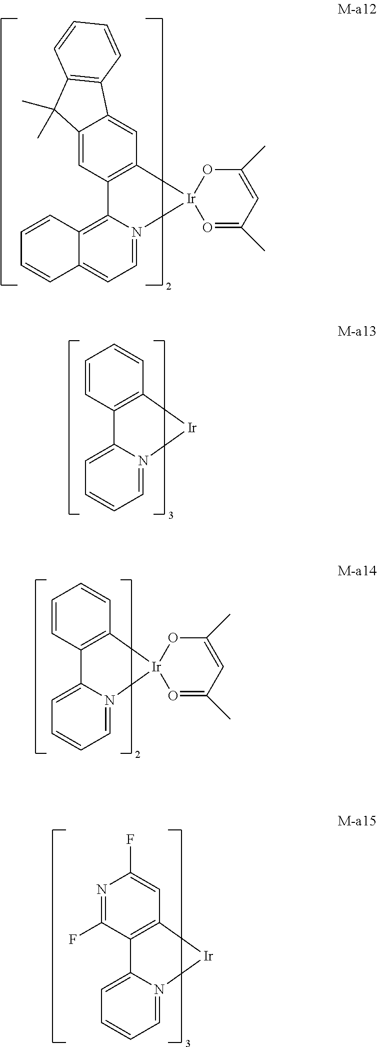

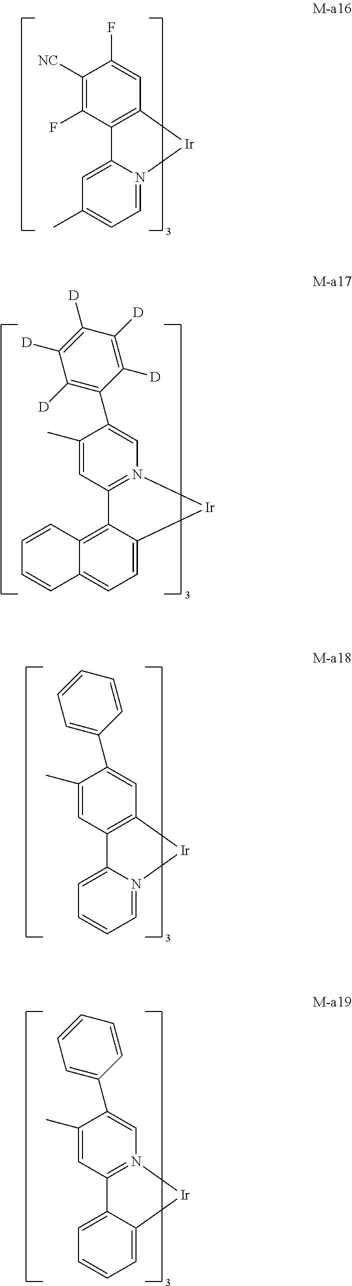

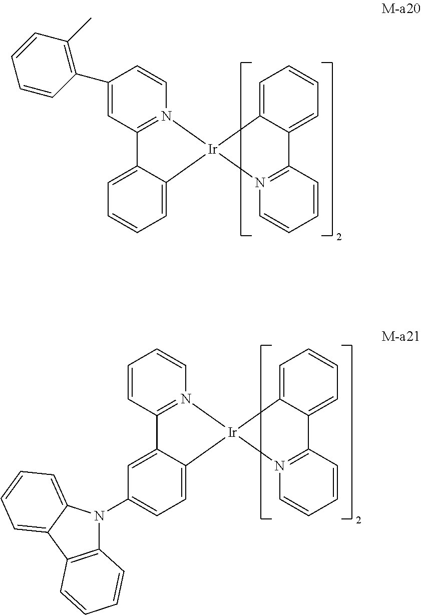

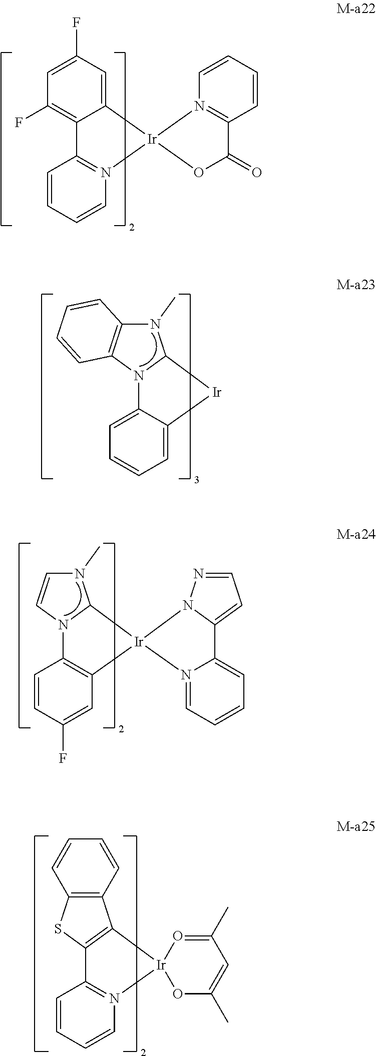

The emission layer EML may include a compound represented by any one of Formulas F-a to F-c. The compound represented by one of Formulas F-a to F-c may be used as a fluorescent dopant material.

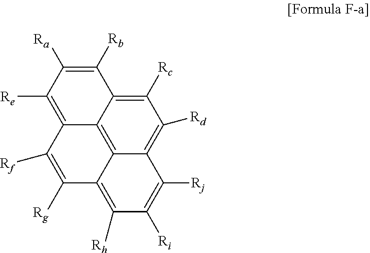

In Formula F-a, two of Rₐ to Rⱼ may each independently be substituted with a group represented by *—NAr₁Ar₂. The remainder of Rₐ to Rⱼ which are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may each independently be a heteroaryl group containing O or S as a ring-forming atom.

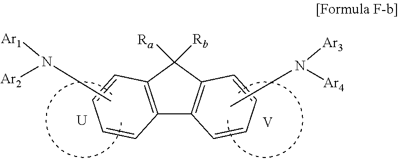

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. When the number of U or V is 1, a fused ring may be respectively present at a portion indicated by U or V. When the number of U or V is 0, a fused ring may not be present at the portion indicated by U or V. When the number of U is 0 and the number of V is 1, or when the number of U is 1 and the number of V is 0, a fused ring having a fluorene core of Formula F-b may be a cyclic compound having four rings. When U and V are each 0, a fused ring having a fluorene core of Formula F-b may be a cyclic compound having three rings. When U and V are each 1, a fused ring having a fluorene core of Formula F-b may be a cyclic compound having five rings.

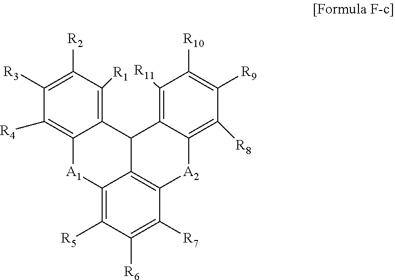

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In Formula F-c, A₁ and A₂ may each independently be bonded to a substituent of a neighboring ring to form a fused ring. For example, when A₁ and A₂ are each independently N(Rₘ), A₁ may be bonded to R₄ or R₅ to form a ring. For example, A₂ may be bonded to R₇ or R₈ to form a ring.

The emission layer EML may include, as a dopant material of the related art, styryl derivatives (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), and the like.

The emission layer EML may include a phosphorescent dopant material of the related art. For example, a metal complex including iridium (Ir), platinum (Pt), osmium (Os), gold (Au), titanium (Ti), zirconium (Zr), hafnium (Hf), europium (Eu), and terbium (Tb), or thulium (Tm) may be used as a phosphorescent dopant. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), platinum octaethyl porphyrin (PtOEP), and the like may be used as a phosphorescent dopant. However, embodiments are not limited thereto.

The emission layer EML may include a quantum dot material. The quantum dot may be a Group II-VI compound, a Group III-VI compound, a Group I-III-VI compound, a Group III-V compound, a Group III-II-V compound, a Group IV-VI compound, a Group IV element, a Group IV compound, or any combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof; or any combination thereof.

Examples of a Group III-VI compound may include: a binary compound such as In₂S₃ and In₂Se₃; a ternary compound such as InGaS₃ and InGaSe₃; or any combination thereof.

Examples of a Group 1-III-VI compound may include: a ternary compound selected from the group consisting of AgInS, AgInS₂, CuInS, CuInS₂, AgGaS₂, CuGaS₂ CuGaO₂, AgGaO₂, AgAlO₂, or a mixture thereof; a quaternary compound such as AgInGaS₂ and CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; or any combination thereof. In an embodiment, a Group III-V compound may further include a Group II element. For example, InZnP or the like may be selected as a Group III—II-V compound.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof.

Examples of a Group IV element may include Si, Ge, or a mixture thereof. Examples of a Group IV compound may include a binary compound selected from the group consisting of SiC, SiGe, and a mixture thereof.

A binary compound, a ternary compound, or a quaternary compound may be present in a particle at a uniform concentration distribution, or may be present in a particle at a partially different concentration distribution. In an embodiment, a quantum dot may have a core/shell structure in which a quantum dot surrounds another quantum dot. A quantum dot having a core/shell structure may have a concentration gradient in which the concentration of a material that is present in the shell decreases towards the core.

In embodiments, a quantum dot may have a core/shell structure that includes a core having nano-crystals and a shell surrounding the core, as described herein. The shell of the quantum dot may serve as a protection layer to prevent the chemical deformation of the core so as to keep semiconductor properties, and/or may serve as a charging layer to impart electrophoresis properties to the quantum dot. The shell may be a single layer or multiple layers. Examples of a shell of the quantum dot may include a metal oxide, a non-metal oxide, a semiconductor compound, or a combination thereof.

Examples of a metal oxide or a non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or a ternary compound such as MgAl₂O₄, CoFe₂O₄, NiFe₂O₄, and CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and the like, but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Color purity or color reproducibility may be improved in any of the above ranges. Light emitted through a quantum dot may be emitted in all directions, so that a wide viewing angle may be improved.

The form of a quantum dot is not particularly limited, and may be any form used in the related art. For example, a quantum dot may have a spherical shape, a pyramidal shape, a multi-arm shape, or a cubic shape, or a quantum dot may be in the form of nanoparticles, nanotubes, nanowires, nanofibers, nanoplatelets, or the like.

The quantum dot may control the color of emitted light according to a particle size thereof. Accordingly, the quantum dot may have various light emitting colors such as blue light, red light, green light, or the like.

In the light emitting element ED according to an embodiment as shown in FIGS. 3 to 6, an electron transport region ETR may be provided on the emission layer EML. The electron transport region ETR may include at least one of a hole blocking layer HBL, an electron transport layer ETL, and an electron injection layer EIL, but embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from an emission layer EML, but embodiments are not limited thereto. The electron transport region ETR may have a thickness in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-1.

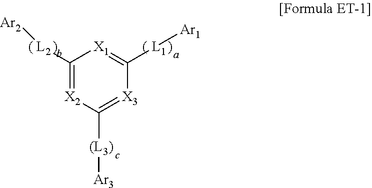

In Formula ET-1, at least one of X₁ to X₃ may each be N; and the remainder of X₁ to X₃ may each independently be C(Rₐ). In Formula ET-1, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or greater, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebg₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include at least one compound selected from Compound ET1 to Compound ET36.

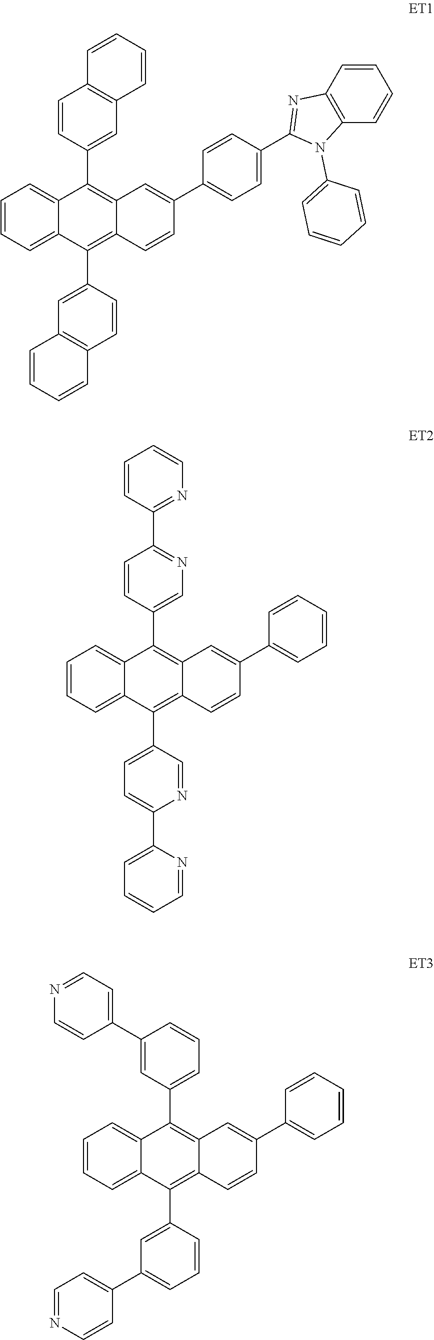 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

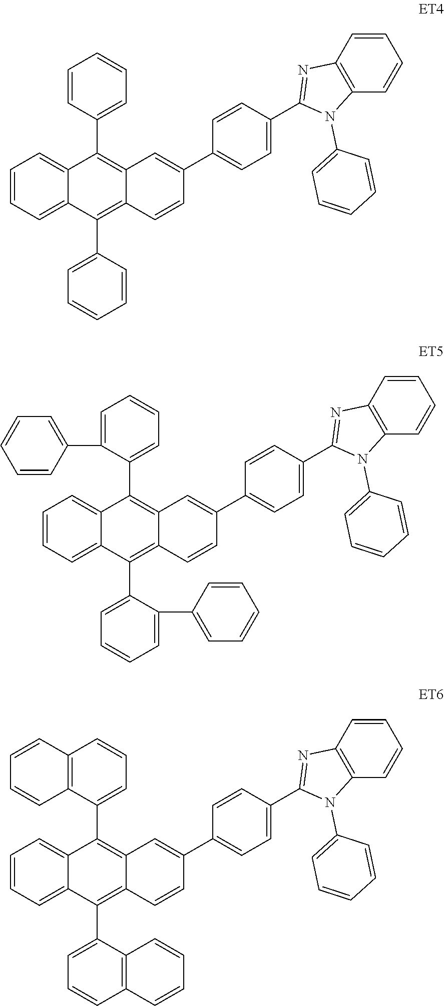 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

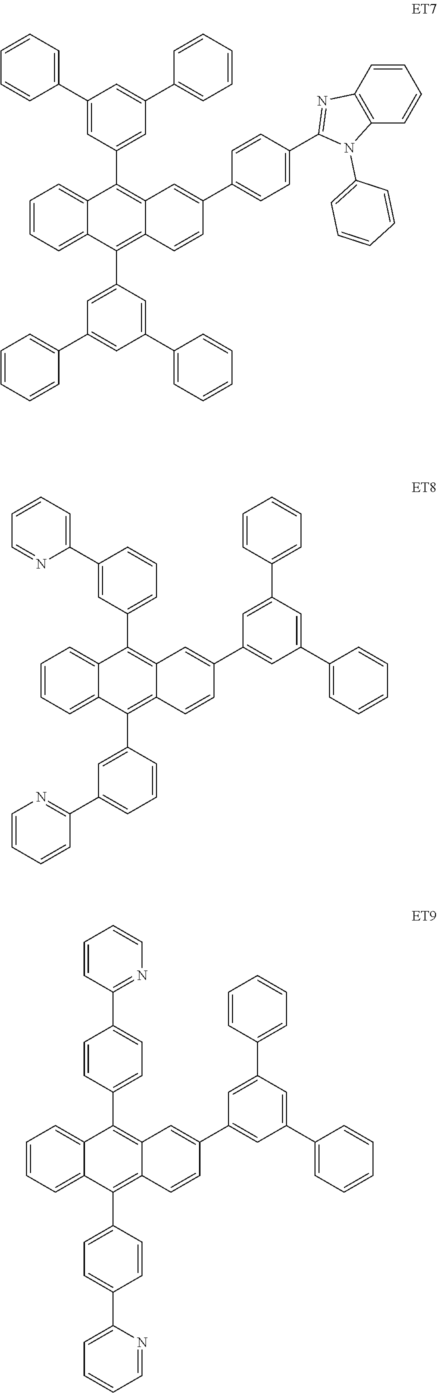 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

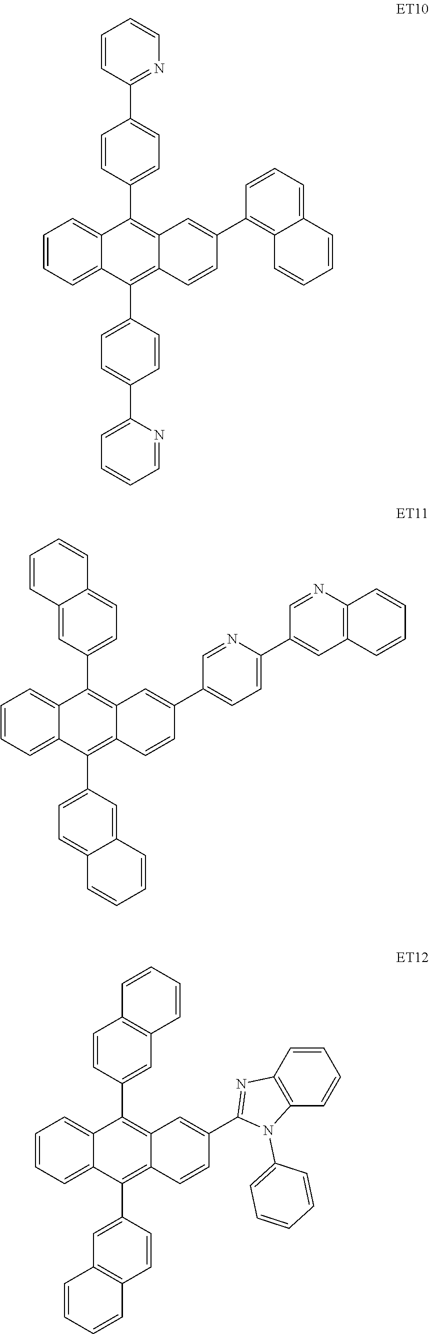 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

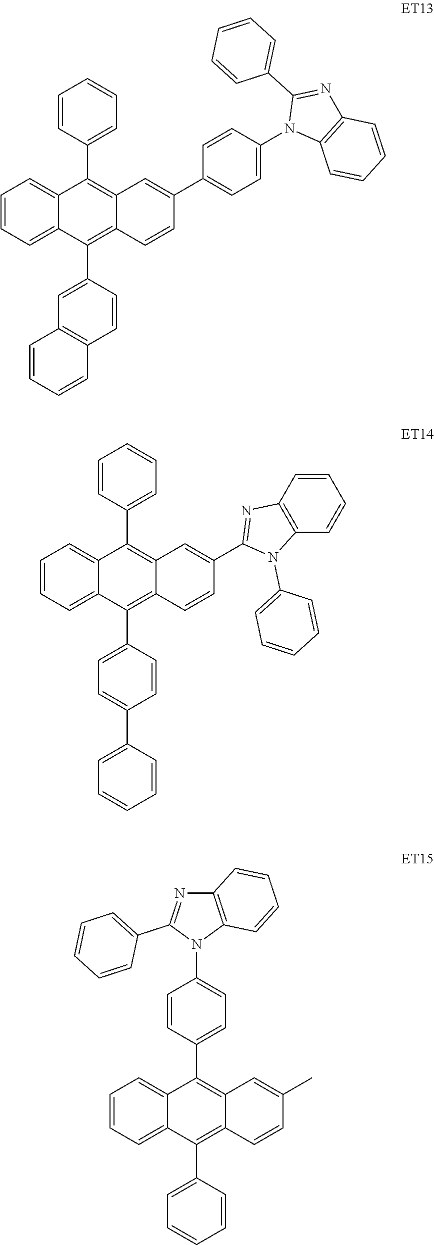 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

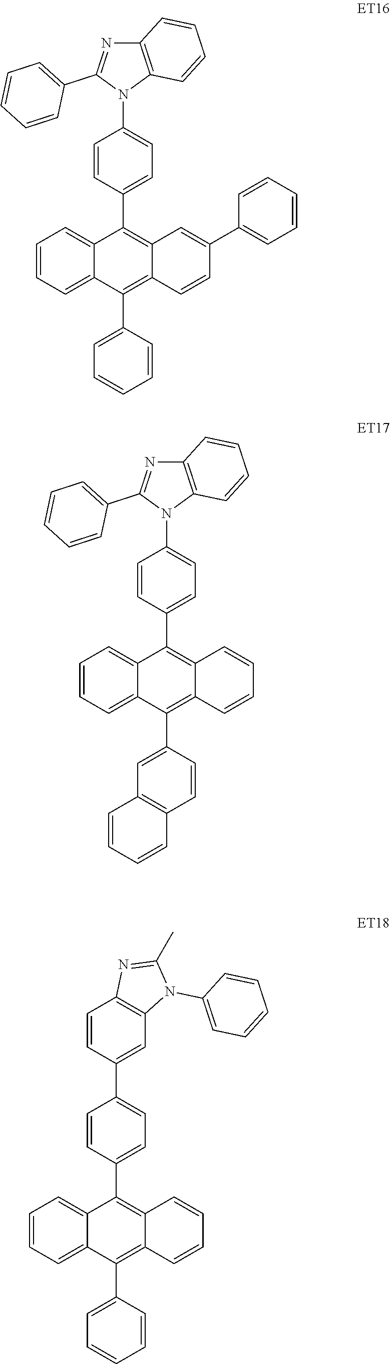 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

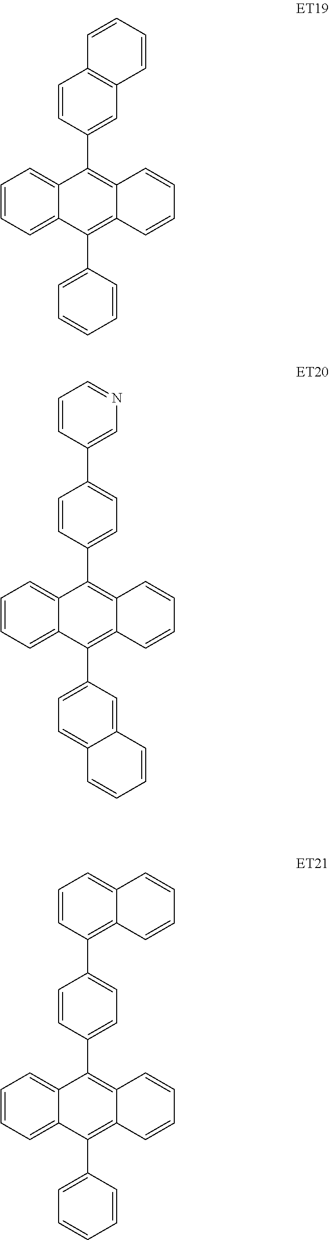

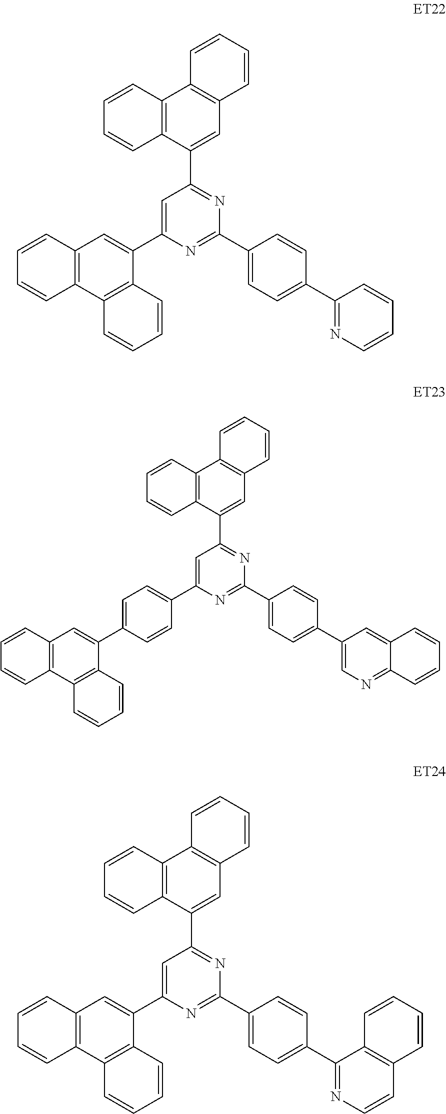 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

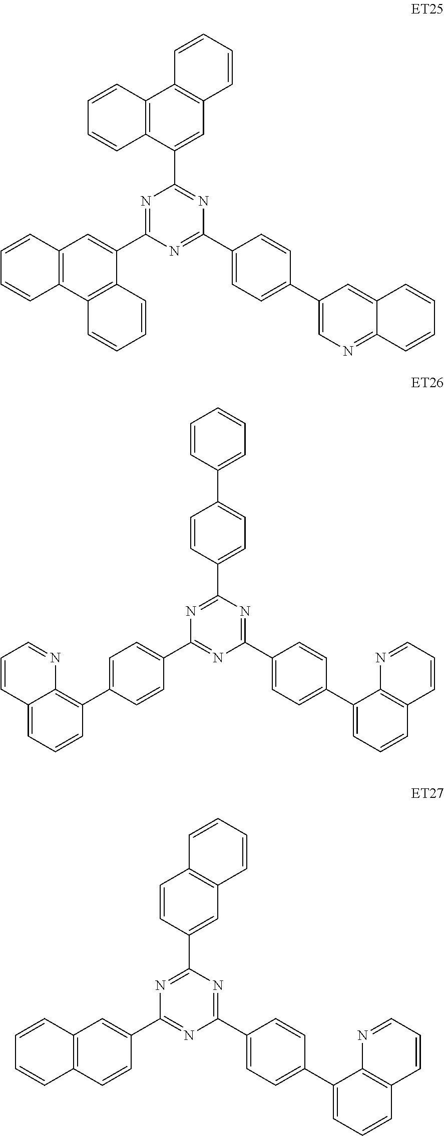 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

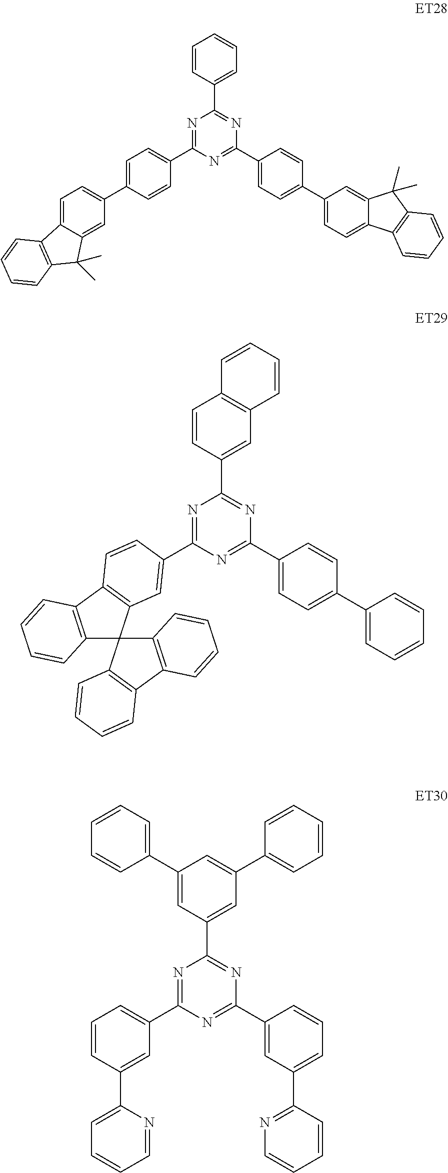 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3nc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

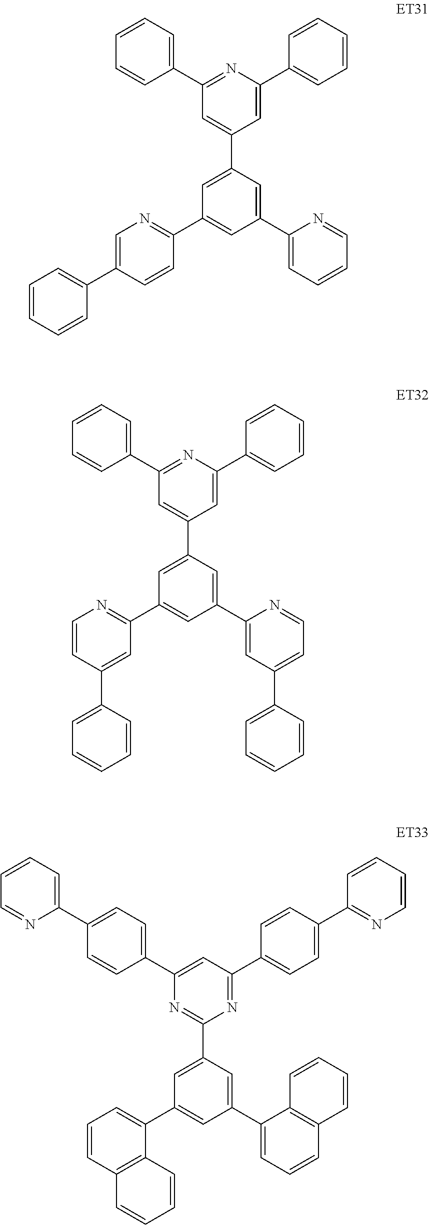 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

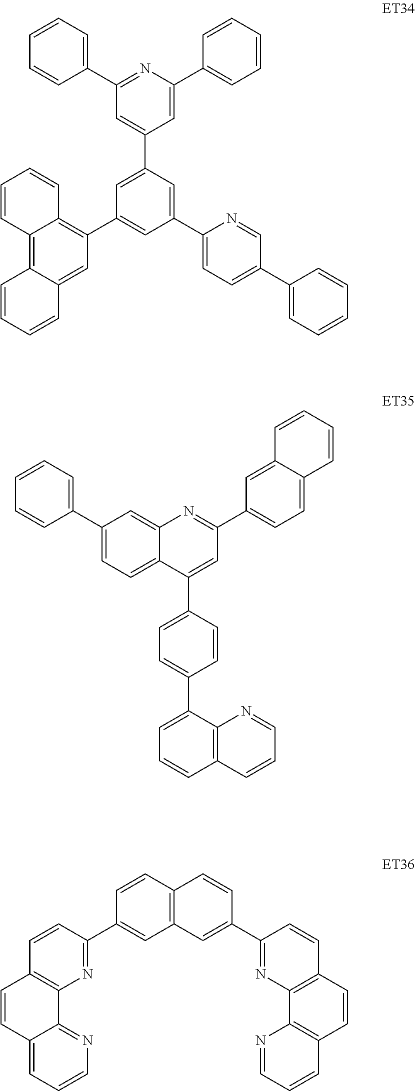 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a halogenated metal such as LiF, NaCl, CsF, RbCl, RbI, CuI, and KI; a lanthanide metal such as Yb; or a co-deposited material of a halogenated metal and a lanthanide metal. For example, the electron transport region ETR may include KI:Yb, RbI:Yb, LiF:Yb, or the like as a co-deposited material. The electron transport region ETR may include a metal oxide such as Li₂O and BaO, or 8-hydroxyl-lithium quinolate (Liq), or the like, but embodiments are limited thereto. In another embodiment, the electron transport region ETR may be formed of a mixture material of an electron transport material and an insulating organometallic salt. The organometallic salt may be a material having an energy band gap equal to or greater than about 4 eV. For example, the organometallic salt may include metal acetates, metal benzoates, metal acetoacetates, metal acetylacetonates, or metal stearates.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen), in addition to the materials described above, but embodiments are not limited thereto.

The electron transport region ETR may include the compounds of the electron transport region as described above in at least one of an electron injection layer EIL, an electron transport layer ETL, and a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. When the thickness of the electron transport layer ETL satisfies any of the above-described ranges, satisfactory electron transport properties may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. When the thickness of the electron injection layer EIL satisfies any of the above-described ranges, satisfactory electron injection properties may be obtained without a substantial increase in driving voltage.

The second electrode EL2 may be provided on the electron transport region ETR. The second electrode EL2 may be a common electrode. The second electrode EL2 may be a cathode or an anode but embodiments are not limited thereto. For example, when the first electrode EL1 is an anode, the second electrode EL2 may be a cathode, and when the first electrode EL1 is a cathode, the second electrode EL2 may be an anode. The second electrode may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), or the like.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgAg). In an embodiment, the second electrode EL2 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), or the like. For example, the second electrode EL2 may include the above-described metal materials, a combination of two or more metal materials selected from the above-described metal materials, or oxides of the above-described metal materials.

Although not shown in the drawings, the second electrode EL2 may be electrically connected to an auxiliary electrode. When the second electrode EL2 is electrically connected to an auxiliary electrode, the resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL includes an inorganic material, the inorganic material may include an alkali metal compound such as LiF, an alkaline earth metal compound such as MgF₂, SiON, SiNₓ, SiO_{y}, or the like.

For example, when the capping layer CPL includes an organic material, the organic material may include α-NPD, NPB, TPD, m-MTDATA, Alq₃ CuPc, N4,N4,N4′,N4′-tetra(biphenyl-4-yl) biphenyl-4,4′-diamine (TPD15), 4,4′,4″-tris(carbazol sol-9-yl)triphenylamine (TCTA), or the like, or may include an epoxy resin or an acrylate such as a methacrylate. However, embodiments are not limited thereto, and the capping layer CPL may include at least one of Compound P1 to Compound P5.

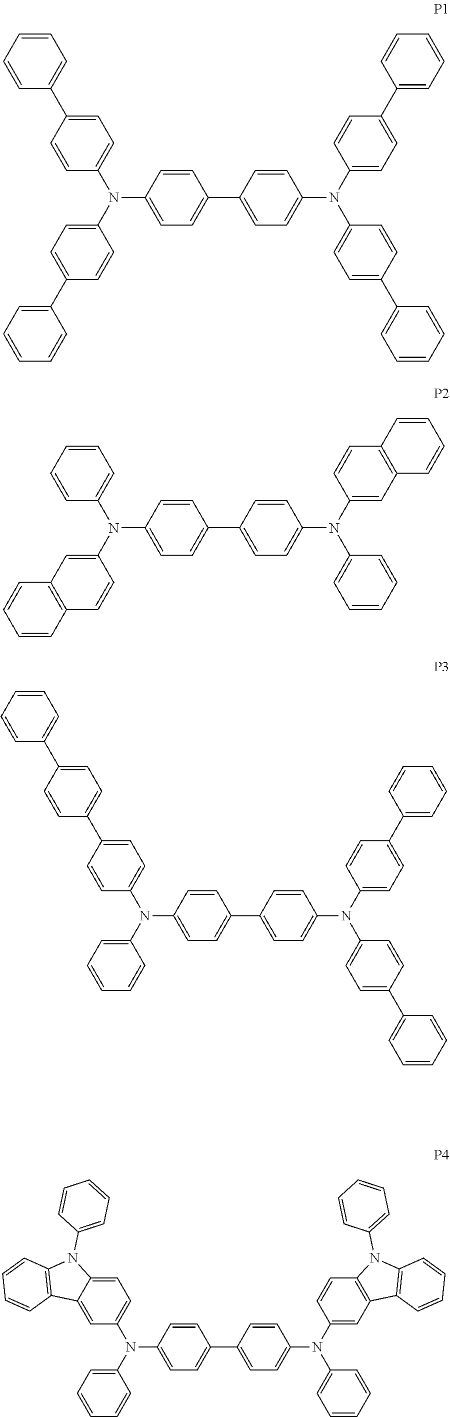 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

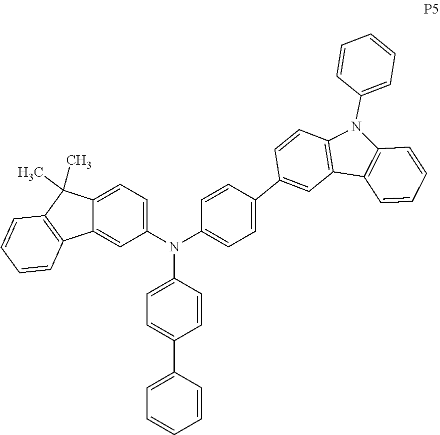 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

The capping layer CPL may have a refractive index equal to or greater than about 1.6. For example, the capping layer CPL may have a refractive index equal to or greater than about 1.6 in a wavelength range of about 550 nm to about 660 nm.

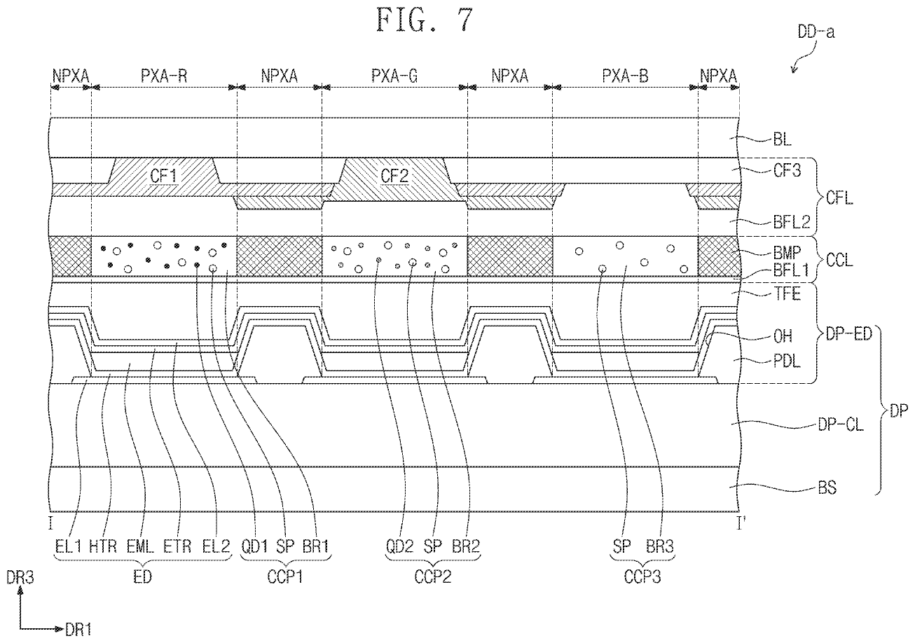

FIGS. 7 to 10 are each a schematic cross-sectional view of a display device according to an embodiment. In the descriptions of the display devices according to embodiments as shown in FIGS. 7 to 10, the features which have been described above with respect to FIGS. 1 to 6 will not be explained again, and the differing features will be described.

Referring to FIG. 7, a display device DD-a according to an embodiment may include a display panel DP having a display element layer DP-ED, a light control layer CCL disposed on the display panel DP, and a color filter layer CFL.

In an embodiment shown in FIG. 7, the display panel DP may include a base layer BS, a circuit layer DP-CL provided on the base layer BS, and a display element layer DP-ED, and the element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 7 may be the same as a structure of a light emitting element ED according to one of FIGS. 3 to 6 as described above.

The emission layer EML of the light emitting element ED included in a display device DD-a according to an embodiment may include the polycyclic compound according to an embodiment as described above.

Referring to FIG. 7, the emission layer EML may be disposed in openings OH defined in the pixel defining films PDL. For example, the emission layer EML, which is separated by the pixel defining films PDL and correspondingly provided to each of the light emitting regions PXA-R, PXA-G, and PXA-B, may emit light in a same wavelength range. In the display device DD-a, the emission layer EML may emit blue light. Although not shown in the drawings, in an embodiment, the emission layer EML may be provided as a common layer for each of the light emitting regions PXA-R, PXA-G, and PXA-B.

The light control layer CCL may be disposed on the display panel DP. The light control layer CCL may include a light converter. The light converter may be a quantum dot or a phosphor. The light converter may convert the wavelength of a provided light and may emit the resulting light. For example, the light control layer CCL may be a layer containing quantum dots or phosphors.

The light control layer CCL may include light control units CCP1, CCP2, and CCP3. The light control units CCP1, CCP2, and CCP3 may be spaced apart from each other.

Referring to FIG. 7, a division pattern BMP may be disposed between the light control units CCP1, CCP2, and CCP3, which are spaced apart from each other, but embodiments are not limited thereto. In FIG. 7, it is shown that the division pattern BMP does not overlap the light control units CCP1, CCP2, and CCP3, but the edges of the light control units CCP1, CCP2, and CCP3 may overlap at least a portion of the division pattern BMP.

The light control layer CCL may include a first light control unit CCP1 including a first quantum dot QD1 that converts first color light provided from the light emitting element ED into second color light, a second light control unit CCP2 including a second quantum dot QD2 that converts the first color light into third color light, and a third light control unit CCP3 that transmits the first color light.

In an embodiment, the first light control unit CCP1 may provide red light, which is the second color light, and the second light control unit CCP2 may provide green light, which is the third color light. The third light control unit CCP3 may transmit and provide blue light, which is the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light control layer CCL may further include scatterers SP. The first light control unit CCP1 may include the first quantum dot QD1 and the scatterers SP, the second light control unit CCP2 may include the second quantum dot QD2 and the scatterers SP, and the third light control unit CCP3 may not include a quantum dot but may include the scatterers SP.

The scatterers SP may be inorganic particles. For example, the scatterers SP may include at least one of TiO₂, ZnO, Al₂O₃, SiO₂, and hollow silica. The scatterers SP may include any of TiO₂, ZnO, Al₂O₃, SiO₂, or hollow silica, or the scatterers SP may be a mixture of two or more materials selected from TiO₂, ZnO, Al₂O₃, SiO₂, and hollow silica.

The first light control unit CCP1, the second light control unit CCP2, and the third light control unit CCP3 may each include base resins BR1, BR2, and BR3 for dispersing the quantum dots QD1 and QD2 and the scatterers SP. In an embodiment, the first light control unit CCP1 may include the first quantum dot QD1 and the scatterers SP dispersed in the first base resin BR1, the second light control unit CCP2 may include the second quantum dot QD2 and the scatterers SP dispersed in the second base resin BR2, and the third light control unit CCP3 may include the scatterers SP dispersed in the third base resin BR3.

The base resins BR1, BR2, and BR3 are each a medium in which the quantum dots QD1 and QD2 and the scatterers SP are dispersed, and may be formed of various resin compositions, which may be generally referred to as a binder. For example, the base resins BR1, BR2, and BR3 may be an acrylic-based resin, a urethane-based resin, a silicone-based resin, an epoxy-based resin, or the like. The base resins BR1, BR2, and BR3 may each be a transparent resin. In an embodiment, the first base resin BR1, the second base resin BR2, and the third base resin BR3 may each be the same as or different from each other.

The light control layer CCL may include a barrier layer BFL1. The barrier layer BFL1 may prevent the permeation of moisture and/or oxygen (hereinafter referred to as “moisture/oxygen”) into the display panel DP. The barrier layer BFL1 may be disposed on the light control units CCP1, CCP2, and CCP3 to prevent the light control units CCP1, CCP2, and CCP3 from being exposed to moisture/oxygen. The barrier layer BFL1 may cover the light control units CCP1, CCP2, and CCP3. A barrier layer BFL2 may be provided between the light control units CCP1, CCP2, and CCP3, and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, a metal thin film in which light transmittance is secured, or the like. The barrier layers BFL1 and BFL2 may each independently further include an organic film. The barrier layers BFL1 and BFL2 may each be formed of a single layer or of multiple layers.

In the display device DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include a light blocking unit (not shown) and filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymer photosensitive resin, and a pigment or a dye. The first filter CF1 may include a red pigment or a red dye, the second filter CF2 may include a green pigment or a green dye, and the third filter CF3 may include a blue pigment or a blue dye. However, embodiments are not limited thereto, and the third filter CF3 may not include a pigment or a dye. The third filter CF3 may include a polymer photosensitive resin, but may not include a pigment or a dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated and may be provided as a single body. The first to third filters CF1, CF2, and CF3 may be disposed to respectively correspond to the red light emitting region PXA-R, the green light emitting region PXA-G, and the blue light emitting region PXA-B.

The light blocking unit (not shown) may be a black matrix. The light blocking unit (not shown) may include an organic light blocking material or an inorganic light blocking material, each including a black pigment or a black dye. The light blocking unit (not shown) may separate boundaries between the adjacent filters CF1, CF2, and CF3. In an embodiment, the light blocking unit (not shown) may be formed of a blue filter.

A base substrate BL may be disposed on the color filter layer CFL. The base substrate BL may provide a base surface on which the color filter layer CFL and the light control layer CCL are disposed. The base substrate BL may be a glass substrate, a metal substrate, a plastic substrate, and the like. However, embodiments are not limited thereto, and the base substrate BL may include an inorganic layer, an organic layer, or a composite material layer. Although not shown in the drawings, in an embodiment, the base substrate BL may be omitted.

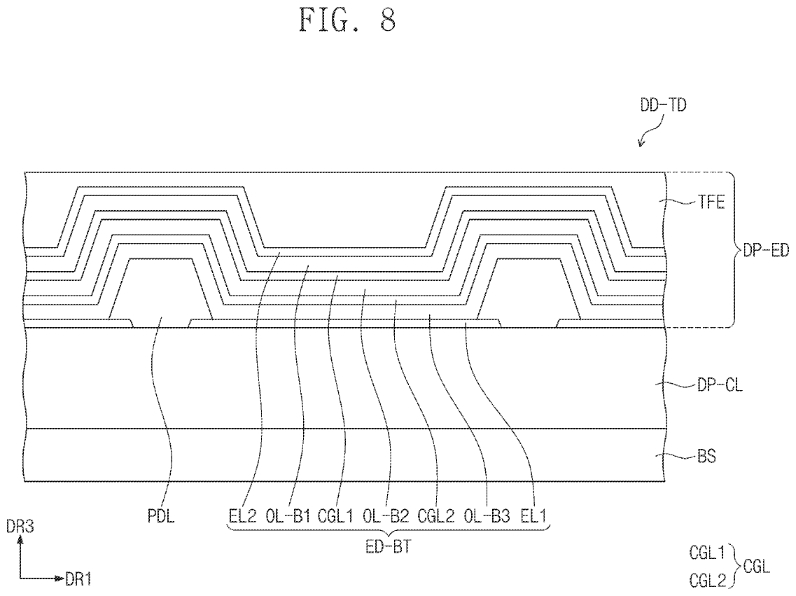

FIG. 8 is a schematic cross-sectional view showing a portion of a display device according to an embodiment. In a display device DD-TD according to an embodiment, a light emitting element ED-BT may include light emitting structures OL-B1, OL-B2, and OL-B3. The light emitting element ED-BT may include a first electrode EL1 and a second electrode EL2 which face each other, and the light emitting structures OL-B1, OL-B2, and OL-B3, which are stacked in a thickness direction between the first electrode EL1 and the second electrode EL2. The light emitting structures OL-B1, OL-B2, and OL-B3 may each include an emission layer EML (see FIG. 7), and a hole transport region HTR and an electron transport region ETR disposed with the emission layer EML (see FIG. 7) therebetween.

For example, the light emitting element ED-BT included in the display device DD-TD may be a light emitting element having a tandem structure that includes multiple emission layers.

In an embodiment shown in FIG. 8, light emitted from the light emitting structures OL-B1, OL-B2, and OL-B3 may each be blue light. However, embodiments are not limited thereto, and the light emitted from each of the light emitting structures OL-B1, OL-B2, and OL-B3 may have wavelength ranges that are different from each other. For example, the light emitting element ED-BT including the light emitting structures OL-B1, OL-B2, and OL-B3, which emit light in different wavelength ranges, may emit white light.

A charge generation layer CGL may be disposed between neighboring light emitting structures among the light emitting structures OL-B1, OL-B2, and OL-B3. In FIG. 8, the charge generation layer CGL includes charge generation layers CGL1 and CGL2. The charge generation layers CGL1 and CGL2 may each independently include a p-type charge generation layer and/or an n-type charge generation layer.

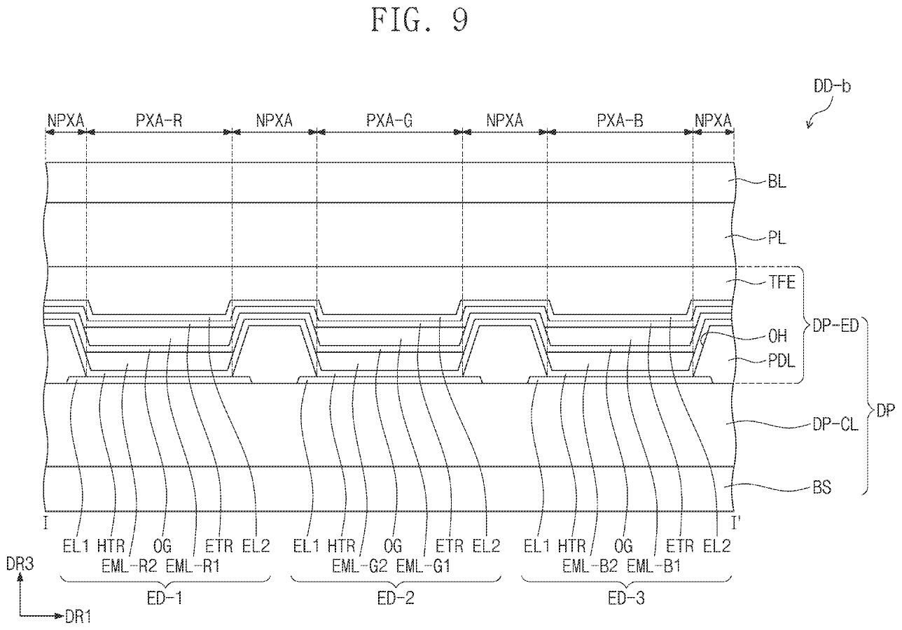

Referring to FIG. 9, a display device DD-b according to an embodiment may include light emitting elements ED-1, ED-2, and ED-3, which each include two emission layers that are stacked. In comparison to the display device DD shown in FIG. 2, the embodiment shown in FIG. 9 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength range.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. A light emitting auxiliary portion OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The light emitting auxiliary portion OG may be a single layer or multiple layers. The light emitting auxiliary portion OG may include a charge generation layer. For example, the light emitting auxiliary portion OG may include an electron transport region, a charge generation layer, and a hole transport region, which may be stacked in that order. The light emitting auxiliary portion OG may be provided as a common layer throughout all of the first to third light emitting elements ED-1, ED-2, and ED-3. However, embodiments are not limited thereto, and the light emitting auxiliary portion OG may be provided by being patterned inside the openings OH defined in the pixel defining films PDL.

The first red emission layer EML-R1, the first green emission layer EML-G1, and the first blue emission layer EML-B1 may each be disposed between the electron transport region ETR and the light emitting auxiliary portion OG. The second red emission layer EML-R2, the second green emission layer EML-G2, and the second blue emission layer EML-B2 may each be disposed between the light emitting auxiliary portion OG and the hole transport region HTR.

For example, the light emitting element ED-1 may include the first electrode EL1, the hole transport region HTR, the second red emission layer EML-R2, the light emitting auxiliary portion OG, the first red emission layer EML-R1, the electron transport region ETR, and the second electrode EL2, which are stacked in that order. The second light emitting element ED-2 may include the first electrode EL1, the hole transport region HTR, the second green emission layer EML-G2, the light emitting auxiliary portion OG, the first green emission layer EML-G1, the electron transport region ETR, and the second electrode EL2, which are stacked in that order. The third light emitting element ED-3 may include the first electrode EL1, the hole transport region HTR, the second blue emission layer EML-B2, the light emitting auxiliary portion OG, the first blue emission layer EML-B1, the electron transport region ETR, and the second electrode EL2, which are stacked in that order.

An optical auxiliary layer PL may be disposed on the display element layer DP-ED. The optical auxiliary layer PL may include a polarizing layer. The optical auxiliary layer PL may be disposed on the display panel DP and may control light that is reflected at the display panel DP from an external light. Although not shown in the drawings, in an embodiment, the optical auxiliary layer PL may be omitted from the display device DD-b.

At least one emission layer included in the display device DD-b shown in FIG. 9 may include the polycyclic compound according to an embodiment as described above. For example, in an embodiment, at least one of a first blue emission layer EML-B1 or a second blue emission layer EML-B2 may include the polycyclic compound according to an embodiment.

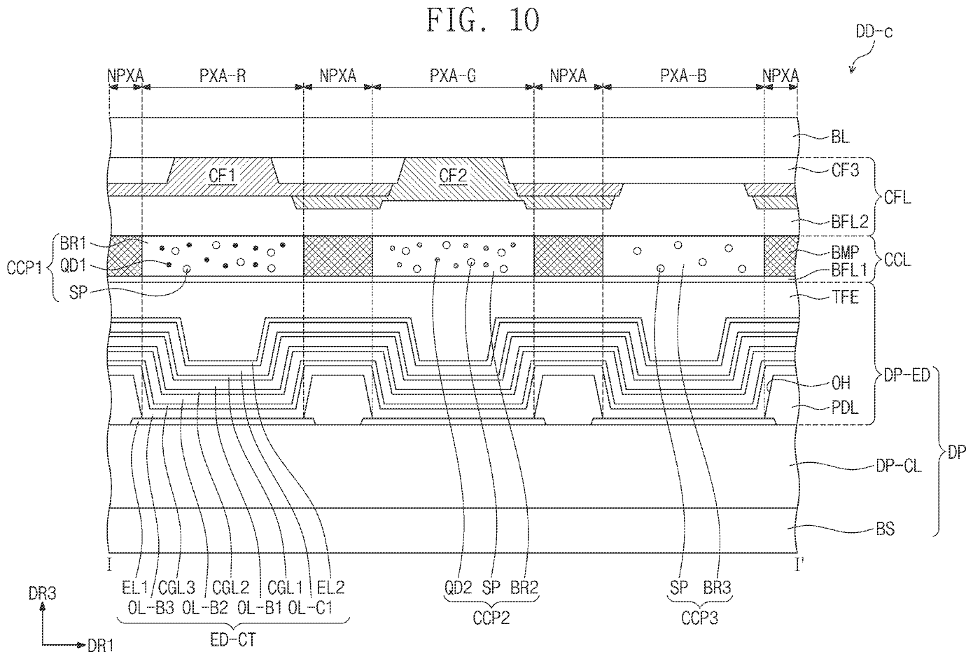

In contrast to FIGS. 8 and 9, the display device DD-c shown in FIG. 10 is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may be disposed between adjacent structures among the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may each emit light having wavelength ranges that are different from each other.

The charge generation layers CGL1, CGL2, and CGL3 which are disposed between neighboring light emitting structures OL-B1, OL-B2, OL-B3, and OL-C1 may each independently include a p-type charge generation layer and/or an n-type charge generation layer.

At least one of the light emitting structures OL-B1, OL-B2, OL-B3, and OL-C1 included in the display device DD-c according to an embodiment may include the polycyclic compound according to an embodiment as described above. For example, in an embodiment, at least one of the first to third light emitting structures OL-B1, OL-B2, and OL-B3 may include a polycyclic compound according to an embodiment as described above.

The light emitting element ED according to an embodiment may include the polycyclic compound according to an embodiment in at least one functional layer disposed between the first electrode EL1 and the second electrode EL2, and may thus exhibit excellent light emitting efficiency and improved lifespan characteristics. For example, an emission layer EML of the light emitting element ED may include the polycyclic compound, and the light emitting element ED may exhibit high efficiency and long lifespan characteristics.

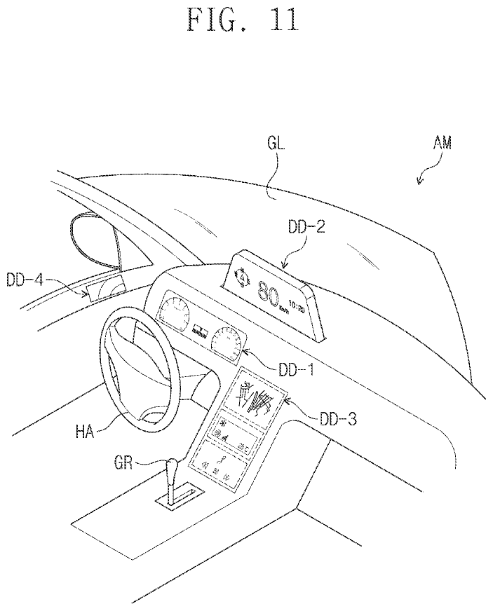

FIG. 11 is a schematic perspective view of an electronic device including a display device according to an embodiment. In FIG. 11, a portion of a vehicle AM is shown as an example of an electronic device. However, the vehicle AM is presented only an example, and the electronic device may be one of various means of transportation, such as bicycles, motorcycles, trains, ships, and airplanes.

Referring to FIG. 11, the vehicle AM may include first to fourth display devices DD-1, DD-2, DD-3, and DD-4. At least one of the first to fourth display devices DD-1, DD-2, DD-3, and DD-4 may have a structure according to one of the display devices DD, DD-a, DD-TD, DD-b, and DD-c as described in reference to FIGS. 1, 2, and 7 to 10.

In an embodiment, at least one of the first to fourth display devices DD-1, DD-2, DD-3, and DD-4 may include a light emitting element ED according to an embodiment as described in reference to one of FIGS. 3 to 6. The first to fourth display devices DD-1, DD-2, DD-3, and DD-4 may each independently include multiple light emitting elements ED (see FIGS. 3 to 6). Each of the light emitting elements ED may include a first electrode EL1, a hole transport region HTR, an emission layer EML, an electron transport region ETR, and a second electrode EL2 (see FIGS. 3 to 6). The emission layer EML may include the polycyclic compound according to an embodiment, as described above. Thus, the first to fourth vehicle display devices DD-1, DD-2, DD-3, and DD-4 may exhibit improved image quality.

Referring to FIG. 11, the vehicle AM may include a steering wheel HA and a gearshift GR for operating the vehicle AM. The vehicle AM may include a front window GL that is disposed so as to face a driver.

The first display device DD-1 may be disposed in a first region that overlaps the steering wheel HA. For example, the first display device DD-1 may be a digital cluster that displays first information of the vehicle AM. The first information may include a first scale that indicates a driving speed of the vehicle AM, a second scale that indicates a rate of engine rotation (for example, as revolutions per minute (RPM)), a fuel gauge, and the like. The first scale and the second scale may each be displayed as digital images.

The second display device DD-2 may be disposed in a second region facing a driver's seat and overlapping the front window GL. The driver's seat may be a seat where the steering wheel HA is disposed. For example, the second display device DD-2 may be a head up display HUD that displays second information of the vehicle AM. The second display device DD-2 may be optically transparent. The second information may include digital numbers that indicate a driving speed of the vehicle AM and may further include information such as the current time.

The third display device DD-3 may be disposed in a third region adjacent to the gearshift GR. For example, the third display device DD-3 may be a center information display (CID) for a vehicle, which is disposed between a driver's seat and a passenger seat, and displays third information. The passenger seat may be a seat that is spaced apart from the driver's seat with the gearshift GR disposed therebetween. The third information may include information about road conditions (e.g., navigation information), music or radio play, video play, temperature inside the vehicle AM, and the like.

The fourth display device DD-4 may be disposed in a fourth region spaced apart from the steering wheel HA and the gearshift GR and adjacent to a side of the vehicle AM. For example, the fourth display device DD-4 may be a digital side mirror that displays fourth information. The fourth information may include images of conditions outside the vehicle AM, which may be taken by a camera module disposed outside the vehicle AM.

The first to fourth information as described above are only presented as examples, and the first to fourth display devices DD-1, DD-2, DD-3, and DD-4 may further display information about interior or exterior of a vehicle. The first to fourth information may include information that is different from each other. However, embodiments are not limited thereto, and some of the first to fourth information may include the same information.

Hereinafter, a polycyclic compound according to an embodiment and a light emitting element according to an embodiment will be described in detail with reference to the Examples and the Comparative Examples. The Examples described below are only provided as illustrations to assist in understanding the disclosure, and the scope thereof is not limited thereto.

### EXAMPLES

### 1. Synthesis of Polycyclic Compounds

A method of synthesizing polycyclic compounds will be described in detail by providing a method of synthesizing Compounds 13, 21, 53, 69, and 79 as examples. A process of synthesizing polycyclic compounds, which will be described hereinafter, is provided only as an example, and thus a process of synthesizing polycyclic compounds according to embodiments is not limited to the Examples below.

### (1) Synthesis of Compound 13

Compound 13 according to an embodiment may be synthesized by, for example, Reaction Formula 1 below.

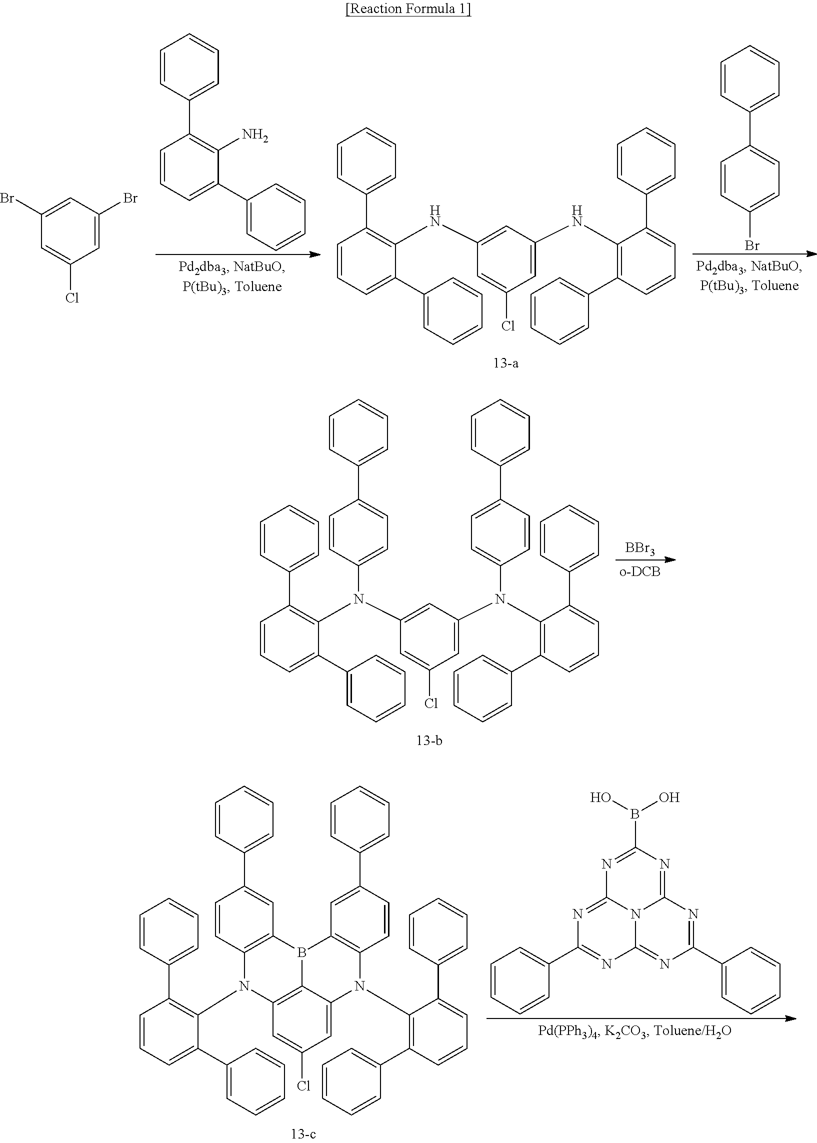

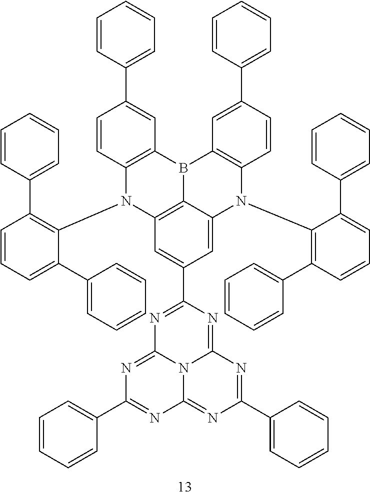 [SMILES: c1ccc(C2=NC3=NC(c4ccccc4)=NC4=NC(c5cc6c7c(c5)N(c5c(-c8ccccc8)cccc5-c5ccccc5)c5ccc(-c8ccccc8)cc5B7c5cc(-c7ccccc7)ccc5N6c5c(-c6ccccc6)cccc5-c5ccccc5)=NC(=N2)N34)cc1]

### 1) Synthesis of Intermediate Compound 13-a

In an argon atmosphere, in a 2 L flask, 1,3-dibromo-5-chlorobenzene (10 g, 37 mmol), [1,1′:3′,1″-terphenyl]-2′-amine (18 g, 74 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 400 mL of toluene, and the reaction solution was stirred at 110° C. for 2 hours. After cooling the resultant product, water (1 L) and ethyl acetate (300 mL) were added thereto for extraction, and an organic layer was collected, dried over MgSO₄, and filtered. The filtered solution was subjected to reduced pressure to remove a solvent, and CH₂Cl₂ and hexane were used as developing solvents to purify and separate the obtained solid through column chromatography using silica gel to obtain Intermediate compound 13-a (colorless liquid, 17 g, yield: 78%) (ESI-LCMS: [M]⁺: C₄₂H₃₁ClN₂. 598.1117)

### 2) Synthesis of Intermediate Compound 13-b

In an argon atmosphere, in a 2 L flask, Intermediate compound 13-a (15 g, 25 mmol), 4-bromo-1,1′-biphenyl (11.6 g, 50 mmol), Pd₂dba₃ (1.1 g, 1.3 mmol), tris-tert-butyl phosphine (1.1 mL, 2.6 mmol), and sodium tert-butoxide (7.2 g, 75 mmol) were added and dissolved in 400 mL of toluene, and the reaction solution was stirred at 100° C. for 12 hours. After cooling the resultant product, water (1 L) and ethyl acetate (300 mL) were added thereto for extraction, and an organic layer was collected, dried over MgSO₄, and filtered. The filtered solution was subjected to reduced pressure to remove a solvent, and CH₂Cl₂ and hexane were used as developing solvents to purify and separate the obtained solid through column chromatography using silica gel to obtain Intermediate compound 13-b (white solid, 11.7 g, yield: 56%) (ESI-LCMS: [M]⁺: C₆₆H₄₇ClN₂. 902.3152)

### 3) Synthesis of Intermediate Compound 13-c

In an argon atmosphere, in a 1 L flask, Intermediate compound 13-b (10 g, 11 mmol) was added and dissolved in 100 mL of o-dichlorobenzene, and BBr3 (1.5 equiv.) was added thereto. The reaction solution was stirred at 140° C. for 12 hours. After cooling the resulting product, triethylamine was added to terminate the reaction and a solvent was removed at reduced pressure, and CH₂Cl₂ and hexane were used as developing solvents to purify and separate the obtained solid through column chromatography using silica gel to obtain Intermediate compound 13-c (yellow solid, 1.2 g, yield: 12%) (ESI-LCMS: [M]⁺: C₆₆H₄₄BClN₂. 910.0886)

### 4) Synthesis of Compound 13

In an argon atmosphere, in a 1 L flask, Intermediate compound 13-c (1 g, 1 mmol), (5,8-diphenyl-1,3,3a1,4,6,7,9-heptaazaphenalen-2-yl)boronic acid (0.73 g, 2 mmol), pd(PPh3)4 (0.06 g, 0.5 mmol), and potassium carbonate (0.4 g, 3 mmol) were added and dissolved in 30 mL of toluene, and the reaction solution was stirred at 100° C. for 12 hours. After cooling the resultant product, water (1 L) and ethyl acetate (300 mL) were added thereto for extraction, and an organic layer was collected, dried over MgSO₄, and filtered. The filtered solution was subjected to reduced pressure to remove a solvent, and CH₂Cl₂ and hexane were used as developing solvents to purify and separate the obtained solid through column chromatography using silica gel to obtain Compound 13-b (yellow solid, 0.86 g, yield: 72%) (ESI-LCMS: [M]⁺: C₈₄H₅₄BN₉. 1199.3516, ¹H-NMR (CDCl₃): d=8.83 (d, 2H), 8.36 (d, 4H), 7.73 (s, 4H), 7.65 (d, 4H), 7.10 (d, 30H), 7.03 (d, 8H), 6.91 (s, 2H))

### (2) Synthesis of Compound 21

Compound 21 according to an embodiment may be synthesized by, for example, Reaction Formula 2 below.

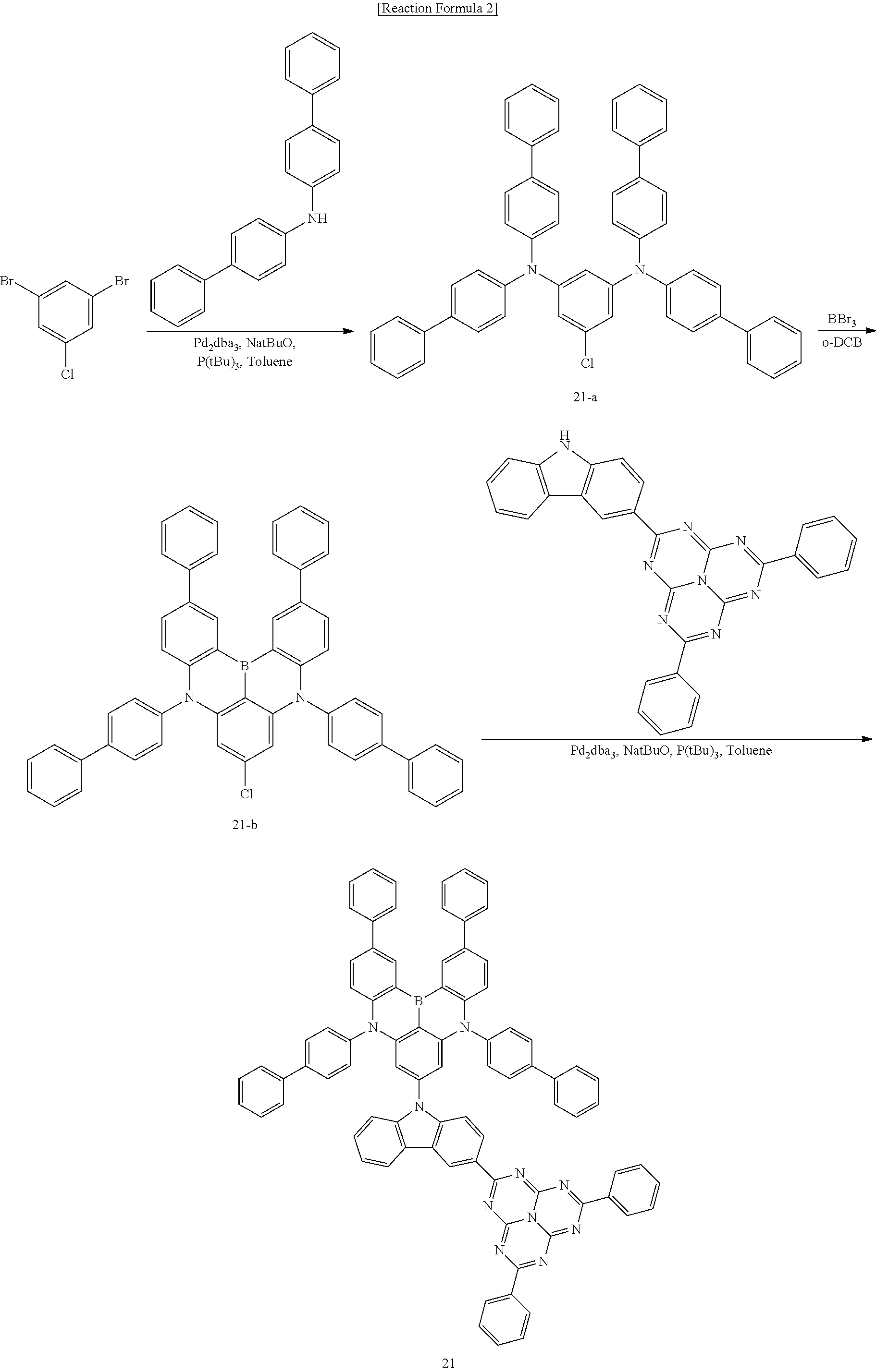

### 1) Synthesis of Intermediate Compound 21-a

In an argon atmosphere, in a 2 L flask, 1,3-dibromo-5-chlorobenzene (10 g, 37 mmol), di([1,1′-biphenyl]-4-yl)amine (24 g, 74 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 400 mL of toluene, and the reaction solution was stirred at 110° C. for 2 hours.

After cooling the resultant product, water (1 L) and ethyl acetate (300 mL) were added thereto for extraction, and an organic layer was collected, dried over MgSO₄, and filtered. The filtered solution was subjected to reduced pressure to remove a solvent, and CH₂Cl₂ and hexane were used as developing solvents to purify and separate the obtained solid through column chromatography using silica gel to obtain Intermediate compound 21-a (white solid, 21 g, yield: 77%) (ESI-LCMS: [M]⁺: C₅₄H₃₉ClN₂. 750.2127)

### 2) Synthesis of Intermediate Compound 21-b

In an argon atmosphere, in a 1 L flask, Intermediate compound 21-a (20 g, 26 mmol) was added and dissolved in 200 mL of o-dichlorobenzene, and BBr₃ (1.5 equiv.) was added thereto. The reaction solution was stirred at 140° C. for 12 hours. After cooling the resulting product, triethylamine was added to terminate the reaction, and a solvent was removed at reduced pressure. CH₂Cl₂ and hexane were used as developing solvents to purify and separate the obtained solid through column chromatography using silica gel to obtain Intermediate compound 21-b (yellow solid, 3.23 g, yield: 23%) (ESI-LCMS: [M]⁺: C₅₄H₃₆BClN₂. 758.2712)

### 3) Synthesis of Compound 21

In an argon atmosphere, in a 1 L flask, Intermediate compound 21-b (3 g, 4 mmol), 2-(9H-carbazol-3-yl)-5,8-diphenyl-1,3,3a1,4,6,7,9-heptaazaphenalene (2 g, 4 mmol), pd₂(dba)₃ (0.2 g, 0.2 mmol), tris-tert-butyl phosphine (0.2 mL, 0.4 mmol), and sodium tert-butoxide (1.1 g, 12 mmol) were added and dissolved in 30 mL of toluene, and the reaction solution was stirred at 100° C. for 12 hours. After cooling the resultant product, water (1 L) and ethyl acetate (300 mL) were added thereto for extraction, and an organic layer was collected, dried over MgSO₄, and filtered. The filtered solution was subjected to reduced pressure to remove a solvent, and CH₂Cl₂ and hexane were used as developing solvents to purify and separate the obtained solid through column chromatography using silica gel to obtain Compound 21 (yellow solid, 3.6 g, yield: 76%) (ESI-LCMS: [M]⁺: C₈₄H₅₃BN₁₀. 1213.2233, ¹H-NMR (CDCl₃): d=8.76 (s, 2H), 8.44 (d, 2H), 8.36 (d, 4H), 8.20 (m, 3H), 7.75 (d, 10H), 7.53 (m, 18H), 7.43 (m, 12H), 7.10 (d, 2H), 6.89 (s, 2H))

### (3) Synthesis of Compound 53

Compound 53 according to an embodiment may be synthesized by, for example, Reaction Formula 3 below.

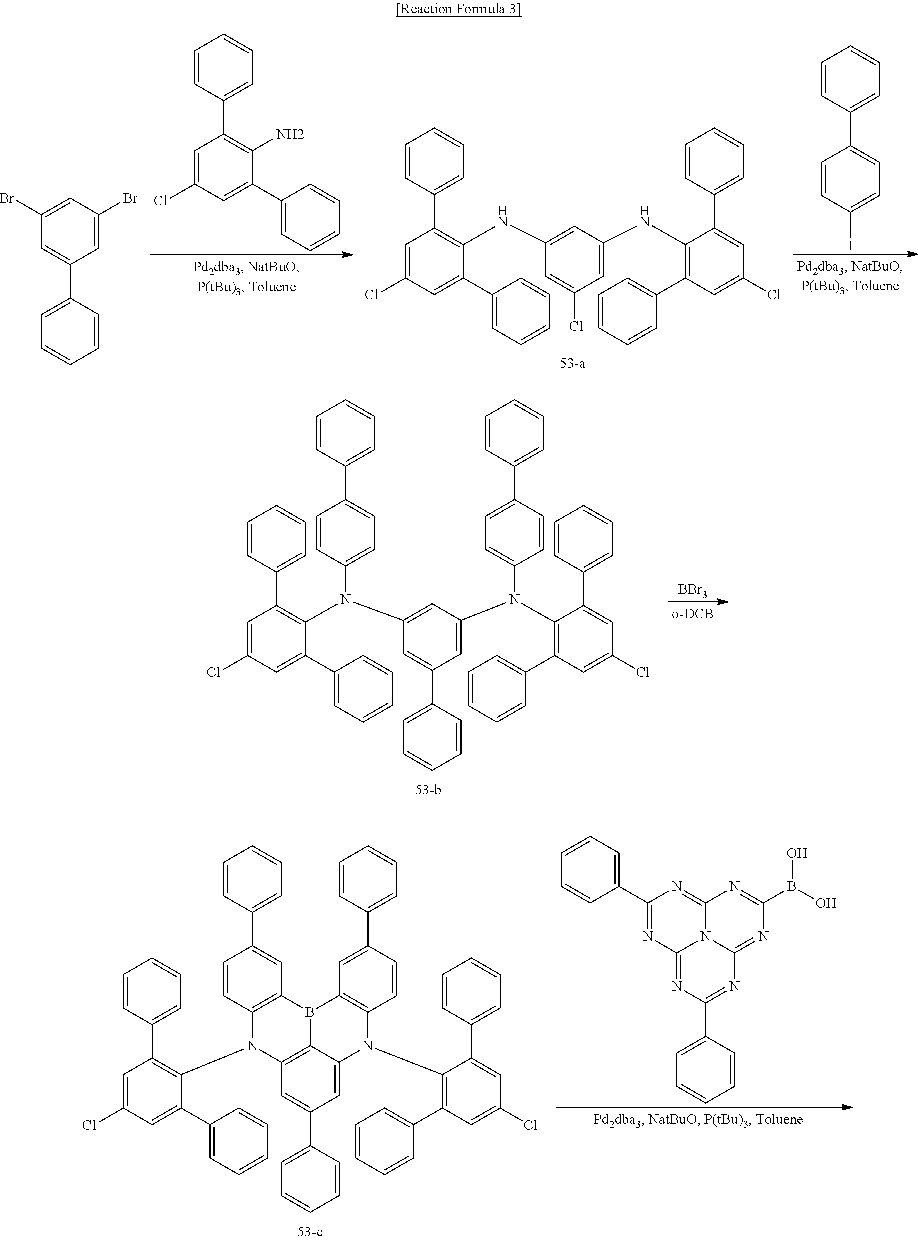

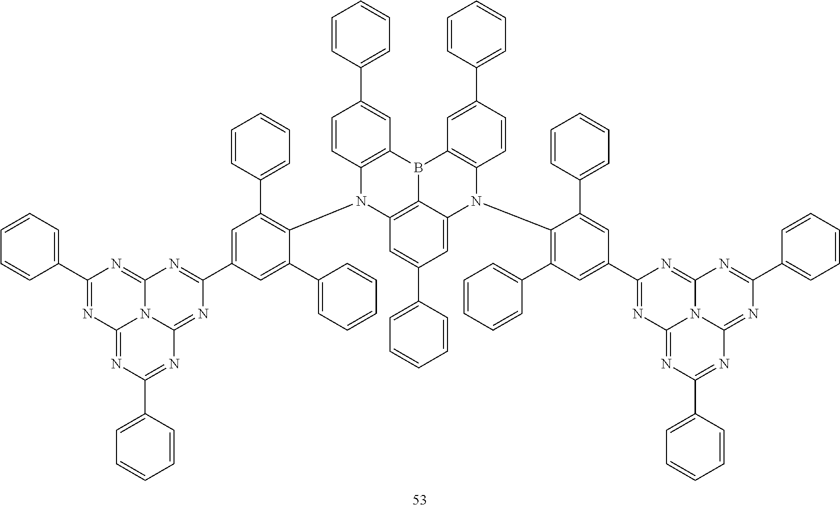 [SMILES: c1ccc(C2=NC3=NC(c4ccccc4)=NC4=NC(c5cc(-c6ccccc6)c(N6c7ccc(-c8ccccc8)cc7B7c8cc(-c9ccccc9)ccc8N(c8c(-c9ccccc9)cc(C9=NC%10=NC(c%11ccccc%11)=NC%11=NC(c%12ccccc%12)=NC(=N9)N%11%10)cc8-c8ccccc8)c8cc(-c9ccccc9)cc6c87)c(-c6ccccc6)c5)=NC(=N2)N34)cc1]

### 1) Synthesis of Intermediate Compound 53-a

In an argon atmosphere, in a 2 L flask, 3,5-dibromo-1,1′-biphenyl (10 g, 32 mmol), 5′-chloro-[1,1′:3′,1″-terphenyl]-2′-amine (18 g, 64 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 400 mL of toluene, and the reaction solution was stirred at 110° C. for 2 hours. After cooling the resultant product, water (1 L) and ethyl acetate (300 mL) were added thereto for extraction, and an organic layer was collected, dried over MgSO₄, and filtered. The filtered solution was subjected to reduced pressure to remove a solvent, and CH₂Cl₂ and hexane were used as developing solvents to purify and separate the obtained solid through column chromatography using silica gel to obtain Intermediate compound 53-a (white solid, 16 g, yield: 71%) (ESI-LCMS: [M]⁺: C₄₈H₃₄Cl₂N₂. 708.7100)

### 2) Synthesis of Intermediate Compound 53-b

In an argon atmosphere, in a 2 L flask, Intermediate compound 53-a (16 g, 23 mmol), 4-iodo-1,1′-biphenyl (13 g, 46 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 400 mL of toluene, and the reaction solution was stirred at 110° C. for 2 hours. After cooling the resultant product, water (1 L) and ethyl acetate (300 mL) were added thereto for extraction, and an organic layer was collected, dried over MgSO₄, and filtered. The filtered solution was subjected to reduced pressure to remove a solvent, and CH₂Cl₂ and hexane were used as developing solvents to purify and separate the obtained solid through column chromatography using silica gel to obtain Intermediate compound 53-b (white solid, 12.5 g, yield: 54%) (ESI-LCMS: [M]⁺: C₇₂H₅₀Cl₂N₂. 1013.0963)

### 3) Synthesis of Intermediate Compound 53-c

In an argon atmosphere, in a 1 L flask, Intermediate compound 53-b (12 g, 12 mmol) was added and dissolved in 200 mL of o-dichlorobenzene, and BBr3 (1.5 equiv.) was added thereto. The reaction solution was stirred at 140° C. for 12 hours. After cooling the resulting product, triethylamine was added to terminate the reaction and a solvent was removed at reduced pressure, and CH₂Cl₂ and hexane were used as developing solvents to purify and separate the obtained solid through column chromatography using silica gel to obtain Intermediate compound 53-c (yellow solid, 2.5 g, yield: 21%) (ESI-LCMS: [M]⁺: C₇₂H₄₇BCl₂N₂. 1020.3217)

### (4) Synthesis of Compound 53

In an argon atmosphere, in a 1 L flask, Intermediate compound 53-c (2.5 g, 2.4 mmol), 2-boronic acid-5,8-diphenyl-1,3,3a1,4,6,7,9-heptaazaphenalene (1.66 g, 5 mmol), pd(PPh3)4 (0.16 g, 0.14 mmol), and potassium carbonate (1.1 g, 12 mmol) were added and dissolved in 50 mL of toluene, and the reaction solution was stirred at 100° C. for 12 hours. After cooling the resultant product, water (1 L) and ethyl acetate (300 mL) were added thereto for extraction, and an organic layer was collected, dried over MgSO₄, and filtered. The filtered solution was subjected to reduced pressure to remove a solvent, and CH₂Cl₂ and hexane were used as developing solvents to purify and separate the obtained solid through column chromatography using silica gel to obtain Compound 53 (yellow solid, 3 g, yield: 77%) (ESI-LCMS: [M]⁺: C₁₀₈H₆₇BN₁₆. 1598.5021, ¹H-NMR (CDCl₃): d=8.96 (s, 2H), 8.36 (d, 8H), 8.00 (s, 4H), 7.75 (d, 6H), 7.50 (m, 12H), 7.43 (m, 12H), 7.36 (m, 9H), 7.08 (d, 8H), 7.00 (s, 2H))

### (4) Synthesis of Compound 69

Compound 69 according to an embodiment may be synthesized by, for example, Reaction Formula 4 below.

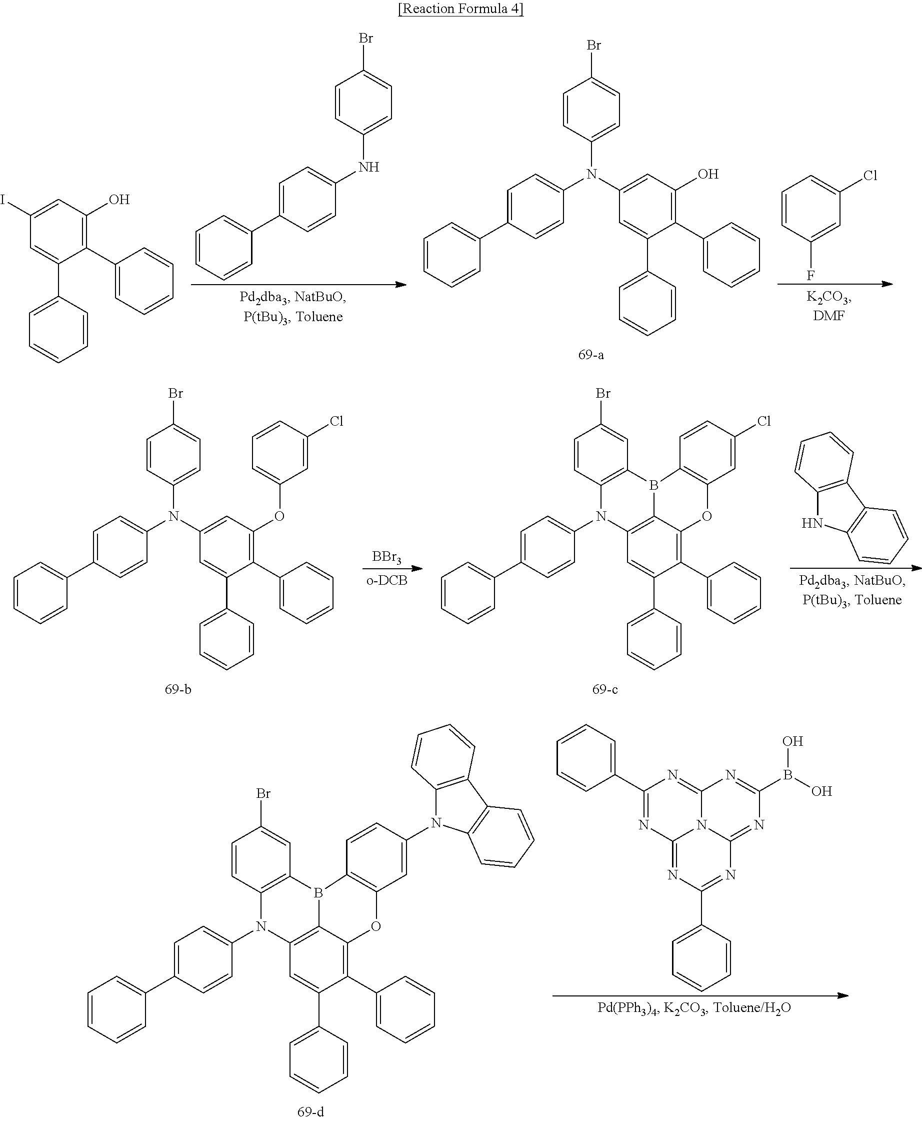

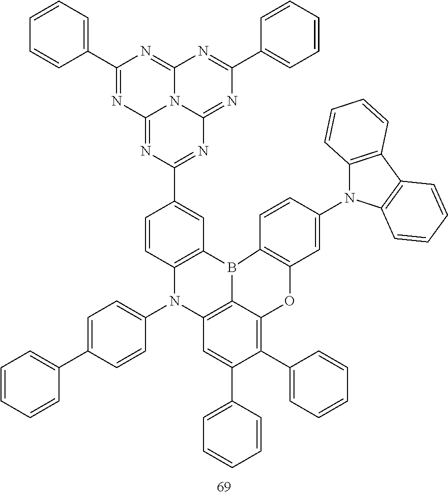 [SMILES: c1ccc(C2=NC3=NC(c4ccccc4)=NC4=NC(c5ccc6c(c5)B5c7ccc(-n8c9ccccc9c9ccccc98)cc7Oc7c5c(cc(-c5ccccc5)c7-c5ccccc5)N6c5ccc(-c6ccccc6)cc5)=NC(=N2)N34)cc1]

### 1) Synthesis of Intermediate Compound 69-a

In an argon atmosphere, in a 2 L flask, 5′-iodo-[1,1′:2′,1″-terphenyl]-3′-ol (10 g, 26 mmol), N-(4-bromophenyl)-[1,1′-biphenyl]-4-amine (8.7 g, 26 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 400 mL of toluene, and the reaction solution was stirred at 110° C. for 2 hours. After cooling the resultant product, water (1 L) and ethyl acetate (300 mL) were added thereto for extraction, and an organic layer was collected, dried over MgSO₄, and filtered. The filtered solution was subjected to reduced pressure to remove a solvent, and CH₂Cl₂ and hexane were used as developing solvents to purify and separate the obtained solid through column chromatography using silica gel to obtain Intermediate compound 69-a (white solid, 9.7 g, yield: 66%) (ESI-LCMS: [M]⁺: C₃₆H₂₆BrNO. 567.1213)

### 2) Synthesis of Intermediate Compound 69-b

In an argon atmosphere, in a 2 L flask, Intermediate compound 69-a (10 g, 17 mmol), 1-chloro-3-fluorobenzene (2.3 g, 17 mmol), and potassium carbonate (4.6 g, 34 mmol) were added and dissolved in 200 mL of DMF, and the reaction solution was stirred at 140° C. for 8 hours. After cooling the resultant product, water (1 L) and ethyl acetate (300 mL) were added thereto for extraction, and an organic layer was collected, dried over MgSO₄, and filtered. The filtered solution was subjected to reduced pressure to remove a solvent, and CH₂Cl₂ and hexane were used as developing solvents to purify and separate the obtained solid through column chromatography using silica gel to obtain Intermediate compound 69-b (white solid, 8.6 g, yield: 75%) (ESI-LCMS: [M]⁺: C₄₂H₂₉BrClNO. 679.0422)

### 3) Synthesis of Intermediate Compound 69-c

In an argon atmosphere, in a 1 L flask, Intermediate compound 69-b (8, 12 mol) was added and dissolved in 200 mL of o-dichlorobenzene, and BBr₃ (1.5 equiv.) was added thereto. The reaction solution was stirred at 140° C. for 12 hours. After cooling the resulting product, triethylamine was added to terminate the reaction and a solvent was removed at reduced pressure, and CH₂Cl₂ and hexane were used as developing solvents to purify and separate the obtained solid through column chromatography using silica gel to obtain Intermediate compound 69-c (yellow solid, 2.5 g, yield: 31%) (ESI-LCMS: [M]⁺: C₄₂H₂₆BBrClNO. 686.8383)

### 4) Synthesis of Compound 69-d

In an argon atmosphere, in a 2 L flask, Intermediate compound 69-c (2.5 g, 3.6 mmol), carbazole (0.58 g, 3.6 mmol), pd₂(dba)₃ (0.2 g, 0.2 mmol), tris-tert-butyl phosphine (0.2 mL, 0.4 mmol), and sodium tert-butoxide (1.1 g, 12 mmol) were added and dissolved in 30 mL of toluene, and the reaction solution was stirred at 100° C. for 12 hours. After cooling the resultant product, water (1 L) and ethyl acetate (300 mL) were added thereto for extraction, and an organic layer was collected, dried over MgSO₄, and filtered. The filtered solution was subjected to reduced pressure to remove a solvent, and CH₂Cl₂ and hexane were used as developing solvents to purify and separate the obtained solid through column chromatography using silica gel to obtain Intermediate compound 69-d (yellow liquid, 2.3 g, yield: 78%) (ESI-LCMS: [M]⁺: C₅₄H₃₄BBrN₂0. 817.5951).

### 5) Synthesis of Compound 69

In an argon atmosphere, in a 1 L flask, Intermediate compound 69-d (2.3 g, 2.8 mmol), (5,8-diphenyl-1,3,3a1,4,6,7,9-heptaazaphenalen-2-yl)boronic acid (1 g, 2.8 mmol), pd(PPh₃)₄ (0.16 g, 0.14 mmol), and potassium carbonate (1.1 g, 12 mmol) were added and dissolved in 50 mL of toluene, and the reaction solution was stirred at 100° C. for 12 hours. After cooling the resultant product, water (1 L) and ethyl acetate (300 mL) were added thereto for extraction, and an organic layer was collected, dried over MgSO₄, and filtered. The filtered solution was subjected to reduced pressure to remove a solvent, and CH₂Cl₂ and hexane were used as developing solvents to purify and separate the obtained solid through column chromatography using silica gel to obtain Intermediate compound 69-d (yellow liquid, 2.3 g, yield: 78%) (ESI-LCMS: [M]⁺: C₇₂H₄₄BN₉O. 1061.3818, ¹H-NMR (CDCl₃): d=8.78 (s, 2H), 8.55 (d, 2H), 8.36 (d, 4H), 8.01 (d, 1H), 7.97 (d, 2H), 7.75 (m, 5H), 7.50 (m, 9H), 7.43 (m, 6H), 7.24 (m, 7H), 7.22 (m, 4H), 7.00 (s, 1H))

### (5) Synthesis of Compound 79

Compound 79 according to an embodiment may be synthesized by, for example, Reaction Formula 5 below.

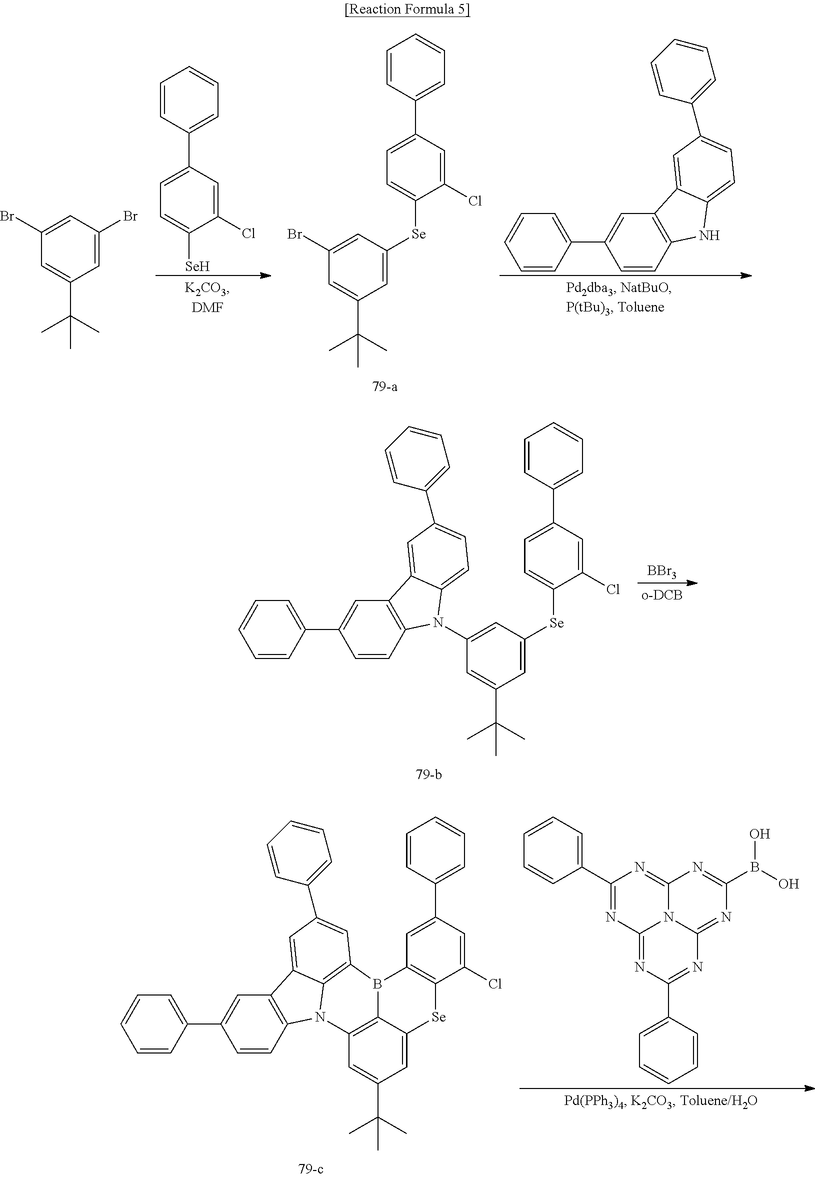

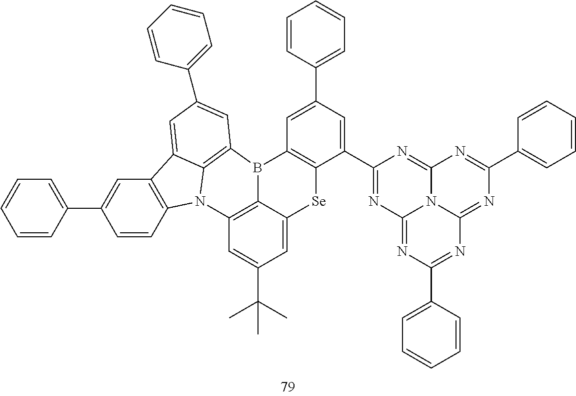 [SMILES: CC(C)(C)c1cc2c3c(c1)-n1c4ccc(-c5ccccc5)cc4c4cc(-c5ccccc5)cc(c41)B3c1cc(-c3ccccc3)cc(C3=NC4=NC(c5ccccc5)=NC5=NC(c6ccccc6)=NC(=N3)N54)c1[Se]2]

### 1) Synthesis of Intermediate Compound 79-a

In an argon atmosphere, in a 2 L flask, 1,3-dibromo-5-(tert-butyl)benzene (10 g, 34 mmol), 3-chloro-[1,1′-biphenyl]-4-selenol (9.1 g, 34 mmol), and potassium carbonate (14.68 g, 106 mmol) were added and dissolved in 400 mL of DMF, and the reaction solution was stirred at 140° C. for 8 hours. After cooling the resultant product, water (1 L) and ethyl acetate (300 mL) were added thereto for extraction, and an organic layer was collected, dried over MgSO₄, and filtered. The filtered solution was subjected to reduced pressure to remove a solvent, and CH₂Cl₂ and hexane were used as developing solvents to purify and separate the obtained solid through column chromatography using silica gel to obtain Intermediate compound 79-a (white solid, 8 g, yield: 49%) (ESI-LCMS: [M]⁺: C₂₂H₂₀BrClSe. 478.7371)

### 2) Synthesis of Intermediate Compound 79-b

In an argon atmosphere, in a 2 L flask, Intermediate compound 79-a (8 g, 16.7 mmol), 3,6-diphenyl-9H-carbazole (10.6 g, 33.2 mmol), pd₂(dba)₃ (0.2 g, 0.2 mmol), tris-tert-butyl phosphine (0.2 mL, 0.4 mmol), and sodium tert-butoxide (5 g, 50 mmol) were added and dissolved in 200 mL of toluene, and the reaction solution was stirred at 100° C. for 12 hours. After cooling the resultant product, water (1 L) and ethyl acetate (300 mL) were added thereto for extraction, and an organic layer was collected, dried over MgSO₄, and filtered. The filtered solution was subjected to reduced pressure to remove a solvent, and CH₂Cl₂ and hexane were used as developing solvents to purify and separate the obtained solid through column chromatography using silica gel to obtain Intermediate compound 79-b (white solid, 9.8 g, yield: 82%) (ESI-LCMS: [M]⁺: C₄₆H₃₆ClNSe. 717.1224)

### 3) Synthesis of Intermediate Compound 79-c

In an argon atmosphere, in a 1 L flask, Intermediate compound 79-b (10 g, 14 mmol) was added and dissolved in 200 mL of o-dichlorobenzene, and BBr₃ (1.5 equiv.) was added thereto. The reaction solution was stirred at 140° C. for 12 hours. After cooling the resulting product, triethylamine was added to terminate the reaction and a solvent was removed at reduced pressure, and CH₂Cl₂ and hexane were used as developing solvents to purify and separate the obtained solid through column chromatography using silica gel to obtain Intermediate compound 79-d (yellow solid, 1.2 g, yield: 12%) (ESI-LCMS: [M]⁺: C₄₆H₃₃BClNSe. 725.1256)

### 3) Synthesis of Compound 79

In an argon atmosphere, in a 1 L flask, Intermediate compound 79-c (1.2 g, 1.6 mmol), (5,8-diphenyl-1,3,3a1,4,6,7,9-heptaazaphenalen-2-yl)boronic acid (0.6 g, 1.6 mmol), pd(PPh3)4 (0.16 g, 0.14 mmol), and potassium carbonate (1.1 g, 12 mmol) were added and dissolved in 50 mL of toluene and 20 mL of H₂O, and the reaction solution was stirred at 100° C. for 12 hours. After cooling the resultant product, water (1 L) and ethyl acetate (300 mL) were added thereto for extraction, and an organic layer was collected, dried over MgSO₄, and filtered. The filtered solution was subjected to reduced pressure to remove a solvent, and CH₂Cl₂ and hexane were used as developing solvents to purify and separate the obtained solid through column chromatography using silica gel to obtain Compound 79 (yellow solid, 0.9 g, yield: 78%) (ESI-LCMS: [M]⁺: C₆₄H₄₃BN₈Se. 1014.2019, ¹H-NMR (CDCl₃): d=8.82 (s, 2H), 8.36 (m, 5H), 8.01 (m, 2H), 7.93 (m, 2H), 7.80 (m, 7H), 7.55 (m, 6H), 7.44 (m, 9H), 7.32 (s, 1H), 7.01 (s, 1H), 1.32 (s, 9H))

### 2. Evaluation of Material Properties of Polycyclic Compounds

In Table 1, material properties of Example Compounds and Comparative Example Compounds were evaluated. Example Compounds and Comparative Example Compounds which were used for the evaluation are as follows.

TABLE 1

| | HOMO | LUMO | S1 | T1 | | | | | | |
|---|---|---|---|---|---|---|---|---|---|---|
| | (eV) | (eV) | (eV) | (eV) | ΔE_{ST} (eV) | PLQY (%) | μ_{Abs} (nm) | μₑₘᵢ (nm) | Stokes-shift | FWHM (sol.) |
| Compound 13 | −5.48 | −2.42 | 2.68 | 2.54 | 0.14 | 96.8 | 450 | 460 | 10 | 31 |
| Compound 21 | −5.45 | −2.38 | 2.71 | 2.56 | 0.15 | 98.8 | 447 | 457 | 10 | 28 |
| Compound 53 | −5.55 | −2.36 | 2.67 | 2.55 | 0.12 | 95.3 | 453 | 465 | 12 | 33 |
| Compound 69 | −5.42 | −2.39 | 2.74 | 2.60 | 0.14 | 97.9 | 445 | 455 | 10 | 34 |
| Compound 79 | −5.44 | −2.41 | 2.65 | 2.55 | 0.10 | 85.9 | 455 | 466 | 11 | 33 |
| Compound C1 | −5.12 | −2.33 | 2.72 | 2.51 | 0.21 | 84.3 | 451 | 463 | 12 | 40 |
| Compound C2 | −5.37 | −2.37 | 2.62 | 2.37 | 0.25 | 83.3 | 454 | 468 | 14 | 37 |
| Compound C3 | −5.25 | −2.35 | 2.78 | 2.60 | 0.18 | 79.6 | 428 | 445 | 17 | 42 |
| Compound C4 | −5.75 | −1.99 | 2.43 | — | 0.0 | 3.0 | 320 | 520 | 200 | 122 |
| Compound C5 | −5.66 | −2.04 | 2.44 | — | −0.4 | 22.0 | 370 | 522 | 152 | 150 |

[Example Compounds] 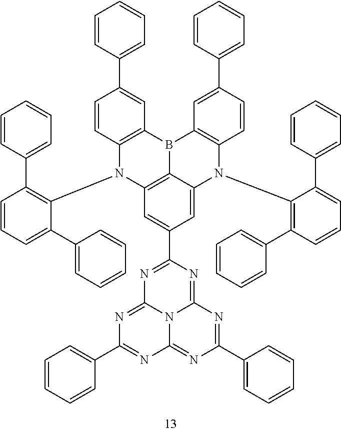 [SMILES: c1ccc(C2=NC3=NC(c4ccccc4)=NC4=NC(c5cc6c7c(c5)N(c5c(-c8ccccc8)cccc5-c5ccccc5)c5ccc(-c8ccccc8)cc5B7c5cc(-c7ccccc7)ccc5N6c5c(-c6ccccc6)cccc5-c5ccccc5)=NC(=N2)N34)cc1] 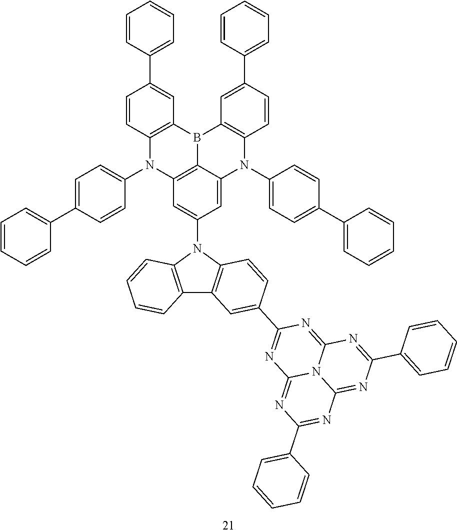 [SMILES: c1ccc(C2=NC3=NC(c4ccccc4)=NC4=NC(c5ccc6c(c5)c5ccccc5n6-c5cc6c7c(c5)N(c5ccc(-c8ccccc8)cc5)c5ccc(-c8ccccc8)cc5B7c5cc(-c7ccccc7)ccc5N6c5ccc(-c6ccccc6)cc5)=NC(=N2)N34)cc1 ; "21"] 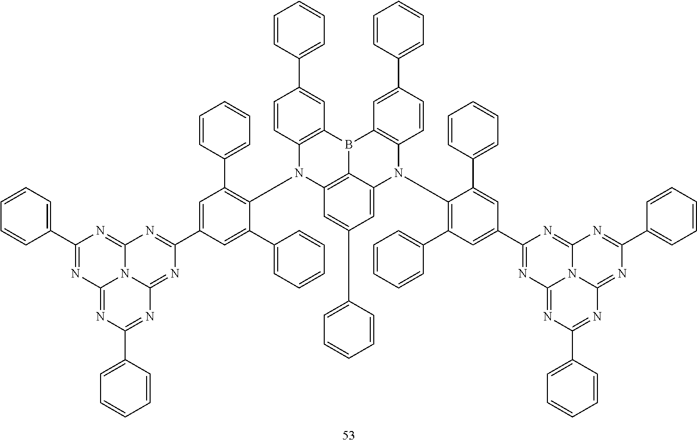 [SMILES: c1ccc(C2=NC3=NC(c4ccccc4)=NC4=NC(c5cc(-c6ccccc6)c(N6c7ccc(-c8ccccc8)cc7B7c8cc(-c9ccccc9)ccc8N(c8c(-c9ccccc9)cc(C9=NC%10=NC(c%11ccccc%11)=NC%11=NC(c%12ccccc%12)=NC(=N9)N%11%10)cc8-c8ccccc8)c8cc(-c9ccccc9)cc6c87)c(-c6ccccc6)c5)=NC(=N2)N34)cc1 ; "53"] 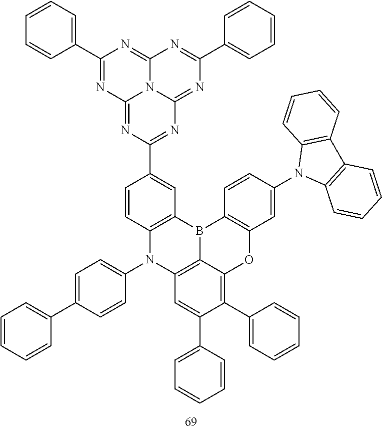 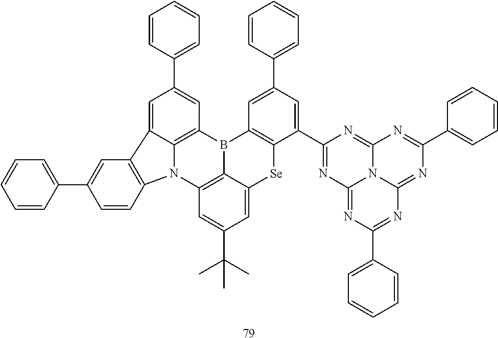 [SMILES: CC(C)(C)c1cc2c3c(c1)-n1c4ccc(-c5ccccc5)cc4c4cc(-c5ccccc5)cc(c41)B3c1cc(-c3ccccc3)cc(C3=NC4=NC(c5ccccc5)=NC5=NC(c6ccccc6)=NC(=N3)N54)c1[Se]2 ; "79"]
[Comparative Example Compounds]

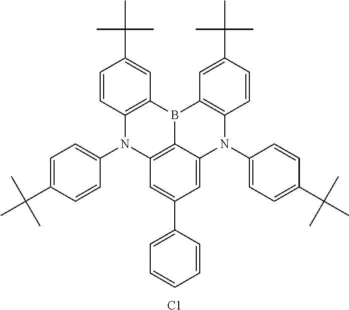

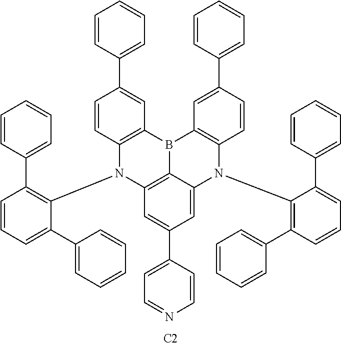

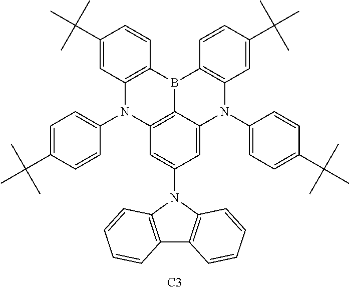

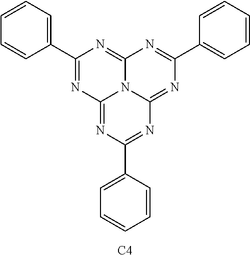

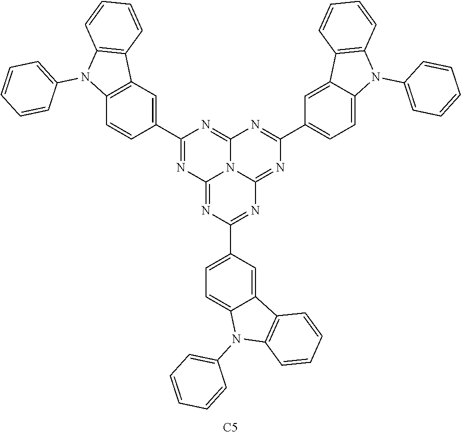

Referring to Table 1, Compounds 13, 21, 53, 69, and 79 were found to have a lower HOMO energy level, a smaller ΔE_{ST} value, higher light emitting efficiency, a smaller Stokes shift, and a higher full width at half maximum (FWHM) than Comparative Example Compounds C1 to C3. In Comparative Example Compounds C4 and C5, it was found that the Stokes-shift was too large and the full width at half maximum (FWHM) characteristics were very poor. The relationship between the material properties of Table 1 and the characteristics of a light emitting element will be described later along with Table 2 below.

### 3. Preparation and Evaluation of Light Emitting Elements Including Polycyclic Compounds

### (1) Preparation of Light Emitting Elements

Light emitting elements that include a polycyclic compound according to an embodiment in an emission layer were prepared using the method below. A light emitting element of Example 1 was prepared using Compound 13, which is an Example Compound described above, as a dopant material of an emission layer. Examples 2 to 5 are light emitting elements prepared using the above-described Compounds 21, 53, 69, and 79 as a dopant material of an emission layer, respectively. Light emitting elements of Comparative Examples 1 to 3 are light emitting elements prepared using the above-described Comparative Example Compounds C1 to C3 as a dopant material of an emission layer, respectively. The above-described Comparative Example Compounds C4 and C5 emitted green light and had an excessively large Stokes-shift to fail to have energy overlap with PS1, which will be described later, and thus preparation of an element was not available.

As a first electrode, a glass substrate having an ITO electrode (15 Ω/cm², 1200 Å) formed thereon was cut to a size of about 50 mm×50 mm×0.7 mm, and subjected to ultrasonic cleaning using isopropyl alcohol and pure water each for 5 minutes. The glass substrate was subjected to ultraviolet irradiation for 30 minutes, and exposed to ozone for cleaning to be mounted on a vacuum deposition apparatus.

A hole injection layer having a thickness of 300 Å was formed through deposition of NPD. A hole transport layer having a thickness of 200 Å was formed through deposition of H-1-19 on an upper portion of the hole injection layer. An auxiliary emission layer having a thickness of 100 Å was formed through deposition of CzSi on an upper portion of the hole transport layer.

An emission layer having a thickness of 200 Å was formed through co-deposition of a host material in which HT33 and ETH82 were mixed at a weight ratio of 1:1, AD-39, and Example compounds or Comparative Example Compounds in a weight ratio of 85:14:1.

A hole blocking layer having a thickness of 200 Å was formed through deposition of TSPO1 on an upper portion of the emission layer. An electron transport layer having a thickness of 300 Å was formed through deposition of TPBI on an upper portion of the hole blocking layer. An electron injection layer having a thickness of 10 Å was formed through deposition of LiF on an upper portion of the electron transport layer. A second electrode having a thickness of 3,000 Å was formed through deposition of Al on an upper portion of the electron injection layer. A capping layer having a thickness of 700 Å was formed through deposition of P4 on an upper portion of the second electrode to prepare a light emitting element.

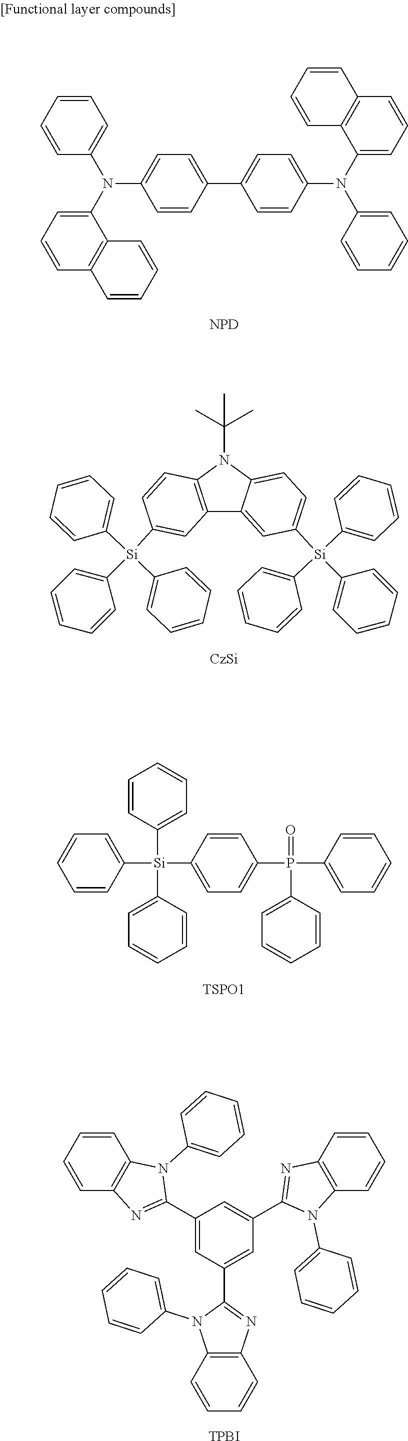

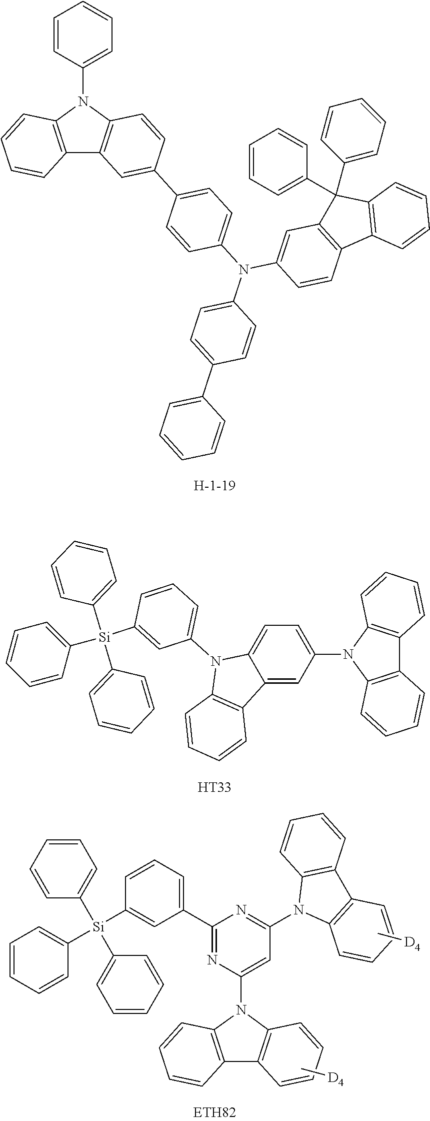

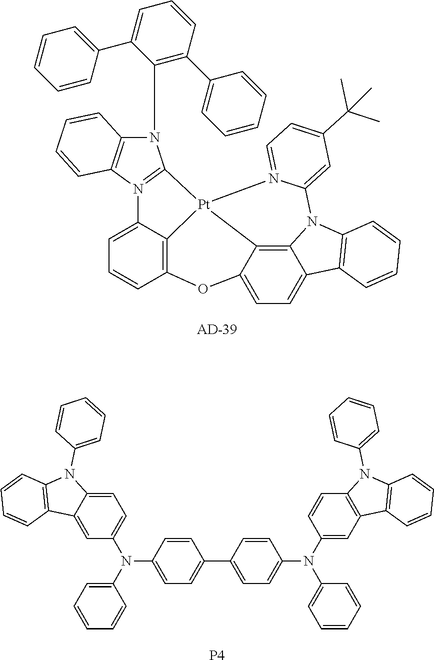

### (2) Evaluation of Light Emitting Elements

In Table 2, the characteristics of the light emitting elements of the Examples and the Comparative Examples were evaluated. The light emitting elements of Examples 1 to 5 and Comparative Examples 1 to 3 were prepared according to the light emitting element example preparation described above.

TABLE 2

| | | | Frontal | Light | | | |
|---|---|---|---|---|---|---|---|
| | | Driving | efficiency | emission | | | |
| | | voltage | Efficiency | wavelength | Lifespan | CIE | Q.E. |
| | Dopant | (V) | (cd/A) | (nm) | (T95) | (x, y) | (%) |
| Example 1 | Compound 13 | 3.6 | 25.1 | 460 | 8.5 | 0.137, 0.053 | 53.7 |
| Example 2 | Compound 21 | 3.4 | 24.9 | 467 | 10.3 | 0.141, 0.058 | 51.0 |
| Example 3 | Compound 53 | 3.1 | 27.1 | 458 | 11.8 | 0.137, 0.051 | 56.9 |
| Example 4 | Compound 69 | 3.5 | 23.3 | 467 | 3.5 | 0.134, 0.059 | 49.9 |
| Example 5 | Compound 79 | 3.7 | 28.9 | 464 | 9.4 | 0.135, 0.057 | 60.1 |
| Comparative | Compound C1 | 4.4 | 19.3 | 465 | 1 | 0.132, 0.051 | 43.9 |
| Example 1 | | | | | | | |
| Comparative | Compound C2 | 4.2 | 21.5 | 470 | 1.2 | 0.136, 0.054 | 46.1 |
| Example 2 | | | | | | | |
| Comparative | Compound C3 | 4.6 | 18.4 | 455 | 1.03 | 0.128, 0.048 | 38.9 |
| Example 3 | | | | | | | |

Referring to Table 2, the light emitting elements of Examples 1 to 5, which are light emitting elements to which the polycyclic compound according to an embodiment is applied, exhibit lower driving voltage, higher light emitting efficiency, higher maximum external quantum efficiency, and greater service life than the light emitting elements of Comparative Examples 1 to 3.

Referring to Tables 1 and 2, it is believed that the polycyclic compound according to an embodiment exhibits small Stokes-shift and a small full width at half maximum due to large steric hindrance caused by the inclusion of a heptazine group. Accordingly, it is believed that, in a light emitting element to which the polycyclic compound according to an embodiment is applied, deep blue light may be emitted and the purity of the light emitting color may be improved to increase light emitting efficiency.

It is believed that a triplet exciton is first stabilized at the high energy level of triplet exciton energy level (T1) of the heptazine group, thereby reducing the degradation of the compound. It is believed that the inclusion of the heptazine group lowers a HOMO energy level, and direct exciton recombination in the core structure may thus be minimized. Accordingly, it is believed that the lifespan of a light emitting element can be improved.

It is believed that as the heptazine group has low electron density, electron injection is accelerated to improve driving voltage.

Comparative Example Compound C1 is a compound having only an alkyl group or an aryl group as a substituent of the core structure, unlike the polycyclic compound according to an embodiment. Therefore, the above-described effects (low HOMO energy level, small ΔE_{ST} value, high light emitting efficiency, small Stokes-shift, and high full width at half maximum) obtained through the inclusion of the heptazine group in the polycyclic compound according to an embodiment are not achievable, and thus when Comparative Example Compound C1 was evaluated to have low light emitting efficiency and lifespan, and high driving voltage when applied to a light emitting element.

Comparative Example Compound C2 is a compound having only an aryl group or a heteroaryl group (pyridine group) containing one nitrogen atom as a substituent of the core structure. Therefore, the above-described effects (low HOMO level, small ΔE_{ST} value, high light emitting efficiency, small Stokes-shift, and high full width at half maximum) obtained through the inclusion of the heptazine group in the polycyclic compound according to an embodiment are not achievable, and thus when Comparative Example Compound C1 was evaluated to have low light emitting efficiency and lifespan, and high driving voltage when applied to a light emitting element.

Comparative Example Compound C3 is a compound having only an aryl group or a heteroaryl group (carbazole group) containing one nitrogen atom as a substituent of the core structure. Therefore, the above-described effects (low HOMO level, small ΔE_{ST} value, high light emitting efficiency, small Stokes-shift, and high full width at half maximum) obtained through the inclusion of the heptazine group in the polycyclic compound according to an embodiment are not achievable, and thus when Comparative Example Compound C1 was evaluated to have low light emitting efficiency and lifespan, and high driving voltage when applied to a light emitting element.

The polycyclic compound represented by Formula 1 may have a core structure having multiple aromatic rings fused therein through a boron atom, at least one nitrogen atom, and at least one heteroatom, and including a phenyl group linked to a nitrogen atom. The at least one heteroatom may be N, O, S, Se, or Te. When the at least one heteroatom is a nitrogen atom, the core structure may include phenyl groups each linked to two nitrogen atoms. For example, the core structure may include three aromatic rings (which may each by hydrocarbon rings or heterocycles) that are fused through one boron atom, at least one nitrogen atom, and at least one heteroatom. At least two of the three aromatic rings may be benzene rings.

In the core structure, a substituent including a tricyclic heteroaryl group containing nitrogen atoms may be linked to at least one of the three aromatic rings or to a phenyl group linked to a nitrogen atom. For example, the tricyclic heteroaryl group containing nitrogen atoms may be a heptazine group containing 7 nitrogen atoms.

As at least one heptazine group is introduced into the core structure of the polycyclic compound represented by Formula 1, characteristics of a light emitting element, such as light emitting efficiency, lifespan, and driving voltage, may be improved.

A light emitting element according to an embodiment may exhibit improved element characteristics of high light emitting efficiency and long service life.

A polycyclic compound according to an embodiment may be included in an emission layer of a light emitting element, and may thus contribute to improving light emitting efficiency and service life of a light emitting element.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode facing the first electrode; and
at least one functional layer disposed between the first electrode and the second electrode, wherein
the at least one functional layer includes:
a first compound represented by Formula 1; and
at least one of a second compound represented by Formula HT and a third compound represented by Formula ET: 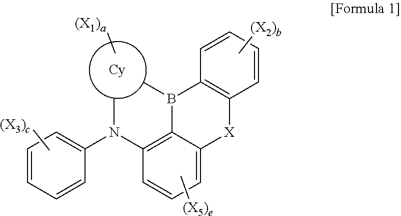
wherein in Formula 1,
Cy is a substituted or unsubstituted hydrocarbon ring having 5 to 30 ring-forming carbon atoms or a substituted or unsubstituted heterocycle having 2 to 30 ring-forming carbon atoms,
X is N(Rₓ), O, S, Se, or Te, and
Rₓ is a group represented by Formula 1a, 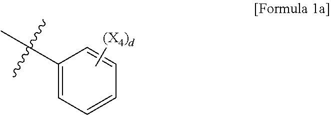
wherein in Formulas 1 and 1a,
a and b are each independently an integer from 1 to 4,
c and d are each independently an integer from 1 to 5,
e is an integer from 1 to 3, and
at least one of X₁ to X₅ is each independently a group represented by Formula 2,
the remainder of X₁ to X₅ are each independently a hydrogen atom, a cyano group, a substituted or unsubstituted oxy group, a substituted or unsubstituted alkyl group having 1 to 60 carbon atoms, a substituted or unsubstituted cycloalkyl group having 3 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring, 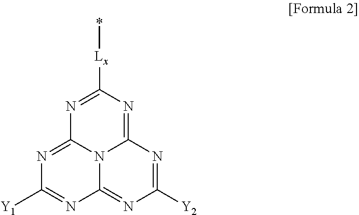
wherein in Formula 2,
Lₓ is a direct linkage, a substituted or unsubstituted amine group, a substituted or unsubstituted arylene group having 6 to 60 carbon atoms, or a substituted or unsubstituted heteroarylene group having 2 to 60 ring-forming carbon atoms,
Y₁ and Y₂ are each independently a substituted or unsubstituted amine group, a substituted or unsubstituted aryl group having 6 to 60 ring-forming carbon atoms, or a substituted or unsubstituted heteroaryl group having 2 to 60 ring-forming carbon atoms, and
-* represents a bond to neighboring atom in Formula 1, 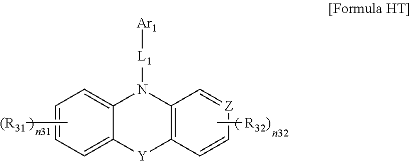
wherein in Formula HT,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Ar₁ is a substituted or unsubstituted aryl group having 6 to 30 ring-forming carbon atoms or a substituted or unsubstituted heteroaryl group having 2 to 30 ring-forming carbon atoms,
Y is a direct linkage, C(R_{y1})(R_{y2}), or Si(R_{y3})(R_{y4}),
Z is C(R_{z}) or N,
R_{y1} to R_{y4}, R₃₁, R₃₂, and R_{z} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring,
n31 is an integer from 0 to 4, and
n32 is an integer from 0 to 3, and 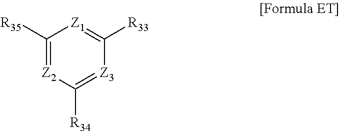
wherein in Formula ET,
Z₁ to Z₃ are each independently N or C(R₃₆),
at least one of Z₁ to Z₃ is each N, and
R₃₃ to R₃₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

2. The light emitting element of claim 1, wherein the at least one functional layer further comprises a fourth compound represented by Formula PS: 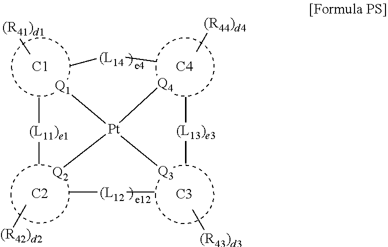
wherein in Formula PS,
Q₁ to Q₄ are each independently C or N,
C1 to C4 are each independently a substituted or unsubstituted hydrocarbon ring having 5 to 30 ring-forming carbon atoms or a substituted or unsubstituted heterocycle having 2 to 30 ring-forming carbon atoms,
L₁₁ to L₁₄ are each independently a direct linkage, 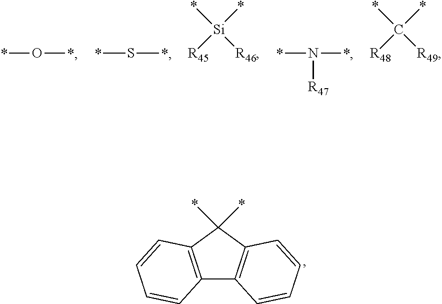
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, wherein in L₁₁ to L₁₄, -* represents a bond to one of C1 to C4,
e1 to e4 are each independently 0 or 1,
R₄₁ to R₄₉ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring, and
d1 to d4 are each independently an integer from 0 to 4.

3. The light emitting element of claim 1, wherein the first compound is represented by one of Formulas 1-1a to 1-1d: 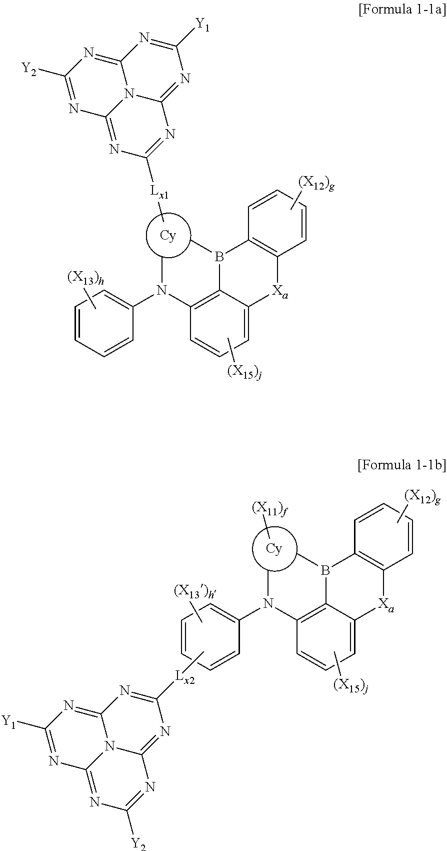 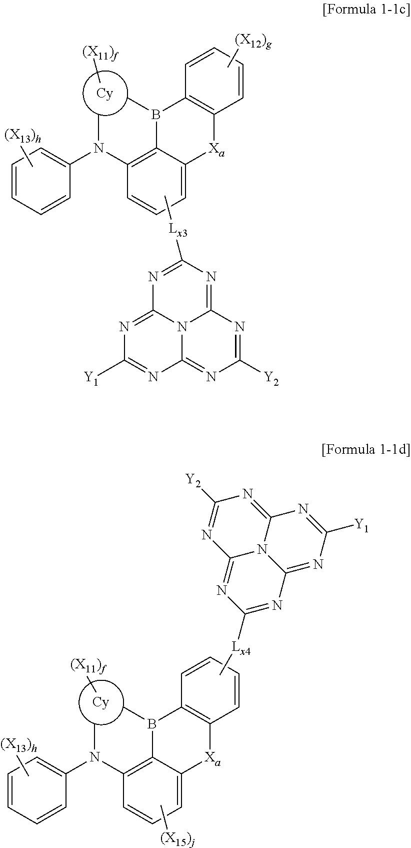
wherein in Formulas 1-1a to 1-1d,
Lₓ₁ to Lₓ₄ are each independently a direct linkage, a substituted or unsubstituted amine group, a substituted or unsubstituted arylene group having 6 to 20 ring-forming carbon atoms, or a substituted or unsubstituted heteroarylene group having 2 to 20 ring-forming carbon atoms,
Xₐ is N(Rₓ₁), O, S, Se, or Te, and
Rₓ₁ is a group represented by Formula 1b, and 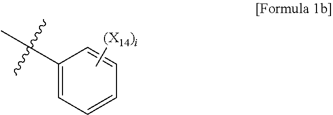
wherein in Formulas 1-1a to 1-1d and 1b,
X₁₁ to X₁₅ and X₁₃ are each independently a hydrogen atom, a cyano group, a substituted or unsubstituted oxy group, a substituted or unsubstituted alkyl group having 1 to 60 carbon atoms, a substituted or unsubstituted cycloalkyl group having 3 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring,
f and g are each independently an integer from 1 to 4,
h and i are each independently an integer from 1 to 5,
j is an integer from 1 to 3,
h′ is an integer from 0 to 4,
Cy is the same as defined in Formula 1, and
Y₁ and Y₂ are the same as defined in Formula 2.

4. The light emitting element of claim 1, wherein the first compound is represented by one of Formulas 1-2a to 1-2d: 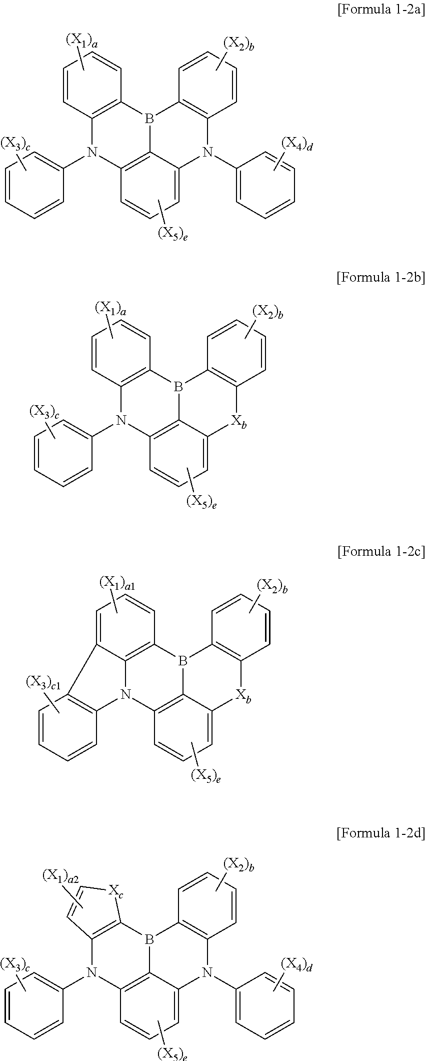
wherein in Formulas 1-2a to 1-2d,
a1 is an integer from 1 to 3,
a2 is 1 or 2,
c1 is an integer from 1 to 4,
X_{b} and X_{c} are each independently O, S, Se, or Te, and
X₁ to X₅ and a to e are the same as defined in Formula 1.

5. The light emitting element of claim 1, wherein the group represented by Formula 2 is represented by one of Formulas 2-1 to 2-3: 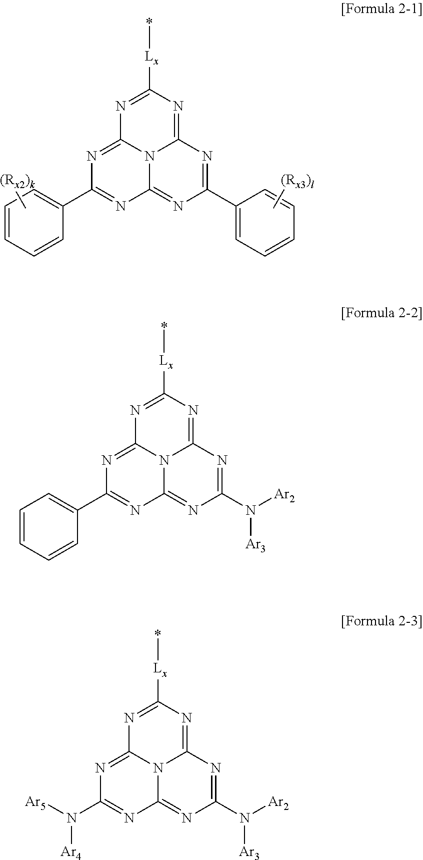
wherein in Formulas 2-1 to 2-3,
Rₓ₂ and Rₓ₃ are each independently a hydrogen atom or a t-butyl group,
k and l are each independently an integer from 0 to 5,
Ar₂ to Ar₅ are each independently an unsubstituted phenyl group, or bonded to an adjacent group to form a ring, and
Lₓ and -* are the same as defined in Formula 2.

6. The light emitting element of claim 1, wherein the at least one functional layer comprises at least one compound selected from Compound Group 1: 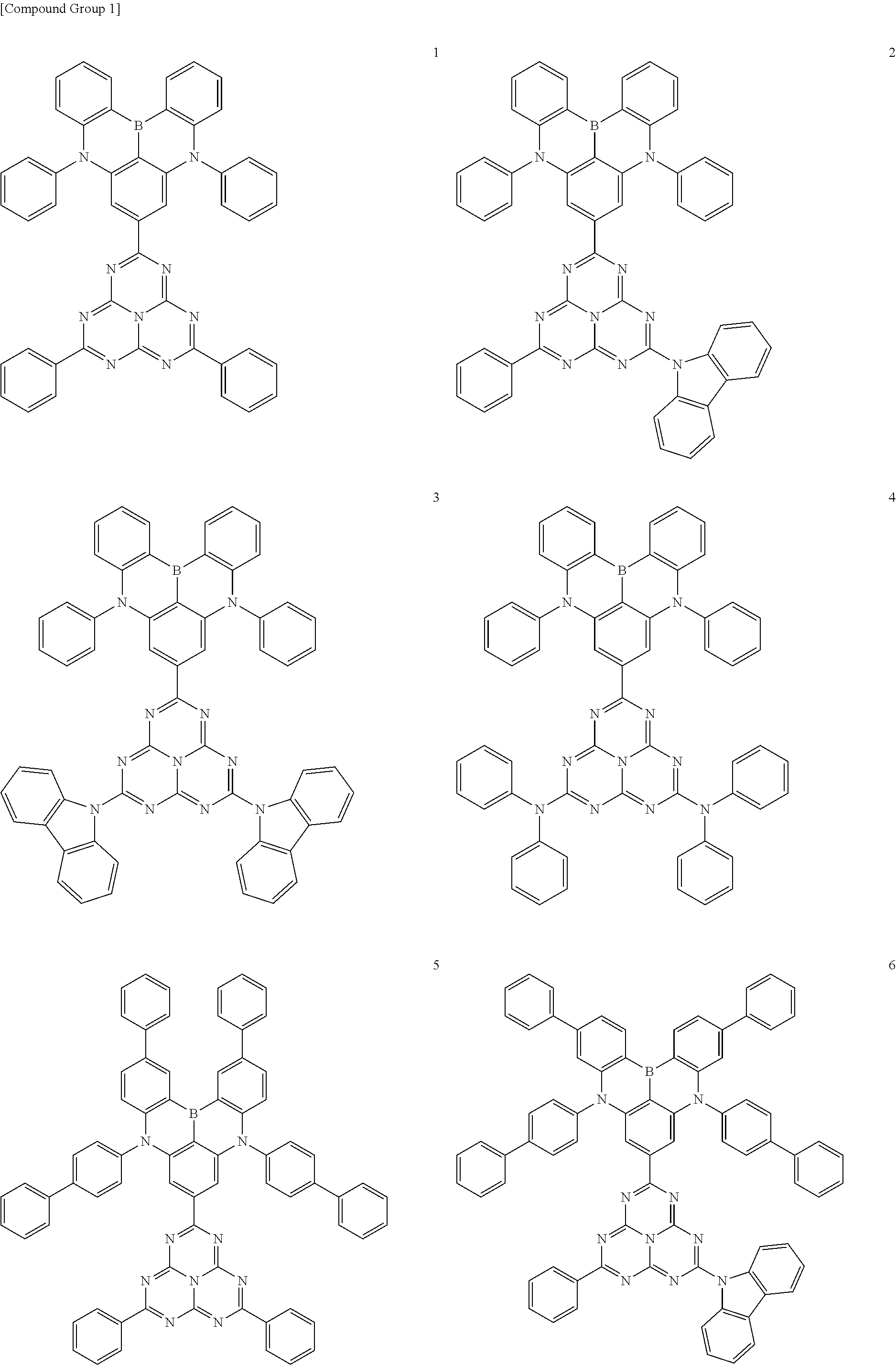 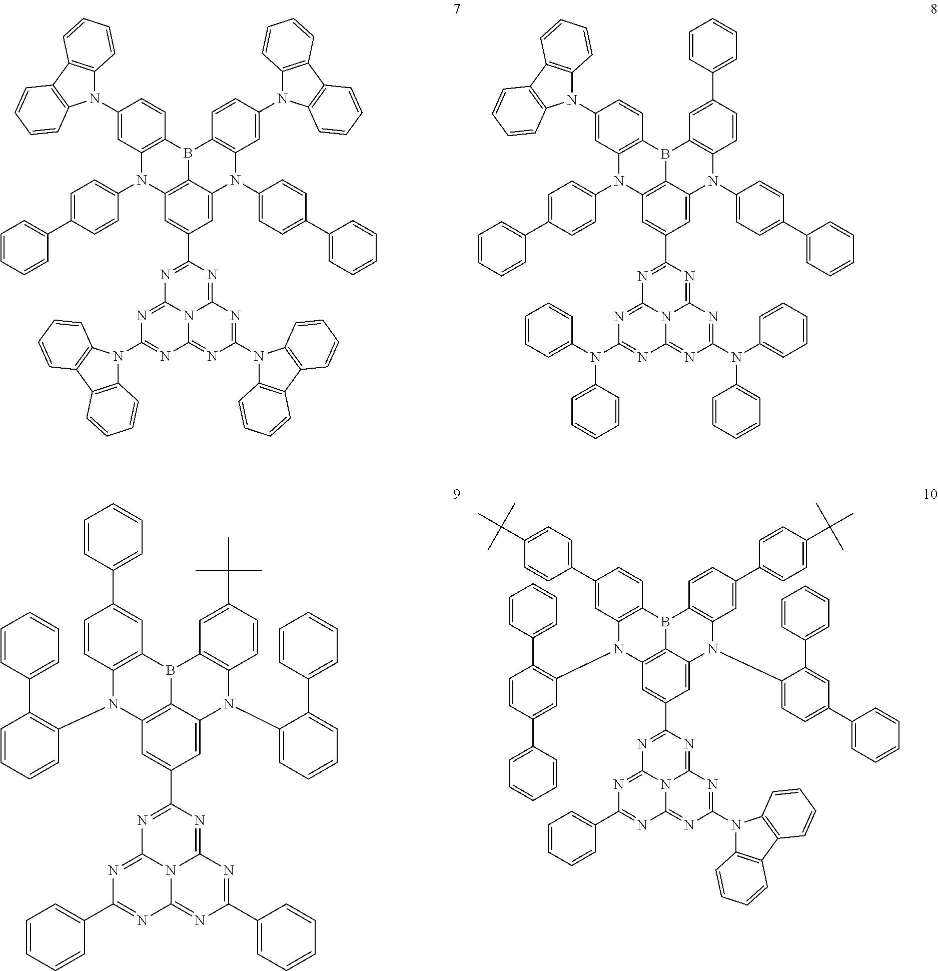 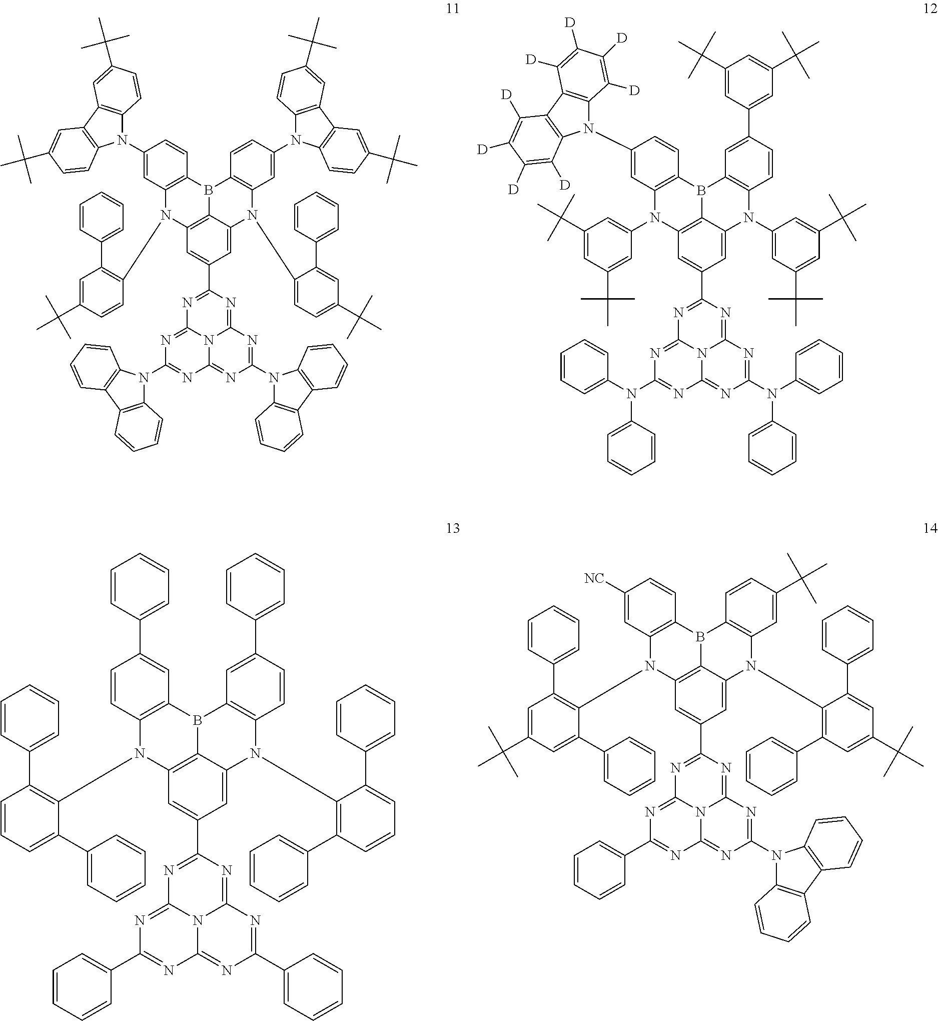 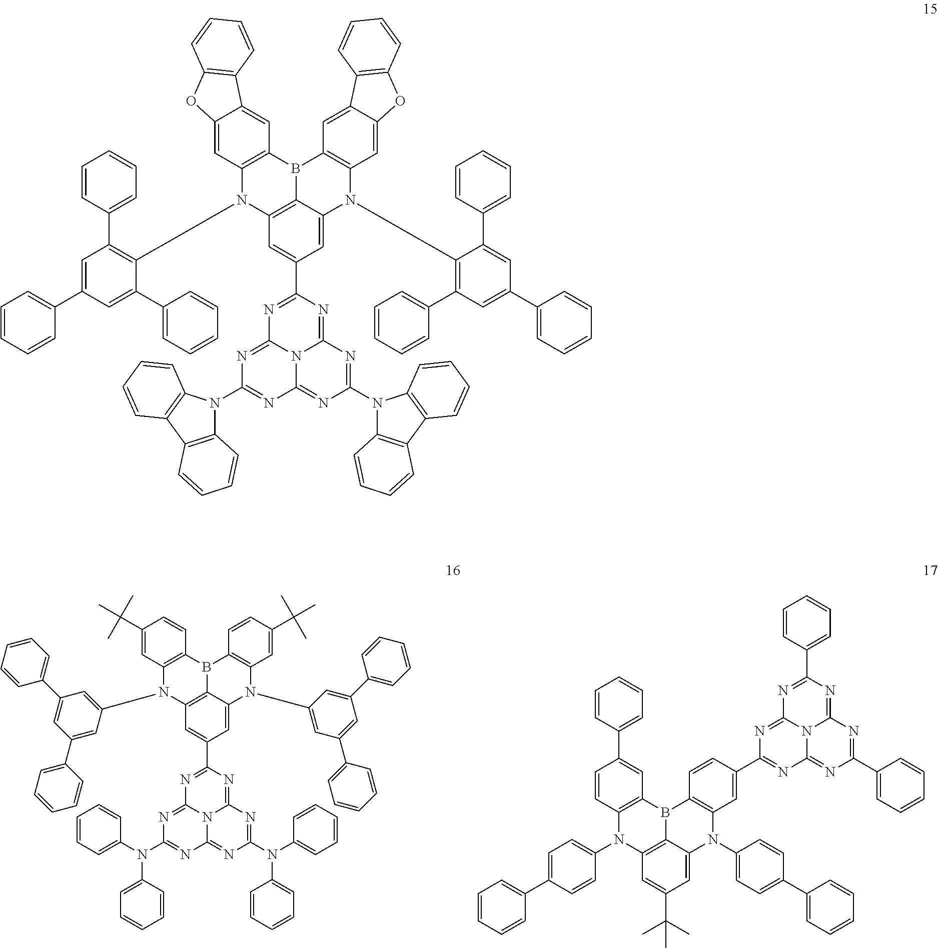 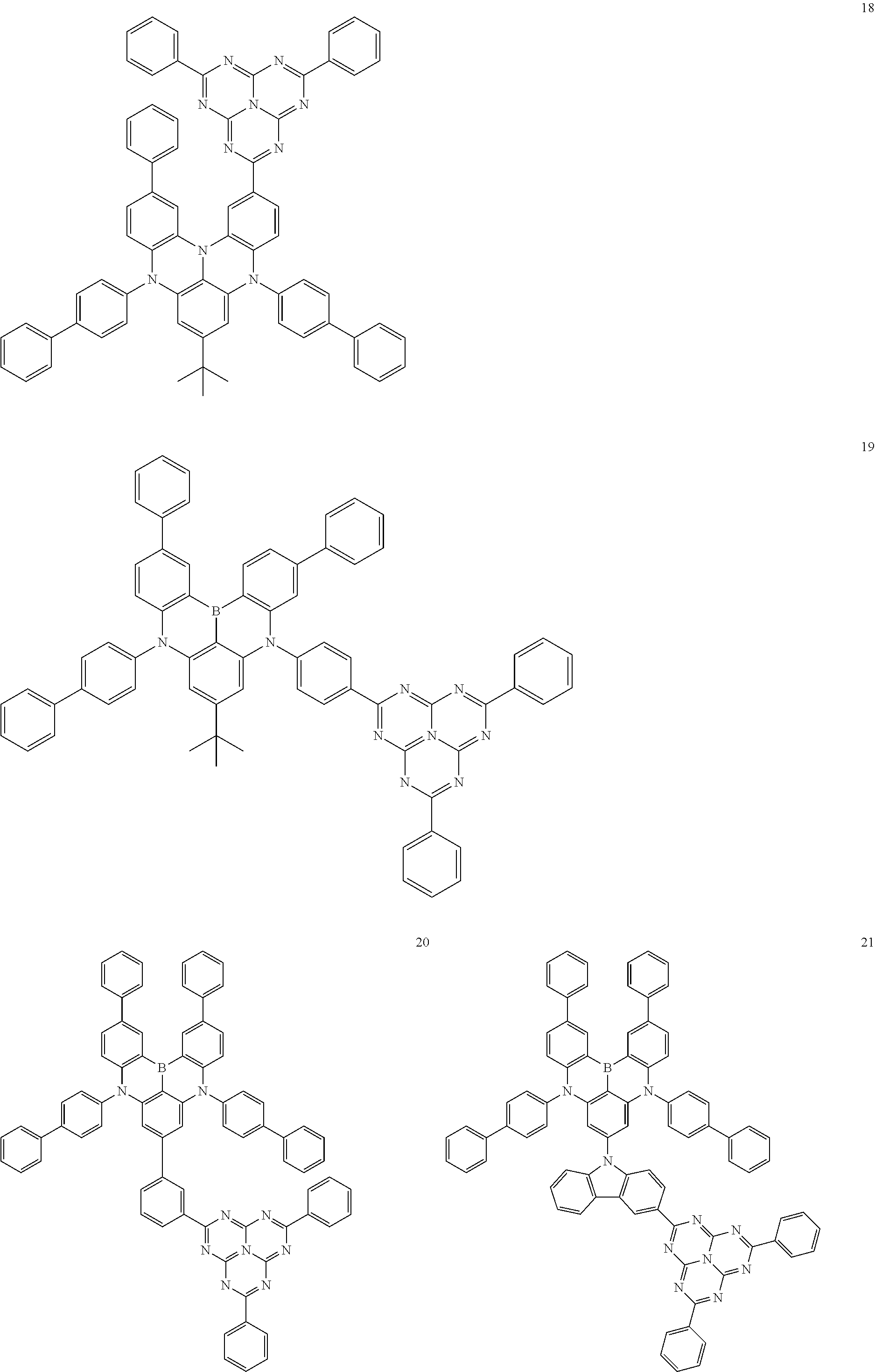 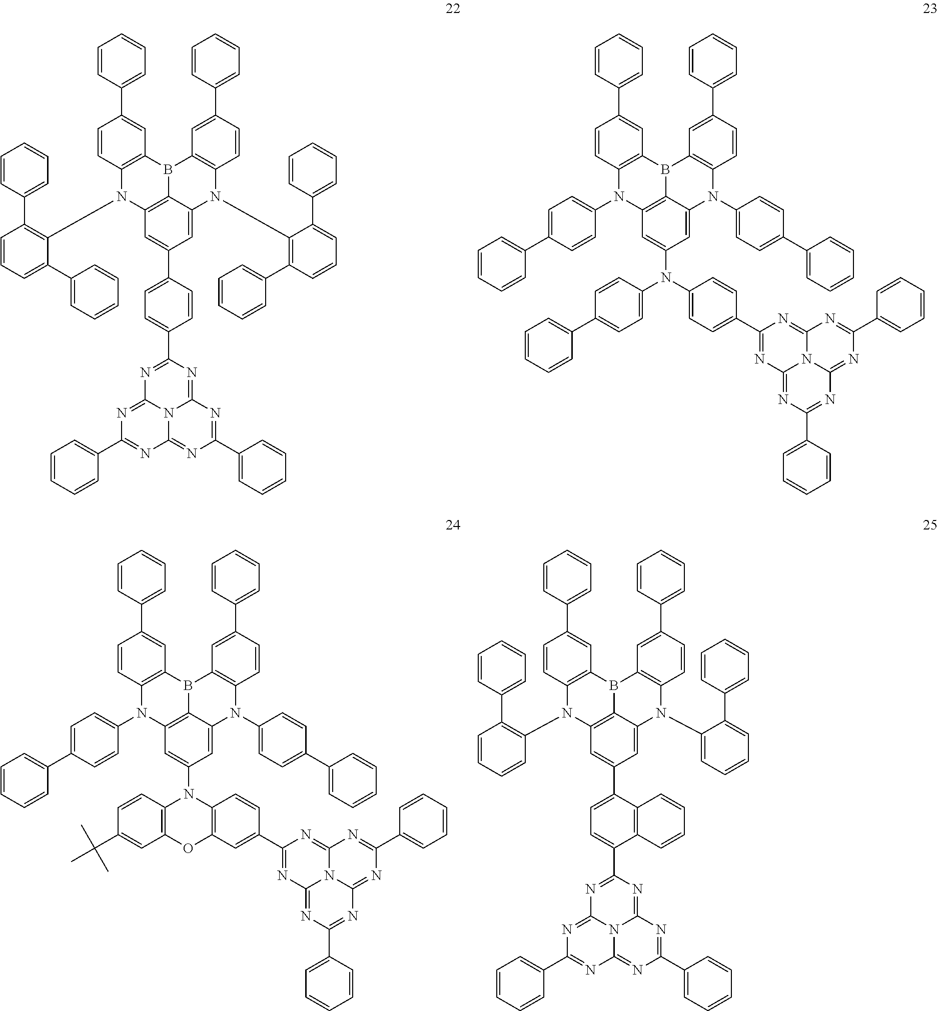 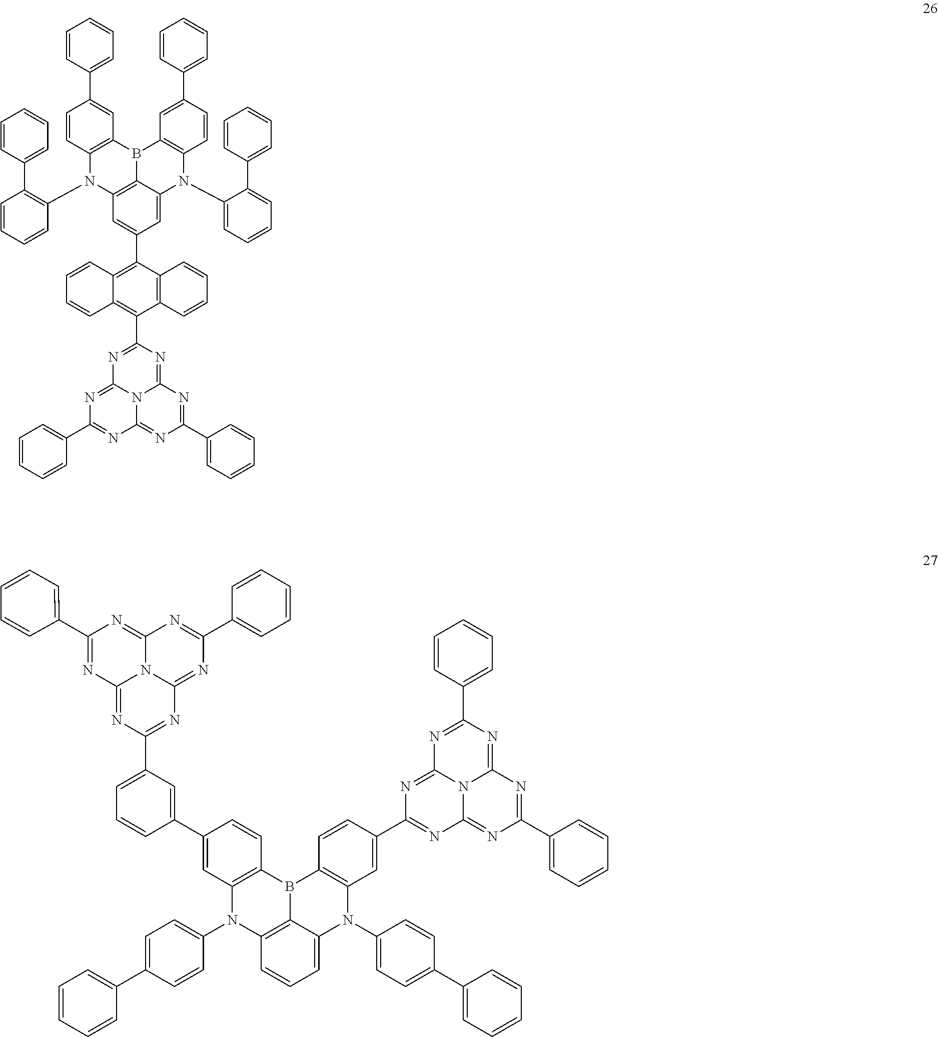 [SMILES: c1ccc(C2=NC3=NC(c4ccccc4)=NC4=NC(c5c6ccccc6c(-c6cc7c8c(c6)N(c6ccccc6-c6ccccc6)c6ccc(-c9ccccc9)cc6B8c6cc(-c8ccccc8)ccc6N7c6ccccc6-c6ccccc6)c6ccccc56)=NC(=N2)N34)cc1 ; c1ccc(C2=NC3=NC(c4ccccc4)=NC4=NC(c5cccc(-c6ccc7c(c6)N(c6ccc(-c8ccccc8)cc6)c6cccc8c6B7c6ccc(C7=NC9=NC(c%10ccccc%10)=NC%10=NC(c%11ccccc%11)=NC(=N7)N%109)cc6N8c6ccc(-c7ccccc7)cc6)c5)=NC(=N2)N34)cc1] 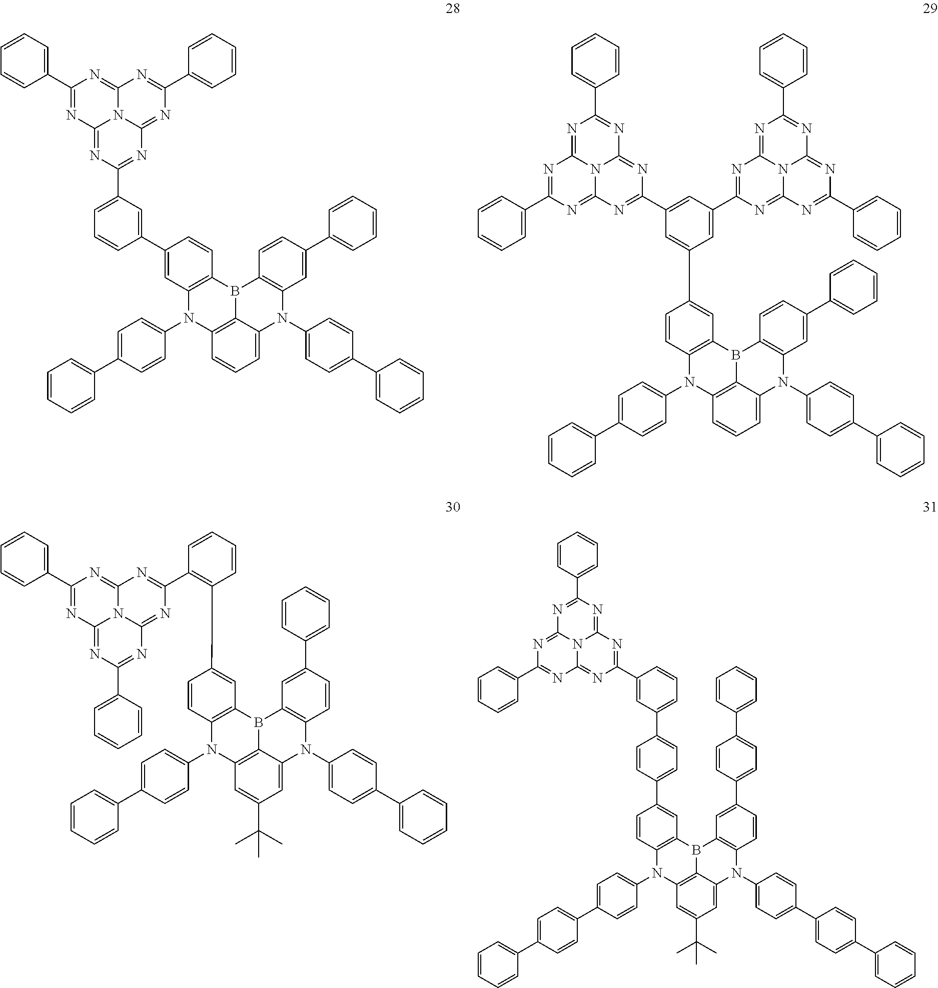 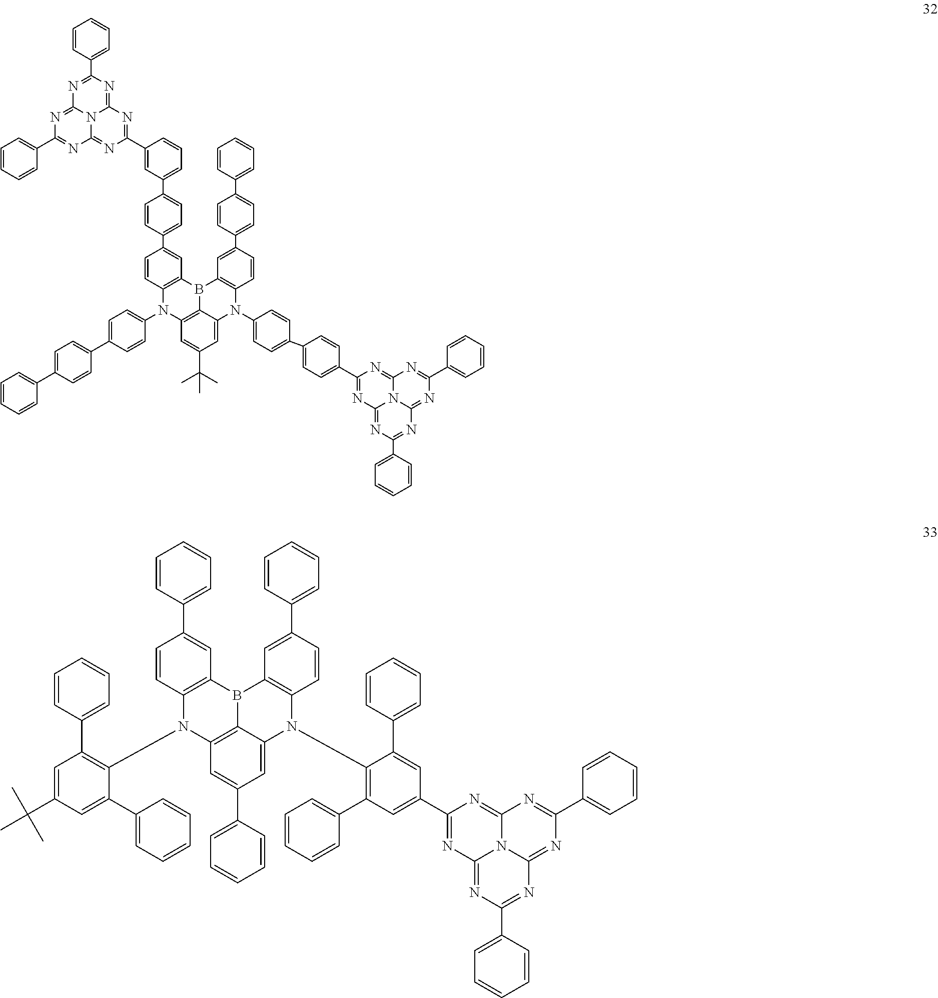 [SMILES: CC(C)(C)c1cc2c3c(c1)N(c1ccc(-c4ccc(-c5ccccc5)cc4)cc1)c1ccc(-c4ccc(-c5cccc(C6=NC7=NC(c8ccccc8)=NC8=NC(c9ccccc9)=NC(=N6)N87)c5)cc4)cc1B3c1cc(-c3ccc(-c4ccccc4)cc3)ccc1N2c1ccc(-c2ccc(C3=NC4=NC(c5ccccc5)=NC5=NC(c6ccccc6)=NC(=N3)N54)cc2)cc1 ; CC(C)(C)c1cc(-c2ccccc2)c(N2c3ccc(-c4ccccc4)cc3B3c4cc(-c5ccccc5)ccc4N(c4c(-c5ccccc5)cc(C5=NC6=NC(c7ccccc7)=NC7=NC(c8ccccc8)=NC(=N5)N76)cc4-c4ccccc4)c4cc(-c5ccccc5)cc2c43)c(-c2ccccc2)c1] 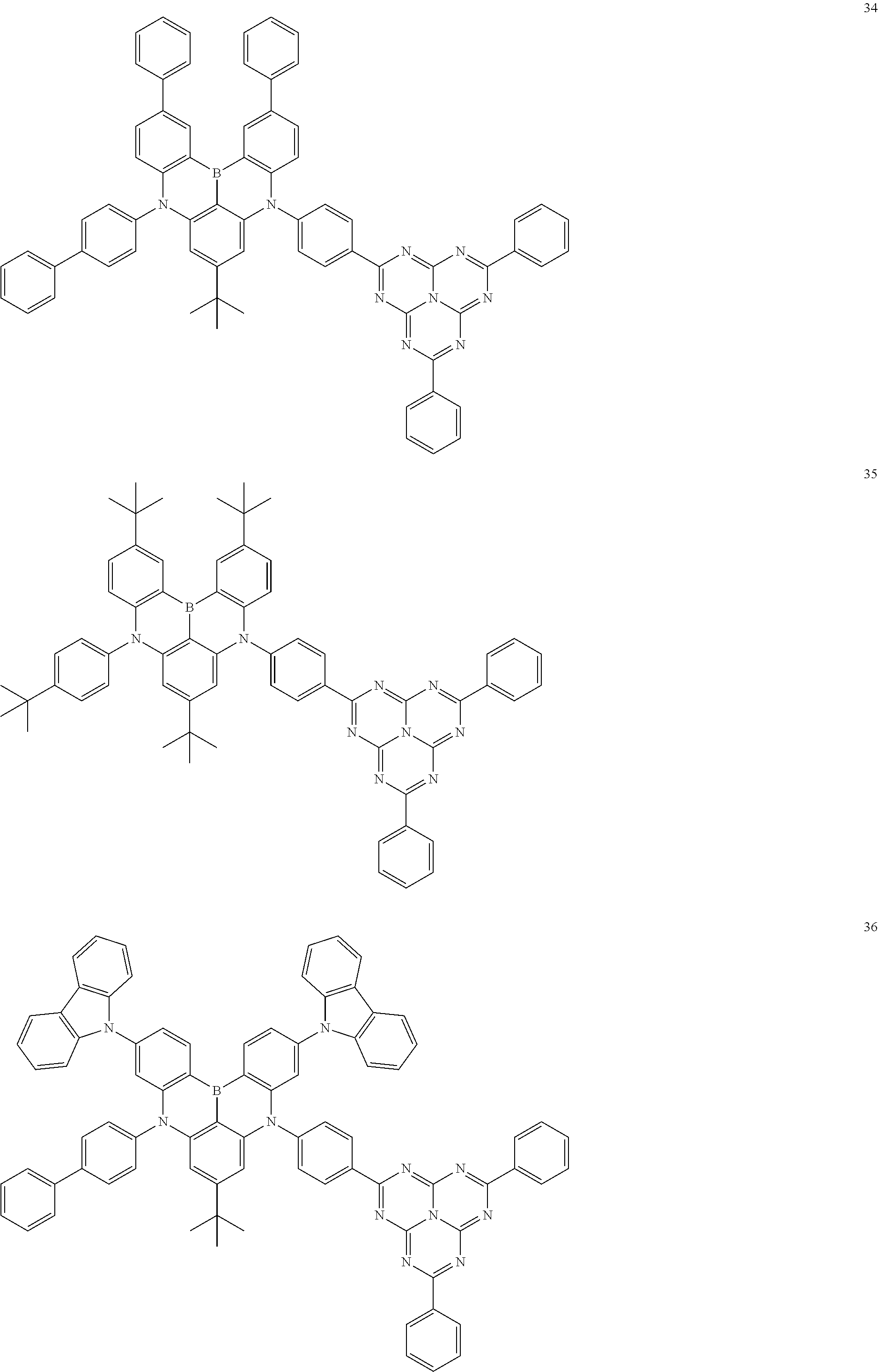 [SMILES: CC(C)(C)c1cc2c3c(c1)N(c1ccc(-c4ccccc4)cc1)c1ccc(-c4ccccc4)cc1B3c1cc(-c3ccccc3)ccc1N2c1ccc(C2=NC3=NC(c4ccccc4)=NC4=NC(c5ccccc5)=NC(=N2)N43)cc1 ; CC(C)(C)c1ccc(N2c3ccc(C(C)(C)C)cc3B3c4cc(C(C)(C)C)ccc4N(c4ccc(C5=NC6=NC(c7ccccc7)=NC7=NC(c8ccccc8)=NC(=N5)N76)cc4)c4cc(C(C)(C)C)cc2c43)cc1 ; CC(C)(C)c1cc2c3c(c1)N(c1ccc(-c4ccccc4)cc1)c1cc(-n4c5ccccc5c5ccccc54)ccc1B3c1ccc(-n3c4ccccc4c4ccccc43)cc1N2c1ccc(C2=NC3=NC(c4ccccc4)=NC4=NC(c5ccccc5)=NC(=N2)N43)cc1] 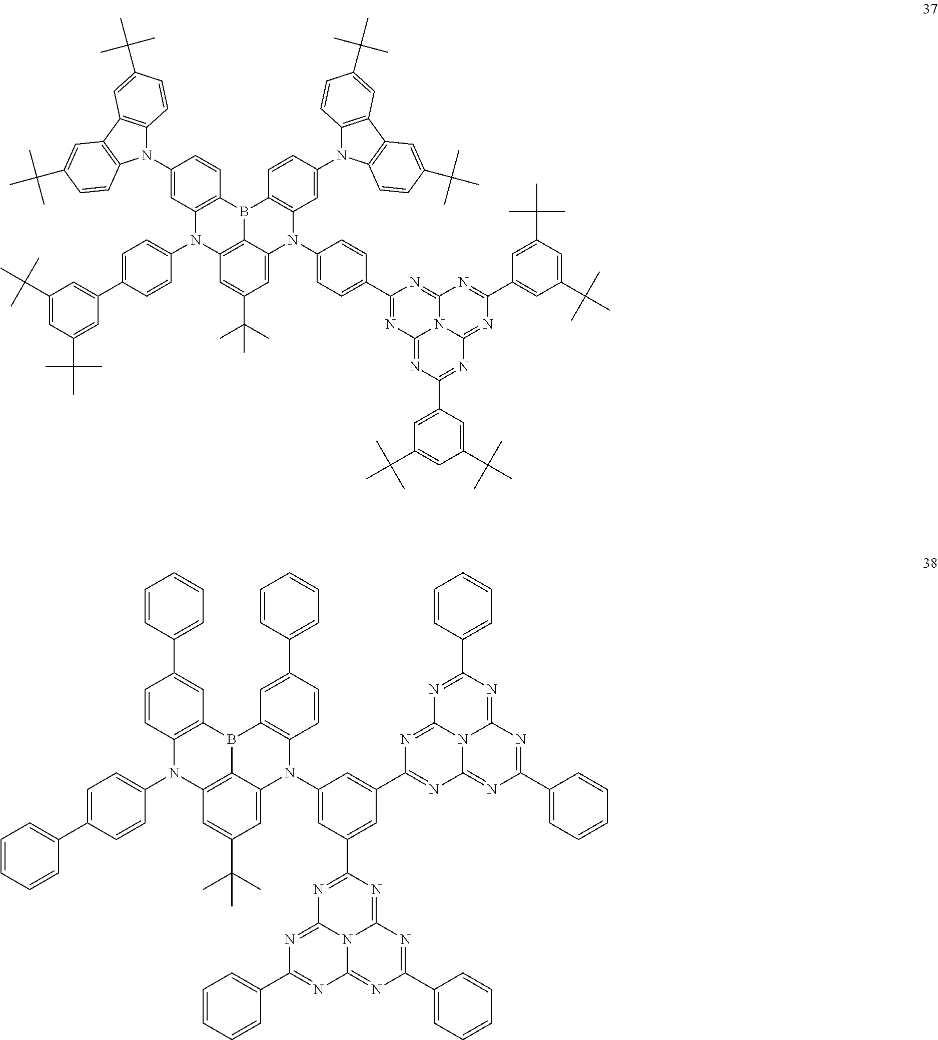 [SMILES: CC(C)(C)c1cc(C2=NC3=NC(c4ccc(N5c6cc(-n7c8ccc(C(C)(C)C)cc8c8cc(C(C)(C)C)ccc87)ccc6B6c7ccc(-n8c9ccc(C(C)(C)C)cc9c9cc(C(C)(C)C)ccc98)cc7N(c7ccc(-c8cc(C(C)(C)C)cc(C(C)(C)C)c8)cc7)c7cc(C(C)(C)C)cc5c76)cc4)=NC4=NC(c5cc(C(C)(C)C)cc(C(C)(C)C)c5)=NC(=N2)N34)cc(C(C)(C)C)c1 ; CC(C)(C)c1cc2c3c(c1)N(c1cc(C4=NC5=NC(c6ccccc6)=NC6=NC(c7ccccc7)=NC(=N4)N65)cc(C4=NC5=NC(c6ccccc6)=NC6=NC(c7ccccc7)=NC(=N4)N65)c1)c1ccc(-c4ccccc4)cc1B3c1cc(-c3ccccc3)ccc1N2c1ccc(-c2ccccc2)cc1] 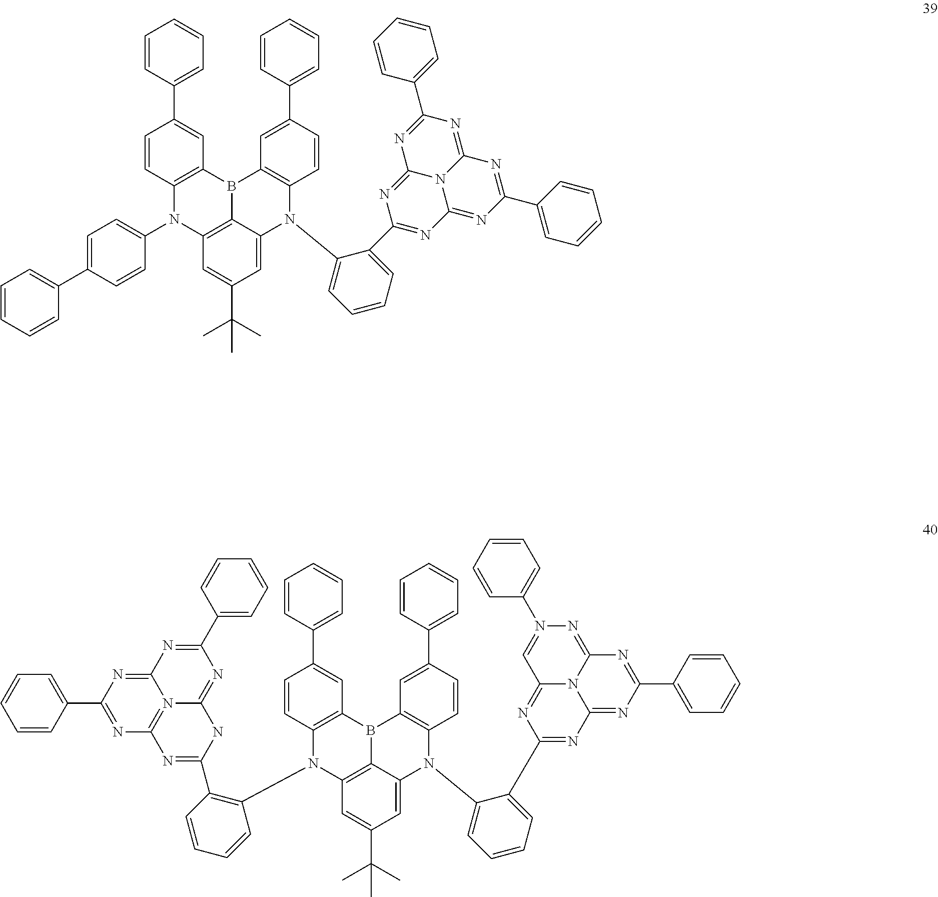 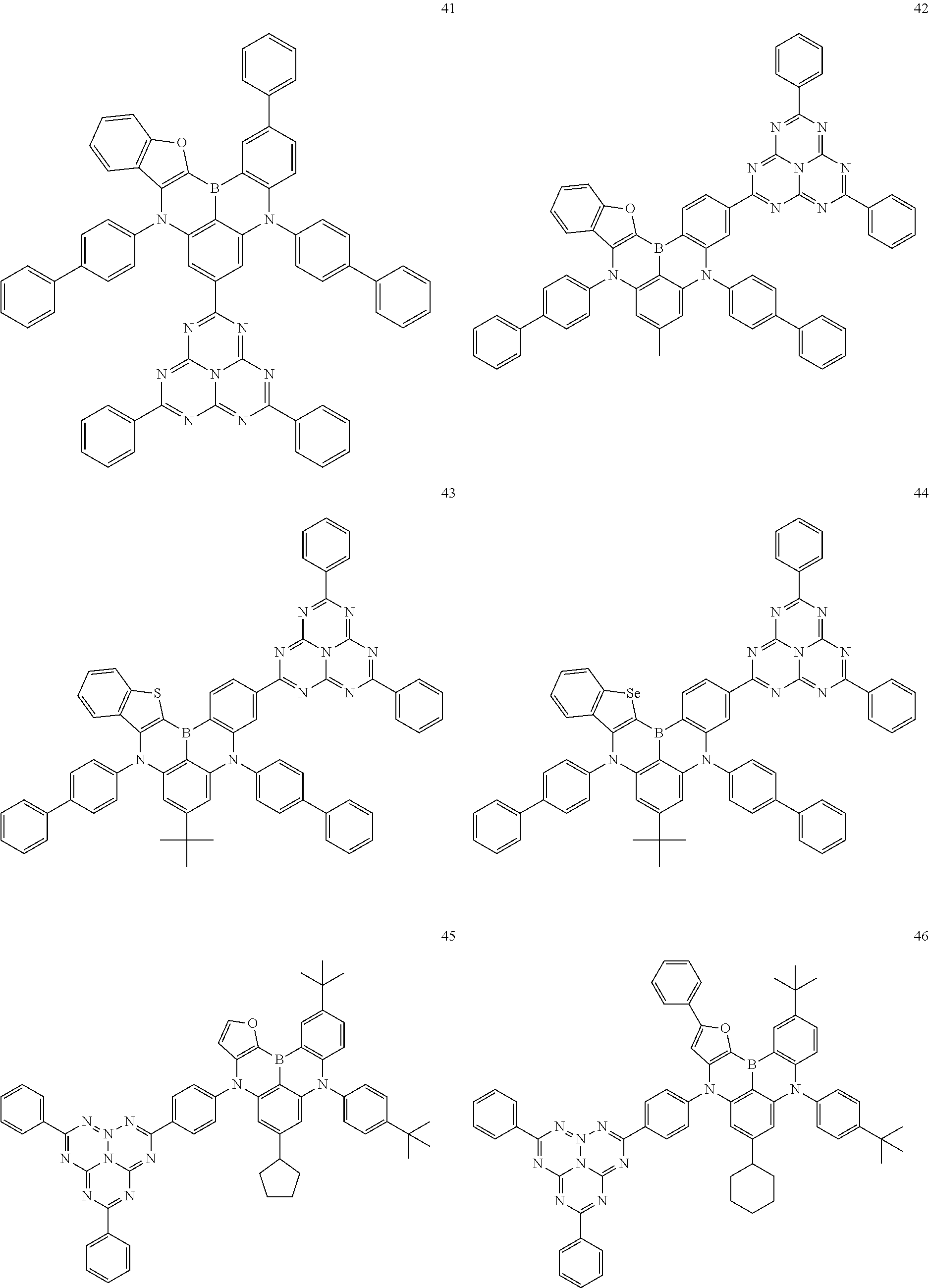 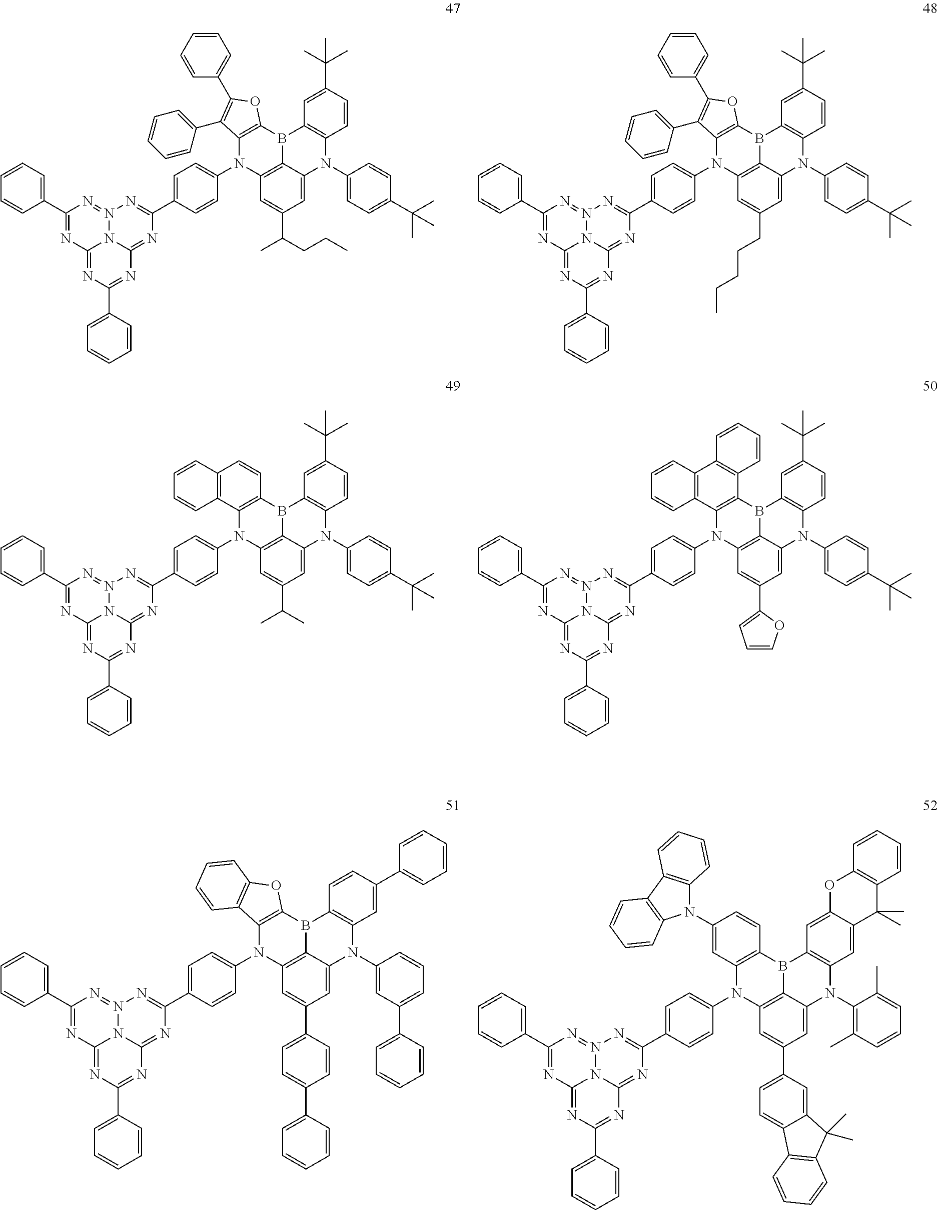 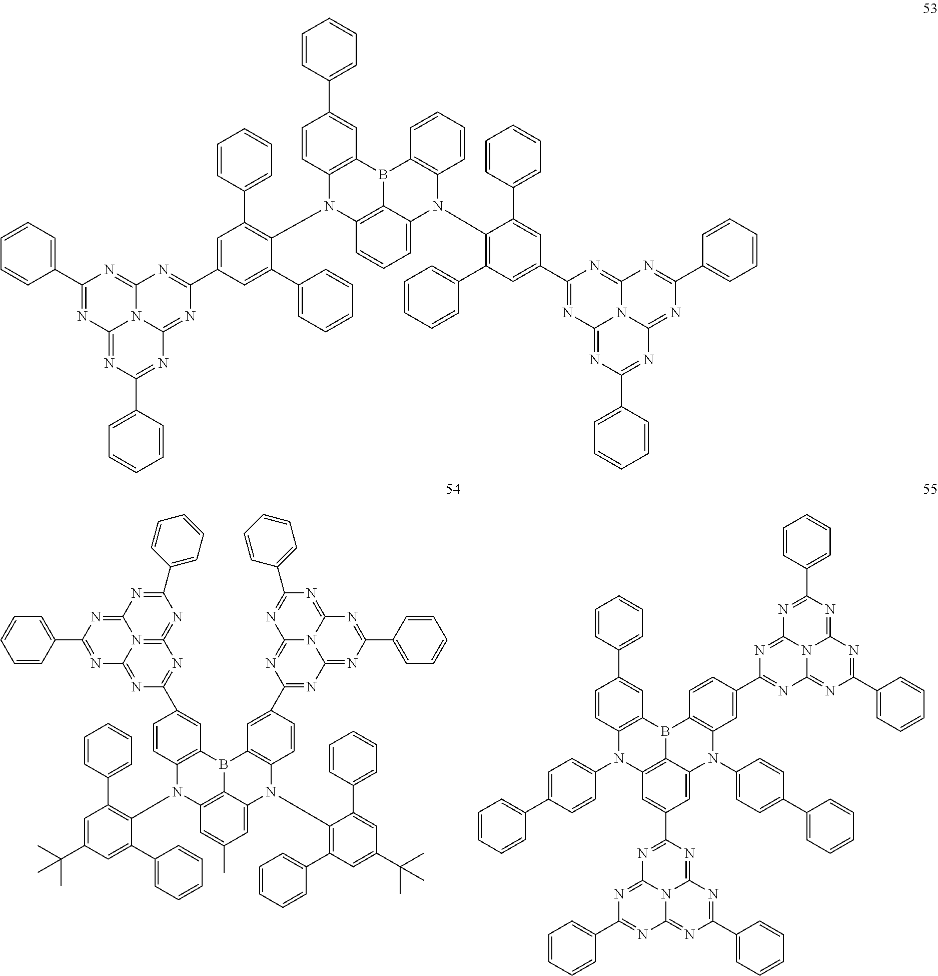 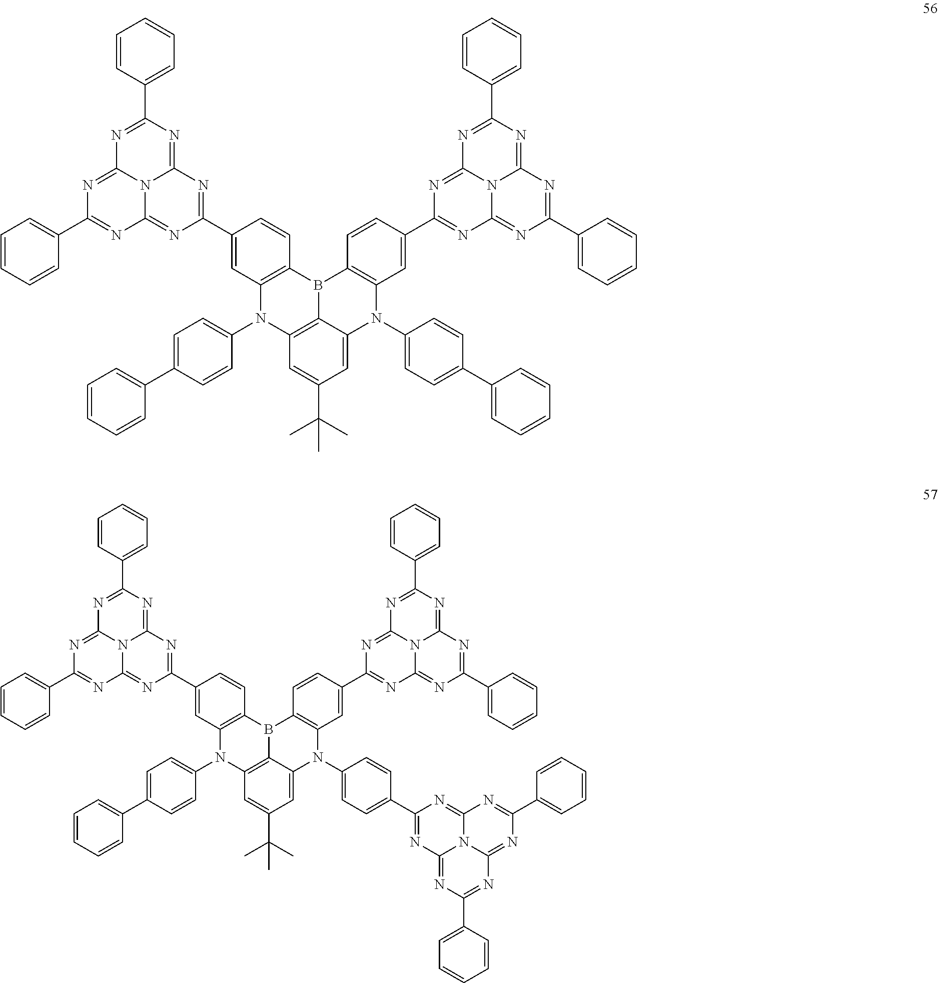 [SMILES: CC(C)(C)c1cc2c3c(c1)N(c1ccc(-c4ccccc4)cc1)c1cc(C4=NC5=NC(c6ccccc6)=NC6=NC(c7ccccc7)=NC(=N4)N65)ccc1B3c1ccc(C3=NC4=NC(c5ccccc5)=NC5=NC(c6ccccc6)=NC(=N3)N54)cc1N2c1ccc(-c2ccccc2)cc1 ; CC(C)(C)c1cc2c3c(c1)N(c1ccc(-c4ccccc4)cc1)c1cc(C4=NC5=NC(c6ccccc6)=NC6=NC(c7ccccc7)=NC(=N4)N65)ccc1B3c1ccc(C3=NC4=NC(c5ccccc5)=NC5=NC(c6ccccc6)=NC(=N3)N54)cc1N2c1ccc(C2=NC3=NC(c4ccccc4)=NC4=NC(c5ccccc5)=NC(=N2)N43)cc1] 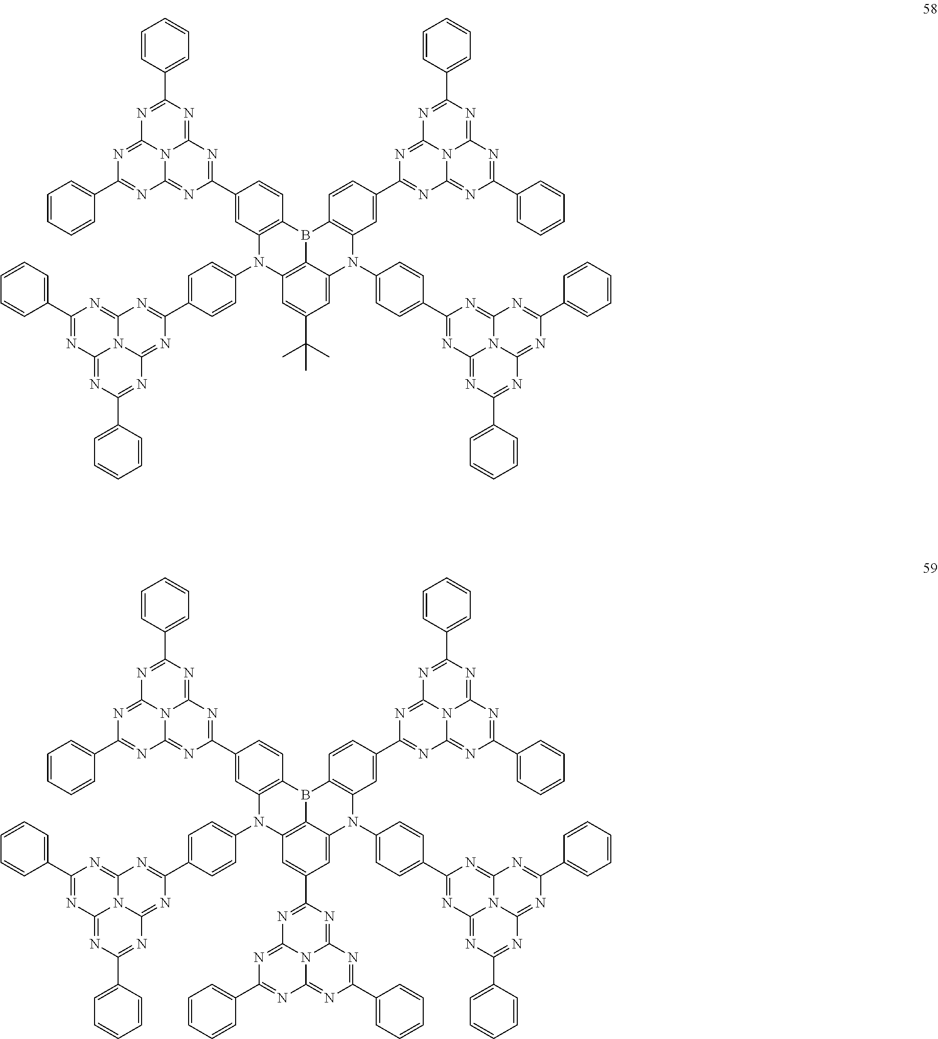 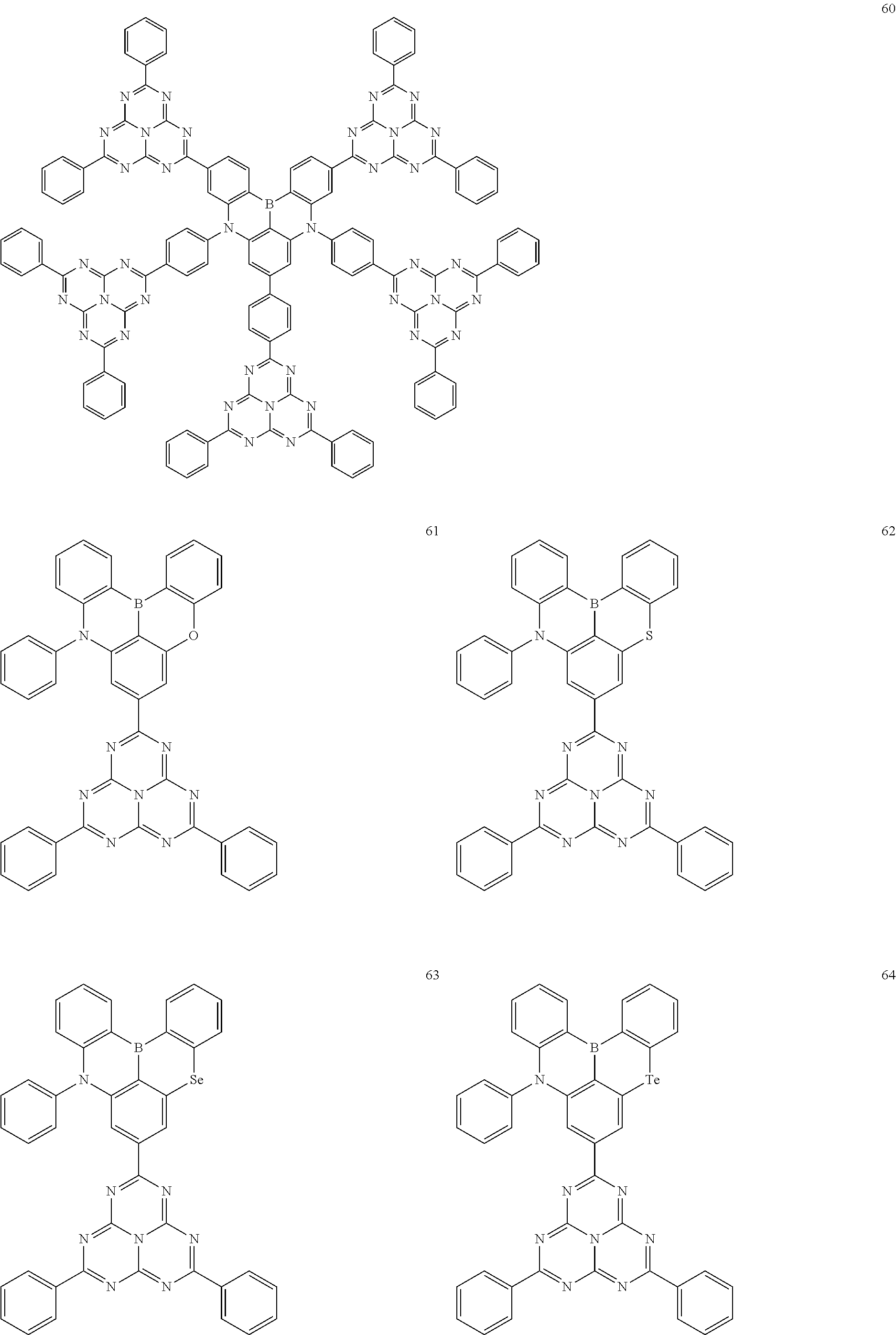 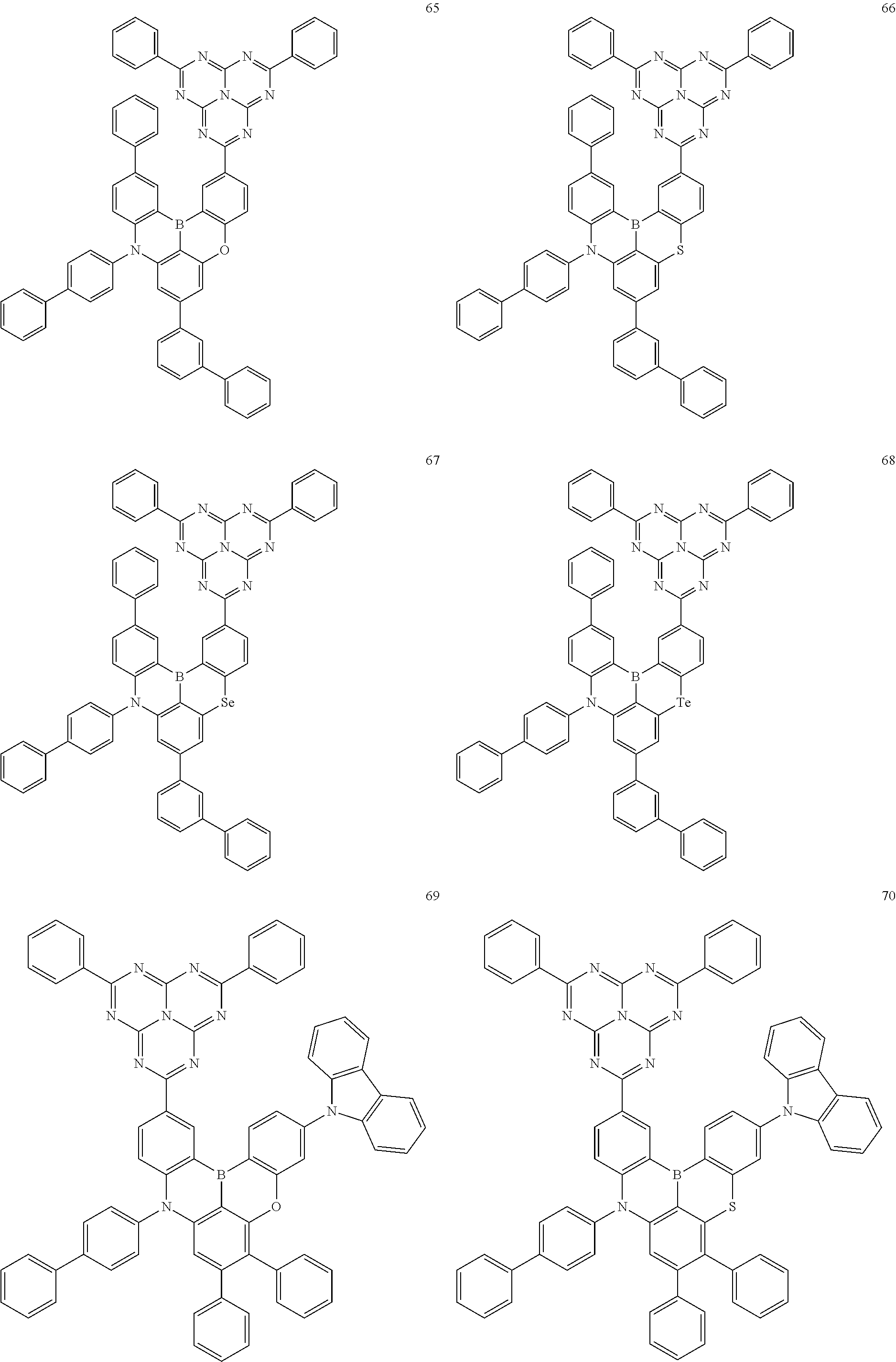 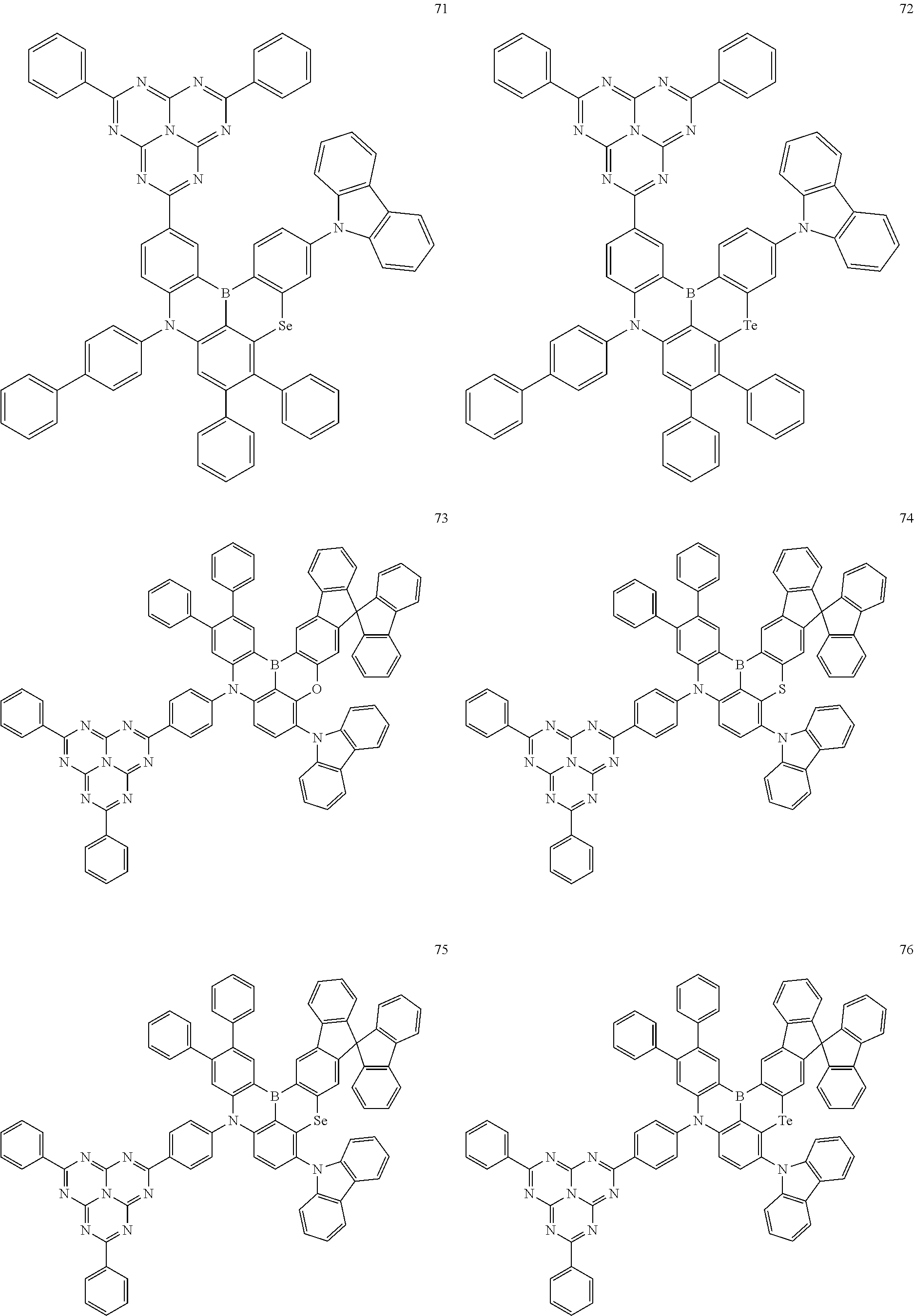 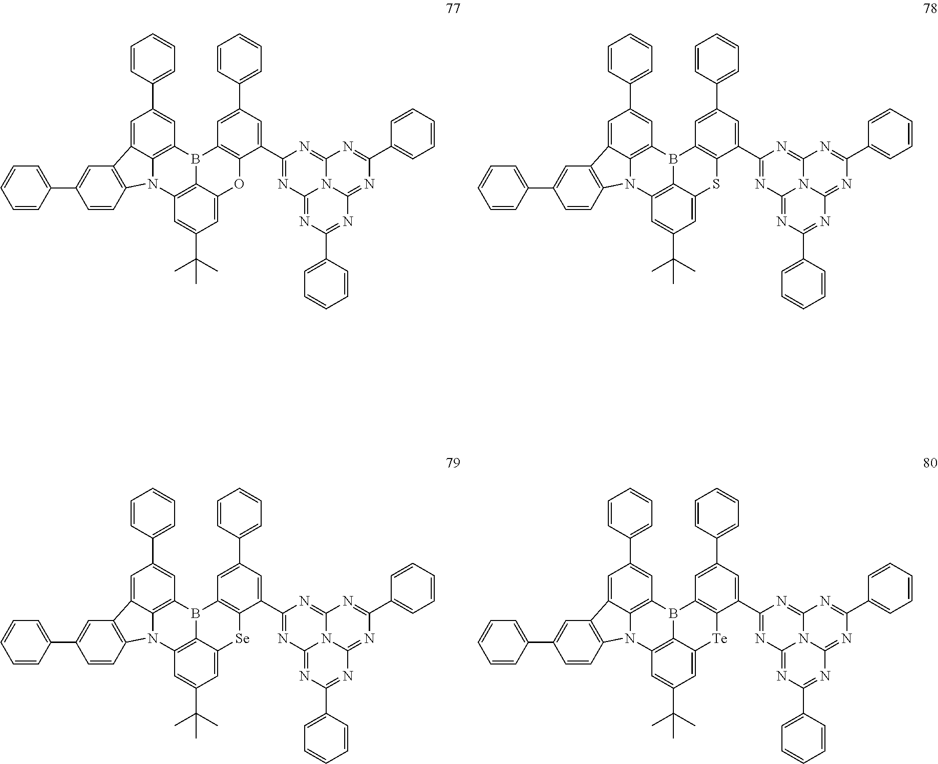
wherein in Compound Group 1,
D represents a deuterium atom.

7. The light emitting element of claim 1, wherein
the at least one functional layer comprises:
an emission layer;
a hole transport region disposed between the first electrode and the emission layer; and
an electron transport region disposed between the emission layer and the second electrode, and
the emission layer includes:
the first compound; and
at least one of the second compound and the third compound.

8. The light emitting element of claim 7, wherein the emission layer emits delayed fluorescence.

9. The light emitting element of claim 7, wherein the emission layer emits blue light.

10. The light emitting element of claim 1, wherein the at least one functional layer comprises the first compound, the second compound, and the third compound.

11. The light emitting element of claim 2, wherein the at least one functional layer comprises the first compound, the second compound, the third compound, and the fourth compound.

12. A light emitting element comprising:
a first electrode;
a second electrode facing the first electrode; and
an emission layer disposed between the first electrode and the second electrode, wherein
the emission layer includes a polycyclic compound represented by Formula 1: 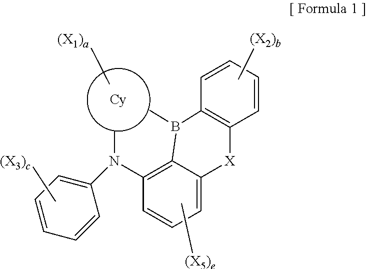
wherein in Formula 1,
Cy is a substituted or unsubstituted hydrocarbon ring having 5 to 30 ring-forming carbon atoms or a substituted or unsubstituted heterocycle having 2 to 30 ring-forming carbon atoms,
X is N(Rₓ), O, S, Se, or Te, and
Rₓ is a group represented by Formula 1a, 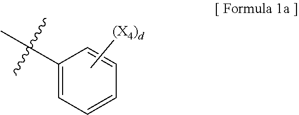
wherein in Formulas 1 and 1a,
a and b are each independently an integer from 1 to 4,
c and d are each independently an integer from 1 to 5,
e is an integer from 1 to 3,
at least one of X₁ to X₅ is each independently a group represented by Formula 3, and the remainder of X₁ to X₅ are each independently a hydrogen atom, a cyano group, a substituted or unsubstituted oxy group, a substituted or unsubstituted alkyl group having 1 to 60 carbon atoms, a substituted or unsubstituted cycloalkyl group having 3 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring, and 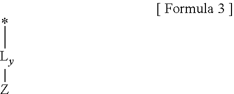
wherein in Formula 3,
L_{y} is a direct linkage, a substituted or unsubstituted amine group, a substituted or unsubstituted arylene group having 6 to 60 ring-forming carbon atoms, or a substituted or unsubstituted heteroarylene group having 2 to 60 ring-forming carbon atoms,
Z is a substituted or unsubstituted tricyclic heteroaryl group having 6 to 11 ring-forming carbon atoms and 2 to 7 ring-forming nitrogen atoms, and
-* represents a bond to neighboring atom in Formula 1.

13. The light emitting element of claim 12, wherein the polycyclic compound is represented by one of Formulas 1-1a to 1-1d: 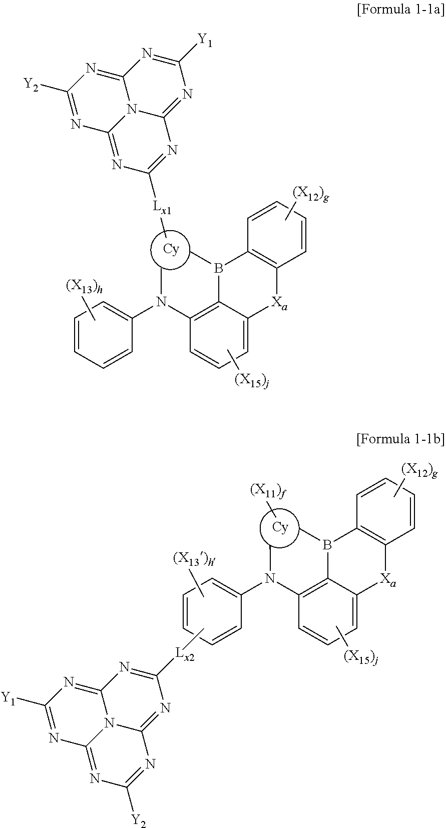 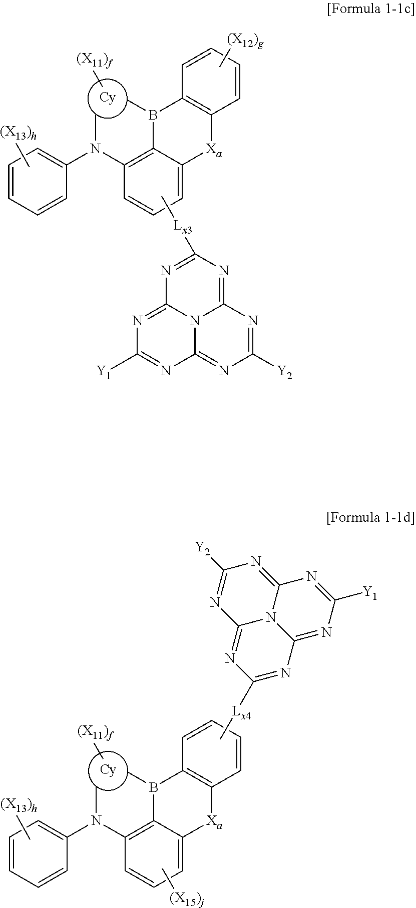
wherein in Formulas 1-1a to 1-1d,
Lₓ₁ to Lₓ₄ are each independently a direct linkage, a substituted or unsubstituted amine group, a substituted or unsubstituted arylene group having 6 to 20 ring-forming carbon atoms, or a substituted or unsubstituted heteroarylene group having 2 to 20 ring-forming carbon atoms,
Xₐ is N(Rₓ₁), O, S, Se, or Te, and
Rₓ₁ is a group represented by Formula 1b, and 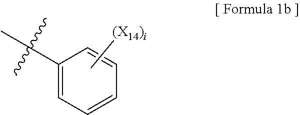
wherein in Formulas 1-1a to 1-1d and 1b,
X₁₁ to X₁₅ and X_{13′} are each independently a hydrogen atom, a cyano group, a substituted or unsubstituted oxy group, a substituted or unsubstituted alkyl group having 1 to 60 carbon atoms, a substituted or unsubstituted cycloalkyl group having 3 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring,
f and g are each independently an integer from 1 to 4,
h and i are each independently an integer from 1 to 5,
j is an integer from 1 to 3,
h′ is an integer from 0 to 4,
Cy is the same as defined in Formula 1, and
Y₁ and Y₂ are the same as defined in Formula 2.

14. The light emitting element of claim 12, wherein the polycyclic compound is represented by one of Formulas 1-2a to 1-2d: 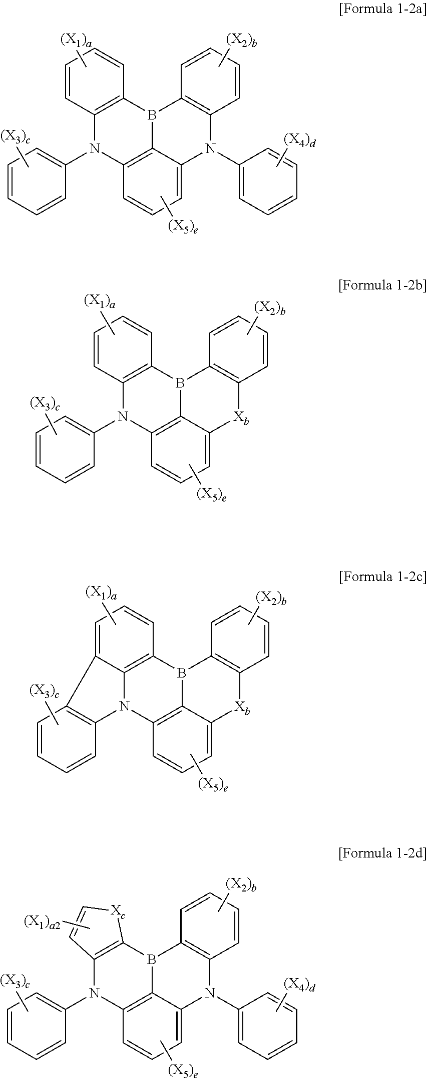
wherein in Formulas 1-2a to 1-2d,
a1 is an integer from 1 to 3,
a2 is 1 or 2,
c1 is an integer from 1 to 4,
X_{b} and X_{c} are each independently O, S, Se, or Te, and
X₁ to X₅ and a to e are the same as defined in Formula 1.

15. The light emitting element of claim 12, wherein Z is a group represented by Formula 4: 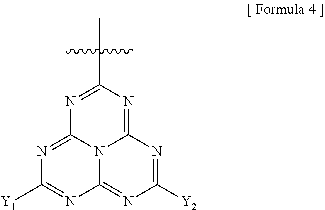
wherein in Formula 4,
Y₁ and Y₂ are each independently a substituted or unsubstituted amine group, a substituted or unsubstituted aryl group having 6 to 20 ring-forming carbon atoms, or a substituted or unsubstituted heteroaryl group having 2 to 20 ring-forming carbon atoms, and 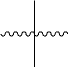
represents a bond to L_{y} in Formula 3.

16. A polycyclic compound represented by Formula 1: 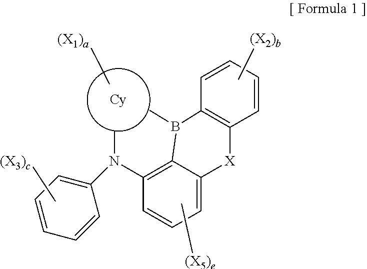
wherein in Formula 1,
Cy is a substituted or unsubstituted hydrocarbon ring having 5 to 30 ring-forming carbon atoms or a substituted or unsubstituted heterocycle having 2 to 30 ring-forming carbon atoms,
X is N(Rₓ), O, S, Se, or Te, and
Rₓ is a group represented by Formula 1a, 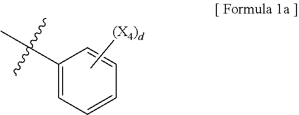
wherein in Formulas 1 and 1a,
a and b are each independently an integer from 1 to 4,
c and d are each independently an integer from 1 to 5,
e is an integer from 1 to 3,
at least one of X₁ to X₅ is each independently a group represented by Formula 2, and
the remainder of X₁ to X₅ are each independently a hydrogen atom, a cyano group, a substituted or unsubstituted oxy group, a substituted or unsubstituted alkyl group having 1 to 60 carbon atoms, a substituted or unsubstituted cycloalkyl group having 3 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring, and 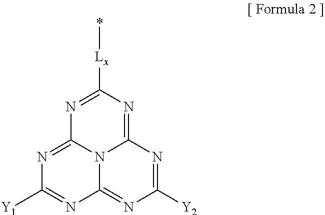
wherein in Formula 2,
Lₓ is a direct linkage, a substituted or unsubstituted amine group, a substituted or unsubstituted arylene group having 6 to 60 carbon atoms, or a substituted or unsubstituted heteroarylene group having 2 to 60 ring-forming carbon atoms,
Y₁ and Y₂ are each independently a substituted or unsubstituted amine group, a substituted or unsubstituted aryl group having 6 to 60 ring-forming carbon atoms, or a substituted or unsubstituted heteroaryl group having 2 to 60 ring-forming carbon atoms, and
-* represents a bond to neighboring atom in Formula 1.

17. The polycyclic compound of claim 16, wherein Formula 1 is represented by one of Formulas 1-1a to 1-1d: 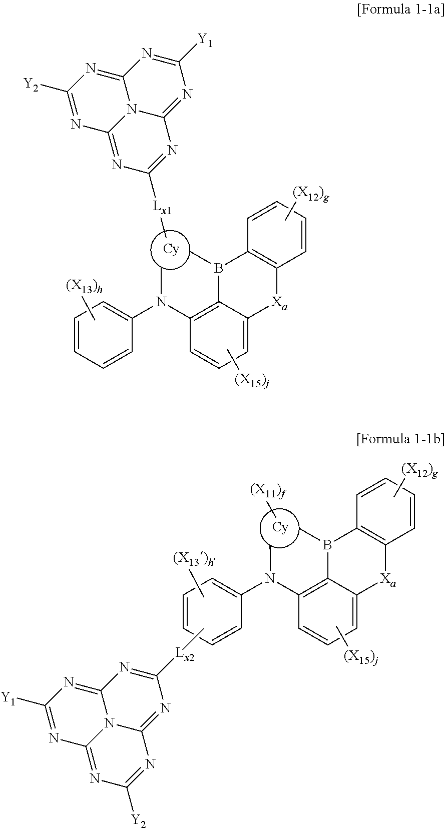 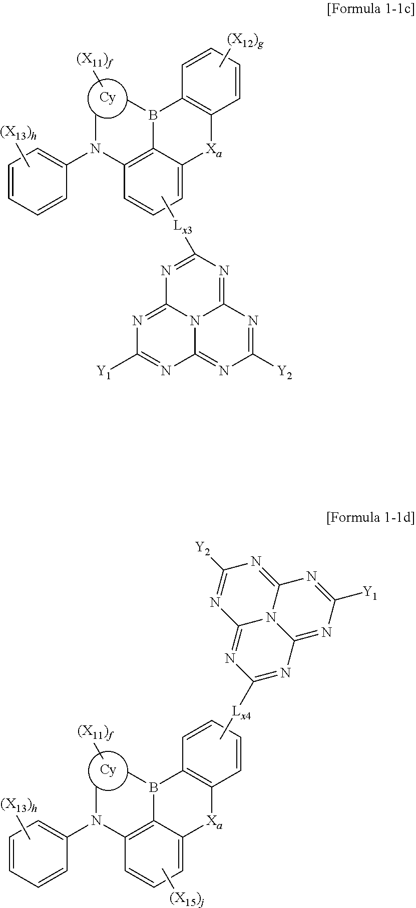
wherein in Formulas 1-1a to 1-1d,
Lₓ₁ to Lₓ₄ are each independently a direct linkage, a substituted or unsubstituted amine group, a substituted or unsubstituted arylene group having 6 to 20 ring-forming carbon atoms, or a substituted or unsubstituted heteroarylene group having 2 to 20 ring-forming carbon atoms,
Xₐ is N(Rₓ₁), O, S, Se, or Te, and
Rₓ₁ is a group represented by Formula 1b, 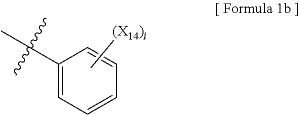
wherein in Formulas 1-1a to 1-1d and 1b,
X₁₁ to X₁₅ and X_{13′} are each independently a hydrogen atom, a cyano group, a substituted or unsubstituted oxy group, a substituted or unsubstituted alkyl group having 1 to 60 carbon atoms, a substituted or unsubstituted cycloalkyl group having 3 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring,
f and g are each independently an integer from 1 to 4,
h and i are each independently an integer from 1 to 5,
j is an integer from 1 to 3,
h′ is an integer from 0 to 4,
Cy is the same as defined in Formula 1, and
Y₁ and Y₂ are the same as defined in Formula 2.

18. The polycyclic compound of claim 16, wherein Formula 1 is represented by one of Formulas 1-2a to 1-2d: 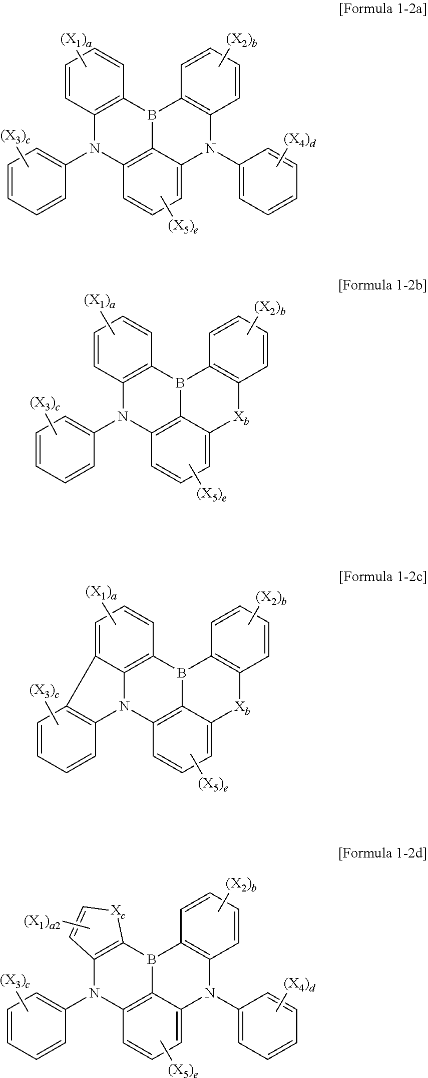
wherein in Formulas 1-2a to 1-2d,
a1 is an integer from 1 to 3,
a2 is 1 or 2,
c1 is an integer from 1 to 4,
X_{b} and X_{c} are each independently O, S, Se, or Te, and
X₁ to X₅ and a to e are the same as defined in Formula 1.

19. The polycyclic compound of claim 16, wherein the group represented by Formula 2 is represented by one of Formulas 2-1 to 2-3: 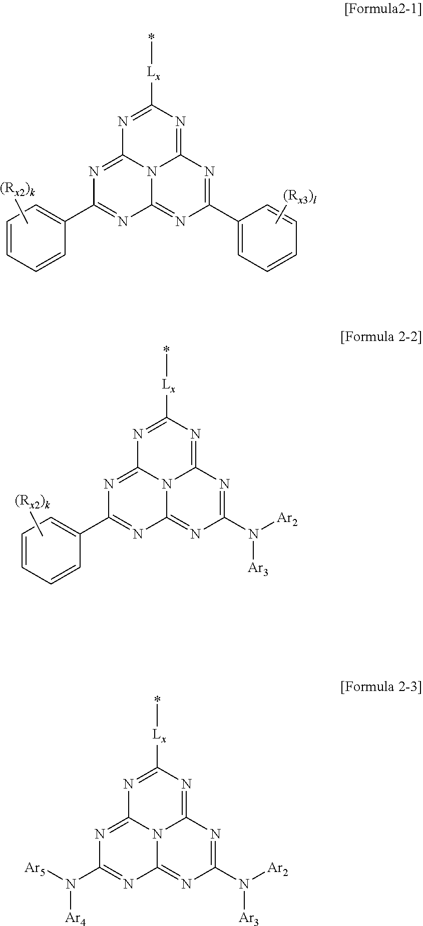
wherein in Formulas 2-1 to 2-3,
Rₓ₂ and Rₓ₃ are each independently a hydrogen atom or a t-butyl group,
k and l are each independently an integer from 0 to 5,
Ar₂ to Ar₅ are each independently an unsubstituted phenyl group, or bonded to an adjacent group to form a ring, and
Lₓ and -* are the same as defined in Formula 2.

20. The polycyclic compound of claim 16, wherein the polycyclic compound represented by Formula 1 is selected from Compound Group 1: 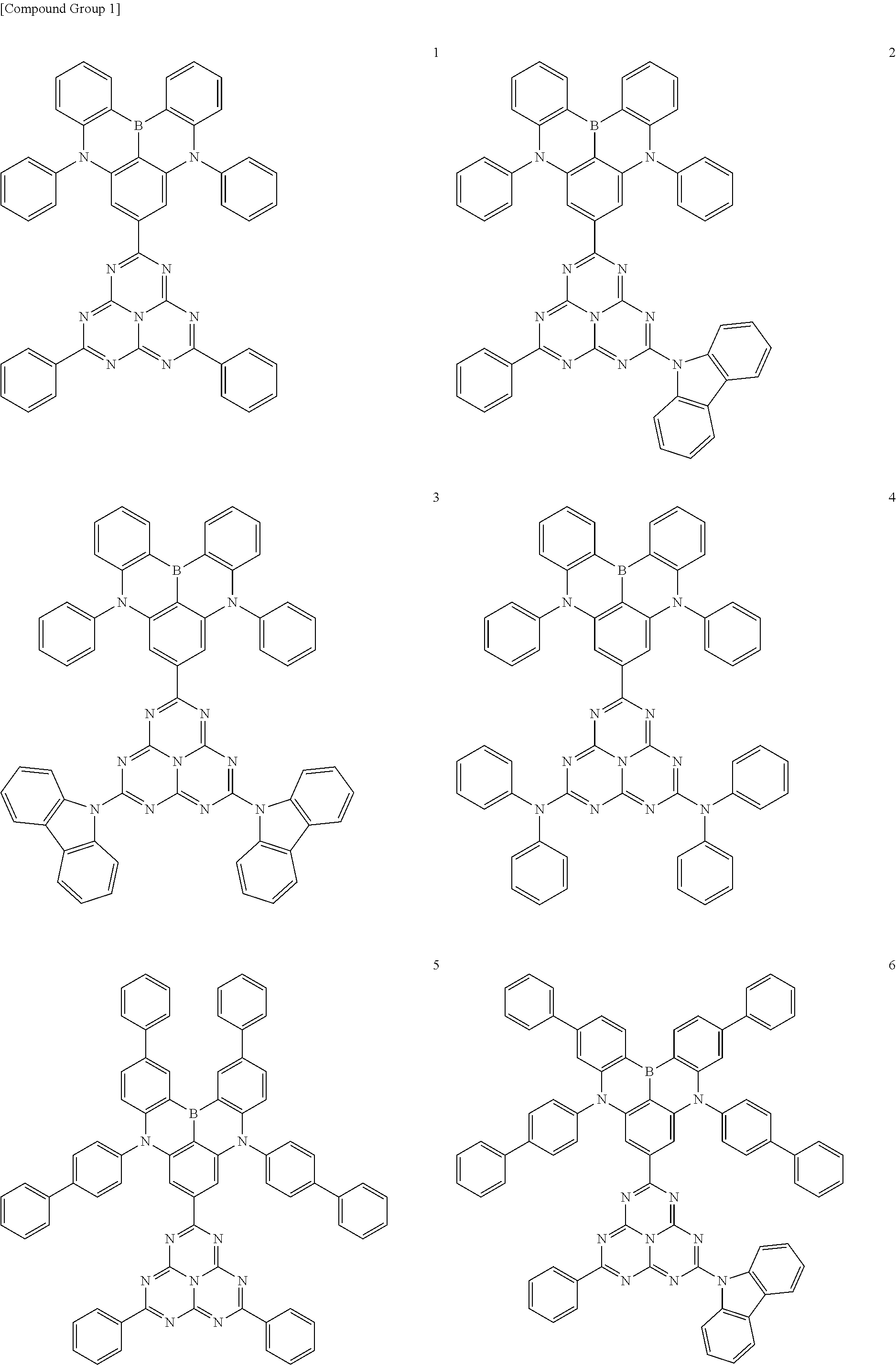 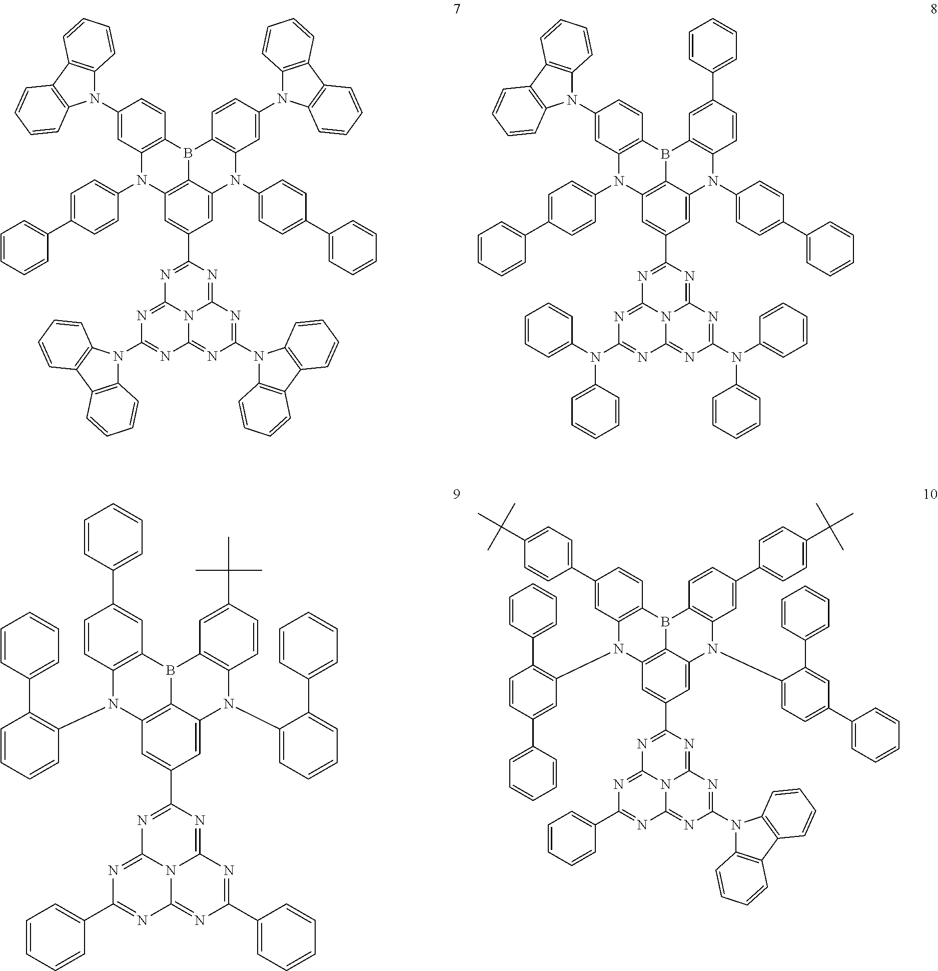 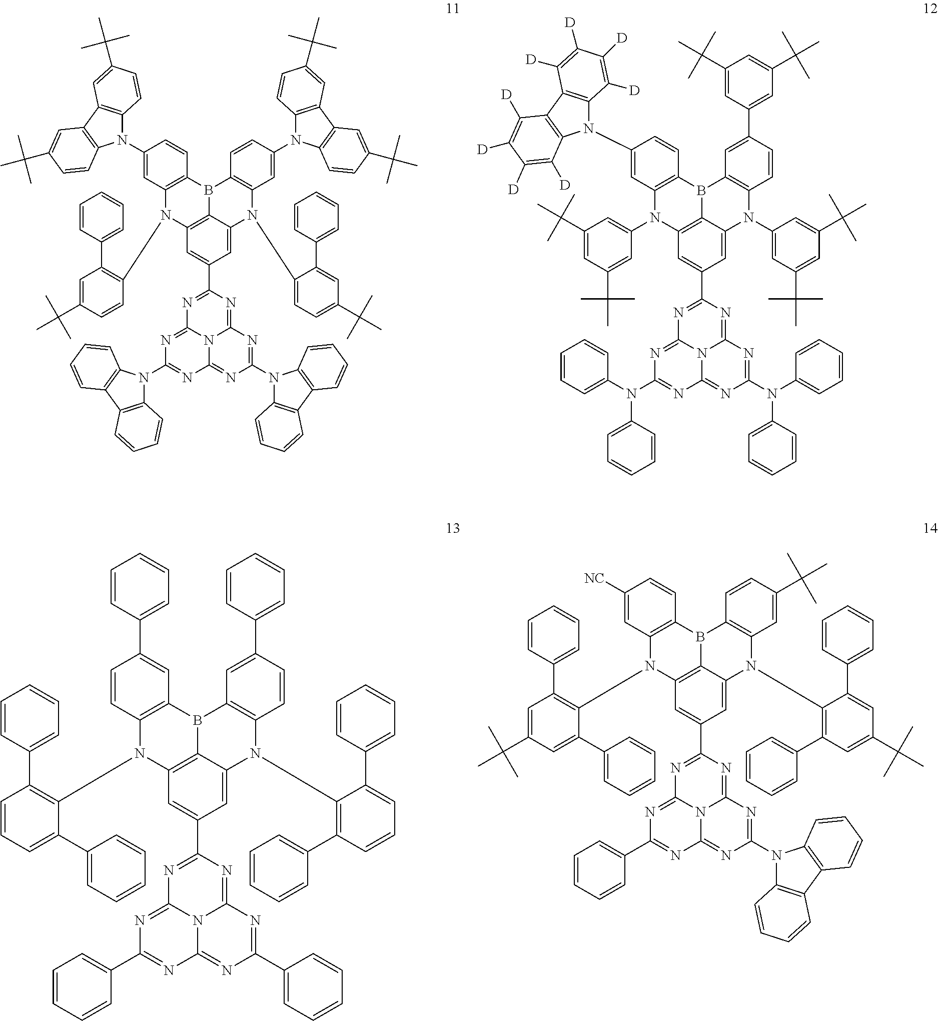 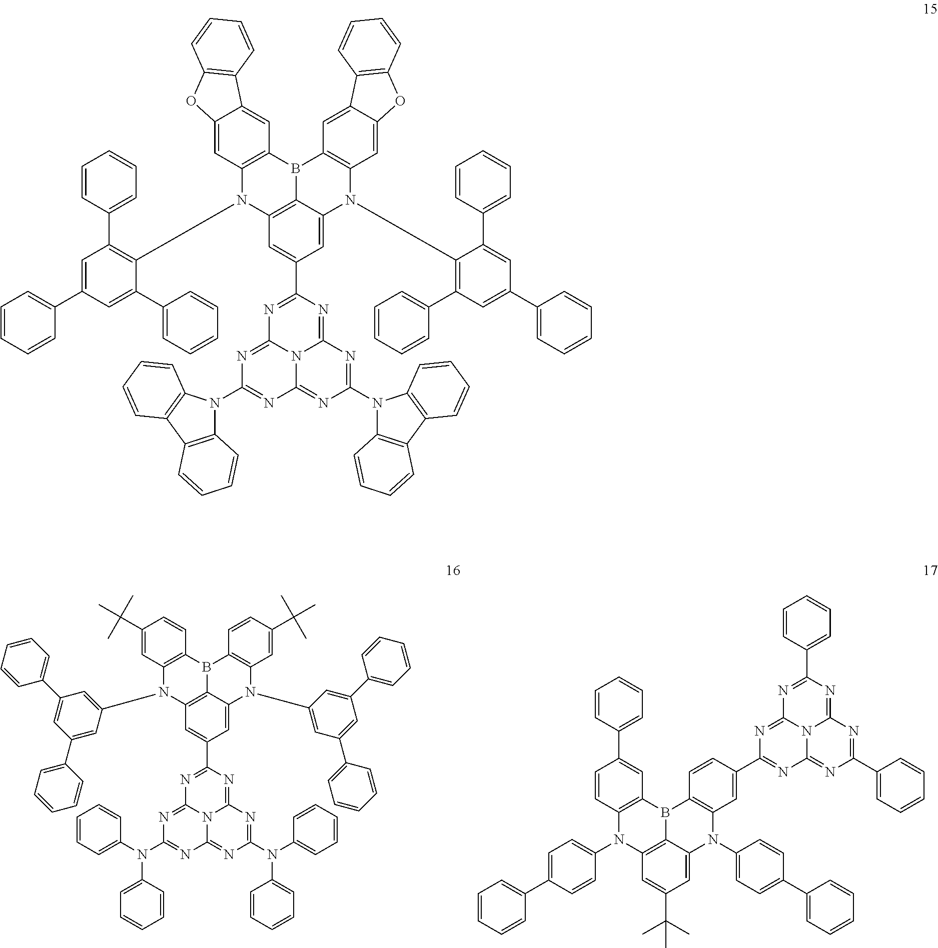 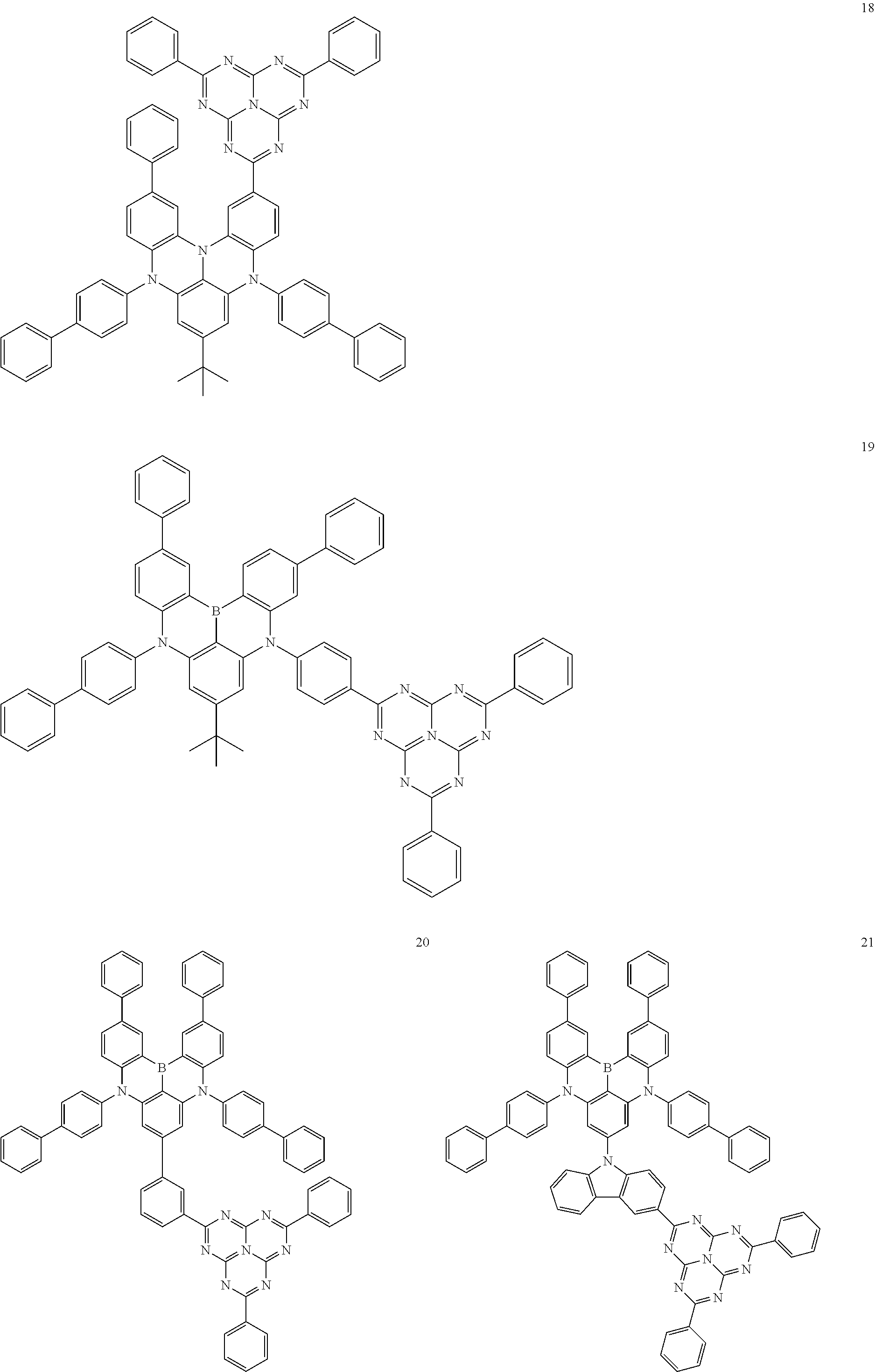 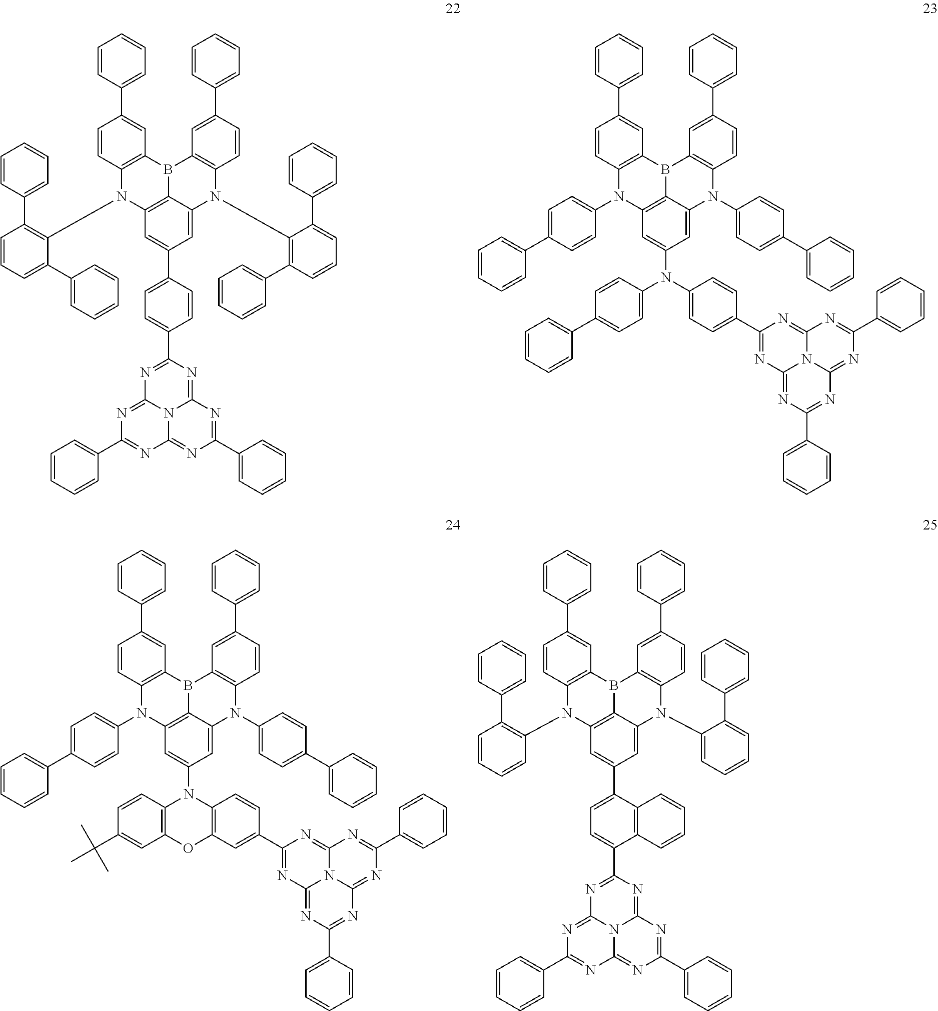 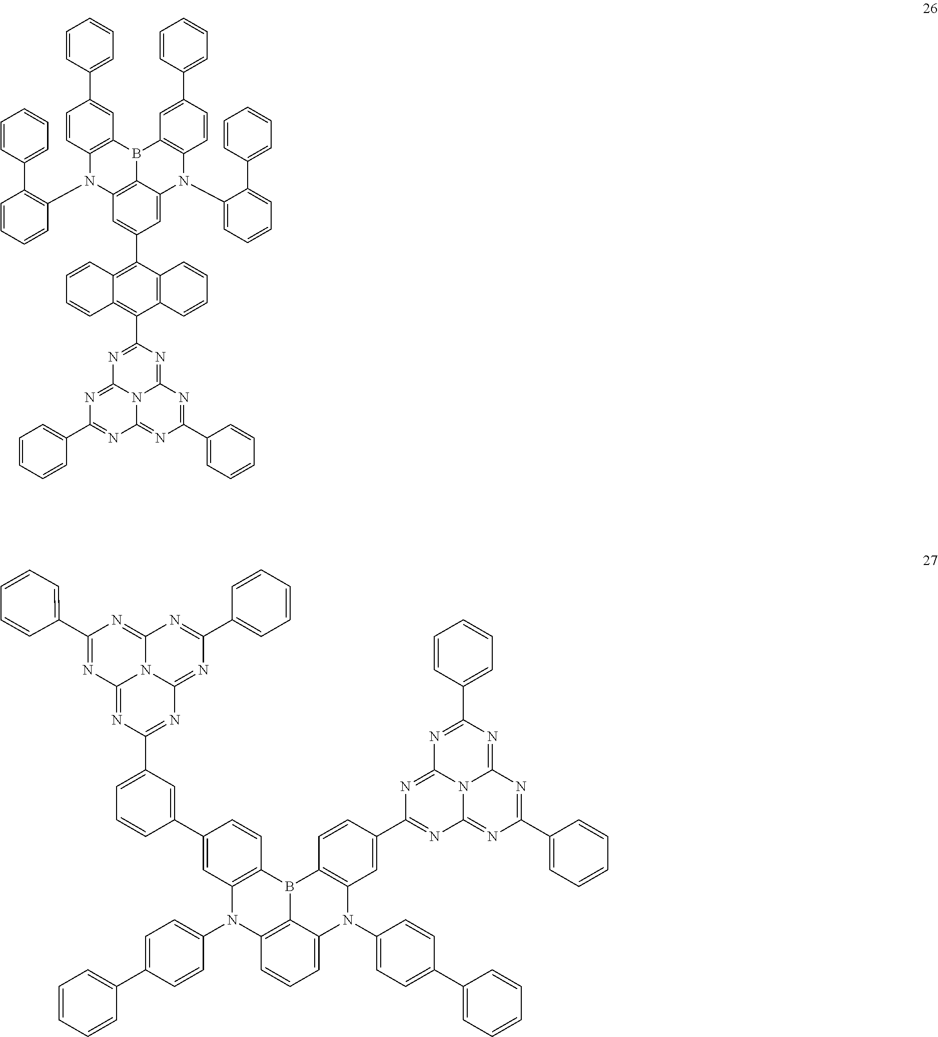 [SMILES: c1ccc(C2=NC3=NC(c4ccccc4)=NC4=NC(c5c6ccccc6c(-c6cc7c8c(c6)N(c6ccccc6-c6ccccc6)c6ccc(-c9ccccc9)cc6B8c6cc(-c8ccccc8)ccc6N7c6ccccc6-c6ccccc6)c6ccccc56)=NC(=N2)N34)cc1 ; c1ccc(C2=NC3=NC(c4ccccc4)=NC4=NC(c5cccc(-c6ccc7c(c6)N(c6ccc(-c8ccccc8)cc6)c6cccc8c6B7c6ccc(C7=NC9=NC(c%10ccccc%10)=NC%10=NC(c%11ccccc%11)=NC(=N7)N%109)cc6N8c6ccc(-c7ccccc7)cc6)c5)=NC(=N2)N34)cc1] 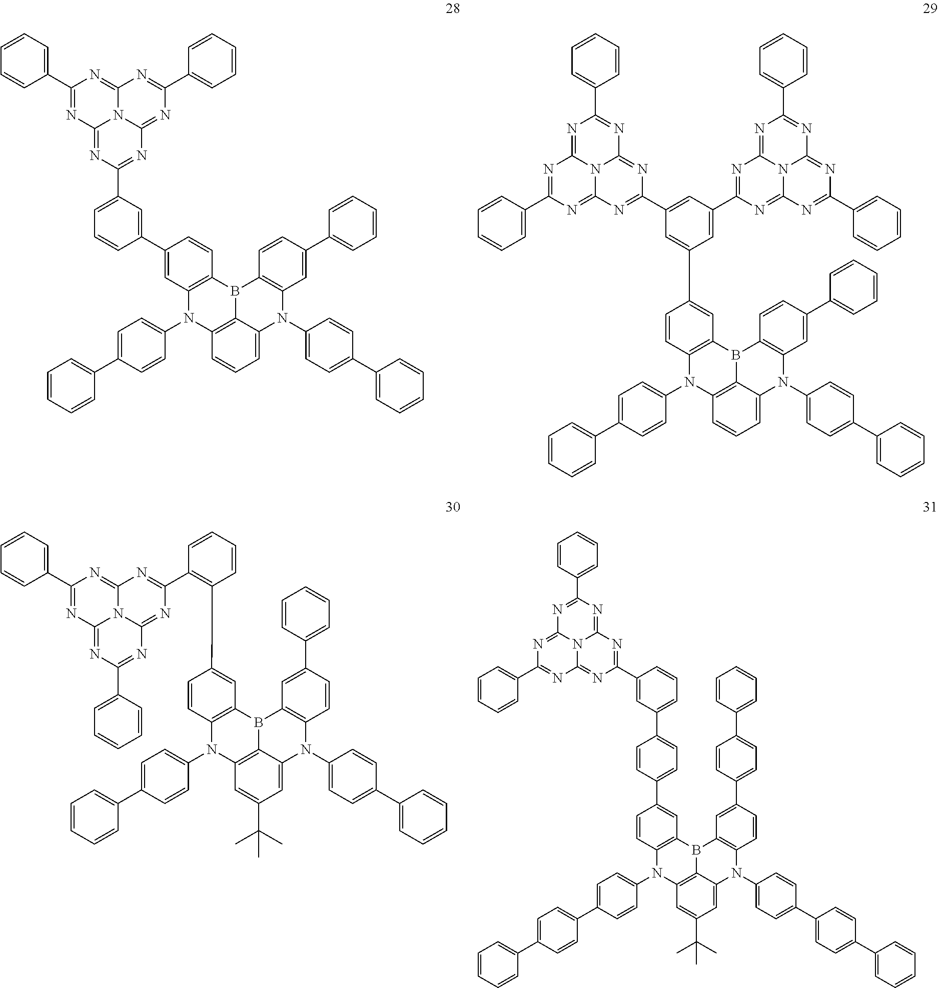 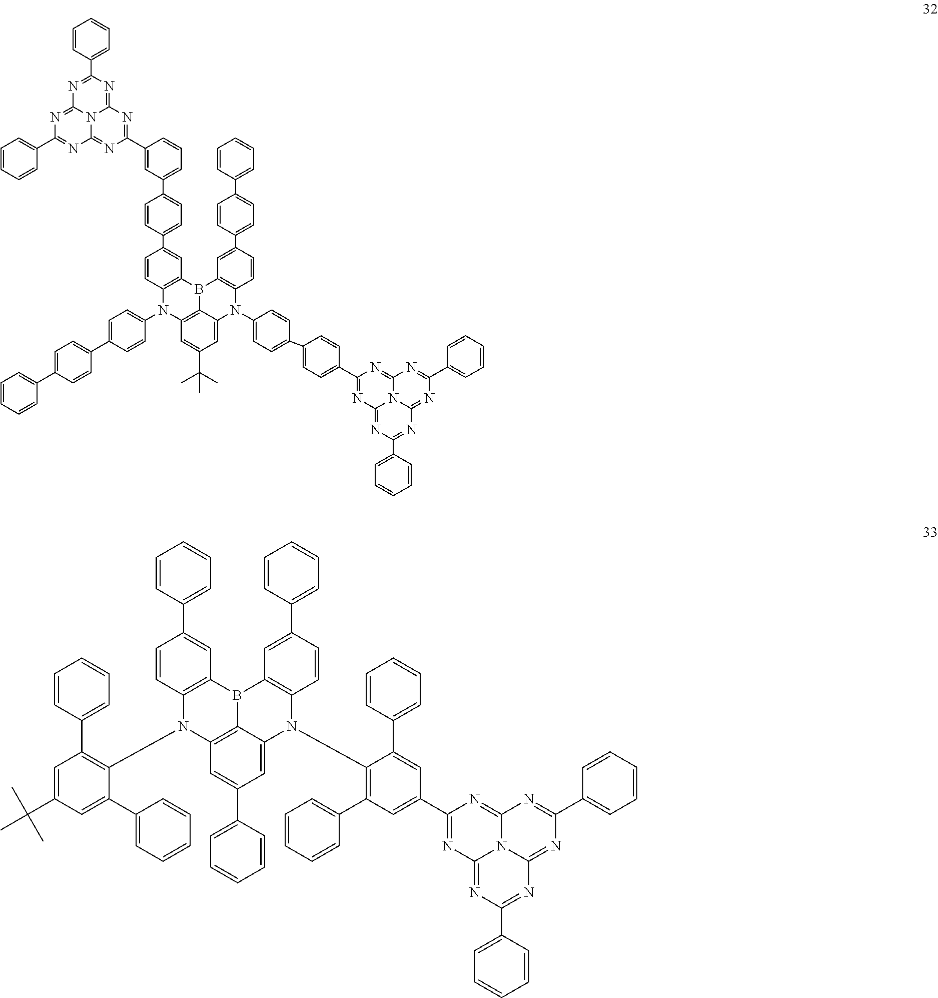 [SMILES: CC(C)(C)c1cc2c3c(c1)N(c1ccc(-c4ccc(-c5ccccc5)cc4)cc1)c1ccc(-c4ccc(-c5cccc(C6=NC7=NC(c8ccccc8)=NC8=NC(c9ccccc9)=NC(=N6)N87)c5)cc4)cc1B3c1cc(-c3ccc(-c4ccccc4)cc3)ccc1N2c1ccc(-c2ccc(C3=NC4=NC(c5ccccc5)=NC5=NC(c6ccccc6)=NC(=N3)N54)cc2)cc1 ; CC(C)(C)c1cc(-c2ccccc2)c(N2c3ccc(-c4ccccc4)cc3B3c4cc(-c5ccccc5)ccc4N(c4c(-c5ccccc5)cc(C5=NC6=NC(c7ccccc7)=NC7=NC(c8ccccc8)=NC(=N5)N76)cc4-c4ccccc4)c4cc(-c5ccccc5)cc2c43)c(-c2ccccc2)c1] 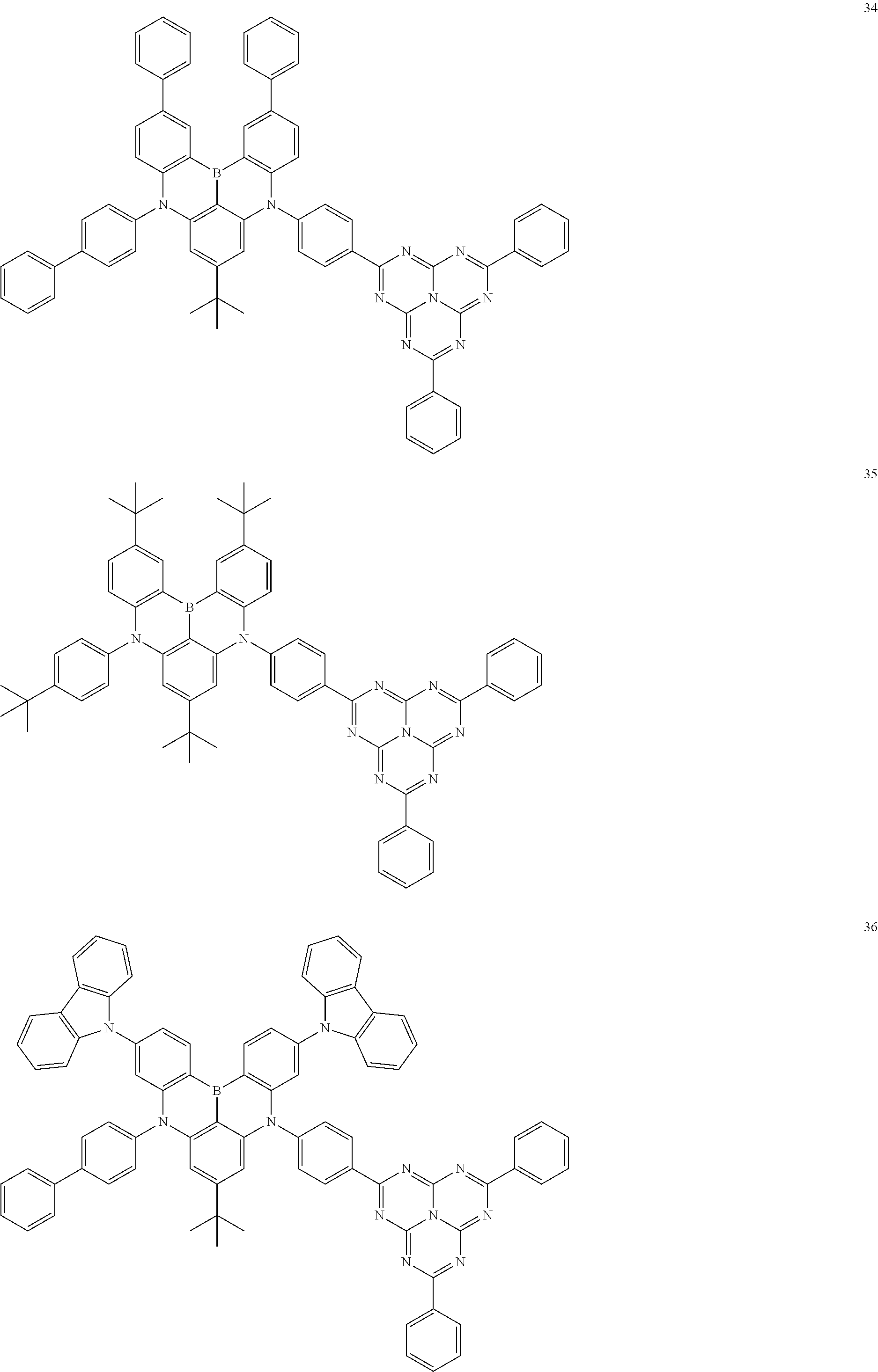 [SMILES: CC(C)(C)c1cc2c3c(c1)N(c1ccc(-c4ccccc4)cc1)c1ccc(-c4ccccc4)cc1B3c1cc(-c3ccccc3)ccc1N2c1ccc(C2=NC3=NC(c4ccccc4)=NC4=NC(c5ccccc5)=NC(=N2)N43)cc1 ; CC(C)(C)c1ccc(N2c3ccc(C(C)(C)C)cc3B3c4cc(C(C)(C)C)ccc4N(c4ccc(C5=NC6=NC(c7ccccc7)=NC7=NC(c8ccccc8)=NC(=N5)N76)cc4)c4cc(C(C)(C)C)cc2c43)cc1 ; CC(C)(C)c1cc2c3c(c1)N(c1ccc(-c4ccccc4)cc1)c1cc(-n4c5ccccc5c5ccccc54)ccc1B3c1ccc(-n3c4ccccc4c4ccccc43)cc1N2c1ccc(C2=NC3=NC(c4ccccc4)=NC4=NC(c5ccccc5)=NC(=N2)N43)cc1] 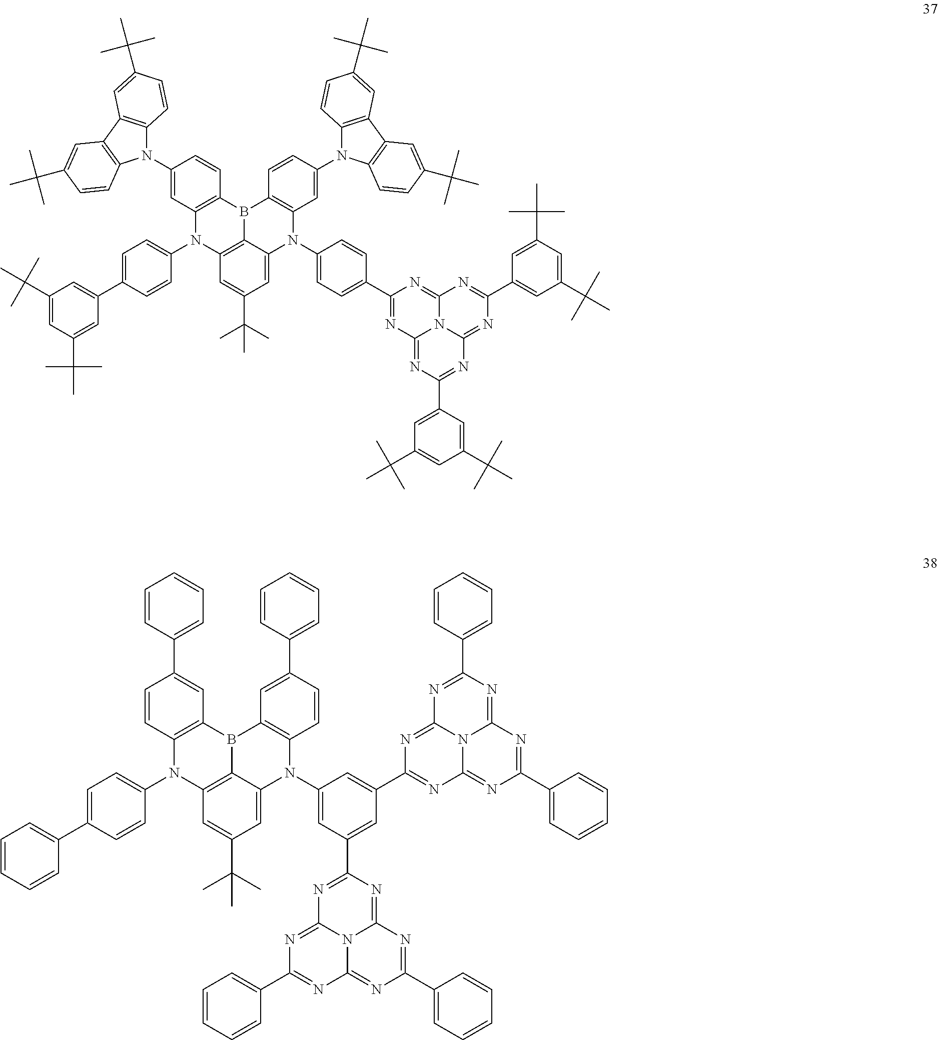 [SMILES: CC(C)(C)c1cc(C2=NC3=NC(c4ccc(N5c6cc(-n7c8ccc(C(C)(C)C)cc8c8cc(C(C)(C)C)ccc87)ccc6B6c7ccc(-n8c9ccc(C(C)(C)C)cc9c9cc(C(C)(C)C)ccc98)cc7N(c7ccc(-c8cc(C(C)(C)C)cc(C(C)(C)C)c8)cc7)c7cc(C(C)(C)C)cc5c76)cc4)=NC4=NC(c5cc(C(C)(C)C)cc(C(C)(C)C)c5)=NC(=N2)N34)cc(C(C)(C)C)c1 ; CC(C)(C)c1cc2c3c(c1)N(c1cc(C4=NC5=NC(c6ccccc6)=NC6=NC(c7ccccc7)=NC(=N4)N65)cc(C4=NC5=NC(c6ccccc6)=NC6=NC(c7ccccc7)=NC(=N4)N65)c1)c1ccc(-c4ccccc4)cc1B3c1cc(-c3ccccc3)ccc1N2c1ccc(-c2ccccc2)cc1] 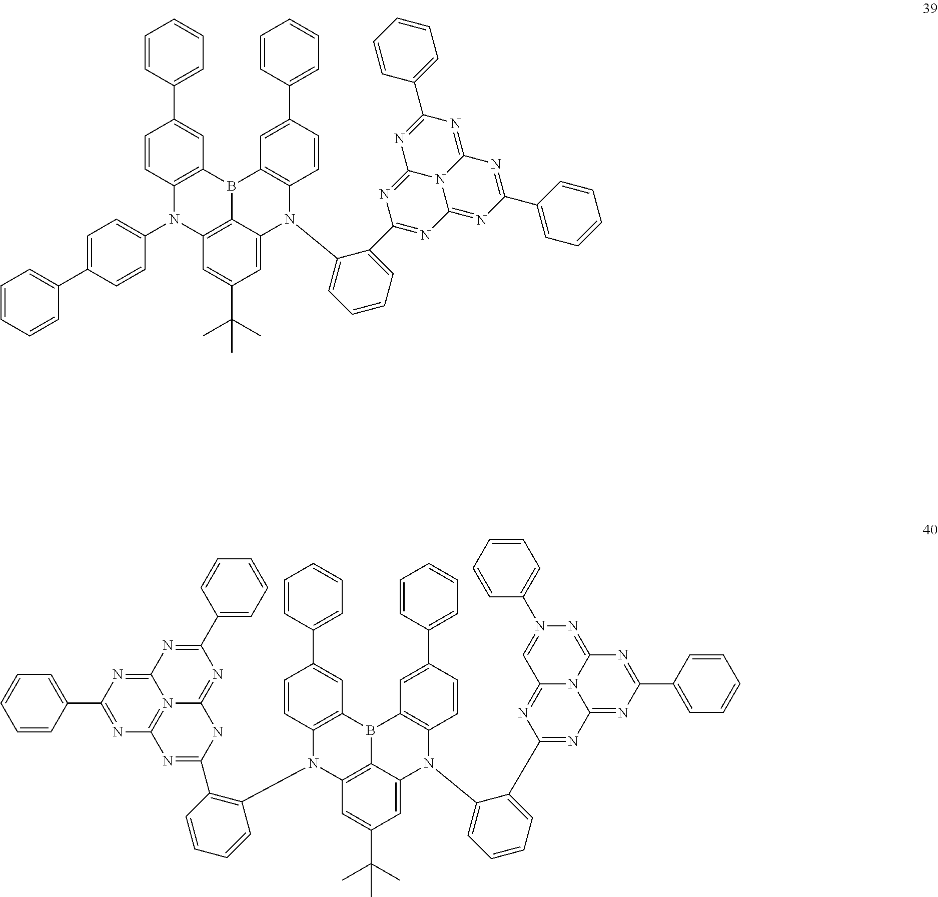 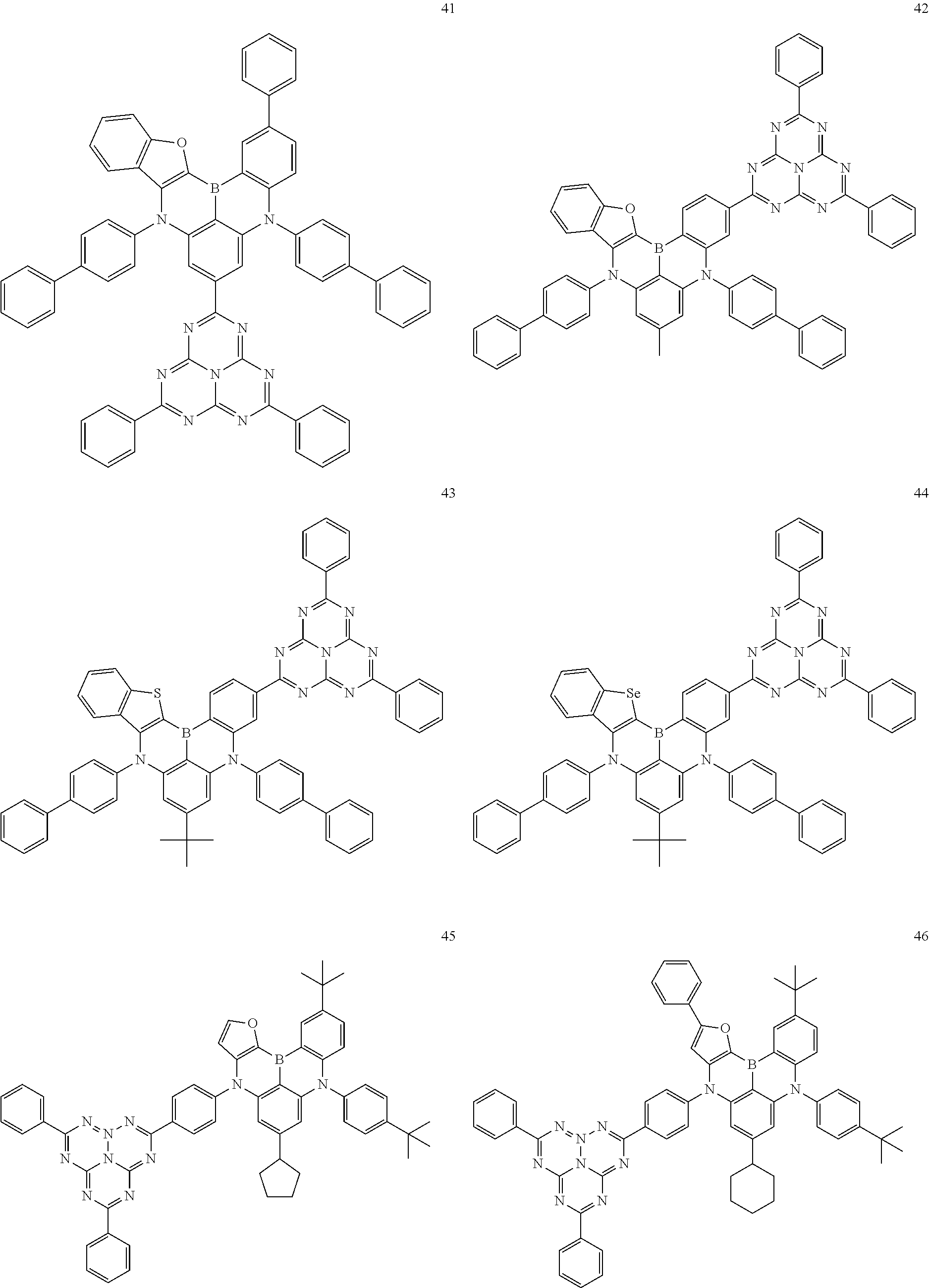 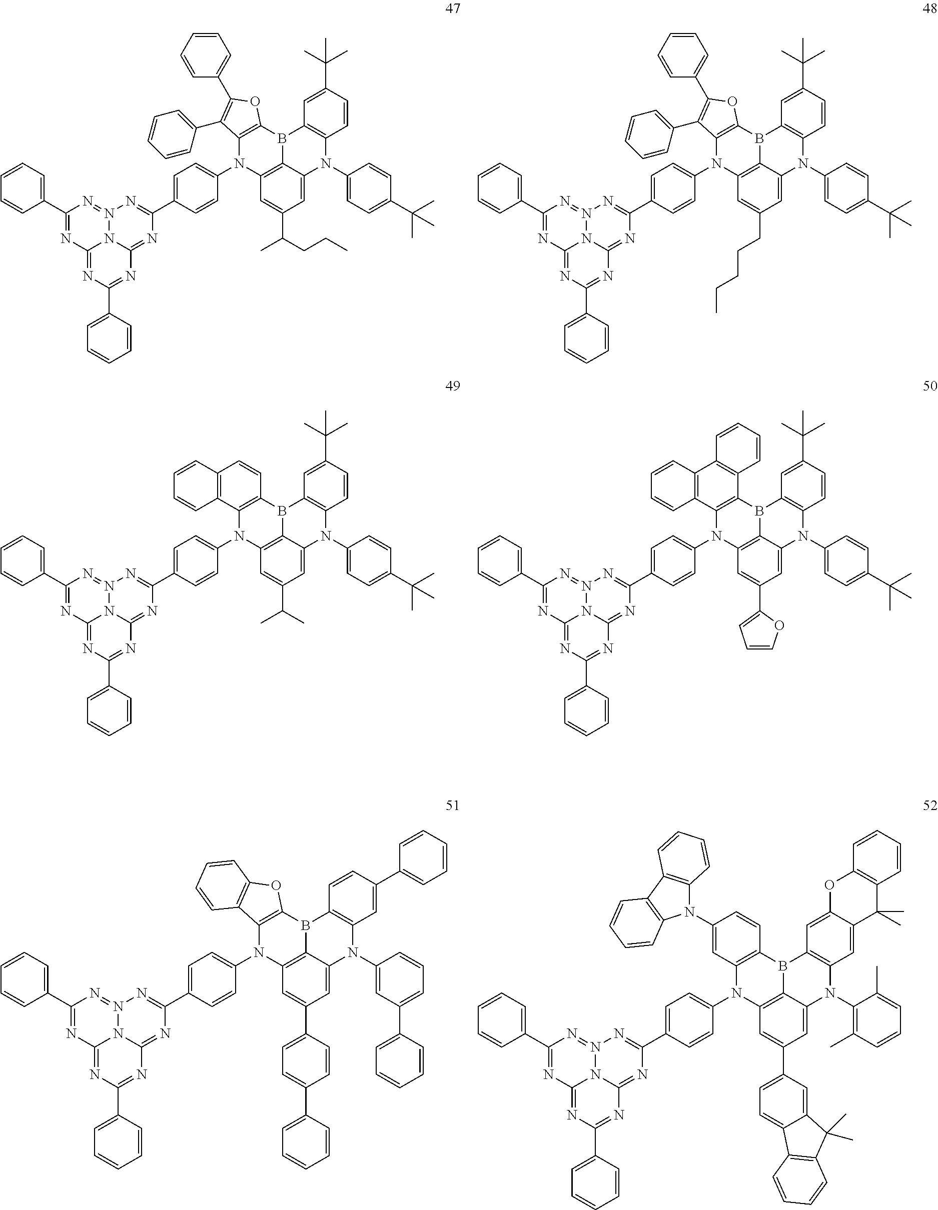 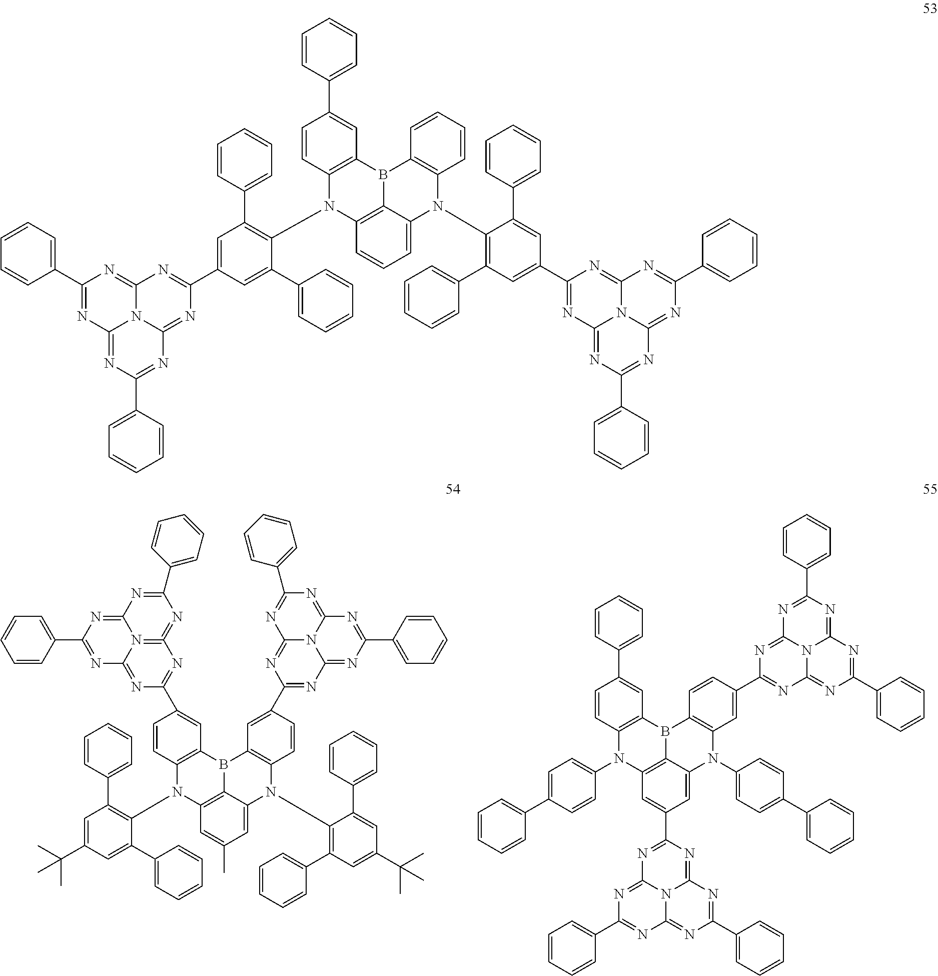 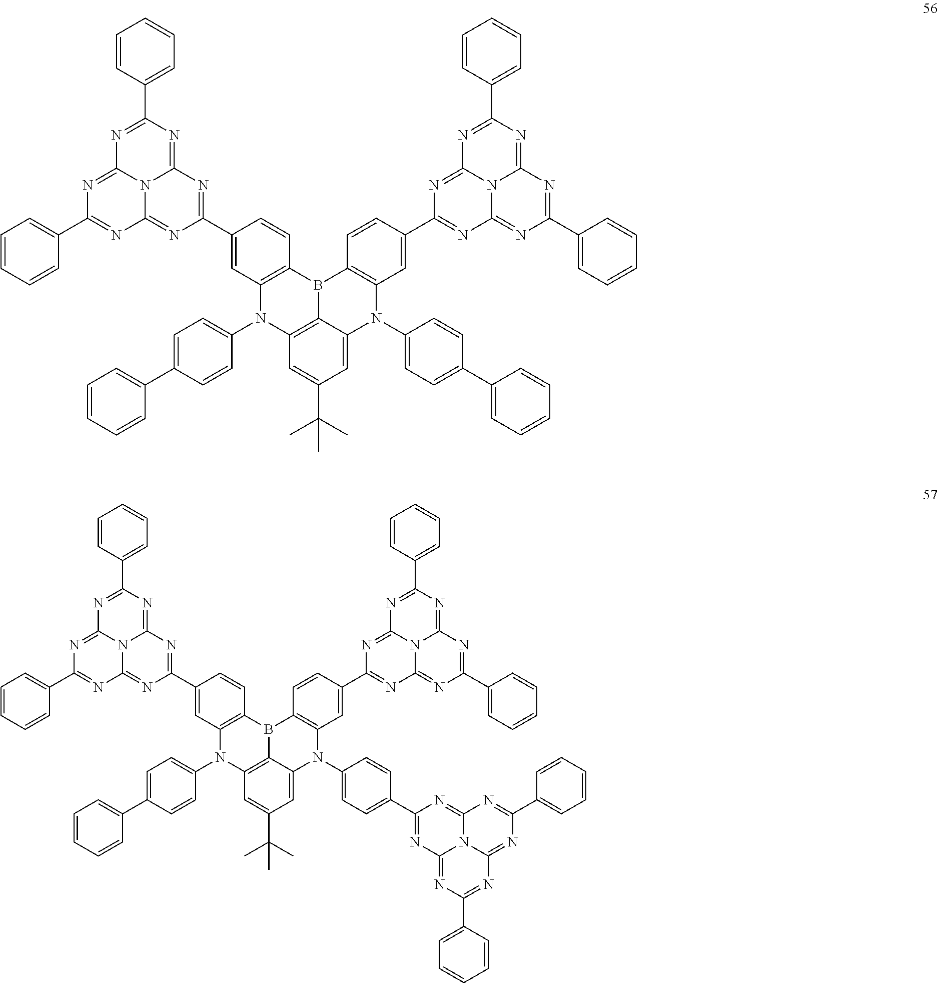 [SMILES: CC(C)(C)c1cc2c3c(c1)N(c1ccc(-c4ccccc4)cc1)c1cc(C4=NC5=NC(c6ccccc6)=NC6=NC(c7ccccc7)=NC(=N4)N65)ccc1B3c1ccc(C3=NC4=NC(c5ccccc5)=NC5=NC(c6ccccc6)=NC(=N3)N54)cc1N2c1ccc(-c2ccccc2)cc1 ; CC(C)(C)c1cc2c3c(c1)N(c1ccc(-c4ccccc4)cc1)c1cc(C4=NC5=NC(c6ccccc6)=NC6=NC(c7ccccc7)=NC(=N4)N65)ccc1B3c1ccc(C3=NC4=NC(c5ccccc5)=NC5=NC(c6ccccc6)=NC(=N3)N54)cc1N2c1ccc(C2=NC3=NC(c4ccccc4)=NC4=NC(c5ccccc5)=NC(=N2)N43)cc1] 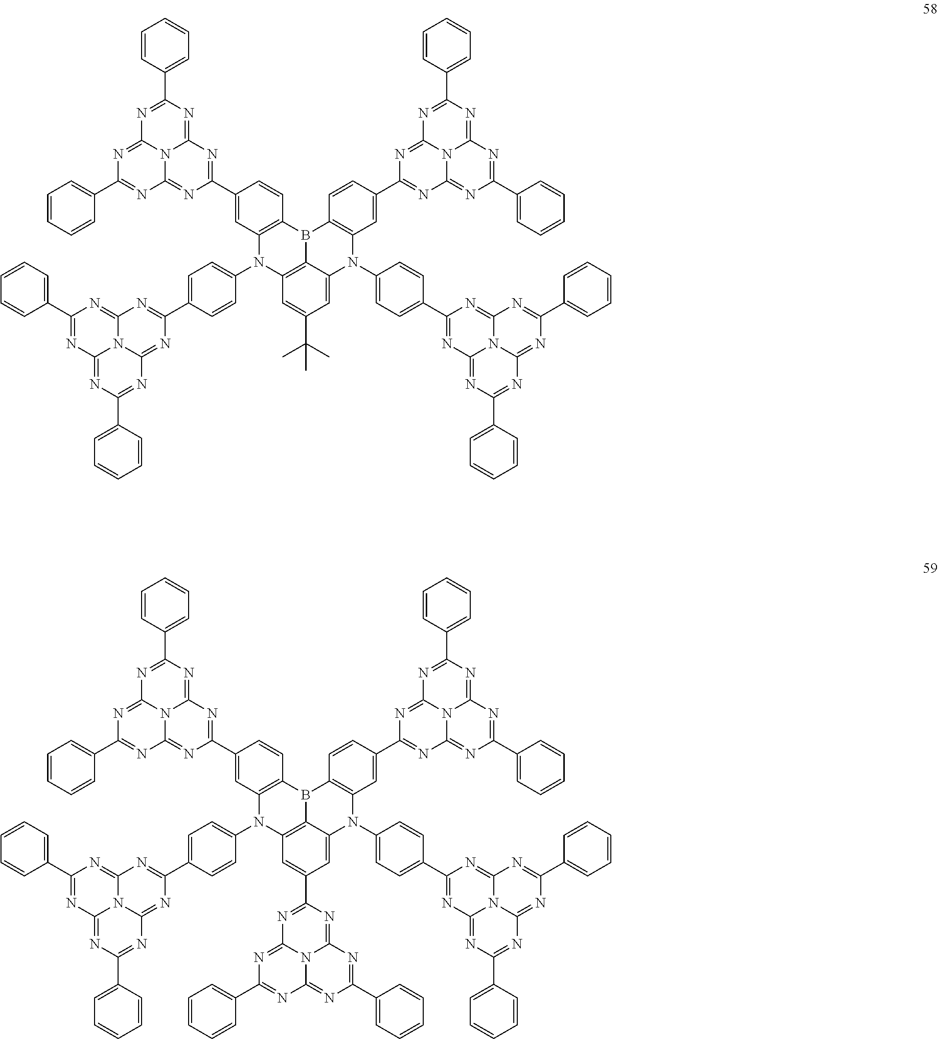 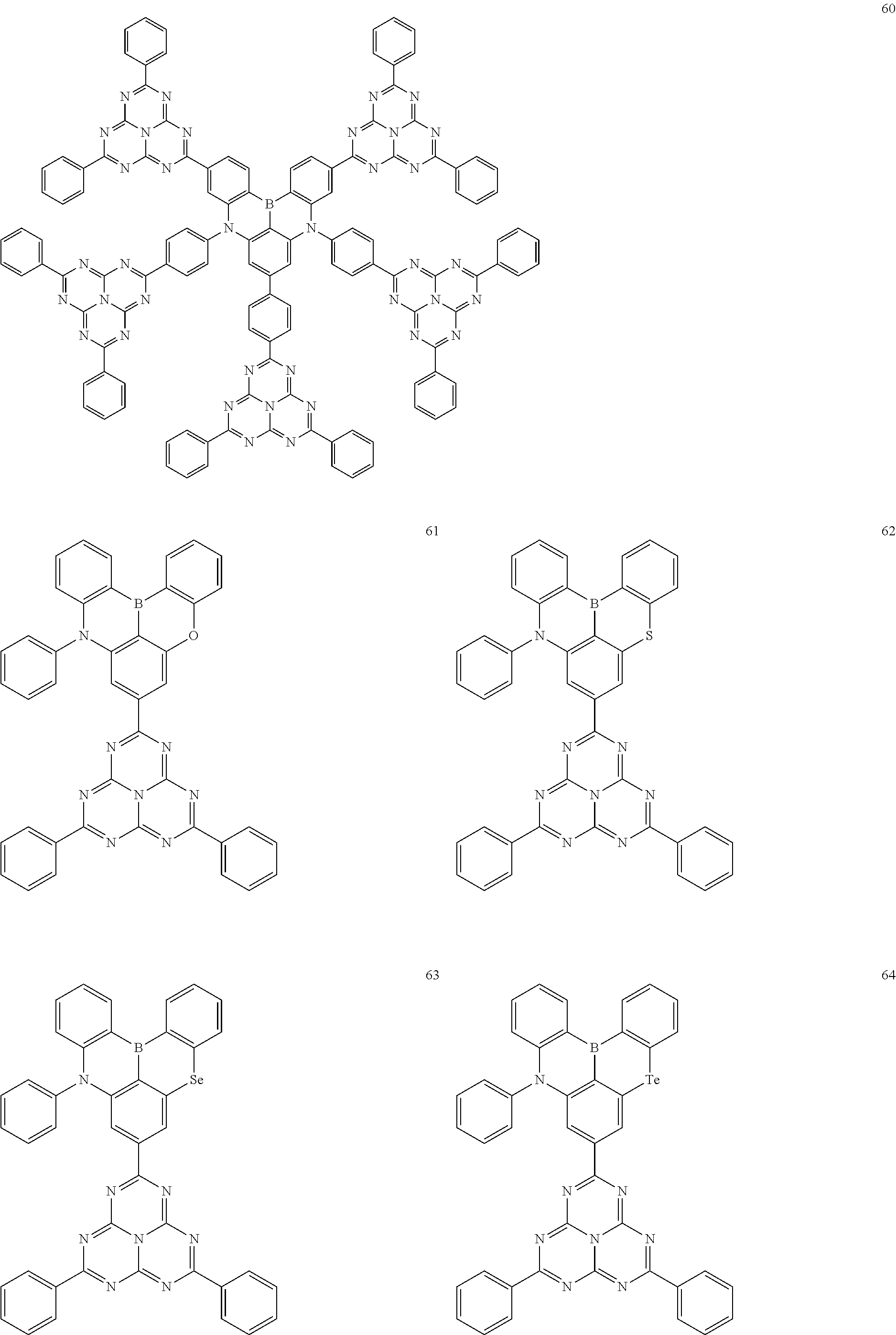 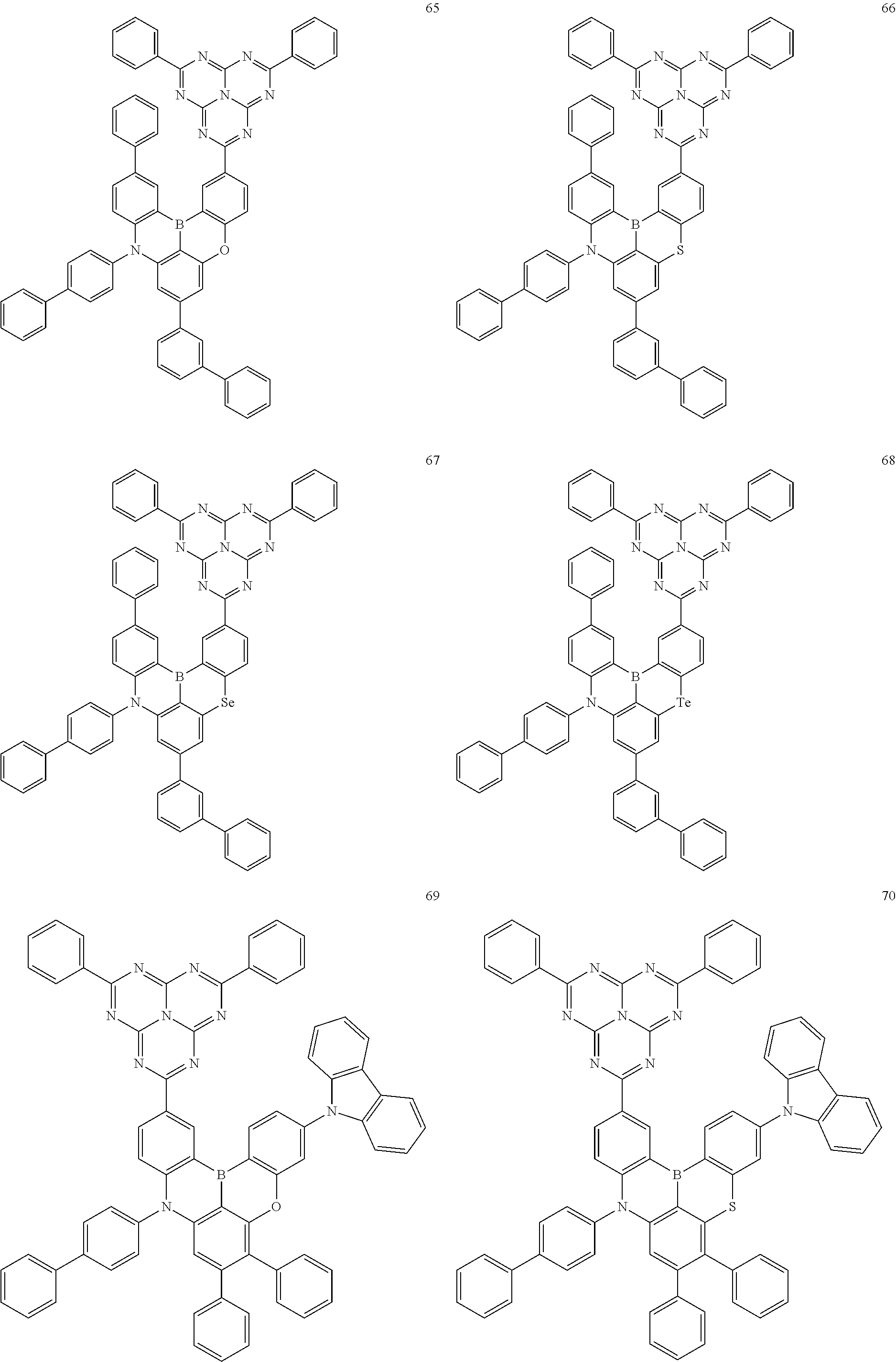 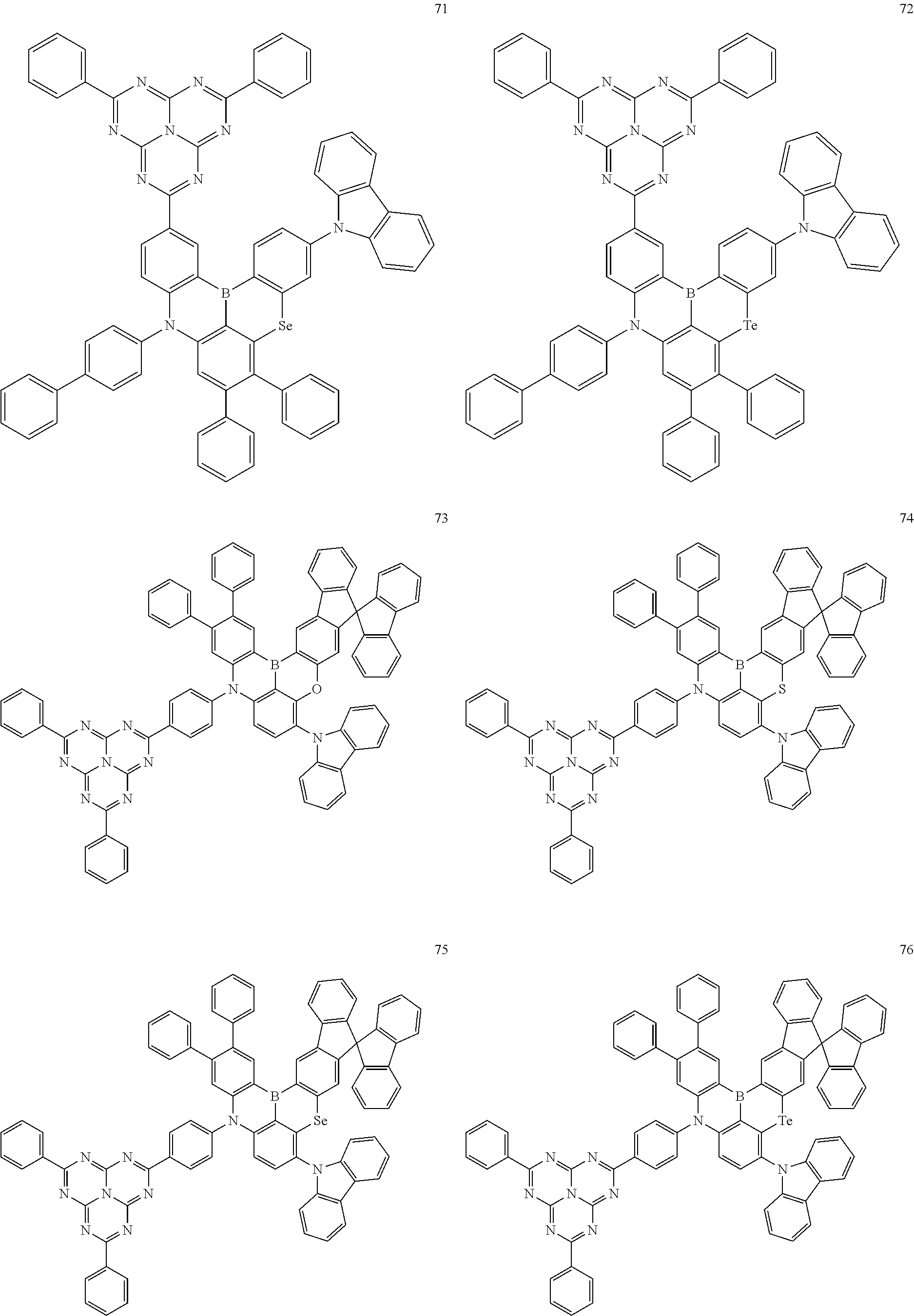 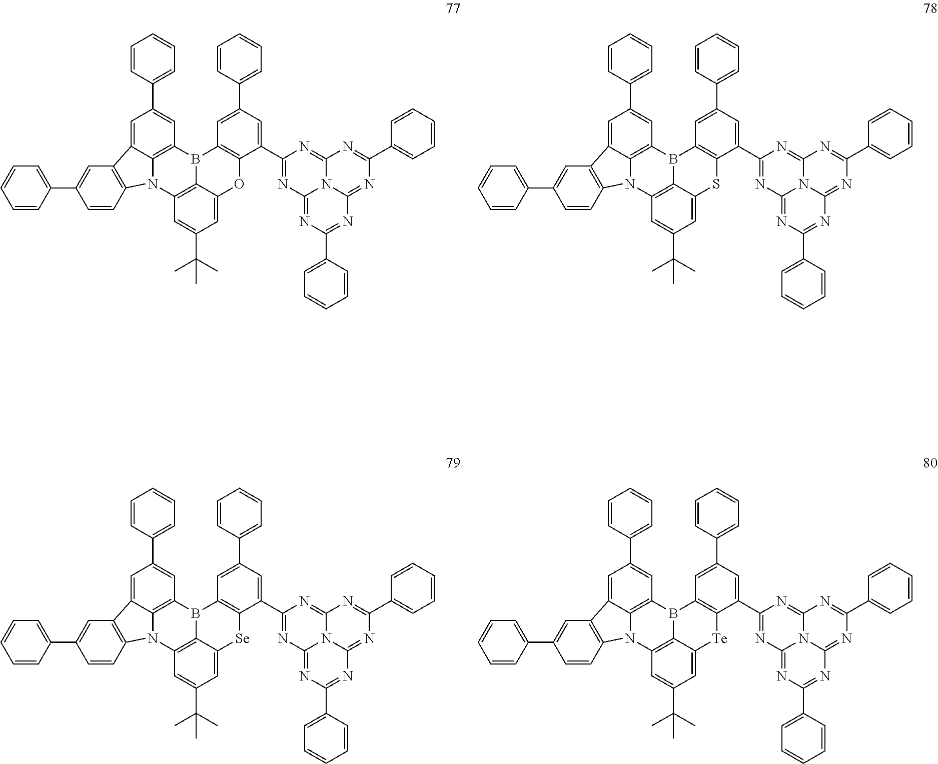
wherein in Compound Group 1,
D represents a deuterium atom.

21. A display device comprising:
a base layer;
a circuit layer disposed on the base layer; and
a display element layer disposed on the circuit layer and comprising a light emitting element, wherein
the light emitting element comprises:
a first electrode;
a second electrode facing the first electrode; and
at least one functional layer disposed between the first electrode and the second electrode, and
the at least one functional layer comprises:
a first compound represented by Formula 1; and
at least one of a second compound represented by Formula HT and a third compound represented by Formula ET: 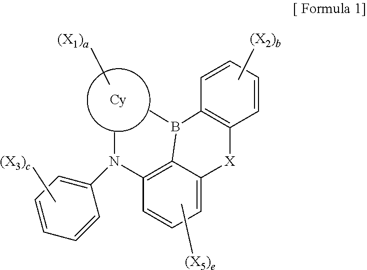
wherein in Formula 1,
Cy is a substituted or unsubstituted hydrocarbon ring having 5 to 30 ring-forming carbon atoms or a substituted or unsubstituted heterocycle having 2 to 30 ring-forming carbon atoms,
X is N(Rₓ), O, S, Se, or Te, and
Rₓ is a group represented by Formula 1a, 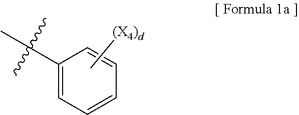
wherein in Formulas 1 and 1a,
a and b are each independently an integer from 1 to 4,
c and d are each independently an integer from 1 to 5,
e is an integer from 1 to 3, and
at least one of X₁ to X₅ is each independently a group represented by Formula 2,
the remainder of X₁ to X₅ are each independently a hydrogen atom, a cyano group, a substituted or unsubstituted oxy group, a substituted or unsubstituted alkyl group having 1 to 60 carbon atoms, a substituted or unsubstituted cycloalkyl group having 3 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring, 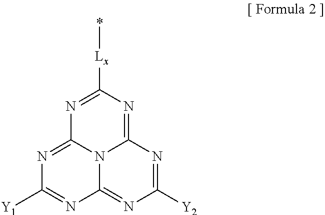
wherein in Formula 2,
Lₓ is a direct linkage, a substituted or unsubstituted amine group, a substituted or unsubstituted arylene group having 6 to 60 carbon atoms, or a substituted or unsubstituted heteroarylene group having 2 to 60 ring-forming carbon atoms,
Y₁ and Y₂ are each independently a substituted or unsubstituted amine group, a substituted or unsubstituted aryl group having 6 to 60 ring-forming carbon atoms, or a substituted or unsubstituted heteroaryl group having 2 to 60 ring-forming carbon atoms, and
-* represents a bond to neighboring atom in Formula 1, 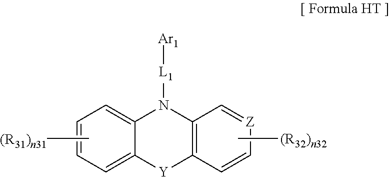
wherein in Formula HT,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Ar₁ is a substituted or unsubstituted aryl group having 6 to 30 ring-forming carbon atoms or a substituted or unsubstituted heteroaryl group having 2 to 30 ring-forming carbon atoms,
Y is a direct linkage, C(R_{y1})(R_{y2}), or Si(R_{y3})(R_{y4}),
Z is C(R_{z}) or N,
R_{y1} to R_{y4}, R₃₁, R₃₂, and R_{z} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring,
n31 is an integer from 0 to 4, and
n32 is an integer from 0 to 3, and 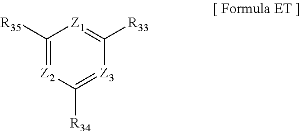
wherein in Formula ET,
Z₁ to Z₃ are each independently N or C(R₃₆),
at least one of Z₁ to Z₃ is each N, and
R₃₃ to R₃₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

22. The display device of claim 21, wherein
the at least one functional layer comprises:
an emission layer;
a hole transport region disposed between the first electrode and the emission layer; and
an electron transport region disposed between the emission layer and the second electrode, and
the emission layer comprises:
the first compound; and
at least one of the second compound and the third compound.

23. The display device of claim 21, further comprising:
a light control layer disposed on the display element layer and including a quantum dot.
